(19) United States
(12) Patent Application Publication
(10) Pub. No.: US 2011/0008728 A1
(43) Pub. Date: Jan. 13, 2011

(54) RESIST COMPOSITION AND METHOD OF FORMING RESIST PATTERN

(75) Inventors: Tsuyoshi NAKAMURA, Kawasaki-shi (JP); Masaru TAKESHITA, Kawasaki-shi (JP); Jiro YOKOYA, Kawasaki-shi (JP); Hideo HADA, Kawasaki-shi (JP); Kensuke MATSUZAWA, Kawasaki-shi (JP); Kazushige DOHTANI, Kawasaki-shi (JP)

Correspondence Address: KNOBBE MARTENS OLSON & BEAR LLP, 2040 MAIN STREET, FOURTEENTH FLOOR, IRVINE, CA, 92614, US

(73) Assignee: TOKYO OHKA KOGYO CO., LTD., Kawasaki-shi (JP)

(21) Appl. No.: 12/788,160

(22) Filed: May 26, 2010

(30) Foreign Application Priority Data
May 29, 2009 (JP) 2009-130943

(51) Int. Cl. G03F 7/20; G03F 7/004

(52) U.S. Cl. 430/270.1; 430/326

(57) ABSTRACT

A resist composition including: a base component which exhibits changed solubility in an alkali developing solution under the action of acid; and an acid-generator component containing an acid generator (B1) consisting of a compound represented by general formula (b1); dissolved in an organic solvent containing an alcohol-based organic solvent having a boiling point of at least 150° C., wherein R⁷″ to R⁹″ represents an aryl group or an alkyl group, provided that at least one of R⁷″ to R⁹″ represents a substituted aryl group which has been substituted with a group represented by the formula: —O—R⁷⁰ (R⁷⁰ represents an organic group), and two of R⁷″ to R⁹″ may be mutually bonded to form a ring with the sulfur atom; X represents a hydrocarbon group of 3 to 30 carbon atoms; Q¹ represents a divalent linking group containing an oxygen atom; and Y¹ represents an alkylene group of 1 to 4 carbon atoms or a fluorinated alkylene group of 1 to 4 carbon atoms.

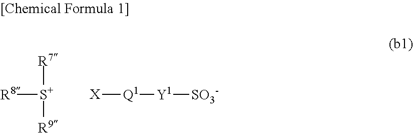

### TECHNICAL FIELD

The present invention relates to a resist composition and a method of forming a resist pattern.

Priority is claimed on Japanese Patent Application No. 2009-130943, filed May 29, 2009, the content of which is incorporated herein by reference.

### BACKGROUND ART

In lithography techniques, for example, a resist film composed of a resist material is formed on a substrate, and the resist film is subjected to selective exposure of radial rays such as light or electron beam through a mask having a predetermined pattern, followed by development, thereby forming a resist pattern having a predetermined shape on the resist film. A resist material in which the exposed portions become soluble in a developing solution is called a positive-type, and a resist material in which the exposed portions become insoluble in a developing solution is called a negative-type.

In recent years, in the production of semiconductor elements and liquid crystal display elements, advances in lithography techniques have lead to rapid progress in the field of pattern miniaturization.

Typically, these miniaturization techniques involve shortening the wavelength (increasing the energy) of the exposure light source. Conventionally, ultraviolet radiation typified by g-line and i-line radiation has been used, but nowadays KrF excimer lasers and ArF excimer lasers are starting to be introduced in mass production. Furthermore, research is also being conducted into lithography techniques that use an exposure light source having a wavelength shorter (energy higher) than these excimer lasers, such as electron beam, extreme ultraviolet radiation (EUV), and X ray.

Resist materials for use with these types of exposure light sources require lithography properties such as a high resolution capable of reproducing patterns of minute dimensions, and a high level of sensitivity to these types of exposure light sources. As a resist material which satisfies these conditions, a chemically amplified resist is used, which is obtained by dissolving a base resin that exhibits a changed solubility in an alkali developing solution under action of acid and an acid-generator component that generates acid upon exposure in an organic solvent. For example, a chemically amplified positive resist is obtained by dissolving, as a base resin, a resin which exhibits increased solubility in an alkali developing solution under action of acid, and an acid generator-component, in an organic solvent. In the formation of a resist pattern, when acid is generated from the acid generator upon exposure, the exposed portions become soluble in an alkali developing solution.

Until recently, polyhydroxystyrene (PHS) or derivative resins thereof in which the hydroxyl groups are protected with acid-dissociable, dissolution-inhibiting groups (PHS-based resins), which exhibit high transparency to a KrF excimer laser (248 nm), have been used as the base resin component of chemically amplified resists. However, because PHS-based resins contain aromatic rings such as benzene rings, their transparency is inadequate for light with wavelengths shorter than 248 nm, such as light of 193 nm. Accordingly, chemically amplified resists that use a PHS-based resin as the base resin component suffer from low levels of resolution in processes that use light of 193 nm.

Resins that contain structural units derived from (meth)acrylate esters within the main chain (acrylic resins) are now widely used as base resins for resists that use ArF excimer laser lithography, as they exhibit excellent transparency in the vicinity of 193 nm (for example, see Patent Document 1).

On the other hand, as acid generators usable in a chemically amplified resist, various types have been proposed including, for example, onium salt acid generators such as iodonium salts and sulfonium salts; oxime sulfonate acid generators; diazomethane acid generators; nitrobenzylsulfonate acid generators; iminosulfonate acid generators; and disulfone acid generators.

Currently, as acid generators, onium salt acid generators having an onium ion such as triphenylsulfonium as the cation moiety are used. As the anion moiety for onium salt acid generators, an alkylsulfonate ion or a fluorinated alkylsulfonate ion in which part or all of the hydrogen atoms within the aforementioned alkylsulfonate ion has been substituted with fluorine atoms is typically used (for example, see Patent Document 2).

Further, chemically amplified resist compositions in which the aforementioned acrylic resins and acid generators are dissolved in an organic solvent, such as propylene glycol monomethyl ether acetate (PGMEA), propylene glycol monomethyl ether (PGME), cyclohexanone (CH), 2-heptanone and ethyl lactate (EL) are now widely used as resists that use ArF excimer laser lithography or the like.

As a technique for further improving the resolution of the resist pattern, a lithography method called liquid immersion lithography (hereafter, frequently referred to as “immersion exposure”) is known in which exposure (immersion exposure) is conducted in a state where the region between the lens and the resist layer formed on a wafer is filled with a solvent (a immersion medium) that has a larger refractive index than the refractive index of air (see for example, Non-Patent Document 1).

According to this type of immersion exposure, it is considered that higher resolutions equivalent to those obtained using a shorter wavelength light source or a larger NA lens can be obtained using the same exposure light source wavelength, with no lowering of the depth of focus. Furthermore, immersion exposure can be conducted by applying a conventional exposure apparatus. As a result, it is expected that immersion exposure will enable the formation of resist patterns of higher resolution and superior depth of focus at lower costs. Accordingly, in the production of semiconductor devices, which requires enormous capital investment, immersion exposure is attracting considerable attention as a method that offers significant potential to the semiconductor industry, both in terms of cost and in terms of lithography properties such as resolution.

Immersion lithography is effective in forming patterns having various shapes. Further, immersion exposure is expected to be capable of being used in combination with currently studied super-resolution techniques, such as phase shift method and modified illumination method. Currently, as the immersion exposure technique, technique using an ArF excimer laser as an exposure source is being actively studied. Further, water is mainly used as the immersion medium.

In immersion exposure, a resist material is required which exhibits not only general lithography properties (e.g., sensitivity, resolution, etching resistance and the like), but also properties suited for immersion lithography. For example, in immersion exposure, when the resist film comes in contact with the immersion medium, elution of a substance contained in the resist film into the immersion medium occurs. The amount of the eluted substance is affected by the properties of the resist film surface (e.g., hydrophilicity, hydrophobicity, and the like). For example, by enhancing the hydrophobicity of the resist film surface, the elution of a substance can be reduced.

Further, as a lithography technique which has been recently proposed, a double patterning method is known in which patterning is conducted two or more times to form a resist pattern (for example, see Non-Patent Documents 2 and 3).

According to the double patterning process, for example, a first resist film is formed on a substrate, and patterning of the first resist film is conducted to form a plurality of resist patterns. Then, a second resist material is applied to the plurality of resist patterns to form a second resist film between the plurality of resist patterns. Then, by conducting patterning of the second resist film, it is presumed that a resist pattern can be formed with a higher resolution than the resist pattern formed by the first patterning.

### DOCUMENTS OF RELATED ART

[Patent Document]

[Patent Document 1] Japanese Unexamined Patent Application, First Publication No. 2003-241385

[Patent Document 2] Japanese Unexamined Patent Application, First Publication No. 2005-037888

[Non-Patent Documents]

[Non-Patent Document 1] Proceedings of SPIE (U.S.), vol. 5754, pp. 119-128 (2005)

[Non-Patent Document 2] Proceedings of SPIE (U.S.), vol. 5256, pp. 985-994 (2003)

[Non-Patent Document 3] Proceedings of SPIE (U.S.), vol. 6153, pp. 615301-1 to 615301-19 (2006)

### SUMMARY OF THE INVENTION

However, in the double patterning process, especially when a chemically amplified positive resist composition is used as a resist material for forming a first resist film, there was a problem that the first resist pattern was likely to be damaged by the second patterning. Specifically, examples of such problem include change in the shape of the first resist pattern (decrease in height (thickness loss), decrease in the line width of a line pattern (pattern thinning) or the like) and disappearance of the first resist pattern itself. These problems are caused by the influence of the organic solvent used for the second resist material or the exposure in the second patterning. These problems are likely to occur as the first resist film becomes thinner or the size of the resist pattern to be formed on the first resist film becomes miniaturized.

For preventing such failure in the shape of the resist pattern, a technique is known in which, after the first patterning, for example, a freezing agent is used to protect the first resist pattern. However, this technique is disadvantageous in terms of improving the throughput. Further, a positive resist composition including an alcohol-based organic solvent can be used as a second resist composition. However, when an alcohol-based organic solvent is used as an organic solvent for a conventional positive resist composition, resist materials such as the aforementioned acrylic resins or onium salt-based acid generators exhibit unsatisfactory solubility in the solvent and are deposited over time, which results in poor storage stability of the positive resist composition.

The present invention takes the above circumstances into consideration, with an object of providing a resist composition and a method of forming a resist pattern in which the resist materials exhibit excellent solubility, exhibit high resolution, and enables formation of a resist pattern having an excellent shape.

For solving the above-mentioned problems, the present invention employs the following aspects.

Specifically, a first aspect of the present invention is a resist composition including: a base component (A) which exhibits increased solubility in an alkali developing solution under the action of acid; and an acid-generator component (B) which generates acid upon exposure; dissolved in an organic solvent (S), wherein the acid-generator component includes an acid generator (B1) consisting of a compound represented by general formula (b1), and the organic solvent (S) includes an alcohol-based organic solvent having a boiling point of at least 150° C.

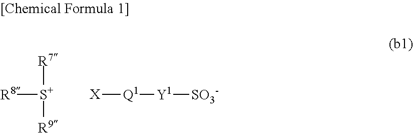

In formula (b1), R⁷″ to R⁹″ each independently represents an aryl group which may have a substituent or an alkyl group which may have a substituent, provided that at least one of R⁷″ to R⁹″ represents a substituted aryl group which has been substituted with a group represented by general formula (b1c-0) shown below, and two of R⁷″ to R⁹″ may be mutually bonded to form a ring with the sulfur atom; X represents a hydrocarbon group of 3 to 30 carbon atoms which may have a substituent; Q¹ represents a divalent linking group containing an oxygen atom; and Y¹ represents an alkylene group of 1 to 4 carbon atoms which may have a substituent or a fluorinated alkylene group of 1 to 4 carbon atoms which may have a substituent.

[Chemical Formula 2]

—O—R⁷⁰ (b1c-0)

In general formula (b1c-0), R⁷⁰ represents an organic group.

A second aspect of the present invention is a method of forming a resist pattern, including: applying a positive resist composition as a first resist composition on a substrate to form a first resist film on the substrate; subjecting the first resist film to selective exposure and alkali developing to form a first resist pattern; applying the positive resist composition of the first aspect as a second resist composition on the substrate on which the first resist pattern is formed to form a second resist film; and subjecting the second resist film to selective exposure and alkali developing to form a resist pattern.

In the present description and claims, an “alkyl group” includes linear, branched or cyclic, monovalent saturated hydrocarbon, unless otherwise specified.

The term “alkylene group” includes linear, branched or cyclic divalent saturated hydrocarbon, unless otherwise specified.

A “lower alkyl group” is an alkyl group of 1 to 5 carbon atoms.

A “halogenated alkyl group” is a group in which part or all of the hydrogen atoms of an alkyl group is substituted with a halogen atom. Examples of the halogen atom include a fluorine atom, a chlorine atom, a bromine atom and an iodine atom.

The term “aliphatic” is a relative concept used in relation to the term “aromatic”, and defines a group or compound that has no aromaticity.

The term “structural unit” refers to a monomer unit that contributes to the formation of a polymeric compound (polymer, copolymer).

The term “exposure” is used as a general concept that includes irradiation with any form of radiation.

The term “(meth)acrylic acid” is a generic term that includes either or both of acrylic acid having a hydrogen atom bonded to the α-position and methacrylic acid having a methyl group bonded to the α-position.

The term “(meth)acrylate ester” is a generic term that includes either or both of the acrylate ester having a hydrogen atom bonded to the α-position and the methacrylate ester having a methyl group bonded to the α-position. The term “(meth)acrylate” is a generic term that includes either or both of the acrylate having a hydrogen atom bonded to the α-position and the methacrylate having a methyl group bonded to the α-position.

According to the present invention, resist materials exhibit excellent solubility, high resolution can be achieved, and a resist pattern having an excellent shape can be formed.

Further, according to the method of the present invention, the first resist pattern is unlikely to be damaged in the double patterning process, and a resist pattern can be formed with a high resolution and an excellent shape. Furthermore, there is no need to use a freezing agent or the like, which results in improved workability.

### BRIEF DESCRIPTION OF THE DRAWINGS

FIG. 1 is a schematic plan view showing an example of a crossline pattern formed by a double patterning process. The schematic diagram shows a line and space (L/S) pattern 2 in the vertical direction formed with the second positive resist composition by assuming that the first L/S pattern 1 does not exist.

FIG. 2 is a photograph showing an image of a contact hole pattern formed by a crossline patterning process.

FIG. 3 is a schematic diagram showing the dimensions of a hole portion in the resist pattern, formed by a crossline patterning process, in the X-axis direction (CDₓ) and the Y-axis direction (CD_{y}), and the length of a diagonal line (CD₁₃₅).

### MODE FOR CARRYING OUT THE INVENTION

### Resist Composition

The resist composition according to the first aspect of the present invention includes a base component (A) which exhibits changed solubility in an alkali developing solution under action of acid (hereafter, referred to as “component (A)”) and an acid-generator component (B) which generates acid upon exposure (hereafter, referred to as “component (B)”), dissolved in an organic solvent (S).

With respect to a resist film formed using the resist composition, when a selective exposure is conducted during formation of a resist pattern, acid is generated from the component (B), and the generated acid acts on the component (A) to change the solubility of the component (A) in an alkali developing solution. As a result, the solubility of the exposed portions in an alkali developing solution is changed, whereas the solubility of the unexposed portions in an alkali developing solution remains unchanged. Therefore, the exposed portions are dissolved and removed by alkali developing in the case of a positive resist composition, whereas unexposed portions are dissolved and removed in the case of a negative resist composition, and hence, a resist pattern can be formed.

It is preferable that the resist composition of the present invention further includes a nitrogen-containing organic compound (D).

The resist composition of the present invention may be either a negative resist composition or a positive resist composition.

<Component (A)>

As the component (A), an organic compound typically used as a base component for a chemically amplified resist composition can be used alone, or two or more of such organic compounds can be mixed together.

Here, the term “base component” refers to an organic compound capable of forming a film, and is preferably an organic compound having a molecular weight of 500 or more. When the organic compound has a molecular weight of 500 or more, the film-forming ability is improved, and a resist pattern of nano level can be easily formed.

The “organic compound having a molecular weight of 500 or more” which can be used as a base component is broadly classified into non-polymers and polymers.

In general, as a non-polymer, any of those which have a molecular weight in the range of 500 to less than 4,000 is used. Hereafter, a non-polymer having a molecular weight in the range of 500 to less than 4,000 is referred to as a low molecular weight compound.

As a polymer, any of those which have a molecular weight of 1,000 or more is generally used. Hereafter, a polymer having a molecular weight of 1,000 or more is referred to as a polymeric compound. With respect to a polymeric compound, the “molecular weight” is the weight average molecular weight in terms of the polystyrene equivalent value determined by gel permeation chromatography (GPC). Hereafter, a polymeric compound is frequently referred to simply as a “resin”.

As the component (A), a resin component which exhibits changed solubility in an alkali developing solution under action of acid may be used. Alternatively, as the component (A), a low molecular weight material which exhibits changed solubility in an alkali developing solution under action of acid may be used.

When the resist composition of the present invention is a negative resist composition, for example, as the component (A), a base component that is soluble in an alkali developing solution is used, and a cross-linking agent is blended in the negative resist composition.

In the negative resist composition, when acid is generated from the component (B) upon exposure, the action of the generated acid causes cross-linking between the base component and the cross-linking agent, and the cross-linked portion becomes insoluble in an alkali developing solution. Therefore, in the formation of a resist pattern, by conducting selective exposure of a resist film formed by applying the negative resist composition onto a substrate, the exposed portions become insoluble in an alkali developing solution, whereas the unexposed portions remain soluble in an alkali developing solution, and hence, a resist pattern can be formed by alkali developing.

Generally, as the component (A) for a negative resist composition, a resin that is soluble in an alkali developing solution (hereafter, referred to as “alkali-soluble resin”) is used.

Examples of the alkali soluble resin include a resin having a structural unit derived from at least one of α-(hydroxyalkyl)acrylic acid and an alkyl ester of α-(hydroxyalkyl)acrylic acid (preferably an alkyl ester having 1 to 5 carbon atoms), as disclosed in Japanese Unexamined Patent Application, First Publication No. 2000-206694; a (meth)acrylic resin or polycycloolefin resin having a sulfoneamide group, as disclosed in U.S. Pat. No. 6,949,325; a (meth)acrylic resin having a fluorinated alcohol, as disclosed in U.S. Pat. No. 6,949,325, Japanese Unexamined Patent Application, First Publication No. 2005-336452 or Japanese Unexamined Patent Application, First Publication No. 2006-317803; and a polycyclolefin resin having a fluorinated alcohol, as disclosed in Japanese Unexamined Patent Application, First Publication No. 2006-259582. These resins are preferable in that a resist pattern can be formed with minimal swelling.

Here, the term “α-(hydroxyalkyl)acrylic acid” refers to one or both of acrylic acid in which a hydrogen atom is bonded to the carbon atom on the α-position having the carboxyl group bonded thereto, and α-hydroxyalkylacrylic acid in which a hydroxyalkyl group (preferably a hydroxyalkyl group of 1 to 5 carbon atoms) is bonded to the carbon atom on the α-position.

As the cross-linking agent, typically, an amino-based cross-linking agent such as a glycoluril having a methylol group or alkoxymethyl group, or a melamine-based cross-linking agent is preferable, as it enables formation of a resist pattern with minimal swelling. The amount of the cross-linker added is preferably within a range from 1 to 50 parts by weight, relative to 100 parts by weight of the alkali-soluble resin.

When the resist composition of the present invention is a positive resist composition, as the component (A), a base component which exhibits increased solubility in an alkali developing solution by action of acid (hereafter, referred to as “component (A0)”) is used.

More specifically, the component (A0) is substantially insoluble in an alkali developing solution prior to exposure, but when acid is generated from the component (B) upon exposure, the action of this acid causes an increase in the solubility of the base component in an alkali developing solution. Therefore, in the formation of a resist pattern, by conducting selective exposure of a resist film formed by applying the positive resist composition onto a substrate, the exposed portions changes from an insoluble state to a soluble state in an alkali developing solution, whereas the unexposed portions remain insoluble in an alkali developing solution, and hence, a resist pattern can be formed by alkali developing.

In the resist composition of the present invention, the component (A) is preferably a base component (A0) which exhibits increased solubility in an alkali developing solution under action of acid. That is, the resist composition of the present invention is preferably a positive resist composition.

The component (A0) may be a resin component (A1) that exhibits increased solubility in an alkali developing solution under the action of acid (hereafter, frequently referred to as “component (A1)”), a low molecular weight material (A2) that exhibits increased solubility in an alkali developing solution under the action of acid (hereafter, frequently referred to as “component (A2)”), or a mixture thereof.

Of the examples shown above, as the component (A), it is preferable to use one containing the component (A1).

[Component (A1)]

As the component (A1), a resin component (base resin) typically used as a base component for a chemically amplified resist composition can be used alone, or two or more of such resin components can be mixed together.

In the present invention, it is preferable that the component (A1) include a structural unit derived from an acrylate ester.

In the present descriptions and claims, the term “structural unit derived from an acrylate ester” refers to a structural unit which is formed by the cleavage of the ethylenic double bond of an acrylate ester.

The term “acrylate ester” is a generic term that includes acrylate esters having a hydrogen atom bonded to the carbon atom on the α-position, and acrylate esters having a substituent (an atom other than a hydrogen atom or a group) bonded to the carbon atom on the α-position. Examples of the substituent include an alkyl group of 1 to 5 carbon atoms and a halogenated alkyl group of 1 to 5 carbon atoms.

With respect to the “structural unit derived from an acrylate ester”, the “α-position (the carbon atom on the α-position)” refers to the carbon atom having the carbonyl group bonded thereto, unless specified otherwise.

With respect to the acrylate ester, specific examples of the alkyl group of 1 to 5 carbon atoms for the substituent at the α-position include linear or branched alkyl groups such as a methyl group, an ethyl group, a propyl group, an isopropyl group, an n-butyl group, an isobutyl group, a tert-butyl group, a pentyl group, an isopentyl group, and a neopentyl group.

Specific examples of the halogenated alkyl group of 1 to 5 carbon atoms include groups in which part or all of the hydrogen atoms of the aforementioned “alkyl group of 1 to 5 carbon atoms for the substituent at the α-position” are substituted with halogen atoms. Examples of the halogen atom include a fluorine atom, a chlorine atom, a bromine atom and an iodine atom, and a fluorine atom is particularly desirable.

In the present invention, it is preferable that a hydrogen atom, an alkyl group of 1 to 5 carbon atoms or a halogenated alkyl group of 1 to 5 carbon atoms is bonded to the α-position of the acrylate ester, a hydrogen atom, an alkyl group of 1 to 5 carbon atoms or a fluorinated alkyl group of 1 to 5 carbon atoms is more preferable, and in terms of industrial availability, a hydrogen atom or a methyl group is the most desirable.

In the resist composition of the present invention, it is particularly desirable that the component (A1) include a structural unit (a1) derived from an acrylate ester containing an acid dissociable, dissolution inhibiting group.

Further, it is preferable that the component (A1) include a structural unit (a2) derived from an acrylate ester containing a lactone-containing cyclic group, as well as the structural unit (a1).

Moreover, it is preferable that the component (A1) further include a structural unit (a5) represented by general formula (a5-1) shown below, as well as the structural unit (a1), or the structural unit (a1) and the structural unit (a2).

Furthermore, it is preferable that the component (A1) further include a structural unit (a6) represented by general formula (a6-1) shown below, as well as the structural unit (a1), the structural units (a1) and (a2), the structural units (a1) and (a5), or the structural units (a1), (a2) and (a5).

(Structural Unit (a1))

The structural unit (a1) is a structural unit derived from an acrylate ester containing an acid dissociable, dissolution inhibiting group.

As the acid dissociable, dissolution inhibiting group in the structural unit (a1), any of the groups that have been proposed as acid dissociable, dissolution inhibiting groups for the base resins of chemically amplified resists can be used, provided the group has an alkali dissolution-inhibiting effect that renders the entire component (A1) insoluble in an alkali developing solution prior to dissociation, and then following dissociation by action of acid, increases the solubility of the entire component (A1) in the alkali developing solution.

Generally, groups that form either a cyclic or chain-like tertiary alkyl ester with the carboxyl group of the (meth)acrylic acid, and acetal-type acid dissociable, dissolution inhibiting groups such as alkoxyalkyl groups are widely known.

Here, a tertiary alkyl ester describes a structure in which an ester is formed by substituting the hydrogen atom of a carboxyl group with a chain-like or cyclic tertiary alkyl group, and a tertiary carbon atom within the chain-like or cyclic tertiary alkyl group is bonded to the oxygen atom at the terminal of the carbonyloxy group (—C(O)—O—). In this tertiary alkyl ester, the action of acid causes cleavage of the bond between the oxygen atom and the tertiary carbon atom.

The chain-like or cyclic alkyl group may have a substituent.

Hereafter, for the sake of simplicity, groups that exhibit acid dissociability as a result of the formation of a tertiary alkyl ester with a carboxyl group are referred to as “tertiary alkyl ester-type acid dissociable, dissolution inhibiting groups”.

Examples of tertiary alkyl ester-type acid dissociable, dissolution inhibiting groups include aliphatic branched, acid dissociable, dissolution inhibiting groups and aliphatic cyclic group-containing acid dissociable, dissolution inhibiting groups.

In the present description and claims, the term “aliphatic branched” refers to a branched structure having no aromaticity.

The “aliphatic branched, acid dissociable, dissolution inhibiting group” is not limited to be constituted of only carbon atoms and hydrogen atoms (not limited to hydrocarbon groups), but is preferably a hydrocarbon group.

Further, the “hydrocarbon group” may be either saturated or unsaturated, but is preferably saturated.

Examples of aliphatic branched, acid dissociable, dissolution inhibiting groups include tertiary alkyl groups of 4 to 8 carbon atoms, and specific examples include a tert-butyl group, tert-pentyl group and tert-heptyl group.

The term “aliphatic cyclic group” refers to a monocyclic group or polycyclic group that has no aromaticity.

The “aliphatic cyclic group” within the structural unit (a1) may or may not have a substituent. Examples of the substituent include an alkyl group of 1 to 5 carbon atoms, an alkoxy group of 1 to 5 carbon atoms, a fluorine atom, a fluorinated alkyl group of 1 to 5 carbon atoms, and an oxygen atom (═O).

The basic ring of the “aliphatic cyclic group” exclusive of substituents is not limited to be constituted from only carbon and hydrogen (not limited to hydrocarbon groups), but is preferably a hydrocarbon group.

Further, the “hydrocarbon group” may be either saturated or unsaturated, but is preferably saturated. Furthermore, the “aliphatic cyclic group” is preferably a polycyclic group.

As such aliphatic cyclic groups, groups in which one or more hydrogen atoms have been removed from a monocycloalkane or a polycycloalkane such as a bicycloalkane, tricycloalkane or tetracycloalkane which may or may not be substituted with a lower alkyl group, a fluorine atom or a fluorinated alkyl group, may be used. Specific examples include groups in which one or more hydrogen atoms have been removed from a monocycloalkane such as cyclopentane and cyclohexane; and groups in which one or more hydrogen atoms have been removed from a polycycloalkane such as adamantane, norbornane, isobornane, tricyclodecane or tetracyclododecane.

As the aliphatic cyclic group-containing acid dissociable, dissolution inhibiting group, for example, a group which has a tertiary carbon atom on the ring structure of the cycloalkyl group can be used. Specific examples include 2-methyl-2-adamantyl group and a 2-ethyl-2-adamantyl group. Further, groups having an aliphatic cyclic group such as an adamantyl group, cyclohexyl group, cyclopentyl group, norbornyl group, tricyclodecyl group or tetracyclododecyl group, and a branched alkylene group having a tertiary carbon atom bonded thereto, as the groups bonded to the oxygen atom of the carbonyl group (—C(O)—O—) within the structural units represented by general formulas (a1″-1) to (a1″-6) shown below, can be used.

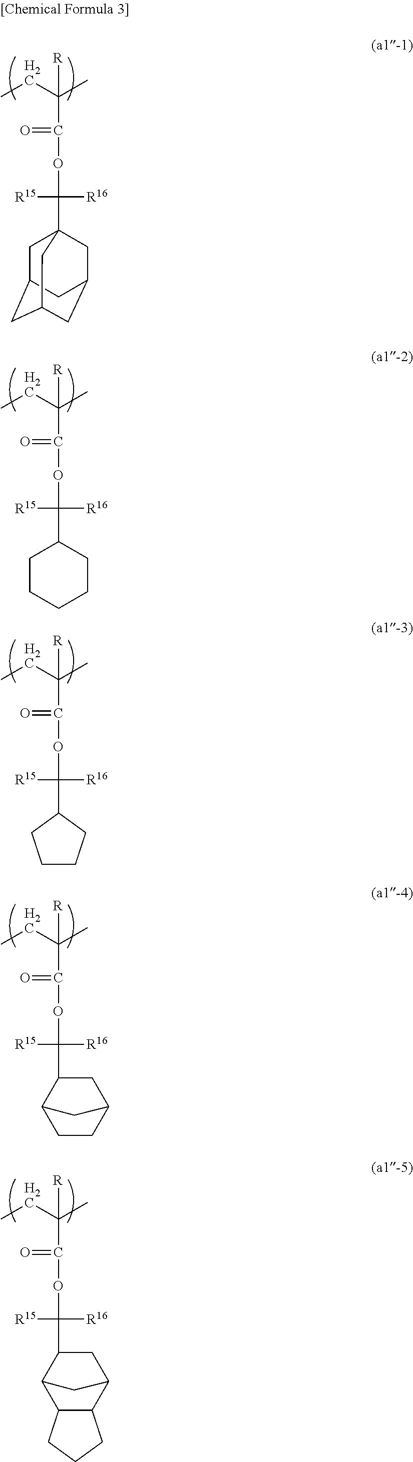

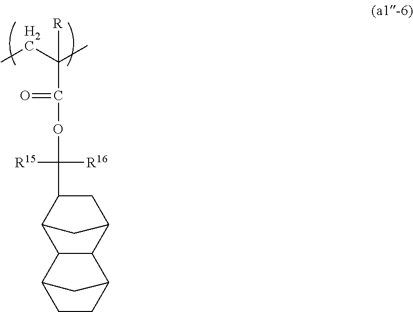

In the formulas, R represents a hydrogen atom, an alkyl group of 1 to 5 carbon atoms or a halogenated alkyl group of 1 to 5 carbon atoms; and R¹⁵ and R¹⁶ each independently represent an alkyl group (which may be linear or branched, and preferably has 1 to 5 carbon atoms).

In general formulas (a1″-1) to (a1″-6) above, the alkyl group or halogenated lower alkyl group for R are the same as the alkyl group of 1 to 5 carbon atoms or halogenated alkyl group of 1 to 5 carbon atoms which can be bonded to the α-position of the aforementioned acrylate ester.

An “acetal-type acid dissociable, dissolution inhibiting group” generally substitutes a hydrogen atom at the terminal of an alkali-soluble group such as a carboxy group or hydroxyl group, so as to be bonded with an oxygen atom. When acid is generated upon exposure, the generated acid acts to break the bond between the acetal-type acid dissociable, dissolution inhibiting group and the oxygen atom to which the acetal-type, acid dissociable, dissolution inhibiting group is bonded.

Examples of acetal-type acid dissociable, dissolution inhibiting groups include groups represented by general formula (p1) shown below.

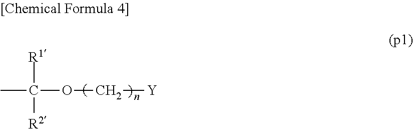

In the formula, R¹′ and R²′ each independently represent a hydrogen atom or an alkyl group of 1 to 5 carbon atoms; n represents an integer of 0 to 3; and Y represents an alkyl group of 1 to 5 carbon atoms or an aliphatic cyclic group.

In general formula (p1) above, n is preferably an integer of 0 to 2, more preferably 0 or 1, and most preferably 0.

As the alkyl group of 1 to 5 carbon atoms for R¹′ and R²′, the same alkyl groups of 1 to 5 carbon atoms as those described above for R can be used, although a methyl group or ethyl group is preferable, and a methyl group is particularly desirable.

In the present invention, it is preferable that at least one of R¹′ and R²′ be a hydrogen atom. That is, it is preferable that the group represented by general formula (p1) is a group represented by general formula (p1-1) shown below.

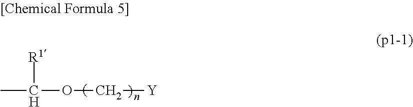

In the formula, R¹′, n and Y are the same as defined above.

As the alkyl group of 1 to 5 carbon atoms for Y, the same alkyl groups of 1 to 5 carbon atoms as those described above can be used.

As the aliphatic cyclic group for Y, any of the aliphatic monocyclic/polycyclic groups which have been proposed for conventional ArF resists and the like can be appropriately selected for use. For example, the same groups described above in connection with the “aliphatic cyclic group” can be used.

Further, as the acetal-type, acid dissociable, dissolution inhibiting group, groups represented by general formula (p2) shown below can also be used.

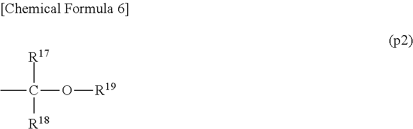

In the formula, R¹⁷ and R¹⁸ each independently represent a linear or branched alkyl group or a hydrogen atom; and R¹⁹ represents a linear, branched or cyclic alkyl group; or R¹⁷ and R¹⁹ each independently represents a linear or branched alkylene group, and the terminal of R¹⁷ is bonded to the terminal of R¹⁹ to form a ring.

The alkyl group for R¹⁷ and R¹⁸ preferably has 1 to 15 carbon atoms, and may be either linear or branched. As the alkyl group, an ethyl group or a methyl group is preferable, and a methyl group is most preferable. It is particularly desirable that either one of R¹⁷ and R¹⁸ be a hydrogen atom, and the other be a methyl group.

R¹⁹ represents a linear, branched or cyclic alkyl group which preferably has 1 to 15 carbon atoms, and may be any of linear, branched or cyclic.

When R¹⁹ represents a linear or branched alkyl group, it is preferably an alkyl group of 1 to 5 carbon atoms, more preferably an ethyl group or methyl group, and most preferably an ethyl group.

When R¹⁹ represents a cycloalkyl group, it preferably has 4 to 15 carbon atoms, more preferably 4 to 12 carbon atoms, and most preferably 5 to 10 carbon atoms. As examples of the cycloalkyl group, groups in which one or more hydrogen atoms have been removed from a monocycloalkane or a polycycloalkane such as a bicycloalkane, tricycloalkane or tetracycloalkane, which may or may not be substituted with a fluorine atom or a fluorinated alkyl group, may be used. Examples of such groups include groups in which one or more hydrogen atoms have been removed from a monocycloalkane such as cyclopentane or cyclohexane; and groups in which one or more hydrogen atoms have been removed from a polycycloalkane such as adamantane, norbornane, isobornane, tricyclodecane or tetracyclododecane. Among these, a group in which one or more hydrogen atoms have been removed from adamantane is preferable.

In general formula (p2) above, R¹⁷ and R¹⁹ may each independently represent a linear or branched alkylene group (preferably an alkylene group of 1 to 5 carbon atoms), and the terminal of R¹⁹ may be bonded to the terminal of R¹⁷.

In such a case, a cyclic group is formed by R¹⁷, R¹⁹, the oxygen atom having R¹⁹ bonded thereto, and the carbon atom having the oxygen atom and R¹⁷ bonded thereto. Such a cyclic group is preferably a 4- to 7-membered ring, and more preferably a 4- to 6-membered ring. Specific examples of the cyclic group include tetrahydropyranyl group and tetrahydrofuranyl group.

As the structural unit (a1), it is preferable to use at least one member selected from the group consisting of structural units represented by formula (a1-0-1) shown below and structural units represented by formula (a1-0-2) shown below.

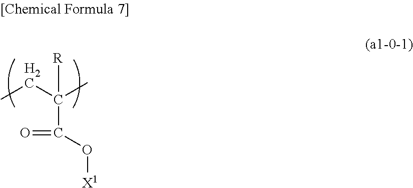

In the formula, R represents a hydrogen atom, an alkyl group of 1 to 5 carbon atoms or a halogenated alkyl group of 1 to 5 carbon atoms; and X¹ represents an acid dissociable, dissolution inhibiting group.

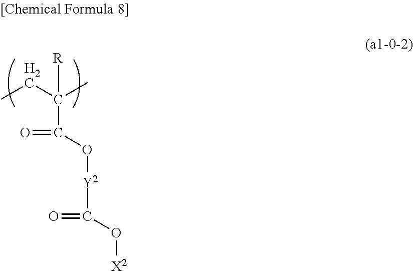

In the formula, R represents a hydrogen atom, an alkyl group of 1 to 5 carbon atoms or a halogenated alkyl group of 1 to 5 carbon atoms; X² represents an acid dissociable, dissolution inhibiting group; and Y² represents a divalent linking group.

In general formula (a1-0-1) above, the alkyl group or halogenated lower alkyl group for R are the same as the alkyl group of 1 to 5 carbon atoms or halogenated alkyl group of 1 to 5 carbon atoms which can be bonded to the α-position of the aforementioned acrylate ester.

X¹ is not particularly limited as long as it is an acid dissociable, dissolution inhibiting group. Examples thereof include the aforementioned tertiary alkyl ester-type acid dissociable, dissolution inhibiting groups and acetal-type acid dissociable, dissolution inhibiting groups, and tertiary alkyl ester-type acid dissociable, dissolution inhibiting groups are preferable.

In general formula (a1-0-2), R is the same as defined above.

X² is the same as defined for X¹ in general formula (a1-0-1).

As the divalent linking group for Y², an alkylene group, a divalent aliphatic cyclic group or a divalent linking group containing a hetero atom can be mentioned.

As the aliphatic cyclic group, the same as those used above in connection with the explanation of “aliphatic cyclic group” can be used, except that two hydrogen atoms have been removed therefrom.

When Y² represents an alkylene group, it preferably has 1 to 10 carbon atoms, more preferably 1 to 6, still more preferably 1 to 4, and most preferably 1 to 3.

When Y² represents a divalent aliphatic cyclic group, it is particularly desirable that the divalent aliphatic cyclic group be a group in which two or more hydrogen atoms have been removed from cyclopentane, cyclohexane, norbornane, isobornane, adamantane, tricyclodecane or tetracyclododecane.

When Y² represents a divalent linking group containing a hetero atom, examples thereof include —O—, —C(═O)—O—, —C(═O)—, —O—C(═O)—O—, —C(═O)—NH—, —NH— (H may be substituted with a substituent such as an alkyl group or an acyl group), —S—, —S(═O)₂—, —S(═O)₂—O—, and “-A-O-B- (wherein 0 is an oxygen atom, and each of A and B independently represents a divalent hydrocarbon group which may have a substituent)”. Further, a plurality of these groups may be used in combination.

When Y² represents a divalent linking group —NH— and the H in the formula is replaced with a substituent such as an alkyl group or an acyl group, the substituent preferably has 1 to 10 carbon atoms, more preferably 1 to 8 carbon atoms, and most preferably 1 to 5 carbon atoms.

When Y² is “A-O-B”, each of A and B independently represents a divalent hydrocarbon group which may have a substituent.

A hydrocarbon “has a substituent” means that part or all of the hydrogen atoms within the hydrocarbon group is substituted with groups or atoms other than hydrogen atom.

The hydrocarbon group for A may be either an aliphatic hydrocarbon group, or an aromatic hydrocarbon group. An “aliphatic hydrocarbon group” refers to a hydrocarbon group that has no aromaticity.

The aliphatic hydrocarbon group for A may be either saturated or unsaturated. In general, the aliphatic hydrocarbon group is preferably saturated.

As specific examples of the aliphatic hydrocarbon group for A, a linear or branched aliphatic hydrocarbon group, and an aliphatic hydrocarbon group having a ring in the structure thereof can be given.

The linear or branched aliphatic hydrocarbon group preferably has 1 to 10 carbon atoms, more preferably 1 to 8, still more preferably 2 to 5, and most preferably 2.

As a linear aliphatic hydrocarbon group, a linear alkylene group is preferable, and specific examples include a methylene group, an ethylene group [—(CH₂)₂—], a trimethylene group [—(CH₂)₃—], a tetramethylene group [—(CH₂)₄—] and a pentamethylene group [—(CH₂)₅—].

As the branched aliphatic hydrocarbon group, a branched alkylene group is preferable, and specific examples include alkylalkylene groups, e.g., alkylmethylene groups such as —CH(CH₃)—, —CH(CH₂CH₃)—, —C(CH₃)₂—, —C(CH₃)(CH₂CH₃)—, —C(CH₃)(CH₂CH₂CH₃)— and —C(CH₂CH₃)₂—; alkylethylene groups such as —CH(CH₃)CH₂—, —CH(CH₃)CH(CH₃)—, —C(CH₃)₂CH₂— and —CH(CH₂CH₃)CH₂—; alkyltrimethylene groups such as —CH(CH₃)CH₂CH₂— and —CH₂CH(CH₃)CH₂—; and alkyltetramethylene groups such as —CH(CH₃)CH₂CH₂CH₂— and —CH₂CH(CH₃)CH₂CH₂—. As the alkyl group within the alkylalkylene group, a linear alkyl group of 1 to 5 carbon atoms is preferable.

The linear or branched aliphatic hydrocarbon group (chain-like aliphatic hydrocarbon group) may or may not have a substituent. Examples of the substituent include a fluorine atom, a fluorinated alkyl group of 1 to 5 carbon atoms, and an oxygen atom (═O).

As examples of the hydrocarbon group containing a ring, a cyclic aliphatic hydrocarbon group (a group in which two hydrogen atoms have been removed from an aliphatic hydrocarbon ring), and a group in which the cyclic aliphatic hydrocarbon group is bonded to the terminal of the aforementioned chain-like aliphatic hydrocarbon group or interposed within the aforementioned chain-like aliphatic hydrocarbon group, can be given.

The cyclic aliphatic hydrocarbon group preferably has 3 to 20 carbon atoms, and more preferably 3 to 12 carbon atoms.

The cyclic aliphatic hydrocarbon group may be either a polycyclic group or a monocyclic group. As the monocyclic group, a group in which two hydrogen atoms have been removed from a monocycloalkane of 3 to 6 carbon atoms is preferable. Examples of the monocycloalkane include cyclopentane and cyclohexane. As the polycyclic group, a group in which two hydrogen atoms have been removed from a polycycloalkane of 7 to 12 carbon atoms is preferable. Examples of the polycycloalkane include adamantane, norbornane, isobornane, tricyclodecane and tetracyclododecane.

The cyclic aliphatic hydrocarbon group may or may not have a substituent. Examples of the substituent include an alkyl group of 1 to 5 carbon atoms, a fluorine atom, a fluorinated alkyl group of 1 to 5 carbon atoms, and an oxygen atom (═O).

As A, a linear aliphatic hydrocarbon group is preferable, more preferably a linear alkylene group, still more preferably a linear alkylene group of 2 to 5 carbon atoms, and most preferably an ethylene group.

As the hydrocarbon group for B, the same divalent hydrocarbon groups as those described above for A can be used.

As B, a linear or branched aliphatic hydrocarbon group is preferable, and a methylene group or an alkylmethylene group is particularly desirable.

The alkyl group within the alkyl methylene group is preferably a linear alkyl group of 1 to 5 carbon atoms, more preferably a linear alkyl group of 1 to 3 carbon atoms, and most preferably a methyl group.

Specific examples of the structural unit (a1) include structural units represented by general formulas (a1-1) to (a1-4) shown below.

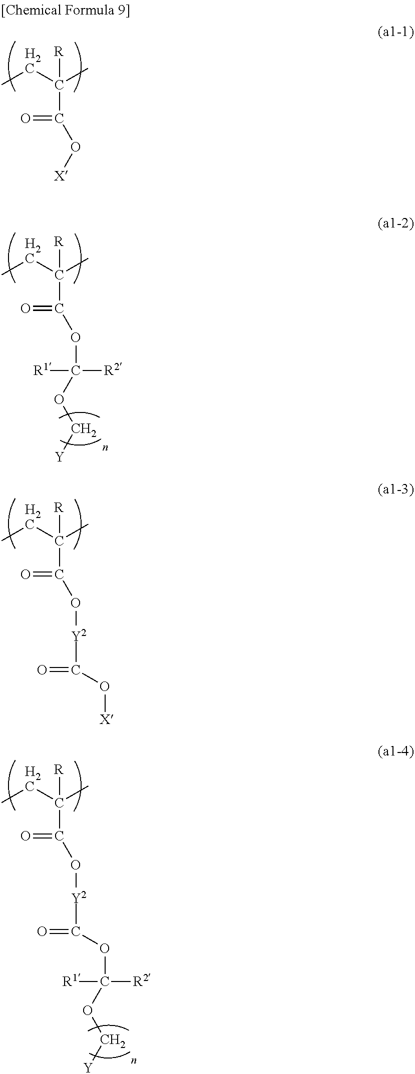

In the formulas, X′ represents a tertiary alkyl ester-type acid dissociable, dissolution inhibiting group; Y represents an alkyl group of 1 to 5 carbon atoms or an aliphatic cyclic group; n represents an integer of 0 to 3; Y² represents a divalent linking group; R is the same as defined above; and each of R¹′ and R²′ independently represents a hydrogen atom or an alkyl group of 1 to 5 carbon atoms.

Examples of the tertiary alkyl ester-type acid dissociable, dissolution inhibiting group for X′ include the same tertiary alkyl ester-type acid dissociable, dissolution inhibiting groups as those described above for X¹.

As R¹′, R²′, n and Y are respectively the same as defined for R¹′, R²′, n and Y in general formula (p1) described above in connection with the “acetal-type acid dissociable, dissolution inhibiting group”.

As examples of Y², the same groups as those described above for Y² in general formula (a1-0-2) can be given.

Specific examples of structural units represented by general formula (a1-1) to (a1-4) are shown below.

In the formulas shown below, R^{α} represents a hydrogen atom, a methyl group or a trifluoromethyl group.

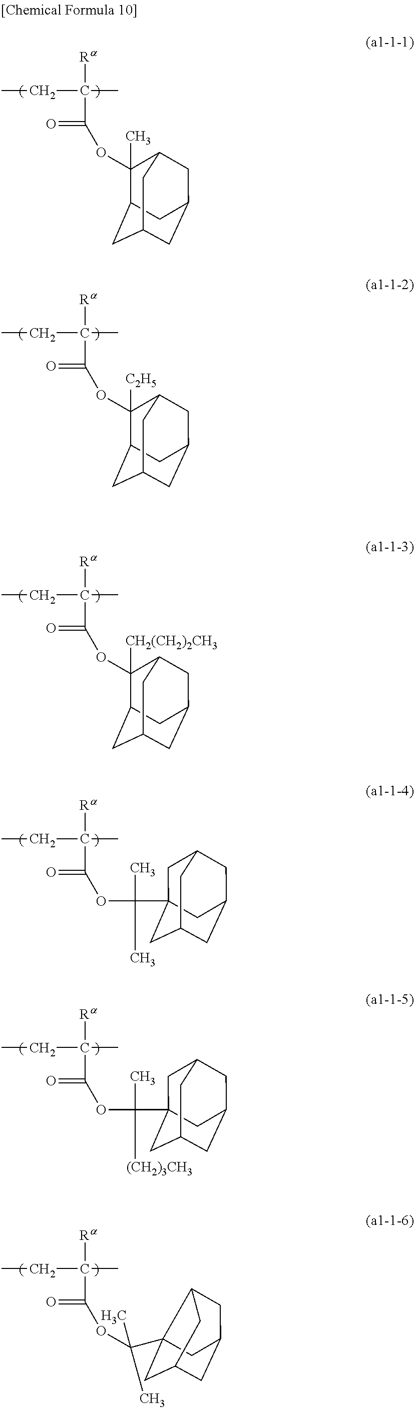

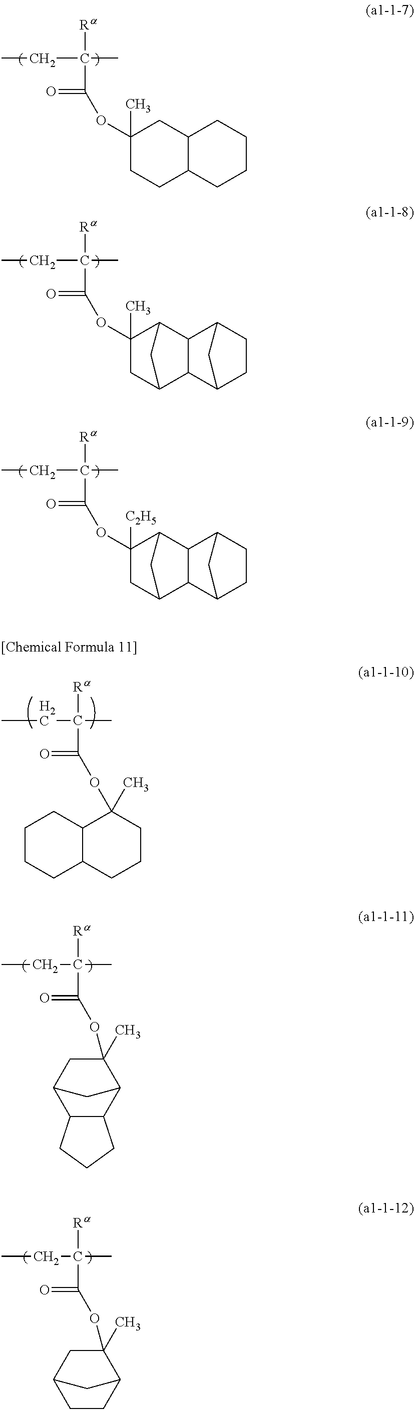

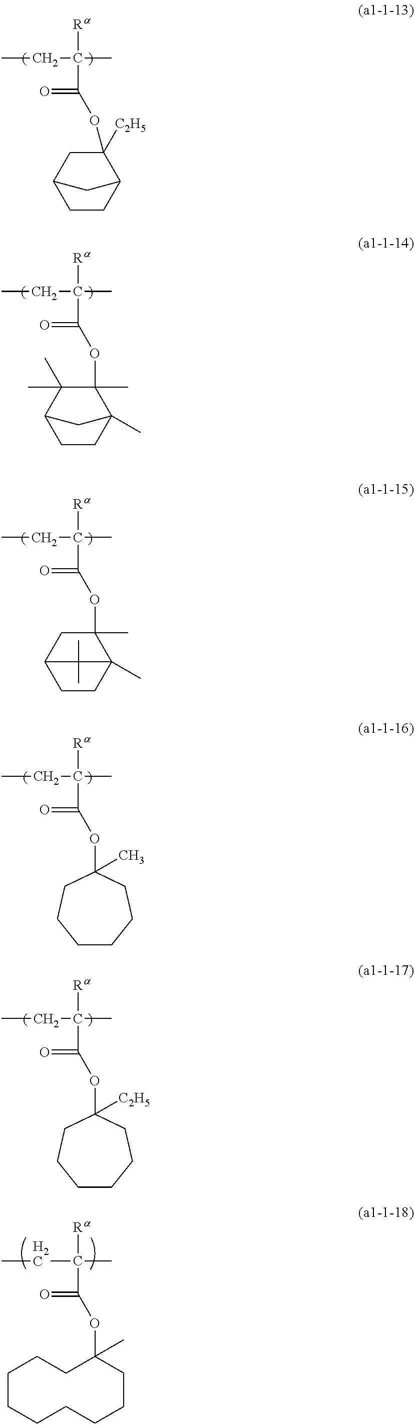

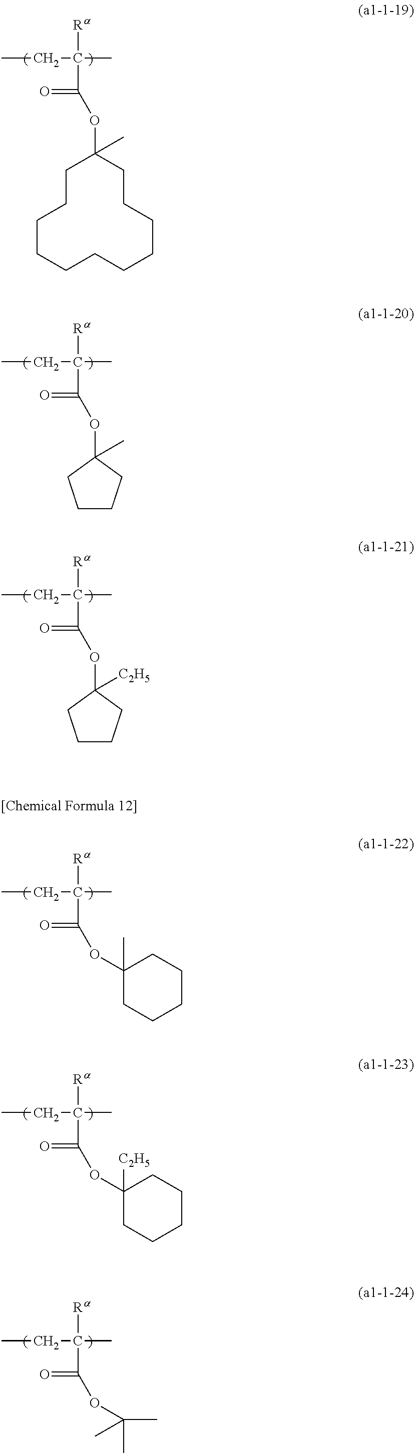

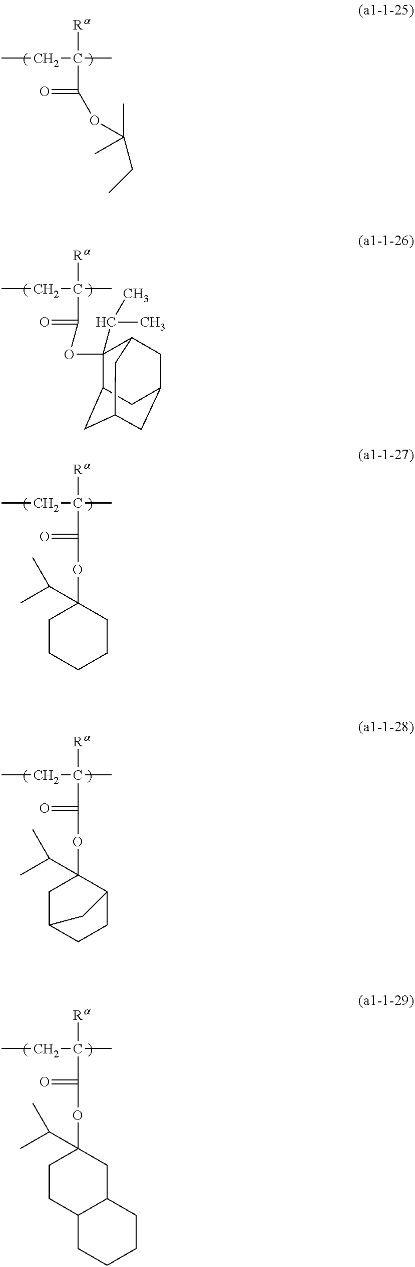

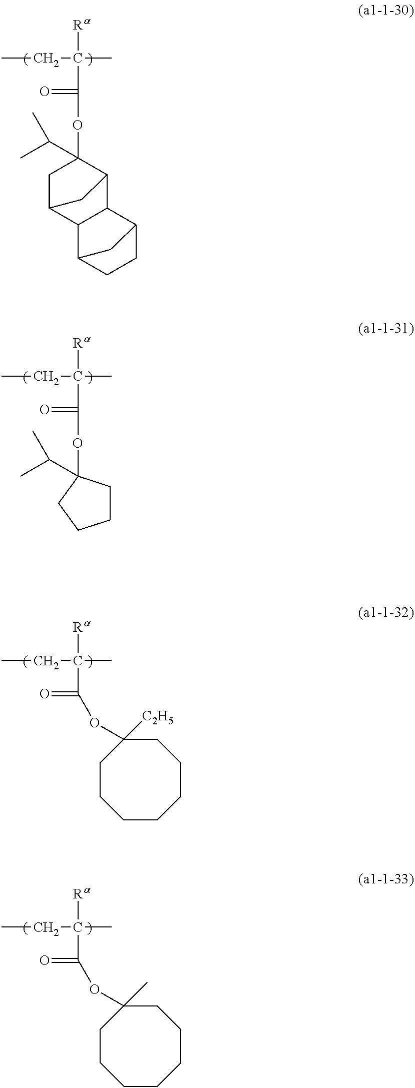

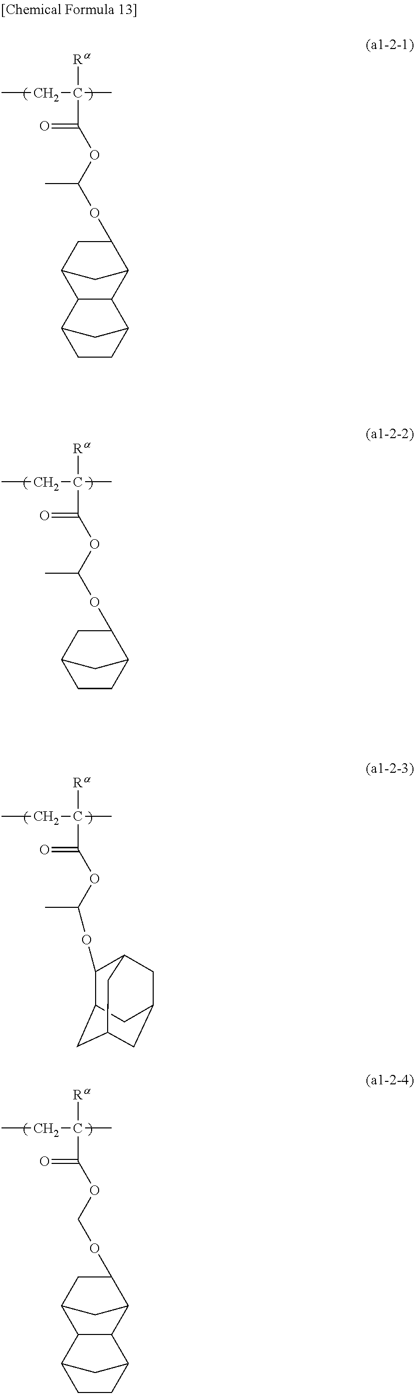

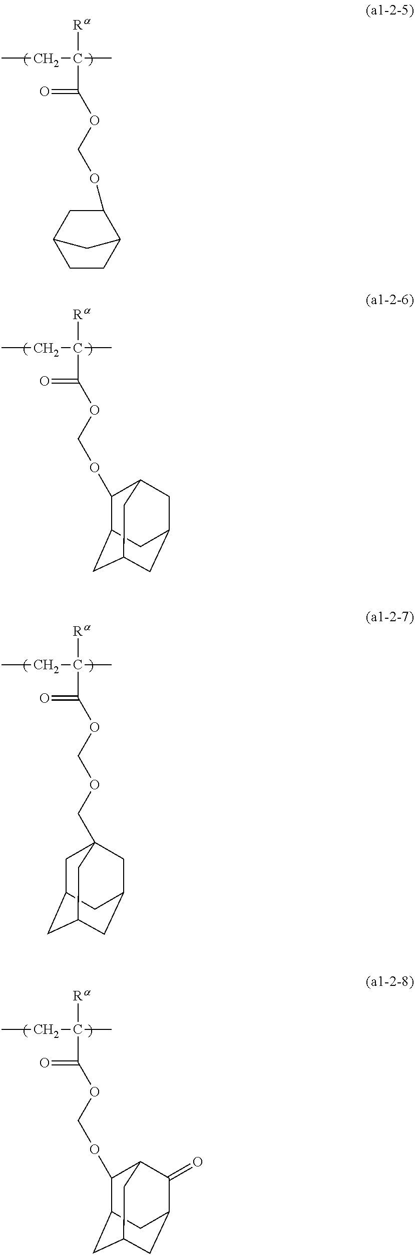

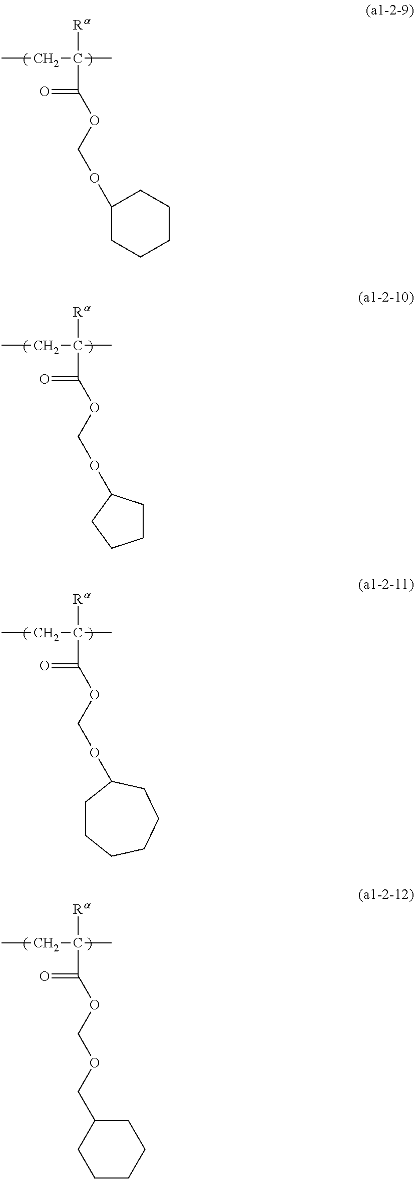

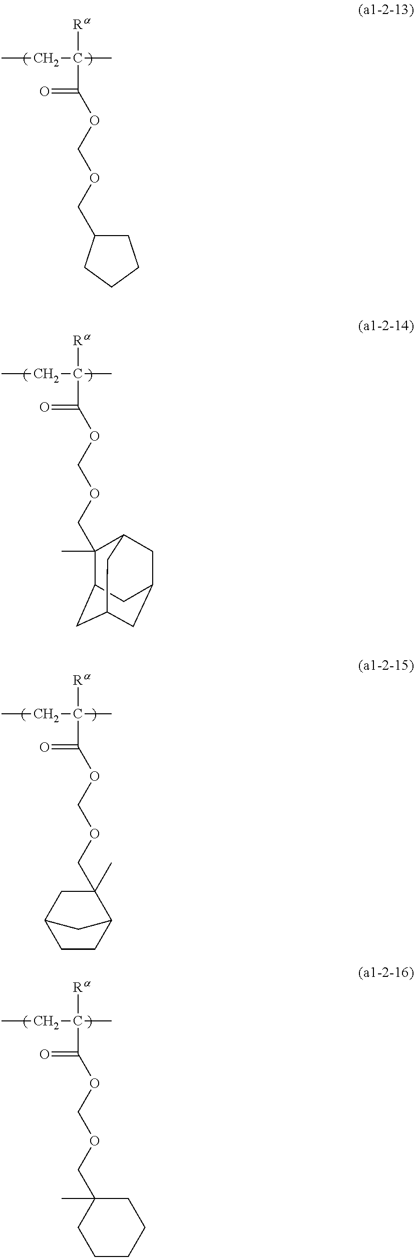

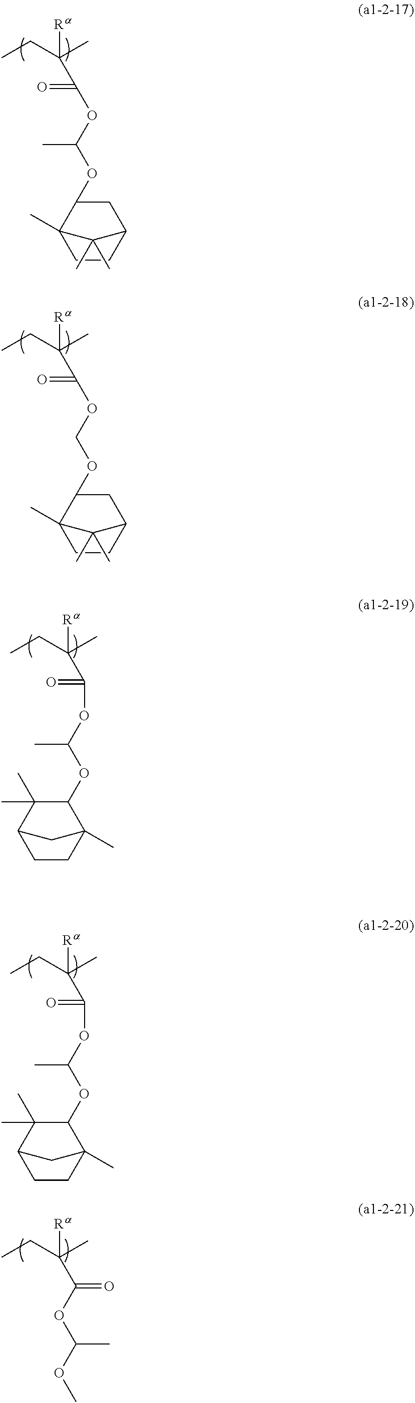

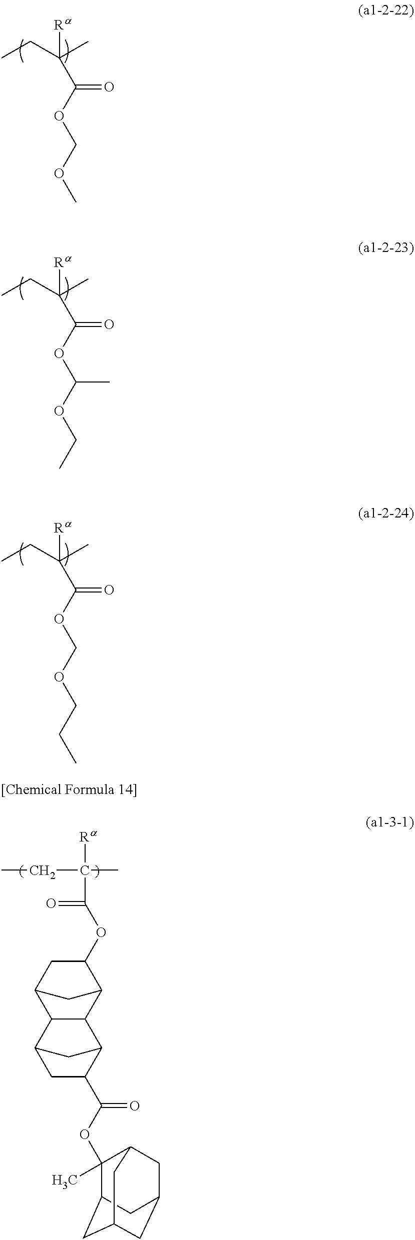

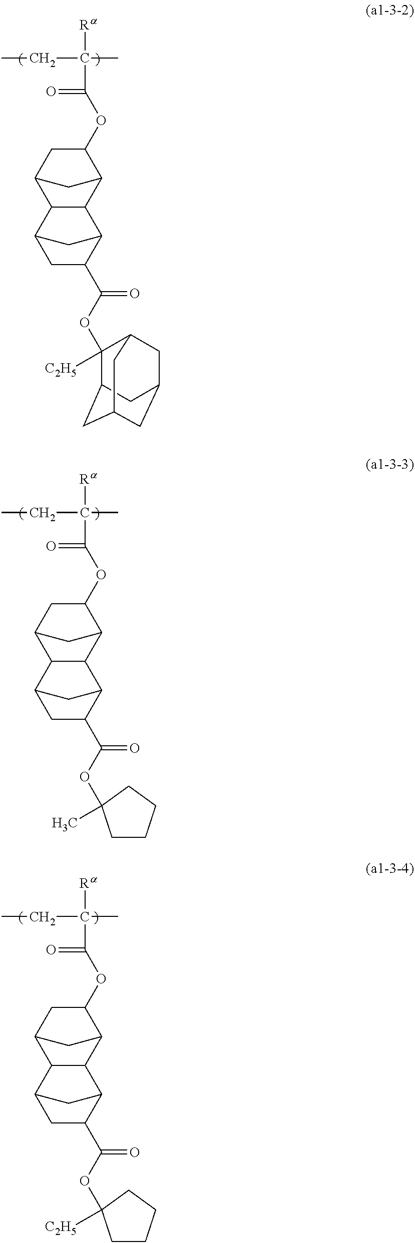

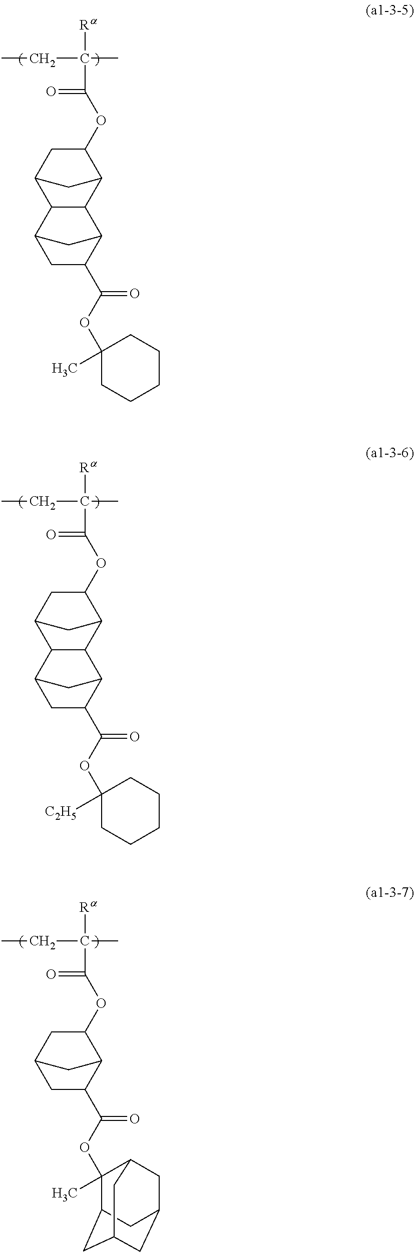

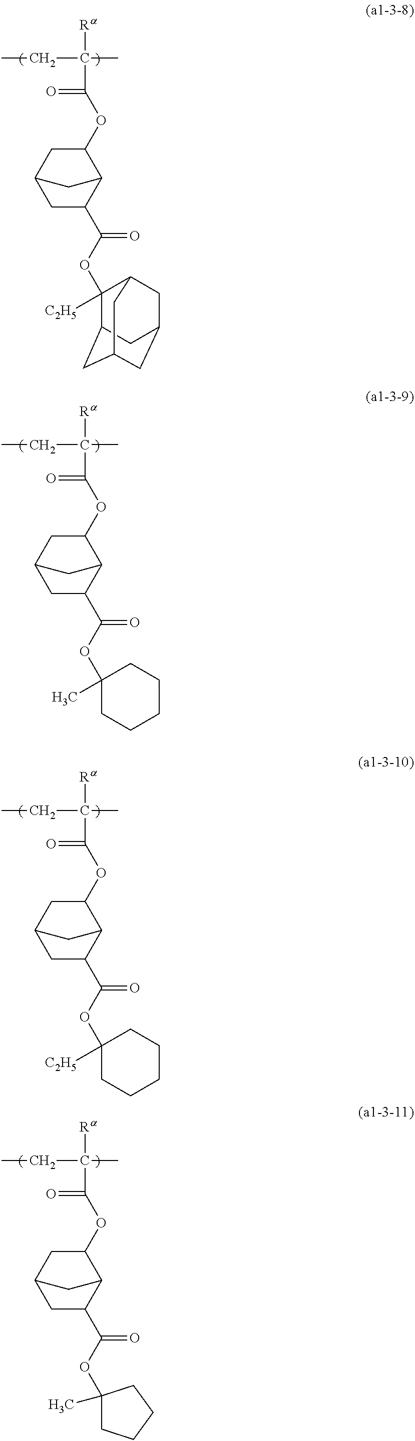

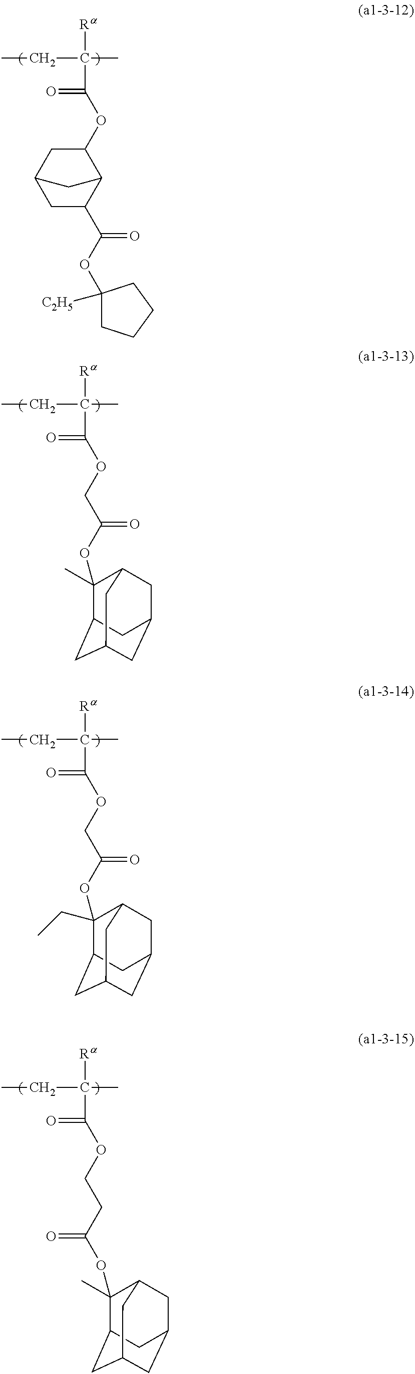

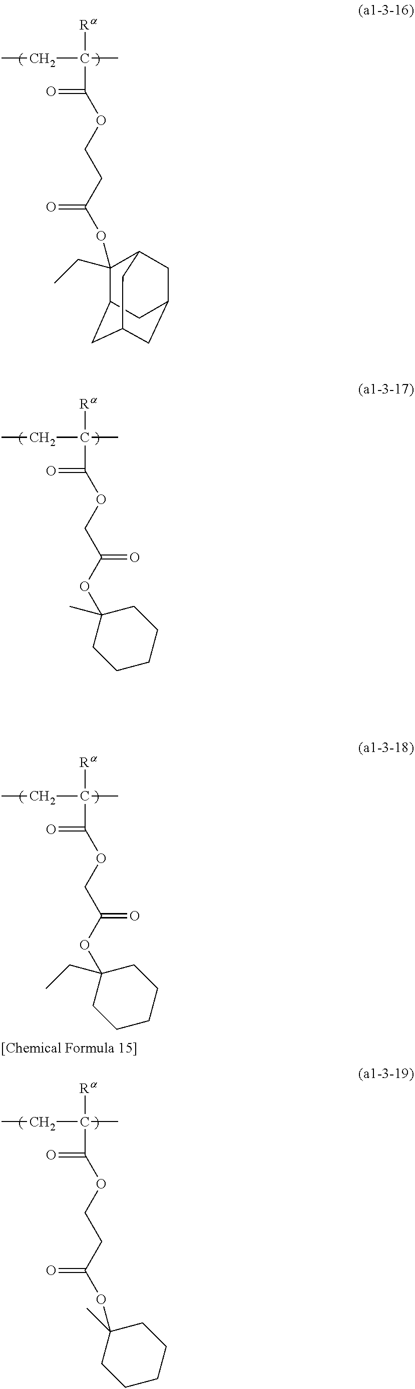

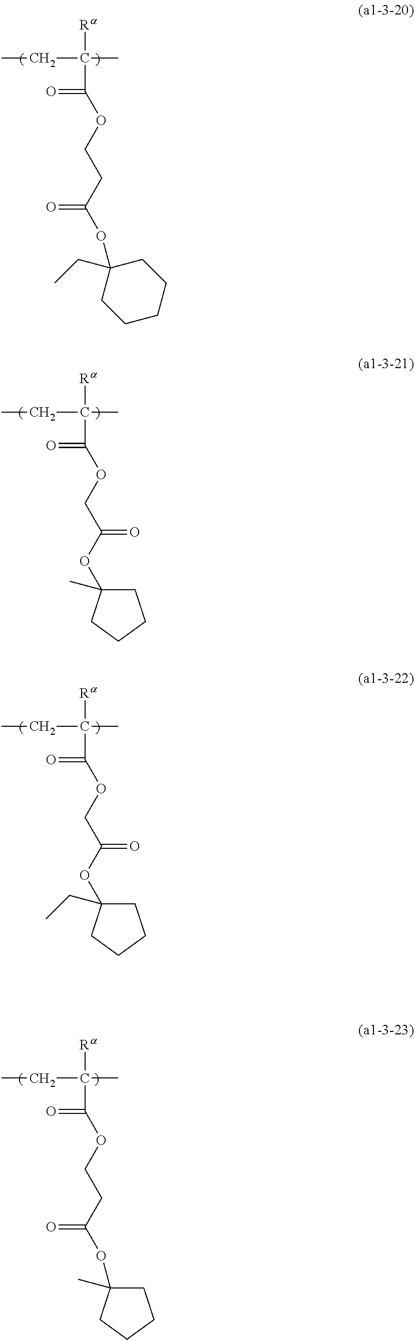

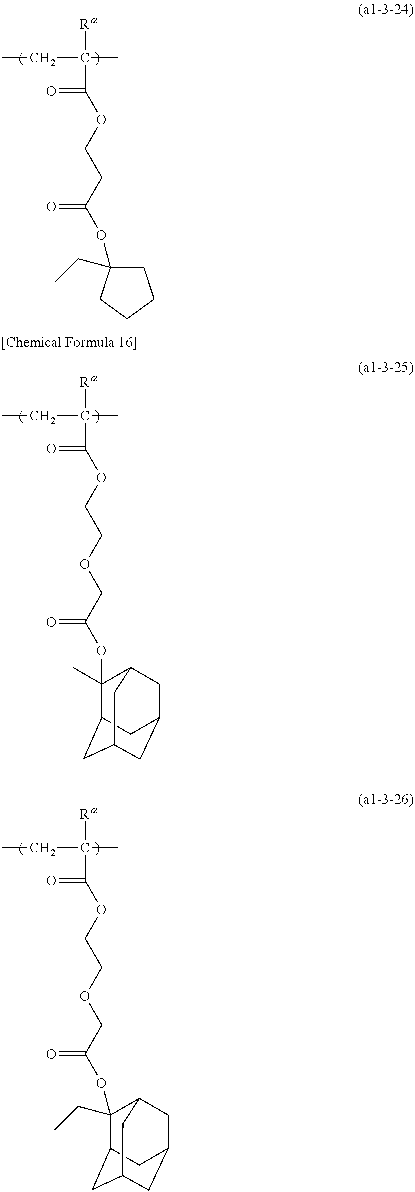

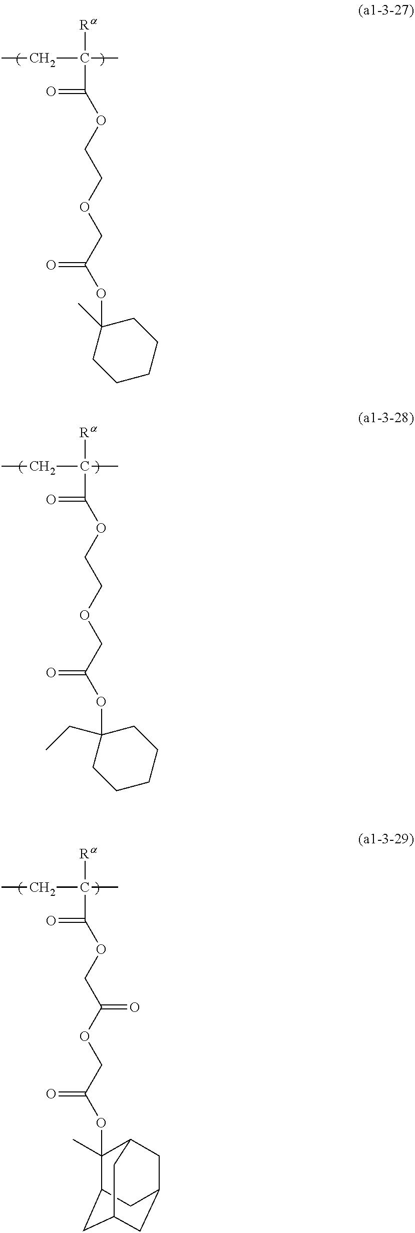

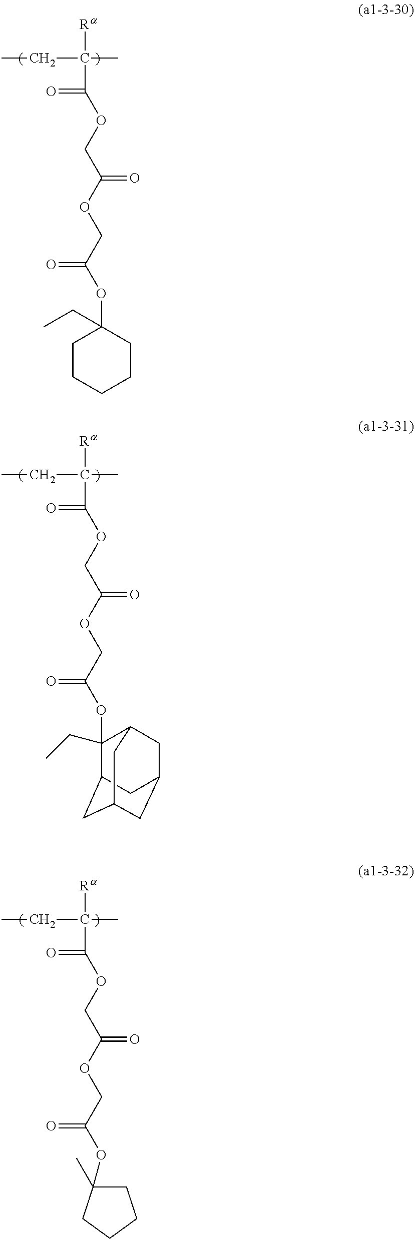

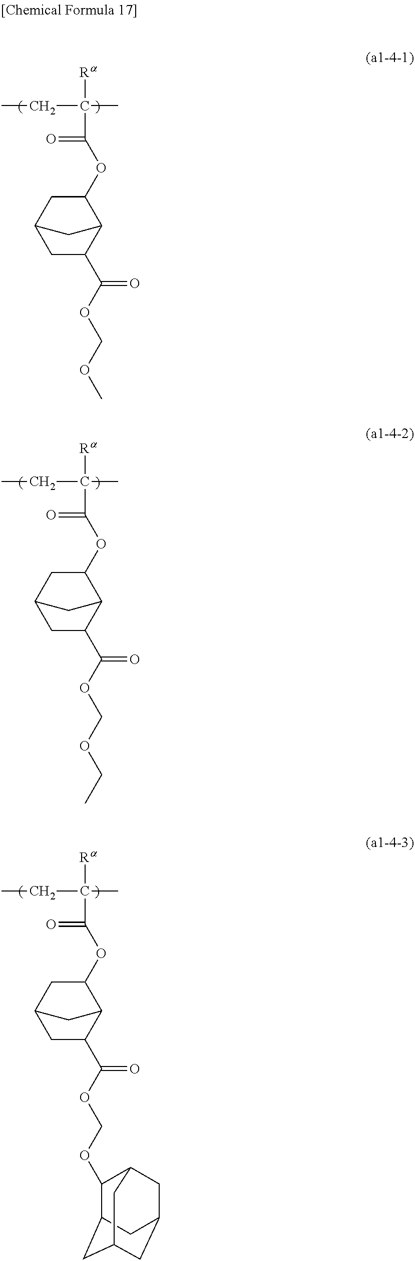

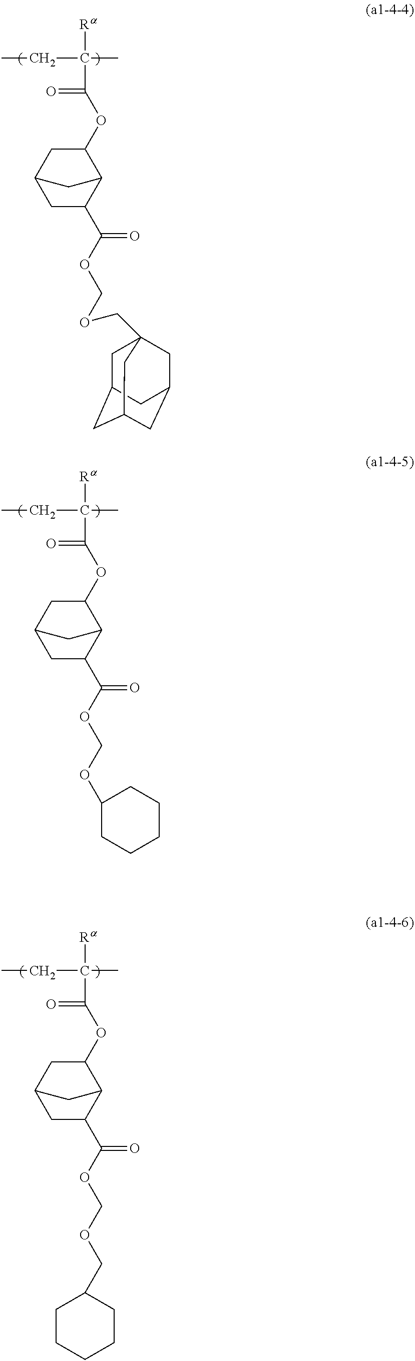

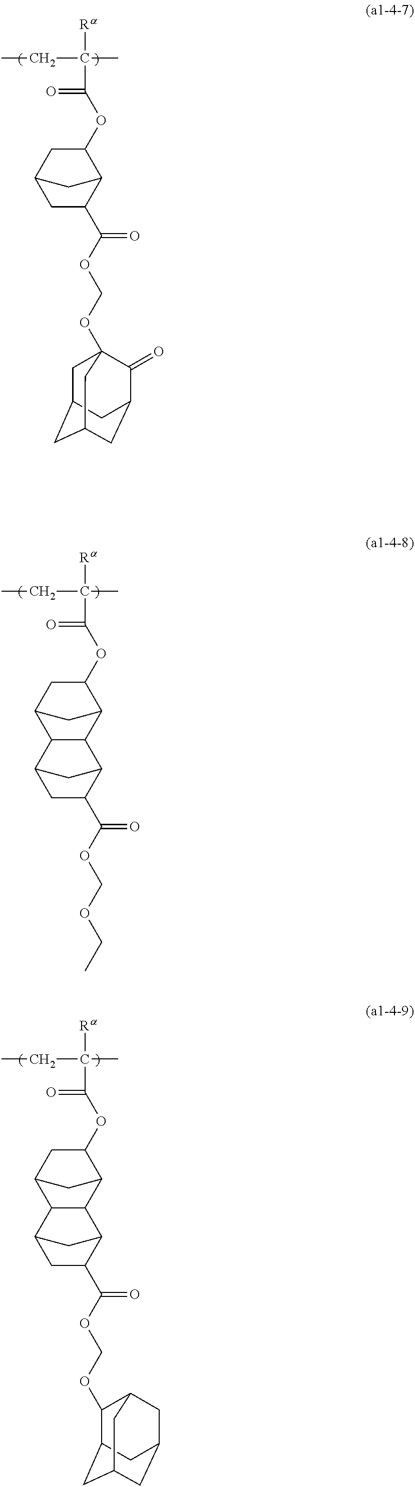

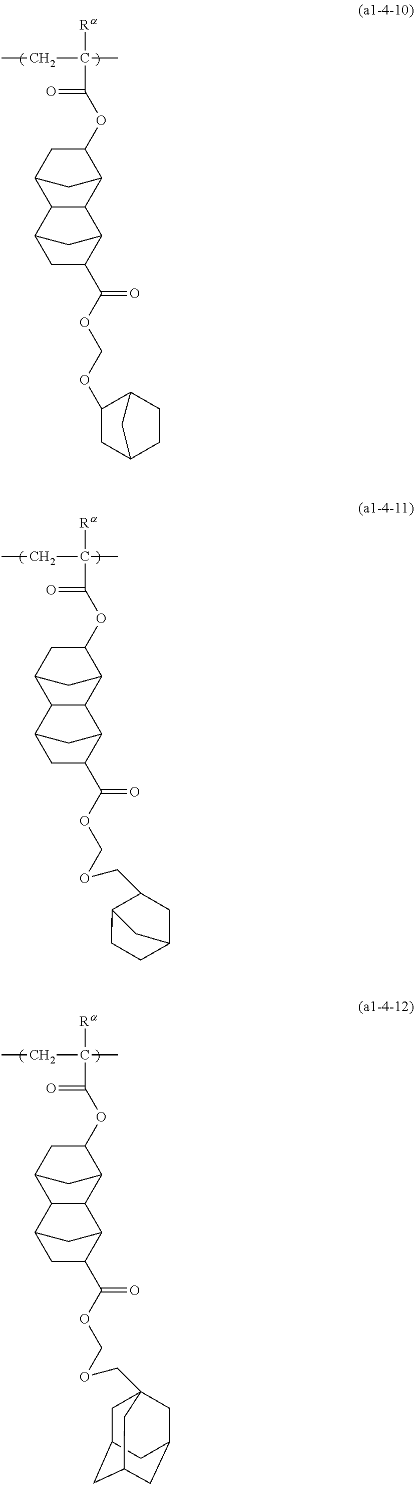

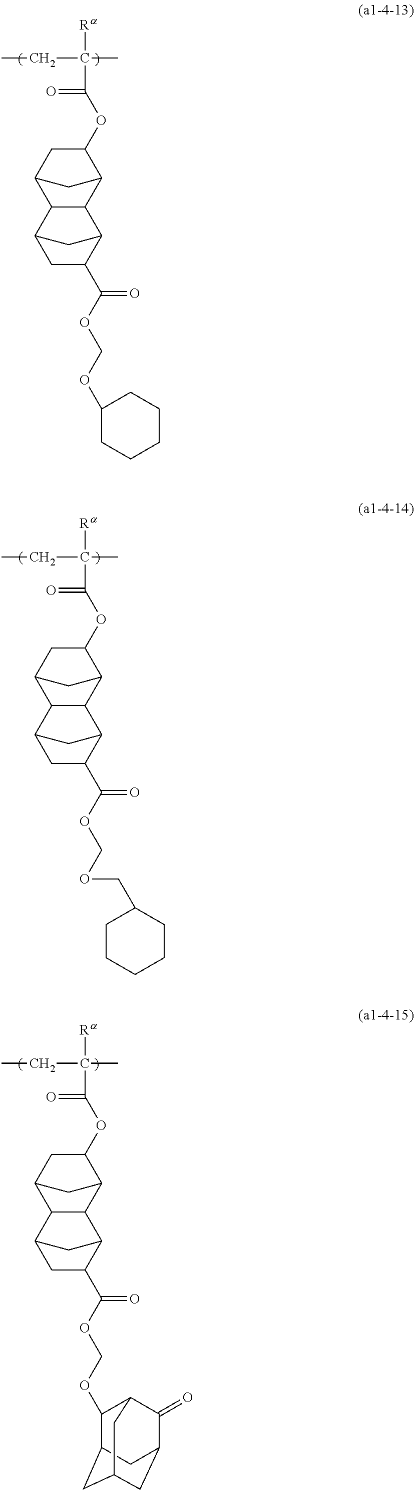

As the structural unit (a1), one type of structural unit may be used alone, or two or more types of structural units may be used in combination.

Among these, structural units represented by general formula (a1-1) or (a1-3) are preferable. More specifically, at least one structural unit selected from the group consisting of structural units represented by formulas (a1-1-1) to (a-1-1-4), (a1-1-20) to (a1-1-23) and (a1-3-25) to (a1-3-28) is more preferable.

Further, as the structural unit (a1), structural units represented by general formula (a1-1-01) shown below which includes the structural units represented by formulas (a1-1-1) to (a1-1-3); structural units represented by general formula (a1-1-02) shown below which includes the structural units represented by formulas (a1-1-16), (a1-1-17), (a1-1-20) to (a1-1-23), (a1-1-32) and (a1-1-33); structural units represented by general formula (a1-3-01) shown below which include the structural units represented by formulas (a1-3-25) and (a1-3-26); and structural units represented by general formula (a1-3-02) shown below which include the structural units represented by formulas (a1-3-27) and (a1-3-28) are also preferable.

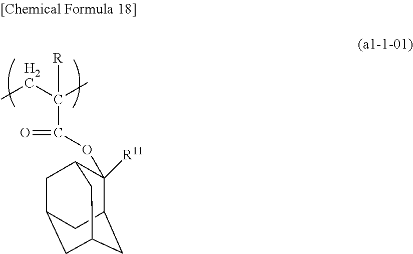

In the formula, R represents a hydrogen atom, an alkyl group of 1 to 5 carbon atoms or a halogenated alkyl group of 1 to 5 carbon atoms; and R¹¹ represents an alkyl group of 1 to 5 carbon atoms.

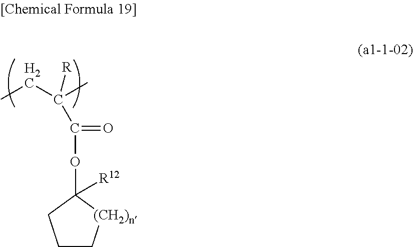

In the formula, R represents a hydrogen atom, an alkyl group of 1 to 5 carbon atoms or a halogenated alkyl group of 1 to 5 carbon atoms; and R¹² represents an alkyl group of 1 to 5 carbon atoms. n′ represents an integer of 1 to 6.

In general formula (a1-1-01), R is the same as defined above.

The alkyl group of 1 to 5 carbon atoms for R¹¹ is the same as defined for the alkyl group of 1 to 5 carbon atoms for R, and a methyl group or an ethyl group is preferable.

In general formula (a1-1-02), R is the same as defined above.

The alkyl group of 1 to 5 carbon atoms for R¹² is the same as the alkyl group of 1 to 5 carbon atoms for R above, preferably a methyl group or an ethyl group, and most preferably an ethyl group.

n′ is preferably 1 or 2.

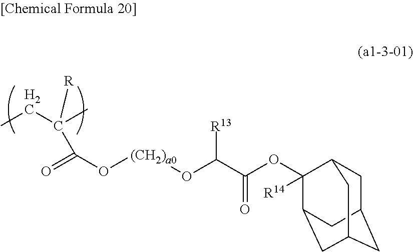

In the formula, R represents a hydrogen atom, an alkyl group of 1 to 5 carbon atoms or a halogenated alkyl group of 1 to 5 carbon atoms; R¹⁴ represents an alkyl group of 1 to 5 carbon atoms; R¹³ represents a hydrogen atom or a methyl group; and a0 represents an integer of 1 to 10.

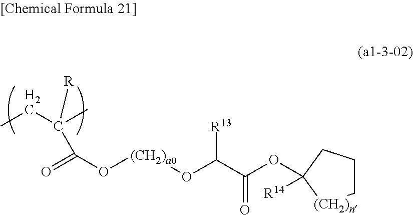

In the formula, R represents a hydrogen atom, an alkyl group of 1 to 5 carbon atoms or a halogenated alkyl group of 1 to 5 carbon atoms; R¹⁴ represents an alkyl group of 1 to 5 carbon atoms; R¹³ represents a hydrogen atom or a methyl group; a0 represents an integer of 1 to 10; and n′ represents an integer of 1 to 6.

In general formulas (a1-3-01) and (a1-3-02), R is the same as defined above.

R¹³ is preferably a hydrogen atom.

The alkyl group of 1 to 5 carbon atoms for R¹⁴ is the same as defined for the alkyl group of 1 to 5 carbon atoms for R, and a methyl group or an ethyl group is preferable.

a0 is preferably an integer of 1 to 8, more preferably an integer of 2 to 5, and most preferably 2.

n′ is the same as defined above, and is preferably 1 or 2.

In the component (A1), the amount of the structural unit (a1) based on the combined total of all structural units constituting the component (A1) is preferably 10 to 80 mol %, more preferably 20 to 70 mol %, and still more preferably 25 to 50 mol %. When the amount of the structural unit (a1) is at least as large as the lower limit of the above-mentioned range, a pattern can be easily formed using a resist composition prepared from the component (A1). On the other hand, when the amount of the structural unit (a1) is no more than the upper limit of the above-mentioned range, a good balance can be achieved with the other structural units.

(Structural Unit (a2))

The structural unit (a2) is a structural unit derived from an acrylate ester containing a lactone-containing cyclic group.

The term “lactone-containing cyclic group” refers to a cyclic group including one ring containing a —O—C(O)— structure (lactone ring). The term “lactone ring” refers to a single ring containing a —O—C(O)— structure, and this ring is counted as the first ring. A lactone-containing cyclic group in which the only ring structure is the lactone ring is referred to as a monocyclic group, and groups containing other ring structures are described as polycyclic groups regardless of the structure of the other rings.

When the component (A1) is used for forming a resist film, the lactone-containing cyclic group of the structural unit (a2) is effective in improving the adhesion between the resist film and the substrate, and increasing the compatibility with the developing solution containing water.

As the structural unit (a2), there is no particular limitation, and an arbitrary structural unit may be used.

Specific examples of lactone-containing monocyclic groups include a group in which one hydrogen atom has been removed from a 4- to 6-membered lactone ring, such as a group in which one hydrogen atom has been removed from β-propionolactone, a group in which one hydrogen atom has been removed from γ-butyrolactone, and a group in which one hydrogen atom has been removed from δ-valerolactone. Further, specific examples of lactone-containing polycyclic groups include groups in which one hydrogen atom has been removed from a lactone ring-containing bicycloalkane, tricycloalkane or tetracycloalkane.

More specifically, examples of the structural unit (a2) include structural units represented by general formulas (a2-1) to (a2-5) shown below.

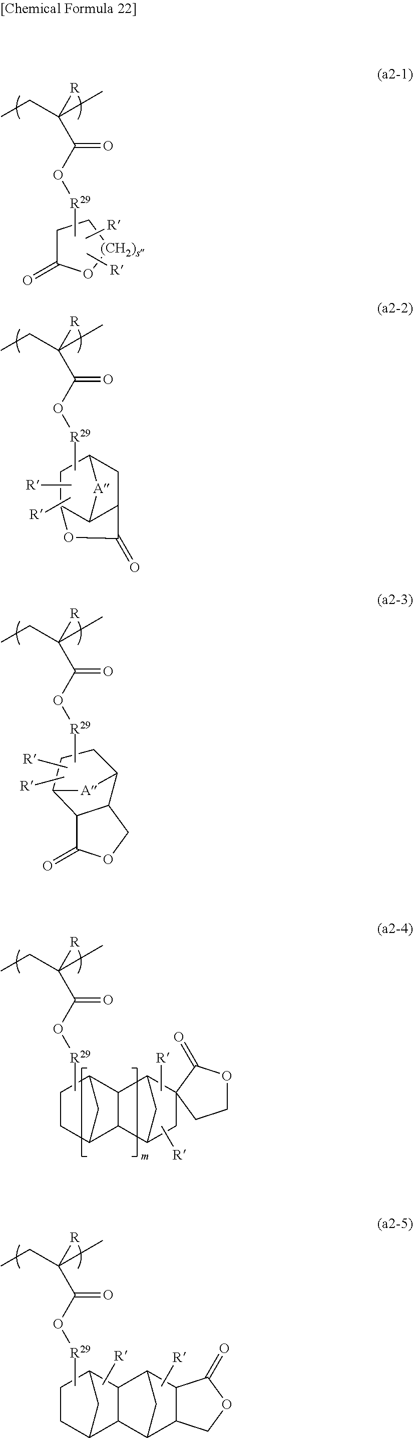

In the formulas, R represents a hydrogen atom, an alkyl group of 1 to 5 carbon atoms or a halogenated alkyl group of 1 to 5 carbon atoms; each R′ independently represents a hydrogen atom, an alkyl group of 1 to 5 carbon atoms, an alkoxy group of 1 to 5 carbon atoms or —COOR″, wherein R″ represents a hydrogen atom or an alkyl group; R²⁹ represents a single bond or a divalent linking group; s″ represents an integer of 0 to 2; A″ represents an oxygen atom, a sulfur atom or an alkylene group of 1 to 5 carbon atoms which may contain an oxygen atom or a sulfur atom; and m represents 0 or 1.

In general formulas (a2-1) to (a2-5), R is the same as defined for R in the structural unit (a1). Of the various possibilities, R is preferably a hydrogen atom or a methyl group.

Examples of the alkyl group of 1 to 5 carbon atoms for R′ include a methyl group, an ethyl group, a propyl group, an n-butyl group and a tert-butyl group.

Examples of the alkoxy group of 1 to 5 carbon atoms for R′ include a methoxy group, an ethoxy group, an n-propoxy group, an iso-propoxy group, an n-butoxy group and a tert-butoxy group

In terms of industrial availability, R′ is preferably a hydrogen atom.

When R″ is a linear or branched alkyl group, it preferably has 1 to 10 carbon atoms, more preferably 1 to 5 carbon atoms.

When R″ is a cyclic alkyl group (cycloalkyl group), it preferably has 3 to 15 carbon atoms, more preferably 4 to 12 carbon atoms, and most preferably 5 to 10 carbon atoms. As examples of the cycloalkyl group, groups in which one or more hydrogen atoms have been removed from a monocycloalkane or a polycycloalkane such as a bicycloalkane, tricycloalkane or tetracycloalkane, which may or may not be substituted with a fluorine atom or a fluorinated alkyl group, may be used. Examples of such groups include groups in which one or more hydrogen atoms have been removed from a monocycloalkane such as cyclopentane or cyclohexane; and groups in which one or more hydrogen atoms have been removed from a polycycloalkane such as adamantane, norbornane, isobornane, tricyclodecane or tetracyclododecane.

As A″, an alkylene group of 1 to 5 carbon atoms or —O— is preferable, more preferably an alkylene group of 1 to 5 carbon atoms, and most preferably a methylene group.

R²⁹ represents a single bond or a divalent linking group. Examples of divalent linking groups include the same divalent linking groups as those described above for Y² in general formula (a1-0-2). Among these, an alkylene group, an ester bond (—C(═O)—O—) or a combination thereof is preferable. The alkylene group as a divalent linking group for R²⁹ is preferably a linear or branched alkylene group. Specific examples include the same linear alkylene groups and branched alkylene groups as those described above for the aliphatic cyclic group A in Y².

s″ is preferably 1 or 2.

Specific examples of structural units represented by general formulas (a2-1) to (a2-5) are shown below. In the formulas shown below, R^{α} represents a hydrogen atom, a methyl group or a trifluoromethyl group.

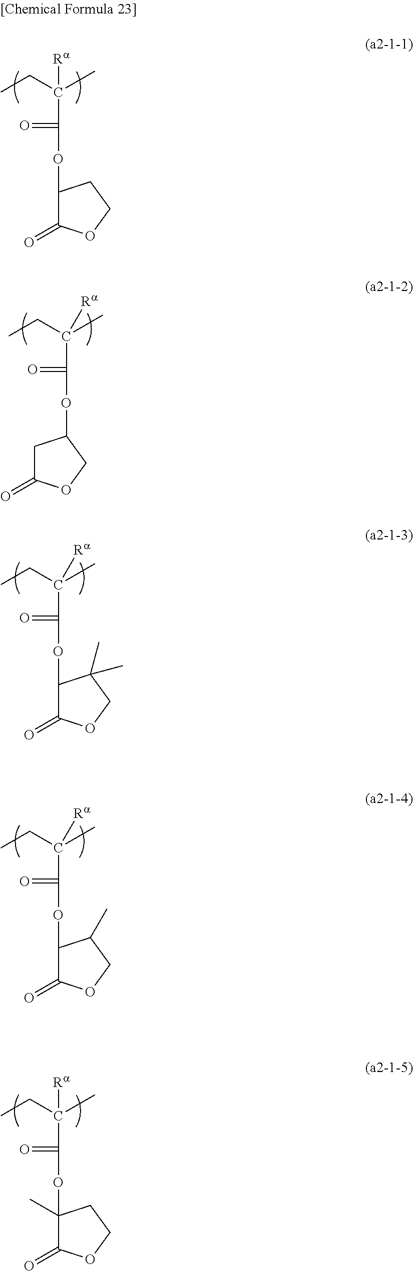

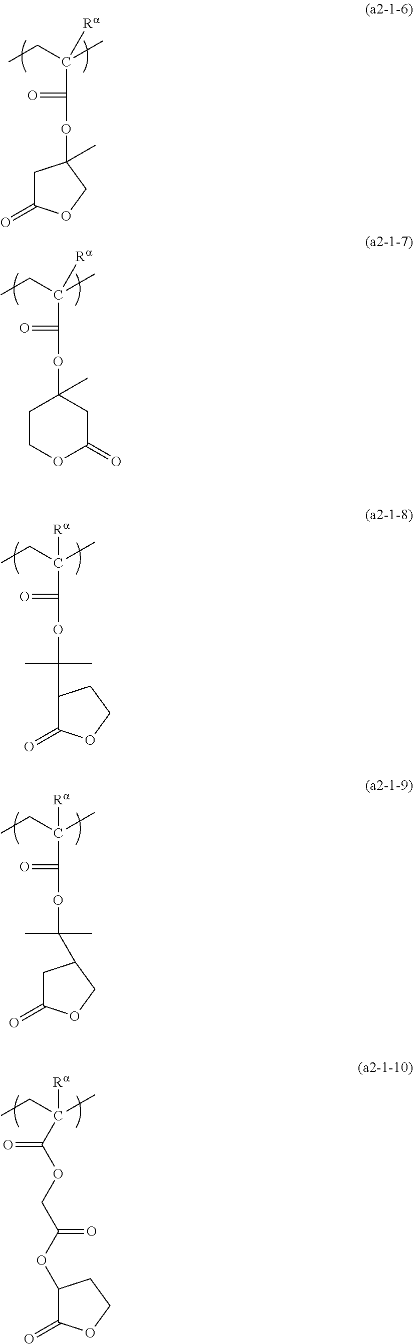

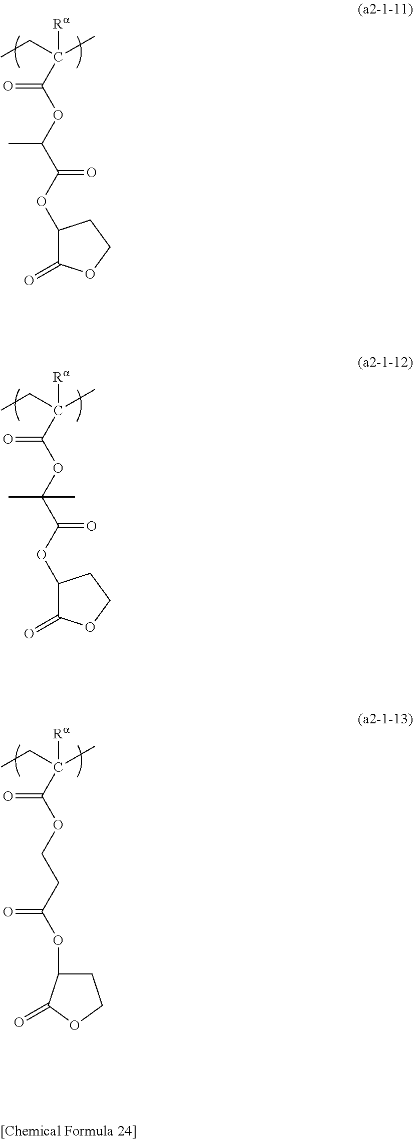

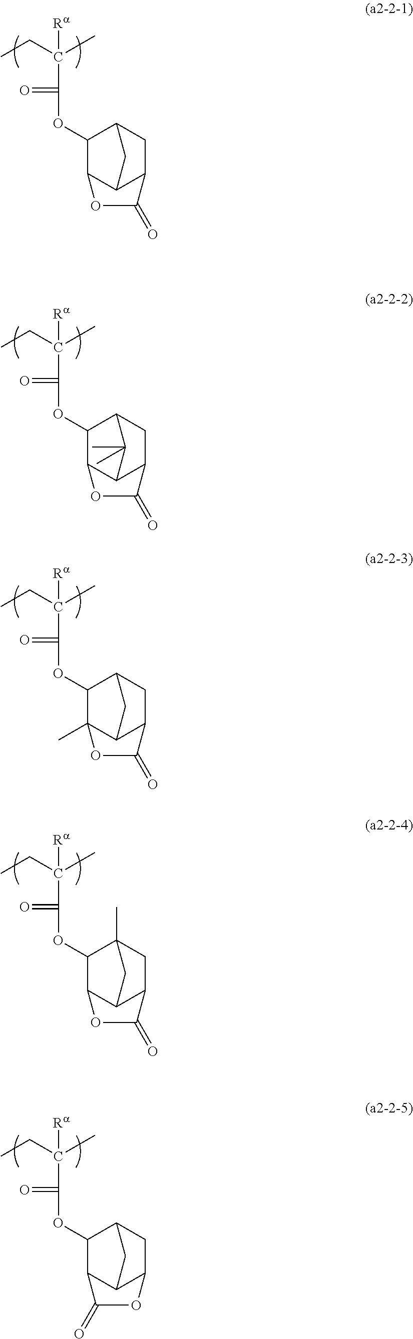

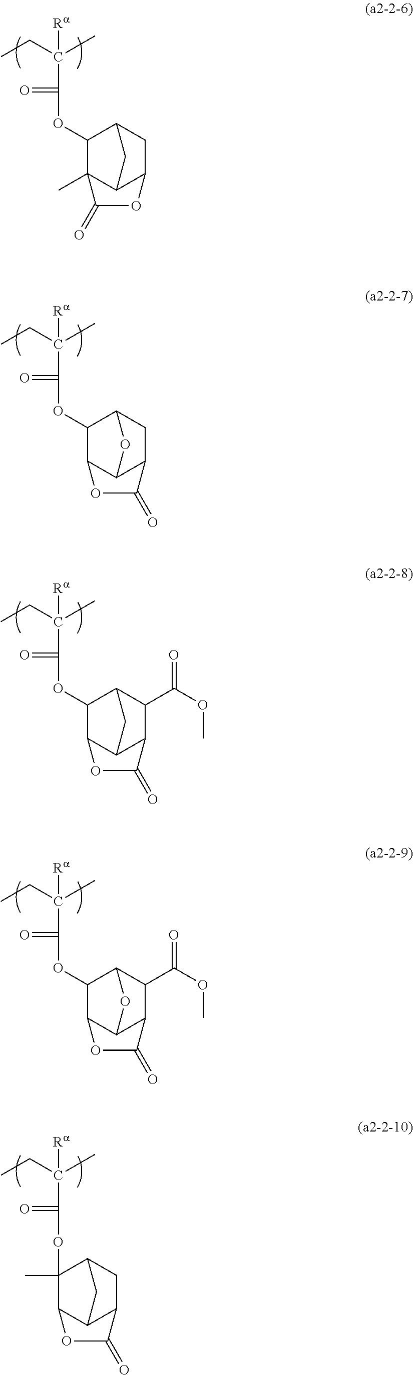

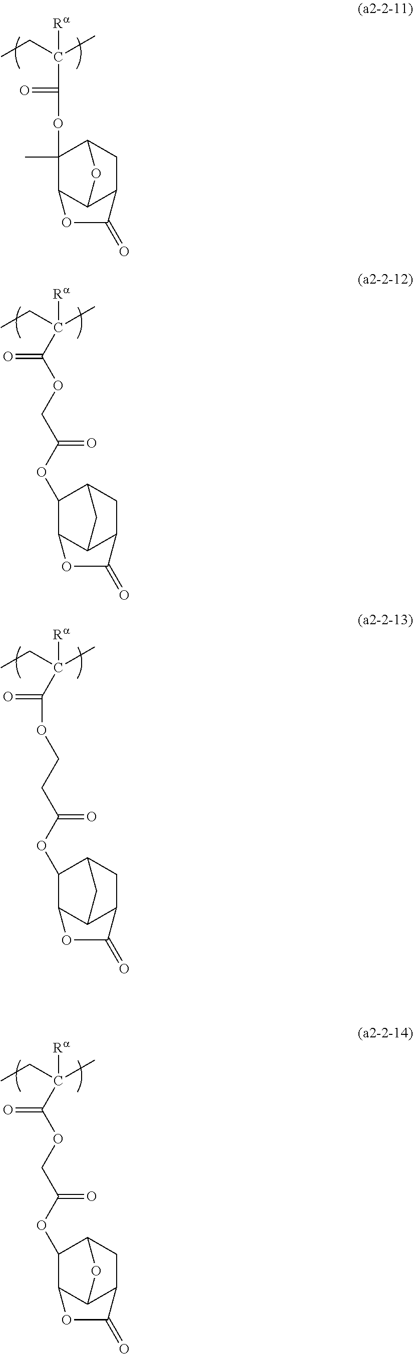

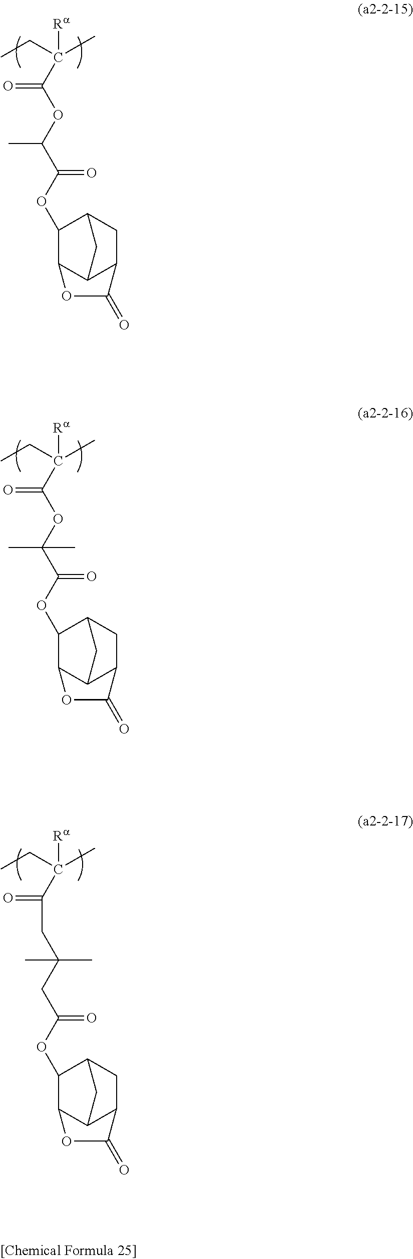

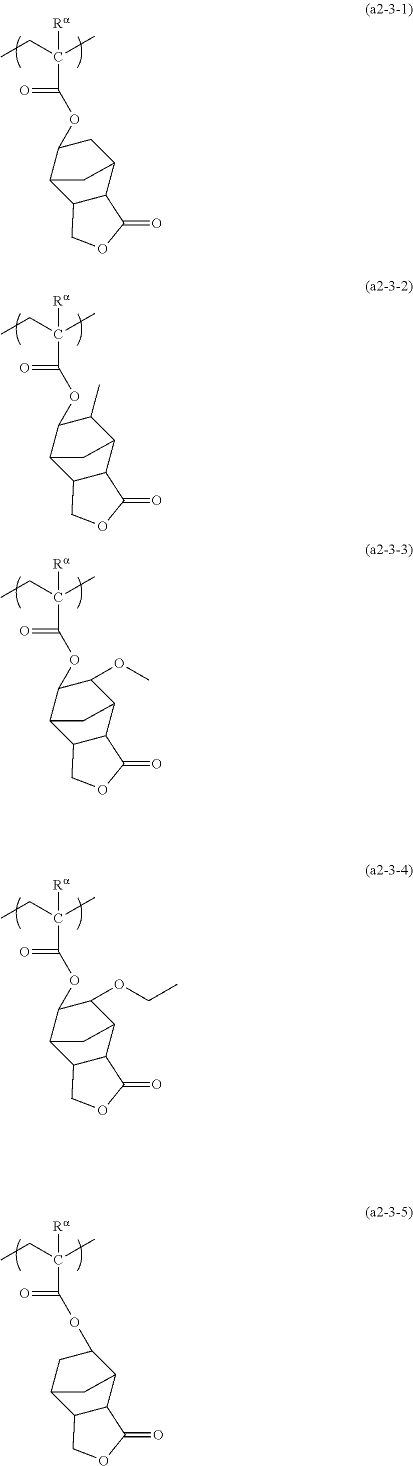

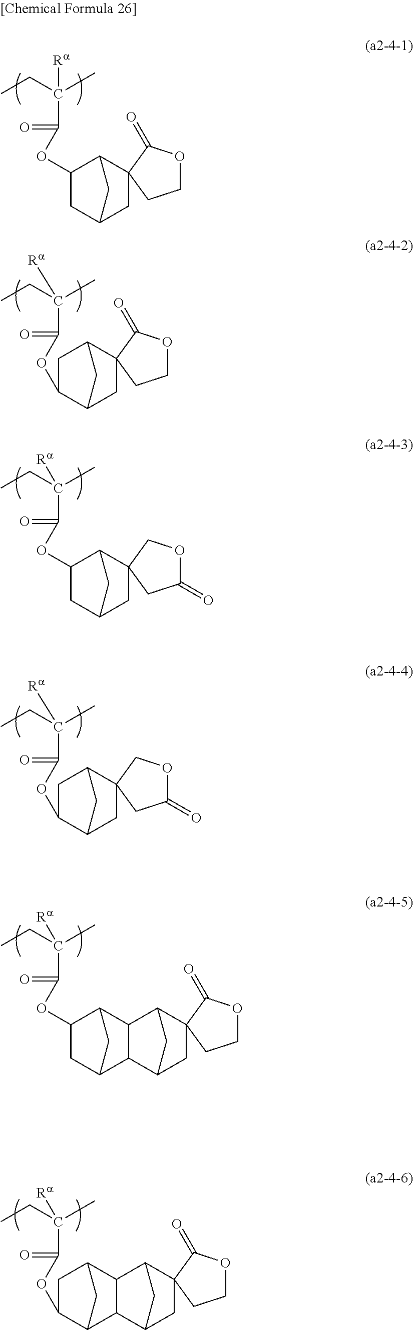

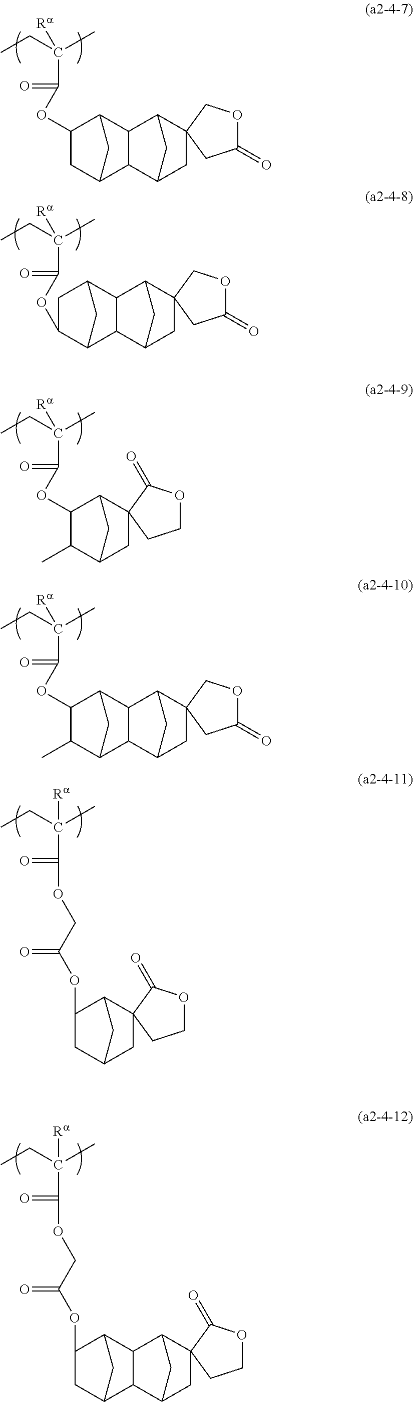

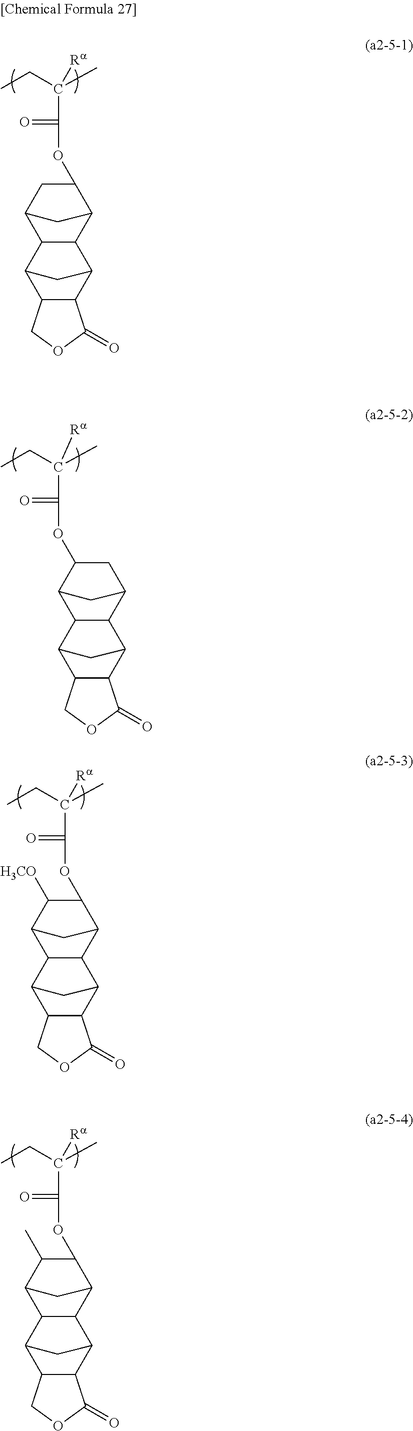

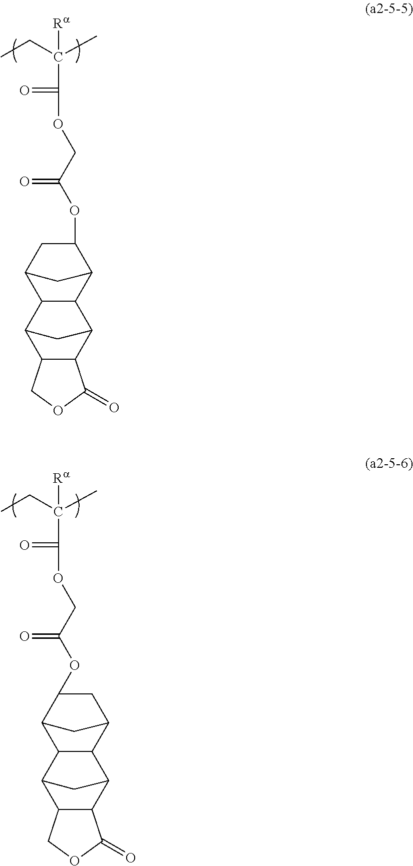

In the component (A1), as the structural unit (a2), one type of structural unit may be used, or two or more types may be used in combination.

As the structural unit (a2), at least one structural unit selected from the group consisting of formulas (a2-1) to (a2-5) is preferable, and at least one structural unit selected from the group consisting of formulas (a2-1) to (a2-3) is more preferable. Of these, it is preferable to use at least one structural unit selected from the group consisting of structural units represented by formulas (a2-1-1), (a2-1-2), (a2-2-1), (a2-2-7), (a2-3-1) and (a2-3-5).

In the component (A1), the amount of the structural unit (a2) based on the combined total of all structural units constituting the component (A1) is preferably 5 to 60 mol %, more preferably 10 to 50 mol %, and still more preferably 20 to 50 mol %. When the amount of the structural unit (a2) is at least as large as the lower limit of the above-mentioned range, the effect of using the structural unit (a2) can be satisfactorily achieved. On the other hand, when the amount of the structural unit (a2) is no more than the upper limit of the above-mentioned range, a good balance can be achieved with the other structural units.

(Structural Unit (a5))

The structural unit (a5) is a structural unit represented by general formula (a5-1) shown below.

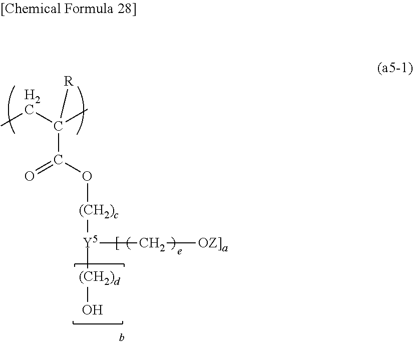

In general formula (a5-1), R represents a hydrogen atom, an alkyl group of 1 to 5 carbon atoms or a halogenated alkyl group of 1 to 5 carbon atoms; Y⁵ represents an aliphatic hydrocarbon group which may have a substituent; Z represents a monovalent organic group; a represents an integer of 1 to 3, and b represents an integer of 0 to 2, provided that a+b=1 to 3; and each of c, d and e independently represents an integer of 0 to 3.

In general formula (a5-1), R is the same as defined above for R in the structural unit (a1). Of the various possibilities, R is preferably a hydrogen atom or a methyl group.

In general formula (a5-1), Y⁵ represents an aliphatic hydrocarbon group which may have a substituent.

The aliphatic hydrocarbon group for Y⁵ may be either a saturated aliphatic hydrocarbon group, or an unsaturated aliphatic hydrocarbon group. Further, the aliphatic hydrocarbon group may be linear, branched or cyclic.

In the present description and claims, an “aliphatic hydrocarbon group” refers to an aliphatic hydrocarbon group that has no aromaticity.

Further, the expression “may have a substituent” means that part of the carbon atoms constituting the aliphatic hydrocarbon group may be substituted with a substituent group containing a hetero atom, or part or all of the hydrogen atoms constituting the aliphatic hydrocarbon group may be substituted with a substituent group containing a hetero atom.

As the “hetero atom” for Y⁵, there is no particular limitation as long as it is an atom other than carbon and hydrogen, and examples thereof include a halogen atom, an oxygen atom, a sulfur atom and a nitrogen atom. Examples of the halogen atom include a fluorine atom, a chlorine atom, an iodine atom and a bromine atom.

The substituent group containing a hetero atom may consist of a hetero atom, or may be a group containing a hetero atom and a group or atom other than a hetero atom. Specific examples thereof include —O—, —C(═O)—O—, —C(═O)—, —O—C(═O)—O—, —C(═O)—NH—, —NH— (the H may be replaced with a substituent such as an alkyl group or an acyl group), —S—, —S(═O)₂— and —S(═O)₂—O—. When the aliphatic hydrocarbon group is cyclic, the aliphatic hydrocarbon group may contain any of these substituent groups in the ring structure.

Examples of the substituent group for substituting part or all of the hydrogen atoms constituting the aliphatic hydrocarbon group include an alkoxy group, a halogen atom, a halogenated alkyl group, a hydroxyl group, an oxygen atom (═O), a cyano group and an alkyl group.

The aforementioned alkoxy group is preferably an alkoxy group having 1 to 5 carbon atoms, more preferably a methoxy group, an ethoxy group, an n-propoxy group, an iso-propoxy group, an n-butoxy group or a tert-butoxy group, and most preferably a methoxy group or an ethoxy group.

Examples of the aforementioned halogen atom include a fluorine atom, a chlorine atom, a bromine atom and an iodine atom, and a fluorine atom is preferable.

Example of the aforementioned halogenated alkyl group includes a group in which part or all of the hydrogen atoms within an alkyl group of 1 to 5 carbon atoms (e.g., a methyl group, an ethyl group, a propyl group, an n-butyl group or a tert-butyl group) have been substituted with the aforementioned halogen atoms.

Examples of the alkyl group include alkyl groups of 1 to 5 carbon atoms such as a methyl group, an ethyl group, a propyl group, an n-butyl group and a tert-butyl group.

When Y⁵ represents a linear or branched aliphatic hydrocarbon group, the linear or branched aliphatic hydrocarbon group preferably has 1 to 10 carbon atoms, more preferably 1 to 5, and most preferably 1 to 3. Specific examples of preferable linear or branched aliphatic hydrocarbon group include chain-like alkylene groups.

When Y⁵ represents a cyclic aliphatic hydrocarbon group (aliphatic cyclic group), the basic ring of the “aliphatic cyclic group” exclusive of substituents (aliphatic ring) is not limited to be constituted from only carbon and hydrogen (not limited to hydrocarbon rings), and the ring (aliphatic ring) may contain a hetero atom (e.g., an oxygen atom or the like) in the structure thereof. Further, the “hydrocarbon ring” may be either saturated or unsaturated, but is preferably saturated.

The aliphatic cyclic group may be either a polycyclic group or a monocyclic group. Examples of aliphatic cyclic groups include groups in which two or more hydrogen atoms have been removed from a monocycloalkane or a polycycloalkane such as a bicycloalkane, tricycloalkane or tetracycloalkane which may or may not be substituted with a lower alkyl group, a fluorine atom or a fluorinated alkyl group. Specific examples include groups in which two or more hydrogen atoms have been removed from a monocycloalkane such as cyclopentane or cyclohexane; and groups in which two or more hydrogen atoms have been removed from a polycycloalkane such as adamantane, norbornane, isobornane, tricyclodecane or tetracyclododecane.

Further examples of the aliphatic cyclic group include groups in which two or more hydrogen atoms have been removed from tetrahydrofuran or tetrahydropyran which may or may not be substituted with a lower alkyl group, a fluorine atom or a fluorinated alkyl group.

The aliphatic cyclic group within the structural unit (a5) is preferably a polycyclic group, and a group in which two or more hydrogen atoms have been removed from adamantane is particularly desirable.

In general formula (a5-1), Z represents a monovalent organic group.

In the present description and claims, the term “organic group” refers to a group containing a carbon atom, and may include atoms other than carbon (e.g., a hydrogen atom, an oxygen atom, a nitrogen atom, a sulfur atom, a halogen atom (such as a fluorine atom and a chlorine atom) and the like).

Examples of the organic group for Z include an aliphatic hydrocarbon group which may have a substituent, an aromatic hydrocarbon group which may have a substituent, and a group represented by the formula -Q⁵-R⁵ (in the formula, Q⁵ represents a divalent linking group, and R⁵ represents an aliphatic hydrocarbon group which may have a substituent or an aromatic hydrocarbon group which may have a substituent).

Examples of the aliphatic hydrocarbon group for the organic group represented by Z include a linear, branched or cyclic, saturated hydrocarbon group of 1 to 20 carbon atoms, and a linear or branched, aliphatic unsaturated hydrocarbon group of 2 to 20 carbon atoms.

Examples of the linear, saturated hydrocarbon group include a methyl group, an ethyl group, a propyl group, a butyl group, a pentyl group, a hexyl group, a heptyl group, an octyl group, a nonyl group and a decyl group.

Examples of the branched, saturated hydrocarbon group include a 1-methylethyl group, a 1-methylpropyl group, a 2-methylpropyl group, a 1-methylbutyl group, a 2-methylbutyl group, a 3-methylbutyl group, a 1-ethylbutyl group, a 2-ethylbutyl group, a 1-methylpentyl group, a 2-methylpentyl group, a 3-methylpentyl group and a 4-methylpentyl group.

The linear or branched alkyl group may have a substituent. Examples of the substituent include an alkoxy group, a halogen atom, a halogenated alkyl group, a hydroxyl group, an oxygen atom (═O), a cyano group and a carboxy group.

The alkoxy group as the substituent for the linear or branched alkyl group is preferably an alkoxy group having 1 to 5 carbon atoms, more preferably a methoxy group, an ethoxy group, an n-propoxy group, an iso-propoxy group, an n-butoxy group or a tert-butoxy group, and most preferably a methoxy group or an ethoxy group.

Examples of the halogen atom as the substituent for the linear or branched alkyl group include a fluorine atom, a chlorine atom, a bromine atom and an iodine atom, and a fluorine atom is preferable.

Examples of the halogenated alkyl group as a substituent include groups in which part or all of the hydrogen atoms within an alkyl group of 1 to 5 carbon atoms (preferably a methyl group, an ethyl group, a propyl group, an n-butyl group, a tert-butyl group, or the like) have been substituted with the aforementioned halogen atoms.

The cyclic, saturated hydrocarbon group may be either a polycyclic group or a monocyclic group. Examples thereof include cyclic, saturated hydrocarbon groups of 3 to 20 carbon atoms, such as groups in which one hydrogen atom has been removed from a monocycloalkane or a polycycloalkane (e.g., a bicycloalkane, a tricycloalkane or a tetracycloalkane). More specific examples include groups in which one hydrogen atom has been removed from a monocycloalkane such as cyclopentane, cyclohexane, cycloheptane or cyclooctane; and groups in which one hydrogen atom has been removed from a polycycloalkane such as adamantane, norbornane, isobornane, tricyclodecane or tetracyclododecane.

The cyclic alkyl group may have a substituent. For example, part of the carbon atoms constituting the ring within the cyclic alkyl group may be substituted with a hetero atom, or a hydrogen atom bonded to the ring within the cyclic alkyl group may be substituted with a substituent.

In the former example, a heterocycloalkane in which part of the carbon atoms constituting the ring within the aforementioned monocycloalkane or polycycloalkane has been substituted with a hetero atom such as an oxygen atom, a sulfur atom or a nitrogen atom, and one hydrogen atom has been removed therefrom, can be used. Further, the ring may contain an ester bond (—C(═O)—O—). More specific examples include a lactone-containing monocyclic group, such as a group in which one hydrogen atom has been removed from γ-butyrolactone; and a lactone-containing polycyclic group, such as a group in which one hydrogen atom has been removed from a bicycloalkane, tricycloalkane or tetracycloalkane containing a lactone ring.

In the latter example, as the substituent, the same substituent groups as those for the aforementioned linear or branched alkyl group, or an alkyl group of 1 to 5 carbon atoms can be used.

Examples of linear unsaturated hydrocarbon groups include a vinyl group, a propenyl group (an allyl group) and a butynyl group.

Examples of branched unsaturated hydrocarbon groups include a 1-methylpropenyl group and a 2-methylpropenyl group.

The aforementioned linear or branched, unsaturated hydrocarbon group may have a substituent. Examples of substituents include the same substituents as those which the aforementioned linear or branched alkyl group may have.

The aromatic hydrocarbon group as the organic group for Z is a hydrocarbon group having an aromatic ring. The aromatic hydrocarbon ring preferably has 3 to 30 carbon atoms, more preferably 5 to 30, still more preferably 5 to 20, still more preferably 6 to 15, and most preferably 6 to 12. Here, the number of carbon atoms within a substituent(s) is not included in the number of carbon atoms of the aromatic hydrocarbon group.

The aromatic hydrocarbon group may be either a group including an aromatic hydrocarbon ring in which the ring skeleton of the aromatic ring is constituted of only carbon atoms, or a group including an aromatic hetero ring in which the ring skeleton of the aromatic ring contains not only carbon atoms but also a hetero atom.

Examples of the aromatic hydrocarbon group include an aryl group which is an aromatic hydrocarbon ring having one hydrogen atom removed therefrom, such as a phenyl group, a biphenyl group, a fluorenyl group, a naphthyl group, an anthryl group or a phenanthryl group; a heteroaryl group in which part of the carbon atoms constituting the aforementioned aryl group has been substituted with a hetero atom such as an oxygen atom, a sulfur atom or a nitrogen atom; and an arylalkyl group, such as a benzyl group, a phenethyl group, a 1-naphthylmethyl group, a 2-naphthylmethyl group, a 1-naphthylethyl group or a 2-naphthylethyl group. The alkyl chain within the arylalkyl group preferably has 1 to 4 carbon atom, more preferably 1 or 2, and most preferably 1.

The aromatic hydrocarbon group may have a substituent. For example, part of the carbon atoms constituting the aromatic ring within the aromatic hydrocarbon group may be substituted with a hetero atom, or a hydrogen atom bonded to the aromatic ring within the aromatic hydrocarbon group may be substituted with a substituent.

In the former example, a heteroaryl group in which part of the carbon atoms constituting the ring within the aforementioned aryl group has been substituted with a hetero atom such as an oxygen atom, a sulfur atom or a nitrogen atom, and a heteroarylalkyl group in which part of the carbon atoms constituting the ring of the aforementioned arylalkyl group has been substituted with the aforementioned heteroatom can be used.

In the latter example, as the substituent for the aromatic group, an alkyl group, an alkoxy group, a halogen atom, a halogenated alkyl group, a hydroxyl group, an oxygen atom (═O), an acetyl group or the like can be used.

Examples of the alkyl group, alkoxy group, halogen atom and halogenated alkyl group as the substituent for the aromatic group include the same substituent groups as those for the aforementioned linear or branched alkyl group, and an alkyl group of 1 to 5 carbon atoms.

In the group represented by the formula -Q⁵-R⁵, Q⁵ represents a divalent linking group, and R⁵ represents an aliphatic hydrocarbon group which may have a substituent or an aromatic hydrocarbon group which may have a substituent.

As examples of the divalent linking group for Q⁵, the same groups as those described above in the explanation of Y² in formula (a1-0-2) can be mentioned.

As examples of R⁵, the same aliphatic hydrocarbon groups and aromatic hydrocarbon groups as those described above for Z can be mentioned.

Among these examples, as the organic group for Z, in consideration of the improvement in solubility in an organic solvent when blended within a resist composition, a group containing an aliphatic hydrocarbon group which may have a substituent is preferable, and a group represented by the formula -Q⁵-R⁸′ (in the formula, Q⁵ represents a divalent linking group, and R⁸′ represents an aliphatic hydrocarbon group which may have a substituent) is more preferable. Specific examples of preferable organic groups include a tertiary alkyl group-containing group and an alkoxyalkyl group.

(Tertiary Alkyl Group-Containing Group)

In the present description and the claims, the term “tertiary alkyl group” refers to an alkyl group having a tertiary carbon atom. As mentioned above, the term “alkyl group” refers to a monovalent saturated hydrocarbon group, and includes chain-like (linear or branched) alkyl groups and cyclic alkyl groups.

The term “tertiary alkyl group-containing group” refers to a group which includes a tertiary alkyl group in the structure thereof. The tertiary alkyl group-containing group may be either constituted of only a tertiary alkyl group, or constituted of a tertiary alkyl group and an atom or group other than a tertiary alkyl group.

Examples of the “atom or group other than a tertiary alkyl group” which constitutes the tertiary alkyl group-containing group with a tertiary alkyl group include a carbonyloxy group, a carbonyl group, an alkylene group and an oxygen atom.

As the tertiary alkyl group-containing group for Z, a tertiary alkyl group-containing group which does not have a ring structure, and a tertiary alkyl group-containing group which has a ring structure can be mentioned.

A tertiary alkyl group-containing group which does not have a ring structure is a group which has a branched tertiary alkyl group as the tertiary alkyl group, and has no ring in the structure thereof.

As the branched tertiary alkyl group, for example, a group represented by general formula (I) shown below can be mentioned.

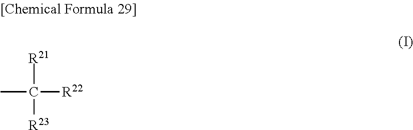

In formula (I), each of R²¹ to R²³ independently represents a linear or branched alkyl group. The number of carbon atoms within the alkyl group is preferably from 1 to 5, and more preferably from 1 to 3.

Further, in the group represented by general formula (I), the total number of carbon atoms is preferably from 4 to 7, more preferably from 4 to 6, and most preferably 4 or 5.

Preferable examples of the group represented by general formula (I) include a tert-butyl group and a tert-pentyl group, and a tert-butyl group is more preferable.

Examples of tertiary alkyl group-containing groups which do not have a ring structure include the aforementioned branched tertiary alkyl group; a tertiary alkyl group-containing, chain-like alkyl group in which the aforementioned branched tertiary alkyl group is bonded to a linear or branched alkylene group; a tertiary alkyloxycarbonyl group which has the aforementioned branched tertiary alkyl group as the tertiary alkyl group; and a tertiary alkyloxycarbonylalkyl group which has the aforementioned branched tertiary alkyl group as the tertiary alkyl group.

As the alkylene group within the tertiary alkyl group-containing, chain-like alkyl group, an alkylene group of 1 to 5 carbon atoms is preferable, an alkylene group of 1 to 4 carbon atoms is more preferable, and an alkylene group of 2 carbon atoms is the most desirable.

As a chain-like tertiary alkyloxycarbonyl group, for example, a group represented by general formula (II) shown below can be mentioned. In general formula (II), R²¹ to R²³ are the same as defined for R²¹ to R²³ in general formula (I). As the chain-like tertiary alkyloxycarbonyl group, a tert-butyloxycarbonyl group (t-boc) and a tert-pentyloxycarbonyl group are preferable.

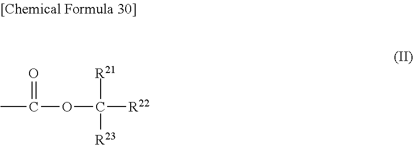

As a chain-like tertiary alkyloxycarbonylalkyl group, for example, a group represented by general formula (III) shown below can be mentioned. In general formula (III), R²¹ to R²³ are the same as defined for R²¹ to R²³ in general formula (I). f represents an integer of 1 to 3, and is preferably 1 or 2. As the chain-like tertiary alkyloxycarbonylalkyl group, a tert-butyloxycarbonylmethyl group and a tert-butyloxycarbonylethyl group are preferable.

Among these, as the tertiary alkyl group-containing group which does not have a ring structure, a tertiary alkyloxycarbonyl group or a tertiary alkyloxycarbonylalkyl group is preferable, a tertiary alkyloxycarbonyl group is more preferable, and a tert-butyloxycarbonyl group (t-boc) is most preferable.

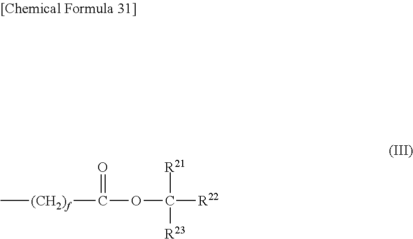

A tertiary alkyl group-containing group which has a ring structure is a group which contains a tertiary carbon atom and a ring in the structure thereof.

In the tertiary alkyl group-containing group which has a ring structure, the ring structure preferably has 4 to 12 carbon atoms which constitute the ring, more preferably 5 to 10 carbon atoms, and most preferably 6 to 10 carbon atoms. As the ring structure, for example, groups in which one or more hydrogen atoms have been removed from a monocycloalkane or a polycycloalkane such as a bicycloalkane, tricycloalkane or tetracycloalkane can be mentioned. Preferable examples include groups in which one or more hydrogen atoms have been removed from a monocycloalkane such as cyclopentane or cyclohexane; and groups in which one or more hydrogen atoms have been removed from a polycycloalkane such as adamantane, norbornane, isobornane, tricyclodecane or tetracyclododecane.

As the tertiary alkyl group-containing group which has a ring structure, for example, a group having the following group (1) or (2) as the tertiary alkyl group can be mentioned.

(1) A group in which a linear or branched alkyl group is bonded to a carbon atom which constitutes the ring of a cyclic alkyl group (cycloalkyl group), so that the carbon atom becomes a tertiary carbon atom.

(2) A group in which an alkylene group (branched alkylene group) having a tertiary carbon atom is bonded to a carbon atom constituting the ring of a cycloalkyl group.

In the aforementioned group (1), the linear or branched alkyl group preferably has 1 to 5 carbon atoms, more preferably 1 to 4 carbon atoms, and most preferably 1 to 3 carbon atoms.

Examples of the group (1) include a 2-methyl-2-adamantyl group, a 2-ethyl-2-adamantyl group, a 1-methyl-1-cycloalkyl group and a 1-ethyl-1-cycloalkyl group.

In the aforementioned group (2), the cycloalkyl group having a branched alkylene group bonded thereto may have a substituent. Examples of the substituent include a fluorine atom, a fluorinated alkyl group of 1 to 5 carbon atoms, and an oxygen atom (═O).

As an example of the group (2), a group represented by general formula (IV) shown below can be given.

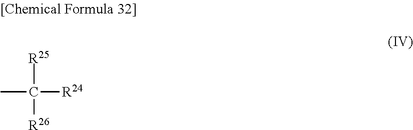

In general formula (IV), R²⁴ represents a cycloalkyl group which may or may not have a substituent. Examples of the substituent which the cycloalkyl group may have include a fluorine atom, a fluorinated alkyl group of 1 to 5 carbon atoms, and an oxygen atom (═O).

Each of R²⁵ and R²⁶ independently represents a linear or branched alkyl group. As the alkyl group, the same alkyl groups as those described above for R²¹ to R²³ in general formula (I) may be mentioned.

(Alkoxyalkyl Group)

As the alkoxyalkyl group for Z, for example, a group represented by general formula (V) shown below can be mentioned.

[Chemical Formula 33]

—R⁴²—O—R⁴¹ (V)

In formula (V), R⁴¹ represents a linear, branched or cyclic alkyl group.

When R⁴¹ represents a linear or branched alkyl group, it is preferably an alkyl group of 1 to 5 carbon atoms, more preferably an ethyl group or a methyl group, and an ethyl group is particularly desirable.

When R⁴¹ represents a cyclic alkyl group, it preferably has 4 to 15 carbon atoms, more preferably 4 to 12 carbon atoms, and most preferably 5 to 10 carbon atoms. As examples of the cyclic alkyl group, groups in which one or more hydrogen atoms have been removed from a monocycloalkane or a polycycloalkane such as a bicycloalkane, tricycloalkane or tetracycloalkane, and which may or may not be substituted with a fluorine atom or a fluorinated alkyl group, may be mentioned. Specific examples include groups in which one or more hydrogen atoms have been removed from a monocycloalkane such as cyclopentane or cyclohexane; and groups in which one or more hydrogen atoms have been removed from a polycycloalkane such as adamantane, norbornane, isobornane, tricyclodecane or tetracyclododecane. Among these, a group in which one or more hydrogen atoms have been removed from adamantane is preferable.

R⁴² represents a linear or branched alkylene group. The alkylene group preferably has 1 to 5 carbon atoms, more preferably 1 to 3 carbon atoms, and most preferably 1 or 2 carbon atoms.

As the alkoxyalkyl group for Z, a group represented by general formula (VI) shown below is particularly desirable.

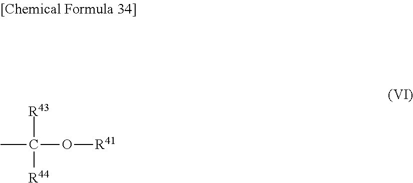

In general formula (VI), R⁴¹ is the same as defined above, and each of R⁴³ and R⁴⁴ independently represents a linear or branched alkyl group or a hydrogen atom.

With respect to R⁴³ and R⁴⁴, the alkyl group preferably has 1 to 15 carbon atoms, and may be either linear or branched. As the alkyl group, an ethyl group or a methyl group is preferable, and a methyl group is most preferable. It is particularly desirable that either one of R⁴³ and R⁴⁴ be a hydrogen atom, and the other be a methyl group.

Among the above-mentioned examples, as Z, a tertiary alkyl group-containing group is preferable, a group represented by general formula (II) above is more preferable, and a tert-butyloxycarbonyl group (t-boc) is most preferable.

In general formula (a5-1), a represents an integer of 1 to 3, and b represents an integer of 0 to 2, with the provision that a+b=1 to 3.

a is preferably 1.

b is preferably 0.

a+b is preferably 1.

c represents an integer of 0 to 3, preferably 0 or 1, and more preferably 0.

d represents an integer of 0 to 3, preferably 0 or 1, and more preferably 0.

e represents an integer of 0 to 3, preferably 0 or 1, and more preferably 0.

As the structural unit (a5), a structural unit represented by general formula (a5-1-1) or (a5-1-2) shown below is particularly desirable.

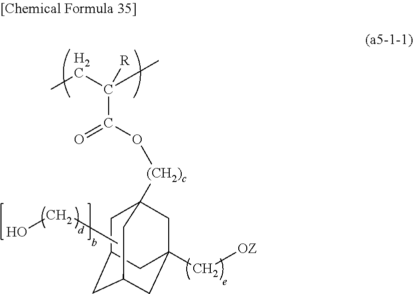

In the formula, R, Z, b, c, d and e are the same as defined above.

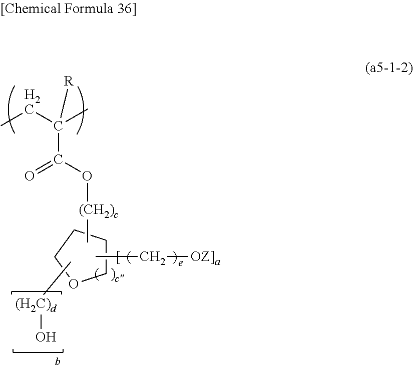

In the formula, R, Z, a, b, c, d and e are the same as defined above, and c″ represents an integer of 1 to 3.

In formula (a5-1-2), c″ represents an integer of 1 to 3, preferably 1 or 2, and still more preferably 1.

When c represents 0 in formula (a5-1-2), the oxygen atom on the terminal of the carbonyloxy group within the acrylate ester is preferably not bonded to the carbon atom which is bonded to the oxygen atom within the cyclic group. That is, when c represents 0, it is preferable that there are at least two carbon atoms present between the terminal oxygen atom and the oxygen atom within the cyclic group (excluding the case where the number of such carbon atom is one (i.e., the case where an acetal bond is formed)).

A monomer for deriving the structural unit (a5) can be synthesized, for example, by protecting part or all of the hydroxyl groups within a compound represented by general formula (a5-1′) shown below (namely, an acrylate ester containing an aliphatic cyclic group having 1 to 3 alcoholic hydroxyl groups) with organic groups (preferably tertiary alkyl group-containing groups or alkoxyalkyl groups) by a conventional method.

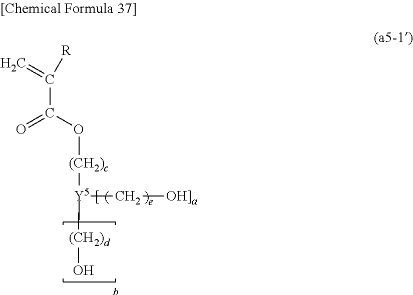

In the formula, R, Y⁵, a, b, c, d and e are the same as defined above.

As the structural unit (a5), one type of structural unit may be used alone, or two or more types of structural units may be used in combination.

The amount of the structural unit (a5) within the component (A1) based on the combined total of all structural units constituting the component (A1) is preferably 1 to 45 mol %, more preferably 5 to 45 mol %, still more preferably 5 to 40 mol %, and most preferably 5 to 35 mol %. When the amount of the structural unit (a5) is at least as large as the lower limit of the above-mentioned range, the solubility of the component (A1) in an organic solvent is improved. On the other hand, when the amount of the structural unit (a5) is no more than the upper limit of the above-mentioned range, a good balance can be achieved with the other structural units.

(Structural Unit (a6))

The structural unit (a6) is a structural unit represented by general formula (a6-1) shown below.

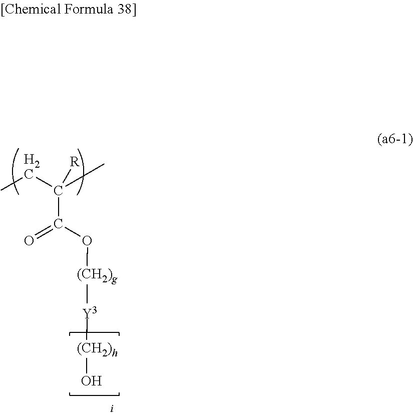

In general formula (a6-1), R represents a hydrogen atom, an alkyl group of 1 to 5 carbon atoms or a halogenated alkyl group of 1 to 5 carbon atoms; Y³ represents an alkylene group or an aliphatic cyclic group; each of g and h independently represents an integer of 0 to 3; and i represents an integer of 1 to 3.

In general formula (a6-1), R represents a hydrogen atom, an alkyl group of 1 to 5 carbon atoms or a halogenated alkyl group of 1 to 5 carbon atoms. R is the same as defined for R in the aforementioned structural unit (a1). Of the various possibilities, R is preferably a hydrogen atom or a methyl group.

Y³ represents an alkylene group or an aliphatic cyclic group.

As the alkylene group for Y³, an alkylene group of 1 to 10 carbon atoms can be used.

As the aliphatic cyclic group for Y³, the same groups as those described above for the aliphatic cyclic group for Y⁵ in general formula (a5-1) can be mentioned. It is preferable that the structure of the basic ring (aliphatic ring) in Y³ be the same as that in Y⁵.

g represents an integer of 0 to 3, preferably 0 or 1, and more preferably 0.

h represents an integer of 0 to 3, preferably 0 or 1, and more preferably 0.

i represents an integer of 1 to 3, and is most preferably 1.

As the structural unit (a6), a structural unit represented by general formula (a6-1-1) shown below is preferable, and a structural unit in which one of the “i” groups of —(CH₂)ₕ—OH is bonded to the 3rd position of the 1-adamantyl group is particularly desirable.

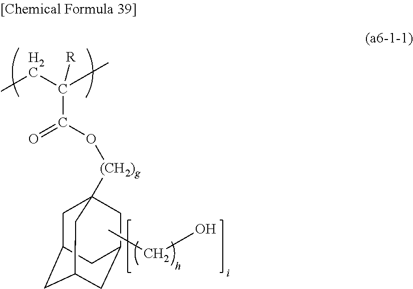

In the formula, R, g, h and i are respectively the same as defined above.

As the structural unit (a6), one type of structural unit may be used alone, or two or more types of structural units may be used in combination.

The amount of the structural unit (a6) within the component (A1) based on the combined total of all structural units constituting the component (A1) is preferably 1 to 40 mol %, more preferably 1 to 35 mol %, still more preferably 5 to 30 mol %, and most preferably 5 to 25 mol %. When the amount of the structural unit (a6) is at least as large as the lower limit of the above-mentioned range, the rectangularity of the cross-sectional shape of the resist pattern is improved, and hence, a resist pattern having an excellent shape can be formed. On the other hand, when the amount of the structural unit (a6) is no more than the upper limit of the above-mentioned range, a good balance can be achieved with the other structural units.

(Other Structural Units)

The component (A1) may also have a structural unit other than the above-mentioned structural units (a1), (a2), (a5) and (a6), as long as the effects of the present invention are not impaired.

As such a structural unit, any other structural unit which cannot be classified as one of the above structural units (a1), (a2), (a5) and (a6) can be used without any particular limitation, and any of the multitude of conventional structural units used within resist resins for ArF excimer lasers or KrF excimer lasers can be used.

Examples of other structural units include a structural unit (a3) derived from an acrylate ester containing a polar group-containing aliphatic hydrocarbon group, and a structural unit (a4) derived from an acrylate ester containing a non-acid-dissociable aliphatic polycyclic group.

Structural Unit (a3)

The structural unit (a3) is a structural unit derived from an acrylate ester containing a polar group-containing aliphatic hydrocarbon group. However, the structural unit (a3) does not include the aforementioned structural units (a5) and (a6).

When the component (A1) includes the structural unit (a3), the hydrophilicity of the component (A) is improved, and hence, the compatibility of the component (A) with the developing solution is improved. As a result, the alkali solubility of the exposed portions improves, which contributes to favorable improvements in the resolution.

Examples of the polar group include a hydroxyl group, cyano group, carboxyl group, or hydroxyalkyl group in which some of the hydrogen atoms of the alkyl group have been substituted with fluorine atoms, although a hydroxyl group is particularly desirable.

Examples of the aliphatic hydrocarbon group include linear or branched hydrocarbon groups (preferably alkylene groups) of 1 to 10 carbon atoms, and cyclic aliphatic hydrocarbon groups (cyclic groups). These cyclic groups can be selected appropriately from the multitude of groups that have been proposed for the resins of resist compositions designed for use with ArF excimer lasers. The cyclic group is preferably a polycyclic group, more preferably a polycyclic group of 7 to 30 carbon atoms.

Of the various possibilities, structural units derived from an acrylate ester that include an aliphatic polycyclic group that contains a hydroxyl group, cyano group, carboxyl group or a hydroxyalkyl group in which part of the hydrogen atoms of the alkyl group have been substituted with fluorine atoms are particularly desirable. Examples of the polycyclic group include groups in which two or more hydrogen atoms have been removed from a bicycloalkane, tricycloalkane, tetracycloalkane or the like. Specific examples include groups in which two or more hydrogen atoms have been removed from a polycycloalkane such as adamantane, norbornane, isobornane, tricyclodecane or tetracyclododecane. Of these polycyclic groups, groups in which two or more hydrogen atoms have been removed from adamantane, norbornane or tetracyclododecane are preferred industrially.

When the aliphatic hydrocarbon group within the polar group-containing aliphatic hydrocarbon group is a linear or branched hydrocarbon group of 1 to 10 carbon atoms, the structural unit (a3) is preferably a structural unit derived from a hydroxyethyl ester of acrylic acid. On the other hand, when the hydrocarbon group is a polycyclic group, structural units represented by formulas (a3-1) and (a3-2) shown below are preferable.

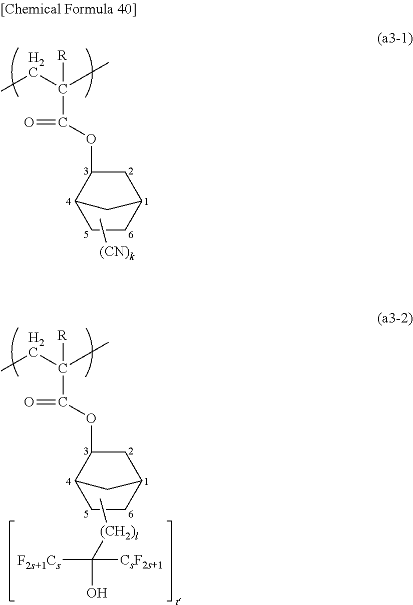

In the formulas, R is the same as defined above; k is an integer of 1 to 3; t′ is an integer of 1 to 3; 1 is an integer of 1 to 5; and s is an integer of 1 to 3.

In general formula (a3-1), k is preferably 1. The cyano group is preferably bonded to the 5th or 6th position of the norbornyl group.

In formula (a3-2), t′ is preferably 1. l is preferably 1. s is preferably 1. Further, it is preferable that a 2-norbornyl group or 3-norbornyl group be bonded to the terminal of the carboxy group of the acrylic acid. The fluorinated alkyl alcohol is preferably bonded to the 5th or 6th position of the norbornyl group.

As the structural unit (a3), one type of structural unit may be used, or two or more types may be used in combination.

The amount of the structural unit (a3) within the component (A1) based on the combined total of all structural units constituting the component (A1) is preferably 5 to 50 mol %, more preferably 5 to 40 mol %, and still more preferably 5 to 25 mol %. When the amount of the structural unit (a3) is at least as large as the lower limit of the above-mentioned range, the effect of using the structural unit (a3) can be satisfactorily achieved. On the other hand, when the amount of the structural unit (a3) is no more than the upper limit of the above-mentioned range, a good balance can be achieved with the other structural units.

Structural Unit (a4)

The structural unit (a4) is a structural unit derived from an acrylate ester containing a non-acid dissociable, aliphatic polycyclic group.

Examples of this polycyclic group include the same groups as those described above in relation to the aforementioned structural unit (a1), and any of the multitude of conventional polycyclic groups used within the resin component of resist compositions for ArF excimer lasers or KrF excimer lasers (and particularly for ArF excimer lasers) can be used.

In consideration of industrial availability and the like, at least one polycyclic group selected from amongst a tricyclodecyl group, adamantyl group, tetracyclododecyl group, isobornyl group, and norbornyl group is particularly desirable. These polycyclic groups may be substituted with a linear or branched alkyl group of 1 to 5 carbon atoms.

Specific examples of the structural unit (a4) include units with structures represented by general formulas (a4-1) to (a4-5) shown below.

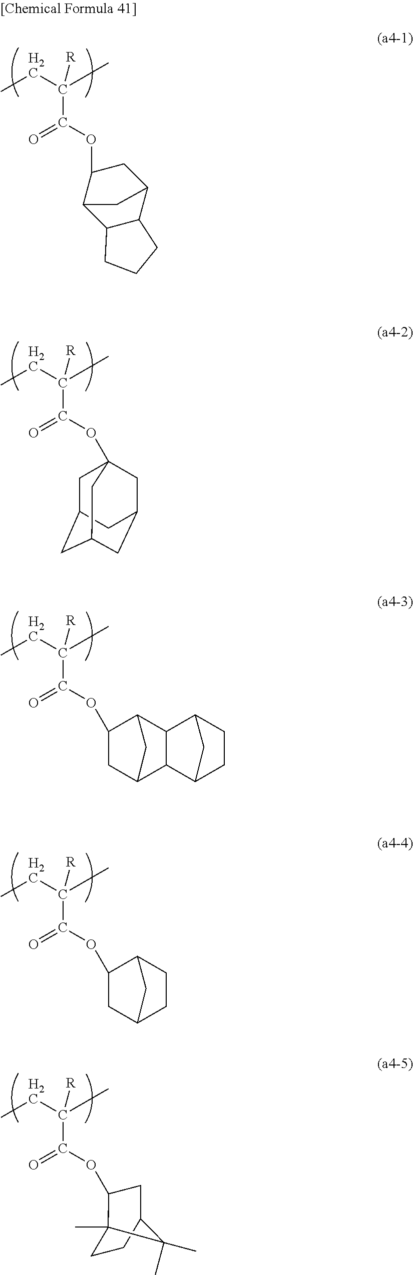

In the formulas, R is the same as defined above.

When the structural unit (a4) is included in the component (A1), the amount of the structural unit (a4) based on the combined total of all the structural units that constitute the component (A1) is preferably within the range from 1 to 30 mol %, and more preferably from 10 to 20 mol %.

In the present invention, the component (A1) is preferably a copolymer having the structural unit (a1). Preferable examples of such copolymer include a copolymer having the structural units (a1) and (a2), a copolymer having the structural units (a1) and (a5), a copolymer having the structural units (a1), (a2) and (a5), a copolymer having the structural units (a1) and (a6), a copolymer having the structural units (a1), (a2) and (a6), a copolymer having the structural units (a1), (a5) and (a6), and a copolymer having the structural units (a1), (a2), (a5) and (a6).

A specific examples of the component (A1) includes a copolymer consisting of the structural units (a1), (a2), (a5) and (a6).

In the component (A0), as the component (A1), one type may be used alone, or two or more types may be used in combination.

In the present invention, as the component (A1), a polymeric compound that includes a combination of structural units such as that shown below is particularly desirable.

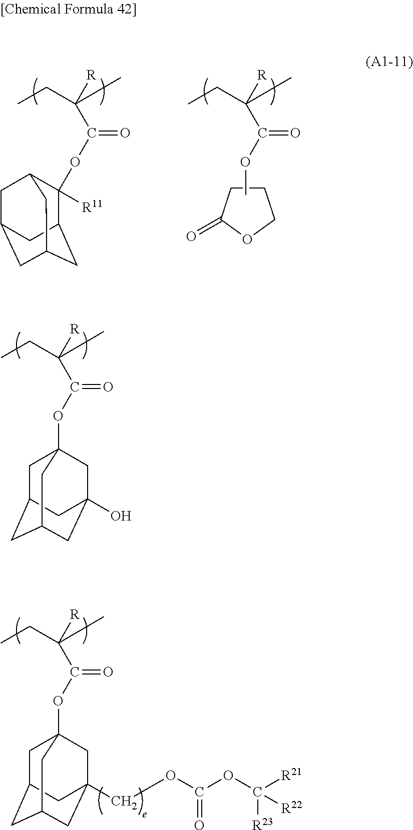

In formula (A1-11), R is the same as defined above, and the plurality of R may be either the same or different from each other; R¹¹ is the same as defined for R¹¹ in formula (a1-1-01); R²¹ to R²³ are the same as defined for R²¹ to R²³ in formula (II) above; and e is the same as defined for e in formula (a5-1) above.

The component (A1) can be obtained, for example, by a conventional radical polymerization or the like of the monomers corresponding with each of the structural units, using a radical polymerization initiator such as azobisisobutyronitrile (AIBN).

Furthermore, in the component (A1), by using a chain transfer agent such as HS—CH₂—CH₂—CH₂—C(CF₃)₂—OH, a —C(CF₃)₂—OH group can be introduced at the terminals of the component (A1). Such a copolymer having introduced a hydroxyalkyl group in which some of the hydrogen atoms of the alkyl group are substituted with fluorine atoms is effective in reducing developing defects and LER (line edge roughness: unevenness of the side walls of a line pattern).

The weight average molecular weight (Mw) (the polystyrene equivalent value determined by gel permeation chromatography) of the component (A1) is not particularly limited, but is preferably 1,000 to 50,000, more preferably 1,500 to 30,000, and most preferably 2,000 to 20,000. When the weight average molecular weight is no more than the upper limit of the above-mentioned range, the resist composition exhibits a satisfactory solubility in a resist solvent. On the other hand, when the weight average molecular weight is at least as large as the lower limit of the above-mentioned range, dry etching resistance and the cross-sectional shape of the resist pattern becomes satisfactory.

Further, the dispersity (Mw/Mn) of the component (A1) is preferably 1.0 to 5.0, more preferably 1.0 to 3.0, and most preferably 1.2 to 2.5. Here, “Mn” indicates the number average molecular weight.

[Component (A2)]

As the component (A2), it is preferable to use a compound that has a molecular weight of at least 500 and less than 2,000, contains a hydrophilic group, and also contains an acid dissociable, dissolution inhibiting group described above in connection with the component (A1). Specific examples include compounds containing a plurality of phenol skeletons in which a part of the hydrogen atoms within hydroxyl groups have been substituted with the aforementioned acid dissociable, dissolution inhibiting groups.

Examples of the component (A2) include low molecular weight phenolic compounds in which a portion of the hydroxyl group hydrogen atoms have been substituted with an aforementioned acid dissociable, dissolution inhibiting group, and these types of compounds are known, for example, as sensitizers or heat resistance improvers for use in non-chemically amplified g-line or i-line resists.

Examples of these low molecular weight phenol compounds include bis(4-hydroxyphenyl)methane, bis(2,3,4-trihydroxyphenyl)methane, 2-(4-hydroxyphenyl)-2-(4′-hydroxyphenyl)propane, 2-(2,3,4-trihydroxyphenyl)-2-(2′,3′,4′-trihydroxyphenyl)propane, tris(4-hydroxyphenyl)methane, bis(4-hydroxy-3,5-dimethylphenyl)-2-hydroxyphenylmethane, bis(4-hydroxy-2,5-dimethylphenyl)-2-hydroxyphenylmethane, bis(4-hydroxy-3,5-dimethylphenyl)-3,4-dihydroxyphenylmethane, bis(4-hydroxy-2,5-dimethylphenyl)-3,4-dihydroxyphenylmethane, bis(4-hydroxy-3-methylphenyl)-3,4-dihydroxyphenylmethane, bis(3-cyclohexyl-4-hydroxy-6-methylphenyl)-4-hydroxyphenylmethane, bis(3-cyclohexyl-4-hydroxy-6-methylphenyl)-3,4-dihydroxyphenylmethane, 1-[1-(4-hydroxyphenyl)isopropyl]-4-[1,1-bis(4-hydroxyphenyl)ethyl]benzene, and dimers, trimers and tetramers of formalin condensation products of phenols such as phenol, m-cresol, p-cresol and xylenol. Needless to say, the low molecular weight phenol compound is not limited to these examples.

Also, there are no particular limitations on the acid dissociable, dissolution inhibiting group, and suitable examples include the groups described above.

In the component (A0), as the component (A2), one type may be used alone, or two or more types may be used in combination.

In the resist composition of the present invention, the amount of the component (A) can be appropriately adjusted depending on the thickness of the resist film to be formed, and the like.

<Component (B)>

In the resist composition of the present invention, the component (B) includes an acid generator (B1) consisting of a compound represented by general formula (b1) shown below (hereafter, this acid generator (B1) is referred to as “component (B1)”).

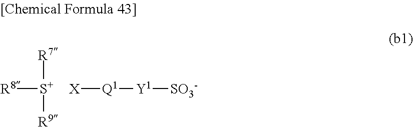

In formula (b1), R⁷″ to R⁹″ each independently represents an aryl group which may have a substituent or an alkyl group which may have a substituent, provided that at least one of R⁷″ to R⁹″ represents a substituted aryl group which has been substituted with a group represented by general formula (b1c-0) shown below, and two of R⁷″ to R⁹″ may be mutually bonded to form a ring with the sulfur atom; X represents a hydrocarbon group of 3 to 30 carbon atoms which may have a substituent; Q¹ represents a divalent linking group containing an oxygen atom; and Y¹ represents an alkylene group of 1 to 4 carbon atoms which may have a substituent or a fluorinated alkylene group of 1 to 4 carbon atoms which may have a substituent.

[Chemical Formula 44]

—O—R⁷⁰ (b1c-0)

In general formula (b1c-0), R⁷⁰ represents an organic group.

Anion Moiety of Component (B1)

In general formula (b1), X represents a hydrocarbon group of 3 to 30 carbon atoms which may have a substituent.

The hydrocarbon group for X may be either an aromatic hydrocarbon group or an aliphatic hydrocarbon group.

The aromatic hydrocarbon group for X is a hydrocarbon group having an aromatic ring. The aromatic hydrocarbon ring preferably has 3 to 30 carbon atoms, more preferably 5 to 30, still more preferably 5 to 20, still more preferably 6 to 15, and most preferably 6 to 12. Here, the number of carbon atoms within a substituent(s) is not included in the number of carbon atoms of the aromatic hydrocarbon group.

Specific examples of aromatic hydrocarbon groups include an aryl group which is an aromatic hydrocarbon ring having one hydrogen atom removed therefrom, such as a phenyl group, a biphenyl group, a fluorenyl group, a naphthyl group, an anthryl group or a phenanthryl group; and an alkylaryl group such as a benzyl group, a phenethyl group, a 1-naphthylmethyl group, a 2-naphthylmethyl group, a 1-naphthylethyl group, or a 2-naphthylethyl group. The alkyl chain within the arylalkyl group preferably has 1 to 4 carbon atom, more preferably 1 or 2, and most preferably 1.

The aromatic hydrocarbon group may have a substituent. For example, part of the carbon atoms constituting the aromatic ring within the aromatic hydrocarbon group may be substituted with a hetero atom, or a hydrogen atom bonded to the aromatic ring within the aromatic hydrocarbon group may be substituted with a substituent.

In the former example, a heteroaryl group in which part of the carbon atoms constituting the ring within the aforementioned aryl group has been substituted with a hetero atom such as an oxygen atom, a sulfur atom or a nitrogen atom, and a heteroarylalkyl group in which part of the carbon atoms constituting the aromatic hydrocarbon ring within the aforementioned arylalkyl group has been substituted with the aforementioned heteroatom can be used.

In the latter example, as the substituent for the aromatic hydrocarbon group, an alkyl group, an alkoxy group, a halogen atom, a halogenated alkyl group, a hydroxyl group, an oxygen atom (═O) or the like can be used.

The alkyl group as the substituent for the aromatic hydrocarbon group is preferably an alkyl group of 1 to 5 carbon atoms, and a methyl group, an ethyl group, a propyl group, an n-butyl group or a tert-butyl group is particularly desirable.

The alkoxy group as the substituent for the aromatic hydrocarbon group is preferably an alkoxy group having 1 to 5 carbon atoms, more preferably a methoxy group, ethoxy group, n-propoxy group, iso-propoxy group, n-butoxy group or tert-butoxy group, and most preferably a methoxy group or an ethoxy group.

Examples of the halogen atom as the substituent for the aromatic hydrocarbon group include a fluorine atom, a chlorine atom, a bromine atom and an iodine atom, and a fluorine atom is preferable.

Example of the halogenated alkyl group as the substituent for the aromatic hydrocarbon group includes a group in which part or all of the hydrogen atoms within the aforementioned alkyl group have been substituted with the aforementioned halogen atoms.

The aliphatic hydrocarbon group for X may be either a saturated aliphatic hydrocarbon group, or an unsaturated aliphatic hydrocarbon group. Further, the aliphatic hydrocarbon group may be linear, branched or cyclic.

In the aliphatic hydrocarbon group for X, part of the carbon atoms constituting the aliphatic hydrocarbon group may be substituted with a substituent group containing a hetero atom, or part or all of the hydrogen atoms constituting the aliphatic hydrocarbon group may be substituted with a substituent group containing a hetero atom.

As the “hetero atom” for X, there is no particular limitation as long as it is an atom other than carbon and hydrogen. Examples of hetero atoms include a halogen atom, an oxygen atom, a sulfur atom and a nitrogen atom. Examples of the halogen atom include a fluorine atom, a chlorine atom, an iodine atom and a bromine atom.

The substituent group containing a hetero atom may consist of a hetero atom, or may be a group containing a group or atom other than a hetero atom.

Specific examples of the substituent group for substituting part of the carbon atoms include —O—, —C(═O)—O—, —C(═O)—, —O—C(═O)—O—, —C(═O)—NH—, —NH— (the H may be replaced with a substituent such as an alkyl group or an acyl group), —S—, —S(═O)₂— and —S(═O)₂—O—. When the aliphatic hydrocarbon group is cyclic, the aliphatic hydrocarbon group may contain any of these substituent groups in the ring structure.

Examples of the substituent group for substituting part or all of the hydrogen atoms include an alkoxy group, a halogen atom, a halogenated alkyl group, a hydroxyl group, an oxygen atom (═O) and a cyano group.

The aforementioned alkoxy group is preferably an alkoxy group having 1 to 5 carbon atoms, more preferably a methoxy group, ethoxy group, n-propoxy group, iso-propoxy group, n-butoxy group or tert-butoxy group, and most preferably a methoxy group or an ethoxy group.

Examples of the aforementioned halogen atom include a fluorine atom, a chlorine atom, a bromine atom and an iodine atom, and a fluorine atom is preferable.

Example of the aforementioned halogenated alkyl group includes a group in which part or all of the hydrogen atoms within an alkyl group of 1 to 5 carbon atoms (e.g., a methyl group, an ethyl group, a propyl group, an n-butyl group or a tert-butyl group) have been substituted with the aforementioned halogen atoms.

As the aliphatic hydrocarbon group, a linear or branched saturated hydrocarbon group, a linear or branched monovalent unsaturated hydrocarbon group, or a cyclic aliphatic hydrocarbon group (aliphatic cyclic group) is preferable.

The linear saturated hydrocarbon group (alkyl group) preferably has 1 to 20 carbon atoms, more preferably 1 to 15, and most preferably 1 to 10. Specific examples include a methyl group, an ethyl group, a propyl group, a butyl group, a pentyl group, a hexyl group, a heptyl group, an octyl group, a nonyl group, a decyl group, an undecyl group, a dodecyl group, a tridecyl group, an isotridecyl group, a tetradecyl group, a pentadecyl group, a hexadecyl group, an isohexadecyl group, a heptadecyl group, an octadecyl group, a nonadecyl group, an icosyl group, a henicosyl group and a docosyl group.

The branched saturated hydrocarbon group (alkyl group) preferably has 3 to 20 carbon atoms, more preferably 3 to 15, and most preferably 3 to 10. Specific examples include a 1-methylethyl group, a 1-methylpropyl group, a 2-methylpropyl group, a 1-methylbutyl group, a 2-methylbutyl group, a 3-methylbutyl group, a 1-ethylbutyl group, a 2-ethylbutyl group, a 1-methylpentyl group, a 2-methylpentyl group, a 3-methylpentyl group and a 4-methylpentyl group.

The unsaturated hydrocarbon group preferably has 2 to 10 carbon atoms, more preferably 2 to 5, still more preferably 2 to 4, and most preferably 3. Examples of linear monovalent unsaturated hydrocarbon groups include a vinyl group, a propenyl group (an allyl group) and a butynyl group. Examples of branched monovalent unsaturated hydrocarbon groups include a 1-methylpropenyl group and a 2-methylpropenyl group.

Among the above-mentioned examples, as the unsaturated hydrocarbon group, a propenyl group is particularly desirable.

The aliphatic cyclic group may be either a monocyclic group or a polycyclic group. The aliphatic cyclic group preferably has 3 to 30 carbon atoms, more preferably 5 to 30, still more preferably 5 to 20, still more preferably 6 to 15, and most preferably 6 to 12.

As the aliphatic cyclic group, a group in which one or more hydrogen atoms have been removed from a monocycloalkane or a polycycloalkane such as a bicycloalkane, tricycloalkane or tetracycloalkane can be used. Specific examples include groups in which one or more hydrogen atoms have been removed from a monocycloalkane such as cyclopentane or cyclohexane; and groups in which one or more hydrogen atoms have been removed from a polycycloalkane such as adamantane, norbornane, isobornane, tricyclodecane or tetracyclododecane.

When the aliphatic cyclic group does not contain a hetero atom-containing substituent group in the ring structure thereof, the aliphatic cyclic group is preferably a polycyclic group, more preferably a group in which one or more hydrogen atoms have been removed from a polycycloalkane, and a group in which one or more hydrogen atoms have been removed from adamantane is particularly desirable.

When the aliphatic cyclic group contains a hetero atom-containing substituent group in the ring structure thereof, the hetero atom-containing substituent group is preferably —O—, —C(═O)—O—, —S—, —S(═O)₂— or —S(═O)₂—O—. Specific examples of such aliphatic cyclic groups include groups represented by formulas (L1) to (L5) and (S1) to (S4) shown below.

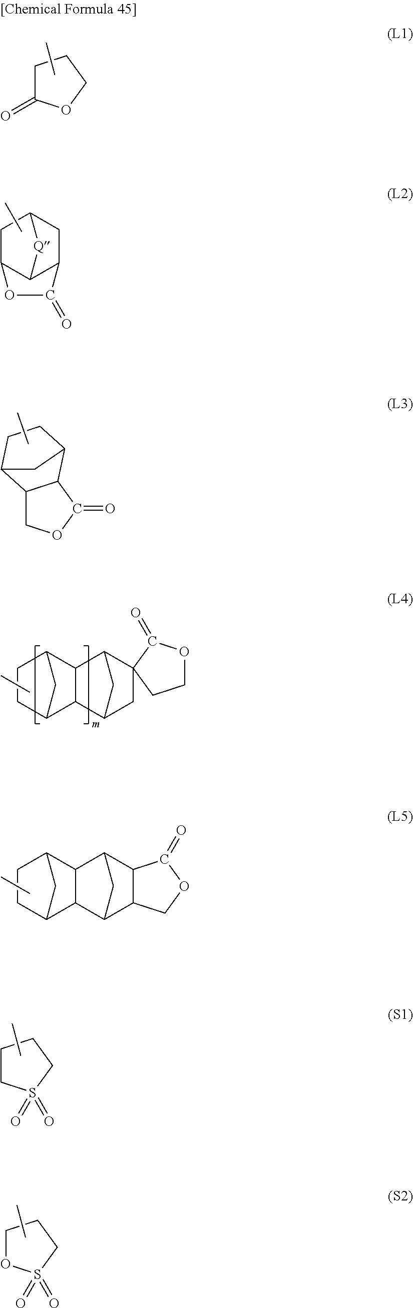

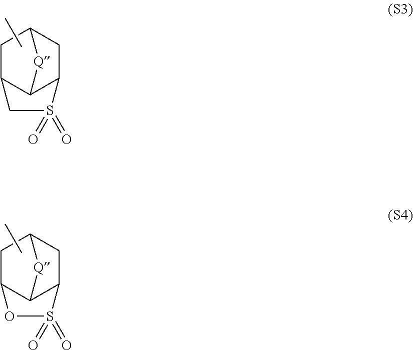

In the formula, Q″ represents an alkylene group of 1 to 5 carbon atoms, —O—, —S—, —O—R⁹⁴— or —S—R⁹⁵— (wherein each of R⁹⁴ and R⁹⁵ independently represents an alkylene group of 1 to 5 carbon atoms); and m represents 0 or 1.

In the formulas, the alkylene group for Q″ and R⁹⁴ to R⁹⁵ is preferably a linear or branched alkylene group, and preferably has 1 to 12 carbon atoms, more preferably 1 to 5, and most preferably 1 to 3.

Specific examples of alkylene groups include a methylene group [—CH₂—]; alkylmethylene groups such as —CH(CH₃)—, —CH(CH₂CH₃)—, —C(CH₃)₂—, —C(CH₃)(CH₂CH₃)—, —C(CH₃)(CH₂CH₂CH₃)— and —C(CH₂CH₃)₂—; an ethylene group [—CH₂CH₂—]; alkylethylene groups such as —CH(CH₃)CH₂—, —CH(CH₃)CH(CH₃)—, —C(CH₃)₂CH₂— and —CH(CH₂CH₃)CH₂—; a trimethylene group (n-propylene group) [—CH₂CH₂CH₂—]; alkyltrimethylene groups such as —CH(CH₃)CH₂CH₂— and —CH₂CH(CH₃)CH₂—; a tetramethylene group [—CH₂CH₂CH₂CH₂—]; alkyltetramethylene groups such as —CH(CH₃)CH₂CH₂CH₂— and —CH₂CH(CH₃)CH₂CH₂—; and a pentamethylene group [—CH₂CH₂CH₂CH₂CH₂—].

In these aliphatic cyclic groups, part of the hydrogen atoms bonded to the carbon atoms constituting the ring structure may be substituted with a substituent. Examples of substituents include an alkyl group, an alkoxy group, a halogen atom, a halogenated alkyl group, a hydroxyl group and an oxygen atom (═O).

As the alkyl group, an alkyl group of 1 to 5 carbon atoms is preferable, and a methyl group, an ethyl group, a propyl group, an n-butyl group or a tert-butyl group is particularly desirable.

As the alkoxy group and the halogen atom, the same groups as the substituent groups for substituting part or all of the hydrogen atoms can be used.

Among the examples described above, as X, a cyclic group which may have a substituent is preferable. The cyclic group may be either an aromatic hydrocarbon group which may have a substituent, or an aliphatic cyclic group which may have a substituent, and an aliphatic cyclic group which may have a substituent is preferable.

As the aromatic hydrocarbon group, a naphthyl group which may have a substituent, or a phenyl group which may have a substituent is preferable.

As the aliphatic cyclic group which may have a substituent, an aliphatic polycyclic group which may have a substituent is preferable. As the aliphatic polycyclic group, the aforementioned group in which one or more hydrogen atoms have been removed from a polycycloalkane, and groups represented by formulas (L2) to (L5), (S3) and (S4) are preferable.

Further, in the present invention, it is also preferable that X have a polar moiety, because it results in improved lithographic properties and resist pattern shape.

Specific examples of X having a polar moiety include those in which a part of the carbon atoms constituting the aliphatic hydrocarbon group for X is substituted with a substituent group containing a hetero atom such as —O—, —C(═O)—O—, —C(═O)—, —O—C(═O)—O—, —C(═O)—NH—, —NH— (wherein H may be substituted with a substituent such as an alkyl group or an acyl group), —S—, —S(═O)₂— and —S(═O)₂—O—.

In general formula (b1), Q¹ represents a divalent linking group containing an oxygen atom.

Q¹ may contain an atom other than oxygen. Examples of atoms other than oxygen include a carbon atom, a hydrogen atom, a sulfur atom and a nitrogen atom.

Examples of divalent linking groups containing an oxygen atom include non-hydrocarbon, oxygen atom-containing linking groups such as an oxygen atom (an ether bond; —O—), an ester bond (—C(═O)—O—), an amido bond (—C(═O)—NH—), a carbonyl group (—C(═O)—) and a carbonate bond (—O—C(═O)—O—); and combinations of the aforementioned non-hydrocarbon, hetero atom-containing linking groups with an alkylene group.

Specific examples of the combinations of the aforementioned non-hydrocarbon, hetero atom-containing linking groups and an alkylene group include —R⁹¹—O—, —R⁹²—O—C(═O)—, —C(═O)—O—R⁹³—O—C(═O)— (in the formulas, each of R⁹¹ to R⁹³ independently represents an alkylene group).

The alkylene group for R⁹¹ to R⁹³ is preferably a linear or branched alkylene group, and preferably has 1 to 12 carbon atoms, more preferably 1 to 5, and most preferably 1 to 3.

Specific examples of alkylene groups include a methylene group [—CH₂—]; alkylmethylene groups such as —CH(CH₃)—, —CH(CH₂CH₃)—, —C(CH₃)₂—, —C(CH₃)(CH₂CH₃)—, —C(CH₃)(CH₂CH₂CH₃)— and —C(CH₂CH₃)₂—; an ethylene group [—CH₂CH₂—]; alkylethylene groups such as —CH(CH₃)CH₂—, —CH(CH₃)CH(CH₃)—, —C(CH₃)₂CH₂— and —CH(CH₂CH₃)CH₂—; a trimethylene group (n-propylene group) [—CH₂CH₂CH₂—]; alkyltrimethylene groups such as —CH(CH₃)CH₂CH₂— and —CH₂CH(CH₃)CH₂—; a tetramethylene group [—CH₂CH₂CH₂CH₂—]; alkyltetramethylene groups such as —CH(CH₃)CH₂CH₂CH₂— and —CH₂CH(CH₃)CH₂CH₂—; and a pentamethylene group [—CH₂CH₂CH₂CH₂CH₂—].

Q¹ is preferably an ester bond or a divalent linking group containing an ester linkage or ether linkage, and more preferably an ester group or a group of —R⁹¹—O—, —R⁹²—O—C(═O)— or —C(═O)—O—R⁹³—O—C(═O)—.

In general formula (b1), Y¹ represents an alkylene group of 1 to 4 carbon atoms which may have a substituent or a fluorinated alkylene group of 1 to 4 carbon atoms which may have a substituent.

As the alkylene group for Y¹, the same alkylene groups as those described above for Q¹ which have 1 to 4 carbon atoms can be mentioned.

As the fluorinated alkylene group for Y¹, the aforementioned alkylene group in which part or all of the hydrogen atoms has been substituted with fluorine atoms can be used.

Specific examples of Y¹ include —CF₂—, —CF₂CF₂—, —CF₂CF₂CF₂—, —CF(CF₃)CF₂—, —CF(CF₂CF₃)—, —C(CF₃)₂—, —CF₂CF₂CF₂CF₂—, —CF(CF₃)CF₂CF₂—, —CF₂CF(CF₃)CF₂—, —CF(CF₃)CF(CF₃)—, —C(CF₃)₂CF₂—, —CF(CF₂CF₃)CF₂—, —CF(CF₂CF₂CF₃)—, —C(CF₃)(CF₂CF₃)—; —CHF—, —CH₂CF₂—, —CH₂CH₂CF₂—, —CH₂CF₂CF₂—, —CH(CF₃)CH₂—, —CH(CF₂CF₃)—, —C(CH₃)(CF₃)—, —CH₂CH₂CH₂CF₂—, —CH₂CH₂CF₂CF₂—, —CH(CF₃)CH₂CH₂—, —CH₂CH(CF₃)CH₂—, —CH(CF₃)CH(CF₃)—, —C(CF₃)₂CH₂—; —CH₂—, —CH₂CH₂—, —CH₂CH₂CH₂—, —CH(CH₃)CH₂—, —CH(CH₂CH₃)—, —C(CH₃)₂—, —CH₂CH₂CH₂CH₂—, —CH(CH₃)CH₂CH₂—, —CH₂CH(CH₃)CH₂—, —CH(CH₃)CH(CH₃)—, —C(CH₃)₂CH₂—, —CH(CH₂CH₃)CH₂—, —CH(CH₂CH₂CH₃)—, and —C(CH₃)(CH₂CH₃)—.

Y¹ is preferably a fluorinated alkylene group, and particularly preferably a fluorinated alkylene group in which the carbon atom bonded to the adjacent sulfur atom is fluorinated. Examples of such fluorinated alkylene groups include —CF₂—, —CF₂CF₂—, —CF₂CF₂CF₂—, —CF(CF₃)CF₂—, —CF₂CF₂CF₂CF₂—, —CF(CF₃)CF₂CF₂—, —CF₂CF(CF₃)CF₂—, —CF(CF₃)CF(CF₃)—, —C(CF₃)₂CF₂—, —CF(CF₂CF₃)CF₂—; —CH₂CF₂—, —CH₂CH₂CF₂—, —CH₂CF₂CF₂—; —CH₂CH₂CH₂CF₂—, —CH₂CH₂CF₂CF₂—, and —CH₂CF₂CF₂CF₂—.

Of these, —CF₂—, —CF₂CF₂—, —CF₂CF₂CF₂— or CH₂CF₂CF₂— is preferable, —CF₂—, —CF₂CF₂— or —CF₂CF₂CF₂— is more preferable, and —CF₂— is particularly desirable.

The alkylene group or fluorinated alkylene group may have a substituent. The alkylene group or fluorinated alkylene group “has a substituent” means that part or all of the hydrogen atoms or fluorine atoms in the alkylene group or fluorinated alkylene group has been substituted with groups other than hydrogen atoms and fluorine atoms.

Examples of substituents which the alkylene group or fluorinated alkylene group may have include an alkyl group of 1 to 4 carbon atoms, an alkoxy group of 1 to 4 carbon atoms, and a hydroxyl group.

In the present invention, as the anion moiety for the component (B1), an anion represented by general formula (b1-1) or (b1-2) shown below is preferable.

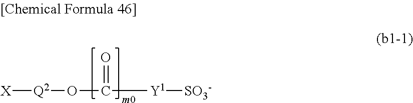

In formula (b1-1), X and Y¹ are the same as defined above; Q² represents a single bond or an alkylene group; and m0 represents 0 or 1.

In general formula (b1-1) above, as X, an aliphatic cyclic group which may have a substituent or an aromatic hydrocarbon group which may have a substituent is preferable. Of these, an aliphatic cyclic group which contains a hetero atom-containing substituent in the ring structure thereof is more preferable

As the alkylene group for Q², the same alkylene groups as those described above for Q¹ can be mentioned.

As Q², a single bond or a methylene group is particularly desirable. Especially, when X is an aliphatic cyclic group which may have a substituent, Q² is preferably a single bond. On the other hand, when X is an aromatic hydrocarbon group, Q² is preferably a methylene group.

m0 may be either 0 or 1. When X is an aliphatic cyclic group which may have a substituent, m0 is preferably 1. On the other hand, when X is an aromatic hydrocarbon group, m0 is preferably 0.

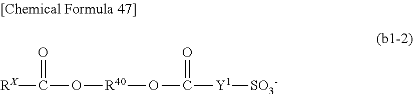

In formula (b1-2), R^{X} represents an aliphatic group which may have a substituent (excluding a nitrogen atom); R⁴⁰ represents an alkylene group; and Y¹ is the same as defined above.

In the formula, R^{X} represents an aliphatic group which may have a substituent (excluding a nitrogen atom), and specific examples thereof include the same aliphatic cyclic groups (which may have a substituent) as those described above in relation to X in general formula (b1-1) (excluding aliphatic cyclic groups having a substituent containing a nitrogen atom).

Examples of R⁴⁰ include the same alkylene groups as those described above for Q² in general formula (b1-1).

Y¹ is the same as defined for Y¹ in general formula (b1-1).

As the anion moiety for the component (B1), an anion represented by any one of general formulas (b1-1-1) to (b1-1-5), (b1-2-1) and (b1-2-2) shown below is particularly desirable.

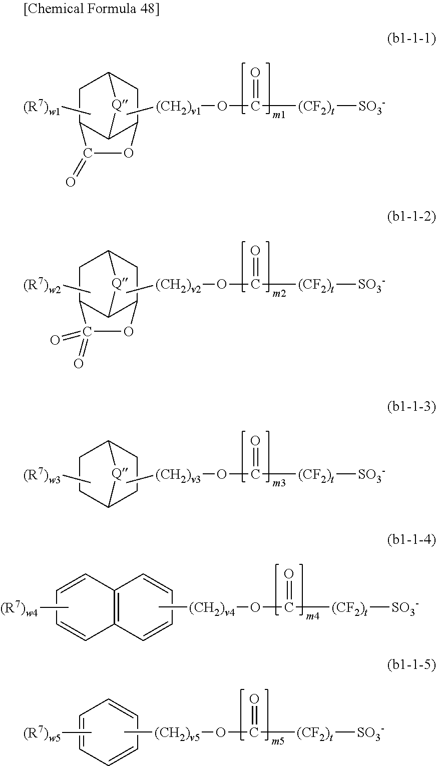

In the formulas, Q″ is the same as defined above; t represents an integer of 1 to 3; each of m1 to m5 independently represents 0 or 1; each of v1 to v5 independently represents an integer of 0 to 3; each of w1 to w5 independently represents an integer of 0 to 3; and R⁷ represents a substituent.

As the substituent for R⁷, the same groups as those which the aforementioned aliphatic hydrocarbon group or aromatic hydrocarbon group for X may have as a substituent can be used.

If there are two or more of the R⁷ group, as indicated by the values w1 to w5, then the two or more of the R⁷ groups may be the same or different from each other.

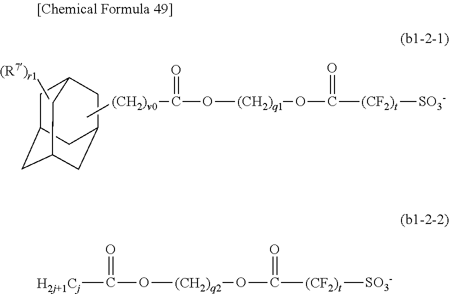

In the formulas, t represents an integer of 1 to 3; v0 represents an integer of 0 to 3; each of q1 and q2 independently represents an integer of 1 to 12; r1 represents an integer of 0 to 3; j represents an integer of 1 to 20; and R⁷′ represents a substituent.

As the substituent for R⁷′, the same groups as those which the aforementioned aliphatic hydrocarbon group or aromatic hydrocarbon group for R^{x} may have as a substituent can be used.

If there are two or more of the R⁷′ group, as indicated by the value r1, then the two or more of the R⁷′ groups may be the same or different from each other.

t is preferably 1 or 2.

v0 is preferably 0 to 2, more preferably 0 or 1, and still more preferably 0.

It is preferable that each of q1 and q2 independently represent 1 to 5, and more preferably 1 to 3.

r1 is preferably an integer of 0 to 2, and more preferably 0 or 1.

j is preferably 1 to 15, and more preferably 1 to 10.

Further, as the anion moiety of the component (B1), an anion represented by general formula (b1-3-1) shown below can also be given as a preferable example.

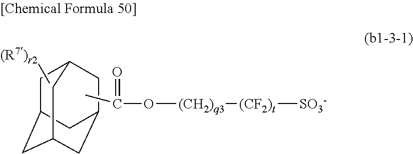

In the formula, t represents an integer of 1 to 3; q3 represents an integer of 1 to 12; r2 represents an integer of 0 to 3; and R⁷′ represents a substituent.

The substituent for R⁷′ is the same as defined above.

If there are two or more of the R⁷′ group, as indicated by the value r2, then the two or more of the R⁷′ groups may be the same or different from each other.

t is preferably 1 or 2.

q3 is preferably 1 to 5, and more preferably 1 to 3.

r2 is preferably an integer of 0 to 2, and more preferably 0 or 1.

Among the aforementioned examples, in terms of achieving excellent lithography properties, the anion moiety for the component (B1) is preferably an anion represented by general formula (b1-2-1), (b1-2-2) or (b1-3-1).

Cation Moiety of Component (B1)

In general formula (b1), R⁷″ to R⁹″ each independently represents an aryl group which may have a substituent or an alkyl group which may have a substituent,

The aryl group for R⁷″ to R⁹″ may be an unsubstituted aryl group having no substituent, or a substituted aryl group in which part or all hydrogen atoms have been substituted.

Examples of unsubstituted aryl group include aryl groups of 6 to 20 carbon atoms. The aryl group preferably has 6 to 10 carbon atoms because it can be synthesized at a low cost. As the aryl group, a phenyl group or a naphthyl group is particularly desirable.

Examples of the substituent for the substituted aryl group include a group represented by general formula (b1c-0), an alkyl group, an alkoxy group, a halogen atom, a halogenated alkyl group and a hydroxy group. As described later, at least one of R⁷″ to R⁹″ represents a substituted aryl group which has been substituted with a group represented by general formula (b1c-0).

The alkyl group as the substituent for the substituted aryl group is preferably an alkyl group having 1 to 5 carbon atoms, and a methyl group, an ethyl group, a propyl group, an n-butyl group or a tert-butyl group is particularly desirable.

The aforementioned alkoxy group as a substituent is preferably an alkoxy group having 1 to 5 carbon atoms, more preferably a methoxy group, an ethoxy group, an n-propoxy group, an iso-propoxy group, an n-butoxy group or a tert-butoxy group, and most preferably a methoxy group or an ethoxy group.

The halogen atom as the substituent is preferably a fluorine atom or a chlorine atom, and a fluorine atom is particularly desirable.

Examples of the halogenated alkyl group as the substituent include the alkyl groups as the substituent for the substituted aryl group in which part or all of the hydrogen atoms have been substituted with a halogen atom. Examples of the halogen atom within the halogenated alkyl group include the same halogen atoms as those described above as the substituent for the substituted aryl group. As the halogenated alkyl group, a fluorinated alkyl group is particularly desirable.

The alkyl group for R⁷″ to R⁹″ is not particularly limited and includes, for example, a linear, branched or cyclic alkyl group having 1 to 10 carbon atoms. In terms of achieving excellent resolution, an alkyl group of 1 to 5 carbon atoms is preferable. Specific examples thereof include a methyl group, an ethyl group, an n-propyl group, an isopropyl group, an n-butyl group, an isobutyl group, an n-pentyl group, a cyclopentyl group, a hexyl group, a cyclohexyl group, a nonyl group, and a decyl group. Among these, a methyl group is most preferable because it is excellent in resolution and can be synthesized at a low cost.

The alkyl group for R⁷″ to R⁹″ may have part or all of the hydrogen atoms substituted with a group other than the group represented by general formula (b1c-0), such as an alkoxy group, a halogen atom, a hydroxy group or an oxygen atom (═O).

As examples of the alkoxy group and halogen atom with which the hydrogen atoms of the aforementioned alkyl group may be substituted, the same alkoxy groups and halogen atoms as those with which the aryl group for R⁷″ to R⁹″ may be substituted can be given.

However, at least one of R⁷″ to R⁹″ represents a substituted aryl group which has been substituted with a group represented by general formula (b1c-0).

[Chemical Formula 51]

—O—R⁷⁰ (b1c-0)

In general formula (b1c-0), R⁷⁰ represents an organic group.

In general formula (b1c-0), R⁷⁰ represents an organic group.

Examples of the organic group represented by R⁷⁰ include the same organic groups as those described above in the explanation of the “monovalent organic group” for Z in general formula (a5-1), such as an aliphatic hydrocarbon group which may have a substituent, an aromatic hydrocarbon group which may have a substituent, a group represented by the formula -Q⁵-R⁵ (in the formula, Q⁵ represents a divalent linking group, and R⁵ represents an aliphatic hydrocarbon group which may have a substituent or an aromatic hydrocarbon group which may have a substituent.

In terms of improving the effects of the present invention, an aliphatic hydrocarbon group which may have a substituent or a group containing an aliphatic hydrocarbon group which may have a substituent (a group represented by the formula -Q⁵-R⁸′, wherein Q⁵ represents a divalent linking group, and R⁸′ represents an aliphatic hydrocarbon group which may have a substituent) is preferable.

Preferable examples of the group represented by general formula (b1c-0) include a group represented by general formula (b1c-0-1) shown below, a group represented by general formula (b1c-0-2) shown below and a group represented by general formula (b1c-0-3) shown below.

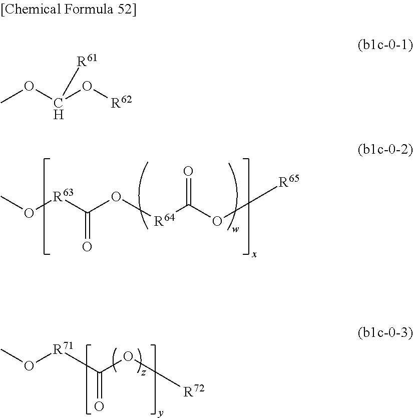

In general formula (b1c-0-1), R⁶¹ represents a hydrogen atom or a linear or branched alkyl group; and R⁶² represents an alkyl group; provided that R⁶¹ and R⁶² may be mutually bonded to form a ring structure. In general formula (b1c-0-2), each of R⁶³ and R⁶⁴ independently represents a linear or branched alkylene group, R⁶⁵ represents an acid dissociable group, w represents 0 or 1 and x represents 0 or 1. In general formula (b1c-0-3), R⁷¹ represents a single bond or a divalent linking group, R⁷² represents a group that is not dissociable by the action of an acid, y represents 0 or 1 and z represents 0 or 1.

In general formula (b1c-0-1), R⁶¹ represents a hydrogen atom or a linear or branched alkyl group.

The alkyl group for R⁶¹ preferably has 1 to 5 carbon atoms. As the alkyl group, an ethyl group or a methyl group is preferable, and a methyl group is most preferable.

R⁶¹ is preferably a hydrogen atom or a methyl group, and a hydrogen atom is particularly desirable.

In general formula (b1c-0-1), R⁶² represents an alkyl group, preferably an alkyl group of 1 to 15 carbon atoms. The alkyl group may be linear, branched or cyclic.

The linear or branched alkyl group for R⁶² preferably has 1 to 5 carbon atoms. Examples thereof include a methyl group, an ethyl group, a propyl group, an n-butyl group and a tert-butyl group.

The cyclic alkyl group for R⁶² preferably has 4 to 15 carbon atoms, more preferably 4 to 12, and most preferably 5 to 10. Specific examples include groups in which one or more hydrogen atoms have been removed from a monocycloalkane or a polycycloalkane such as a bicycloalkane, tricycloalkane or tetracycloalkane which may or may not be substituted with a lower alkyl group, a fluorine atom or a fluorinated alkyl group. Examples of the monocycloalkane include cyclopentane and cyclohexane. Examples of polycycloalkanes include adamantane, norbornane, isobornane, tricyclodecane and tetracyclododecane. Among these, a group in which one or more hydrogen atoms have been removed from adamantane is preferable.

R⁶¹ and R⁶² may be mutually bonded to form a ring structure.

In such a case, a cyclic group is formed by R⁶¹, R⁶², the oxygen atom having R⁶² bonded thereto, and the carbon atom having the oxygen atom and R⁶¹ bonded thereto. Such a cyclic group is preferably a 4- to 7-membered ring, and more preferably a 4- to 6-membered ring.

A specific example of the group represented by general formula (b1c-0-1) is shown below.

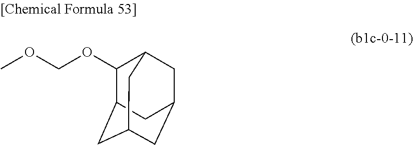

In general formula (b1c-0-2), each of R⁶³ and R⁶⁴ independently represents a linear or branched alkylene group.

Examples of the alkylene group for R⁶³ and R⁶⁴ include the same alkylene groups as those described above for Y² in general formula (a1-0-2).

Among these, an alkylene group of 1 to 6 carbon atoms is preferable, an alkylene group of 1 to 4 carbon atoms is more preferable, a methylene group or an ethylene group is still more preferable, and a methylene group is particularly desirable.

In general formula (b1c-0-2), R⁶⁵ represents an acid dissociable group.

An “acid dissociable group” is an organic group that is dissociable by the action of an acid. The acid dissociable group is not particularly limited, and any group which has been proposed as an acid dissociable, dissolution inhibiting group of a base resin for a chemically amplified resist can be used. Specific examples include the same acid dissociable, dissolution inhibiting groups as those described for the structural unit (a1). The acid dissociable group is preferably a cyclic or chain-like tertiary alkyl ester-type acid dissociable group or an acetal-type acid dissociable group such as an alkoxyalkyl group. Among these, cyclic or chain-like tertiary alkyl ester-type acid dissociable group is particularly desirable.

In general formula (b1c-0-2), w represents 0 or 1.

In general formula (b1c-0-2), x represents 0 or 1, and preferably 1.

Specific examples of the group represented by general formula (b1c-0-2) are shown below.

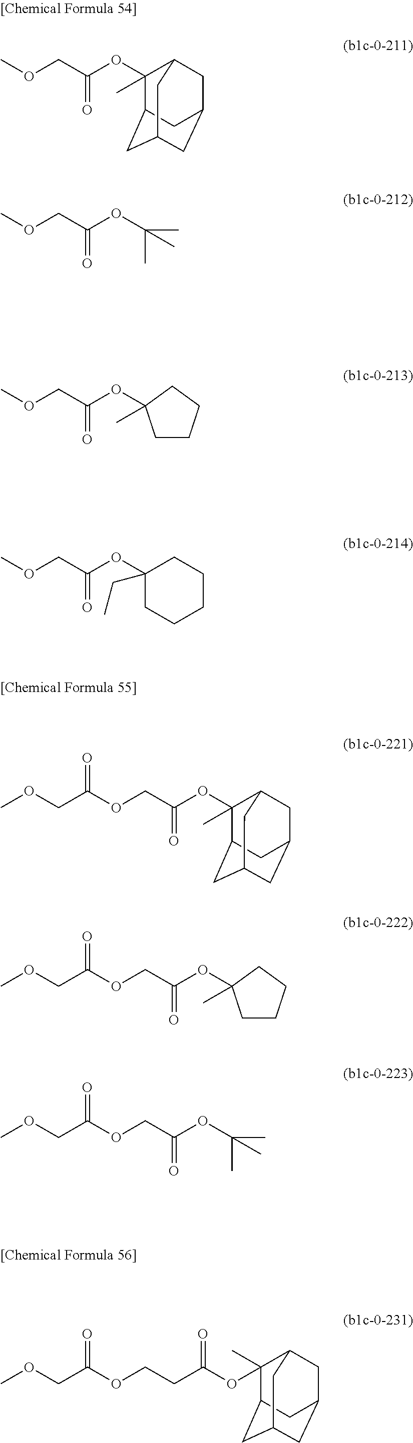

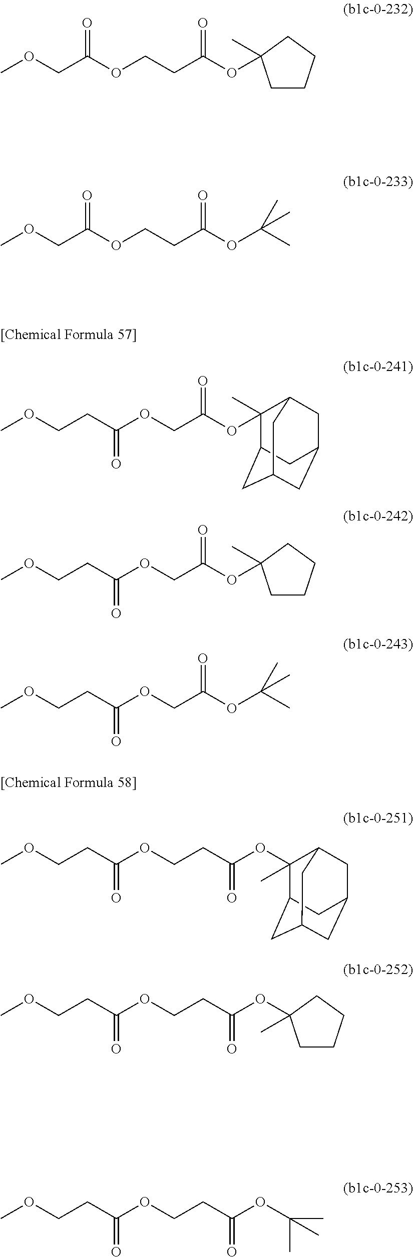

In general formula (b1c-0-3), R⁷¹ represents a single bond or a divalent linking group.

Examples of the divalent linking group for R⁷¹ include an alkylene group and a group containing a hetero atom (hereafter, referred to as “hetero atom-containing linking group”).

The alkylene group is preferably a linear or branched alkylene group, more preferably an alkylene group of 1 to 5 carbon atoms, and still more preferably an alkylene group of 1 to 3 carbon atoms (a methylene group, an ethylene group or a propylene group).

The “hetero atom” within the hetero atom-containing linking group is an atom other than carbon and hydrogen, and examples thereof include an oxygen atom, a sulfur atom and a nitrogen atom.

Examples of the hetero atom-containing linking group include non-hydrocarbon, heteroatom-containing linking groups, such as an oxygen atom (ether bond: —O—), a sulfur atom (thioether bond: —S—), an —NH— bond (H may be substituted with a substituent such as an alkyl group or an acyl group), an ester bond (—COO—), an amide bond (—CONH—) and a carbonyl group (—CO—), a carbonate bond (—OCOO—); and a combination of the aforementioned non-hydrocarbon, hetero atom-containing linking group with the aforementioned alkylene group. An example of such combination include —R⁹⁸—O— (in the formula, R⁹⁸ represents an alkylene group). In the formula, the alkylene group for R⁹⁸ include the same alkylene groups as those described above as the divalent linking group for R⁷¹.

The divalent linking group for R⁷¹ is preferably an oxygen atom, a sulfur atom or —R⁹⁸—O—, and an oxygen atom or —R⁹⁸—O— is particularly desirable.

Among these, R⁷¹ is preferably a single bond or an alkylene group, and a single bond is particularly desirable.

In general formula (b1c-0-3), R⁷² represents a group that is not dissociable by the action of an acid (hereafter, referred to as “acid non-dissociable group”).

The acid non-dissociable group for R⁷² is not particularly limited as long as it is a group that is not dissociated by the action of an acid, and is preferably a hydrocarbon group that is not dissociated by the action of an acid and which may have a substituent.

The hydrocarbon group for R⁷² may be an aromatic hydrocarbon group or an aliphatic hydrocarbon group.

Examples of the aliphatic hydrocarbon group for R⁷² include a linear or branched, saturated hydrocarbon group of 1 to 15 carbon atoms, a cyclic saturated hydrocarbon group of 3 to 20 carbon atoms and a linear, branched or cyclic, unsaturated hydrocarbon group of 2 to 5 carbon atoms.

The linear or branched saturated hydrocarbon group has 1 to 15 carbon atoms, and preferably 4 to 10 carbon atoms.

Examples of the linear, saturated hydrocarbon group include a methyl group, an ethyl group, a propyl group, a butyl group, a pentyl group, a hexyl group, a heptyl group, an octyl group, a nonyl group and a decyl group.

Examples of the branched, saturated hydrocarbon group include a 1-methylethyl group, a 1-methylpropyl group, a 2-methylpropyl group, a 1-methylbutyl group, a 2-methylbutyl group, a 3-methylbutyl group, a 1-ethylbutyl group, a 2-ethylbutyl group, a 1-methylpentyl group, a 2-methylpentyl group, a 3-methylpentyl group and a 4-methylpentyl group, but excluding tertiary alkyl groups.

The linear or branched, saturated hydrocarbon group may have a substituent. Examples of the substituent include an alkoxy group, a halogen atom, a halogenated alkyl group, a hydroxyl group, an oxygen atom (═O), a cyano group and a carboxy group.

The alkoxy group as the substituent for the linear or branched saturated hydrocarbon group is preferably an alkoxy group having 1 to 5 carbon atoms, more preferably a methoxy group, an ethoxy group, an n-propoxy group, an iso-propoxy group, an n-butoxy group or a tert-butoxy group, and most preferably a methoxy group or an ethoxy group.

Examples of the halogen atom as the substituent for the linear or branched, saturated alkyl group include a fluorine atom, a chlorine atom, a bromine atom and an iodine atom, and a fluorine atom is preferable.

Example of the halogenated alkyl group as the substituent for the linear or branched, saturated hydrocarbon group includes a group in which part or all of the hydrogen atoms within the aforementioned linear or branched, saturated hydrocarbon group have been substituted with the aforementioned halogen atoms.

The cyclic, saturated hydrocarbon group may be either a polycyclic group or a monocyclic group. Examples thereof include cyclic, saturated hydrocarbon groups of 3 to 20 carbon atoms, such as groups in which one hydrogen atom has been removed from a monocycloalkane or a polycycloalkane (e.g., a bicycloalkane, a tricycloalkane or a tetracycloalkane). More specific examples include groups in which one hydrogen atom has been removed from a monocycloalkane such as cyclopentane, cyclohexane, cycloheptane or cyclooctane; and groups in which one or more hydrogen atoms have been removed from a polycycloalkane such as adamantane, norbornane, isobornane, tricyclodecane or tetracyclododecane.

The cyclic, saturated hydrocarbon group may have a substituent. For example, part of the carbon atoms constituting the ring within the cyclic alkyl group may be substituted with a hetero atom, or a hydrogen atom bonded to the ring within the cyclic alkyl group may be substituted with a substituent.

In the former example, a heterocycloalkane in which part of the carbon atoms constituting the ring within the aforementioned monocycloalkane or polycycloalkane has been substituted with a hetero atom such as an oxygen atom, a sulfur atom or a nitrogen atom, and one hydrogen atom has been removed therefrom, can be used. Further, the ring may contain an ester bond (—C(═O)—O—). More specific examples include a lactone-containing monocyclic group, such as a group in which one hydrogen atom has been removed from γ-butyrolactone; and a lactone-containing polycyclic group, such as a group in which one hydrogen atom has been removed from a bicycloalkane, tricycloalkane or tetracycloalkane containing a lactone ring.

In the latter example, as the substituent, the same substituent groups as those for the aforementioned linear or branched alkyl group can be used.

Further, the aliphatic hydrocarbon group for R⁷² may be a combination of a linear or branched alkyl group with a cyclic alkyl group.

Examples of the combination of a linear or branched alkyl group with a cyclic alkyl group include groups in which a cyclic alkyl group as a substituent is bonded to a linear or branched alkyl group, and groups in which a linear or branched alkyl group as a substituent is bonded to a cyclic alkyl group.

Examples of linear unsaturated hydrocarbon groups include a vinyl group, a propenyl group (an allyl group) and a butynyl group.

Examples of branched unsaturated hydrocarbon groups include a 1-methylpropenyl group and a 2-methylpropenyl group.

The aforementioned linear or branched, unsaturated hydrocarbon group may have a substituent. Examples of substituents include the same substituents as those which the aforementioned linear or branched alkyl group may have.

The aromatic hydrocarbon group for R⁷² may be either a group including an aromatic hydrocarbon ring in which the ring skeleton of the aromatic ring is constituted of only carbon atoms, or a group including an aromatic hetero ring in which the ring skeleton of the aromatic ring contains not only carbon atoms but also a hetero atom.

Examples of the aromatic hydrocarbon group include an aryl group which is an aromatic hydrocarbon ring having one hydrogen atom removed therefrom, such as a phenyl group, a biphenyl group, a fluorenyl group, a naphthyl group, an anthryl group or a phenanthryl group; a heteroaryl group in which part of the carbon atoms constituting the aforementioned aryl group has been substituted with a hetero atom such as an oxygen atom, a sulfur atom or a nitrogen atom; and an arylalkyl group, such as a benzyl group, a phenethyl group, a 1-naphthylmethyl group, a 2-naphthylmethyl group, a 1-naphthylethyl group or a 2-naphthylethyl group. The alkyl chain within the arylalkyl group preferably has 1 to 4 carbon atom, more preferably 1 or 2, and most preferably 1.

The aromatic hydrocarbon group may have a substituent. For example, part of the carbon atoms constituting the aromatic ring within the aromatic hydrocarbon group may be substituted with a hetero atom, or a hydrogen atom bonded to the aromatic ring within the aromatic hydrocarbon group may be substituted with a substituent.

In the former example, a heteroaryl group in which part of the carbon atoms constituting the ring within the aforementioned aryl group has been substituted with a hetero atom such as an oxygen atom, a sulfur atom or a nitrogen atom, and a heteroarylalkyl group in which part of the carbon atoms constituting the ring of the aforementioned arylalkyl group has been substituted with the aforementioned heteroatom can be used.

In the latter example, as the substituent for the aromatic hydrocarbon group, an alkyl group, an alkoxy group, a halogen atom, a halogenated alkyl group, a hydroxyl group, an oxygen atom (═O) or the like can be used.

Examples of the alkyl group, alkoxy group, halogen atom and halogenated alkyl group as the substituent for the aromatic group include the same substituent groups as those for the aforementioned linear or branched alkyl group.

Among these, the hydrocarbon group for the acid non-dissociable group represented by R⁷² is preferably a cyclic group, and more preferably a cyclic, saturated hydrocarbon group. In particular, a group in which one hydrogen atom has been removed from adamantane is preferable, and an adamantyl group or a 1-(1-adamantyl)methyl group is most preferable.

Alternatively, the hydrocarbon group as the acid non-dissociable group represented by R⁷² may be a linear or branched, saturated hydrocarbon group which may have a substituent. Specifically, preferable examples thereof include a hexyl group, a decyl group and a halogenated alkyl group (preferably a fluorinated alkyl group).

In general formula (b1c-0-3), y represents 0 or 1.

In general formula (b1c-0-3), z represents 0 or 1, and preferably 1.

Preferable examples of the group represented by general formula (b1c-0-3) include a group represented by general formula (b1c-0-31) shown below, a group represented by general formula (b1c-0-32) shown below and a group represented by general formula (b1c-0-33) shown below.

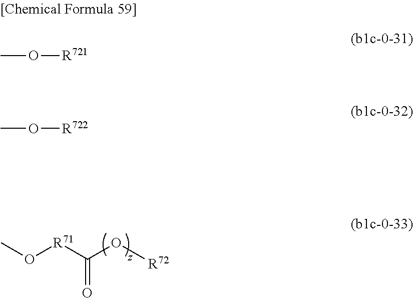

In general formula (b1c-0-31), R⁷²¹ represents an alkyl group of 4 to 10 that is not an acid dissociable group. In general formula (b1c-0-32), R⁷²² represents a fluorinated alkyl group. In general formula (b1c-0-33), R⁷¹ represents a single bond or a divalent linking group, R⁷² represents a group that is not dissociable by the action of an acid, and z represents 0 or 1.

In general formula (b1c-0-31), R⁷²¹ represents an alkyl group of 4 to 10 that is not an acid dissociable group.

The alkyl group for R⁷²¹ may be linear, branched or cyclic.

As the alkyl group for R⁷²¹, the linear, branched or cyclic, saturated hydrocarbon groups described above for R⁷² which have 4 to 10 carbon atoms can be mentioned.

The linear or branched alkyl group preferably has 4 to 8 carbon atoms, and more preferably 5 to 7 carbon atoms.

The cyclic alkyl group may be either a polycyclic group or a monocyclic group as long as it has 4 to 10 carbon atoms.

Among these, R⁷²¹ is preferably as linear or branched alkyl group, and more preferably a linear alkyl group.

When R⁷²¹ represents a branched alkyl group, as described above, it does not include tertiary alkyl groups (e.g., tert-butyl group).

In general formula (b1c-0-32), R⁷²² represents a fluorinated alkyl group.

Examples of the fluorinated alkyl group for R⁷²² include groups in which part or all of the hydrogen atoms of unsubstituted alkyl groups have been fluorinated.

The unsubstituted alkyl group may be linear, branched or cyclic. Alternatively, the unsubstituted alkyl group may be a combination of a linear or branched alkyl group with a cyclic alkyl group.

The unsubstituted linear alkyl group preferably has 1 to 10 carbon atoms, and more preferably 1 to 8. Specific examples include a methyl group, an ethyl group, an n-propyl group, an n-butyl group, an n-pentyl group, an n-hexyl group, an n-heptyl group, an n-octyl group, an n-nonyl group and an n-decyl group.

The unsubstituted branched alkyl group preferably has 3 to 10 carbon atoms, and more preferably 3 to 8.

As an example of an unsubstituted cyclic alkyl group, a group in which one hydrogen atom has been removed from a monocycloalkane or a polycycloalkane such as a bicycloalkane, tricycloalkane or tetracycloalkane can be given. Specific examples include monocycloalkyl groups such as a cyclopentyl group and a cyclohexyl group; and polycycloalkyl groups such as an adamantyl group, a norbornyl group, an isobornyl group, a tricyclodecyl group and a tetracyclododecyl group.

Examples of the combination of a linear or branched alkyl group with a cyclic alkyl group include groups in which a cyclic alkyl group as a substituent is bonded to a linear or branched alkyl group, and groups in which a linear or branched alkyl group as a substituent is bonded to a cyclic alkyl group.

The unsubstituted alkyl group is preferably a linear or branched alkyl group, and a linear alkyl group is particularly desirable.

The fluorinated alkyl group for R⁷²² may be either a group in which part of the hydrogen atoms within an unsubstituted alkyl group described below has been substituted with a fluorine atom, or a group in which all of the hydrogen atoms within an unsubstituted alkyl group described below has been substituted with a fluorine atom (i.e., a perfluoroalkyl group).

The fluorinated alkyl group preferably has 2 or more carbon atoms, and have no fluorine atom bonded to the carbon atom adjacent to the oxygen atom (—O—). Further, it is preferable that the terminal carbon atom of the R⁷²² group have a fluorine atom bonded thereto.

As the fluorinated alkyl group, a linear or branched fluorinated alkyl group is preferable, and a group represented by general formula (I-1) is particularly desirable.

[Chemical Formula 60]

-R^{10′}-R^{11″} (I-1)

In the formula, R¹⁰″ represents a linear or branched alkylene group, and R¹¹″ represents a linear or branched perfluoroalkyl group.

In formula (I-1), the alkylene group for R¹⁰″ may be linear or branched, and is preferably linear. Further, the alkylene group preferably has 1 to 10 carbon atoms, and more preferably 3 to 5 carbon atoms.

Specific examples of the alkylene group include groups in which the aforementioned unsubstituted linear alkyl group or unsubstituted branched alkyl group has one hydrogen atom removed therefrom. As R¹⁰″, a propylene group is particularly desirable.

The perfluoroalkyl group for R¹¹″ may be linear or branched, and is preferably linear. Further, the perfluoroalkyl group preferably has 1 to 10 carbon atoms, and more preferably 1 to 4 carbon atoms. As R¹¹″, a nonafluoro-n-butyl group is particularly desirable.

As a group represented by formula (I-1), —(CH₂)ₚ—(CF₂)_{q}—CF₃ is particularly desirable. In the formula above, p represents an integer of 1 to 10, and preferably an integer of 3 to 5. q represents an integer of 0 to 9, and preferably an integer of 0 to 3. Further, p+q is preferably an integer of 2 to 20, and more preferably an integer of 4 to 7.

In general formula (b1c-0-33), R⁷¹ represents a single bond or a divalent linking group, R⁷² represents a group that is not dissociable by the action of an acid and z represents 0 or 1, and are respectively the same as defined for R⁷¹, R⁷² and z in general formula (b1c-0-3).

Specific examples of groups represented by general formula (b1c-0-3) are shown below.

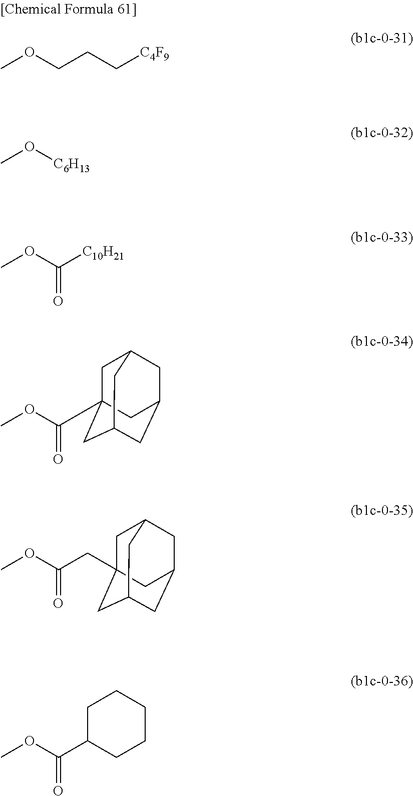

Among the aforementioned examples, in terms of superiority in the effects of the present invention, the group represented by general formula (b1c-0) is preferably a group represented by general formula (b1c-0-1), a group represented by general formula (b1c-0-2) or a group represented by general formula (b1c-0-3).

In the compound represented by general formula (b1), two of R⁷″ to R⁹″ may be mutually bonded to form a ring with the sulfur atom. In such a case, the ring including the sulfur atom is preferably a 3- to 10-membered ring, and more preferably a 5- to 7-membered ring.

When two of R⁷″ to R⁹″ are mutually bonded to form a ring with the sulfur atom, the remaining one of R⁷″ to R⁹″ is preferably an aryl group, and the aryl group is preferably a substituted aryl group having a group represented by general formula (b1c-0) as a substituent.

As described above, in the component (B1), at least one of R⁷″ to R⁹″ represents a substituted aryl group (hereafter, referred to as “substituted aryl group (I)”) which has been substituted with a group represented by general formula (b1c-0).

One substituted aryl group (I) represented by one of R⁷″ to R⁹″ preferably has 1 to 3 groups represented by general formula (I), and most preferably 1.

In the substituted aryl group (I), the aryl group to which the group represented by general formula (b1c-0) is bonded is preferably a phenyl group or a naphthyl group, and most preferably a phenyl group. In such a case, the group represented by general formula (b1c-0) is preferably bonded to the para position of the phenyl group.

The substituted aryl group (I) may have a substituent other than a group represented by general formula (b1c-0). Examples of such a substituent include an alkyl group, an alkoxy group, a halogen atom, a halogenated alkyl group and a hydroxy group. As specific examples of these substituents, the same groups as those described above for the substituent of the aforementioned substituted aryl group can be mentioned.

The number of such a substituent that one substituted aryl group (I) represented by one of R⁷″ to R⁹″ has is preferably 0 to 2.

Among R⁷″ to R⁹″, either one, two or three may represent a substituted aryl group (I). However, it is particularly desirable that one of R⁷″ to R⁹″ represent a substituted aryl group (I).

In such a case, it is preferable that the remaining two represent an aryl group which may have a substituent other than a group represented by general formula (b1c-0), or the remaining two be mutually bonded to form a ring with the sulfur atom in the formula.

When each of the remaining two represents an aryl group other than the group represented by general formula (b1c-0) which may have a substituent, the aryl group is preferably an unsubstituted aryl group, more preferably a phenyl group or a naphthyl group, and most preferably a phenyl group.

Specific examples of preferable cation moieties for the component (B1) are shown below.

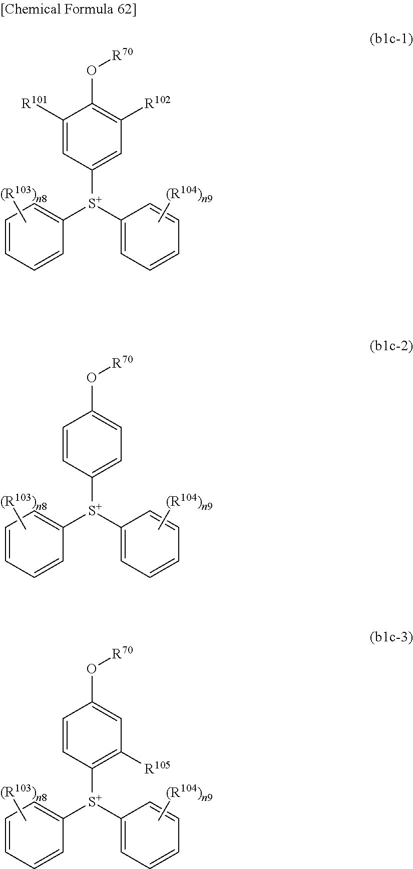

In the formulas, R⁷⁰ represents an organic group; each of R¹⁰¹ to R¹⁰⁵ independently represents an alkyl group or an alkoxy group; and each of n8 and n9 independently represents an integer of 0 to 5.

In formulas (b1c-1) to (b1c-3), R⁷⁰ is the same as defined for R⁷⁰ in general formula (b1c-0).

The alkyl group and the alkoxy group for R¹⁰¹ to R¹⁰⁵ is the same as defined for the alkyl group and the alkoxy group as the substituent for the aforementioned substituted aryl group.

Each of n8 and n9 independently represents an integer of 0 to 5, preferably 0 or 1, and most preferably 0.

The component (B1) can be produced by a conventional method.

As the component (B1), a compound having an anion represented by general formula (b1-1) as the anion moiety (hereafter, this compound is referred to as “compound (B1-1)”) and a compound having an anion represented by general formula (b1-2) as the anion moiety (hereafter, this compound is referred to as “compound (B1-2)”) can be produced as follows.

[Production Method of Compound (B1-1)]

The compound (B1-1) can be produced by a method including reacting a compound (b0-1) represented by general formula (b0-1) shown below with a compound (b0-2) represented by general formula (b0-2) shown below.

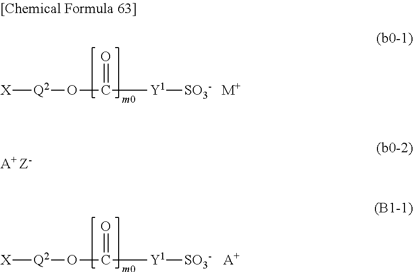

In formulas (b0-1) and (b0-2), X, Q², m0 and Y¹ are respectively the same as defined for X, Q², m0 and Y¹ in general formula (b1-1).

M⁺ represents an alkali metal ion. Examples of alkali metal ions include a sodium ion, a lithium ion and a potassium ion, and a sodium ion or a lithium ion is preferable.

A⁺ represents the cation moiety in general formula (b1) [⁺S(R⁷″)(R⁸″)(R⁹″)].

Z⁻ represents a non-nucleophilic ion.

Examples of non-nucleophilic ions include a halogen ion such as a bromine ion or a chlorine ion; an ion capable of forming an acid exhibiting a lower acidity than the compound (b0-1); BF₄⁻, AsF₆⁻, SbF₆⁻, PF₆⁻ and ClO₄⁻.

Examples of ions for Z⁻ which are capable of forming an acid exhibiting a lower acidity than the compound (b0-1) include sulfonic acid ions such as a p-toluenesulfonate ion, a methanesulfonate ion and a benzenesulfonate ion.

As the compound (b0-1) and the compound (b0-2), commercially available compounds may be used, or the compounds may be synthesized by a conventional method.

Production Method of Compound (b0-1)

The method of producing the compound (b0-1) is not particularly limited. For example, a compound represented by general formula (b0-1-11) shown below can be dissolved in a solvent such a tetrahydrofuran or water, and the resulting solution can be subjected to a reaction in an aqueous solution of an alkali metal hydroxide such as sodium hydroxide or lithium hydroxide, thereby obtaining a compound represented by general formula (b0-1-12) shown below. Then, the compound represented by general formula (b0-1-12) can be subjected to a dehydration/condensation reaction with an alcohol represented by general formula (b0-1-13) shown below in an organic solvent such as benzene or dichloroethane in the presence of an acidic catalyst, thereby obtaining a compound represented by general formula (b0-1) above in which m0 is 1 (i.e., a compound represented by general formula (b0-1-1) shown below).

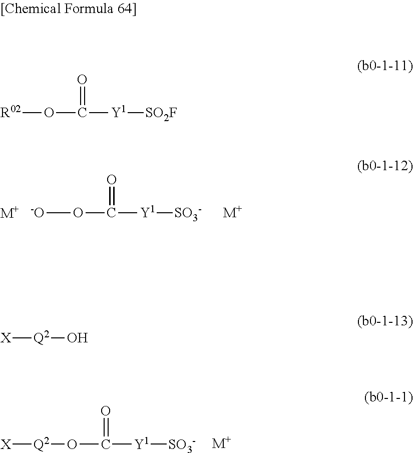

In the formulas, R⁰² represents an alkyl group of 1 to 5 carbon atoms; and X, Q², Y¹ and M⁺ are respectively the same as defined for X, Q², Y¹ and M⁺ in formula (b0-1).

Alternatively, for example, silver fluoride, a compound represented by general formula (b0-1-01) shown below and a compound represented by general formula (b0-1-02) shown below can be subjected to a reaction in an organic solvent such as diglyme anhydride to obtain a compound represented by general formula (b0-1-03) shown below. Then, the compound represented by general formula (b0-1-03) can be reacted with an alkali metal hydroxide such as sodium hydroxide or lithium hydroxide in an organic solvent such as tetrahydrofuran, acetone or methyl ethyl ketone, thereby obtaining a compound represented by general formula (b0-1) above in which m0 is 0 (i.e., a compound represented by general formula (b0-1-0) shown below).

In general formula (b0-1-02), as the halogen atom for Xₕ, a bromine atom or a chlorine atom is preferable.

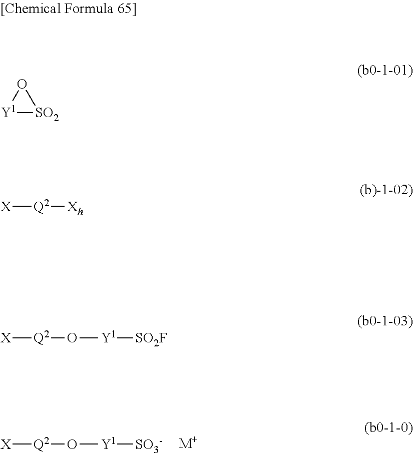

In the formulas, X, Q², Y¹ and M⁺ are respectively the same as defined for X, Q², Y¹ and M⁺ in formula (b0-1); and Xₕ represents a halogen atom.

Production Method of Compound (b0-2)

The production method of the compound (b0-2) is not particularly limited. For example, when R⁷″ represents a substituted aryl group having one group represented by general formula (b1c-0), the compound (b0-2) can be produced by either one of the two methods described below.

i) Production Method of Compound (b0-2) (1)

Firstly, for example, a compound represented by general formula (b1-15-01) shown below and a compound represented by general formula (b1-15-02) shown below are added to and reacted in a solution of an organic acid H⁺B⁻ (B⁻ represents an anion moiety of an organic acid, such as a methanesulfonate ion). Then, pure water and an organic solvent (e.g., dichloromethane, tetrahydrofuran, or the like) are added thereto, and the organic phase is collected. From the organic phase, a compound represented by general formula (b1-15-03) is obtained.

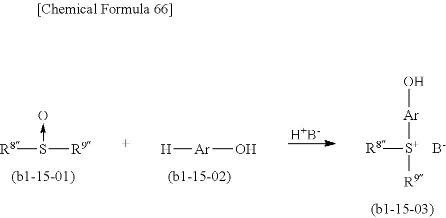

In the formulas, R⁸″ and R⁹″ are the same as defined above; Ar represents an arylene group in which one hydrogen atom has been removed from the aryl group represented by R⁷″ in general formula (b1); and B⁻ represents an anion moiety of an organic acid.

Subsequently, the compound represented by general formula (b1-15-03) is added to an organic solvent (e.g., dichloromethane, tetrahydrofuran, or the like), followed by cooling. Then, a compound represented by general formula (b1-0-1) shown below is added thereto and reacted, followed by liquid separation and washing with water. From the resulting organic phase, a compound represented by general formula (b1-15-04) shown below, i.e., the compound (b0-2) is obtained.

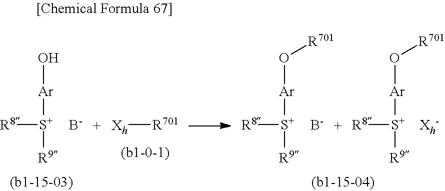

In the formulas, R⁸″ and R⁹″ are the same as defined above; Ar represents an arylene group in which one hydrogen atom has been removed from the aryl group represented by R⁷″ in general formula (b1); B⁻ represents an anion moiety of an organic acid; Xₕ represents a halogen atom; and R⁷⁰¹ represents an organic group.

The halogen atom for Xₕ is preferably a bromine atom or a chlorine atom.

In the formulas, R⁷⁰¹ represents an organic group. Specific examples of preferable organic groups include:

—CH(R⁶¹)—O—R⁶²;

—[R⁶³—C(═O)—O—(R⁶⁴—C(═O)—O—)_{w}—]ₓ—R⁶⁵; and

—R⁷¹—C(═O)—(O)_{z}—R⁷².

Herein, R⁶¹, R⁶², R⁶³, R⁶⁴, w, x, R⁶⁵, R⁷¹, z and R⁷² are the same as defined above.

Although the compound represented by general formula (b1-15-04) is a mixture of a compound having the organic acid (B⁻) as the anion moiety and a compound having the halogen ion (Xₕ⁻) as the anion moiety, it can be reacted with the aforementioned compound (b0-1) which is an alkali metal salt or a compound (b0-01) described later to substitute the anion moiety with the desired anion (X-Q¹-Y¹—SO₃⁻).

ii) Production Method of Compound (b0-2) (2)

Firstly, a compound represented by general formula (b1-15-02) is added to an organic solvent (e.g., acetone, dichloromethane, tetrahydrofuran, or the like), followed by cooling. Then, a compound represented by general formula (b1-0-2) shown below is added thereto and reacted, followed by liquid separation and washing with water. From the resulting organic phase, a compound represented by general formula (b1-0-3) shown below is obtained.

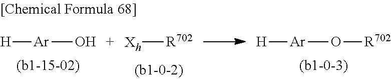

In the formula, Ar represents an arylene group in which one hydrogen atom has been removed from the aryl group represented by R⁷″ in general formula (b1); Xₕ represents a halogen atom; and R⁷⁰² represents an organic group.

The halogen atom for Xₕ is preferably a bromine atom or a chlorine atom.

In the formulas, R⁷⁰² represents an organic group, and specific examples thereof include the aforementioned alkyl group of 4 to 10 carbon atoms represented by R⁷²¹ that is not an acid dissociable group, and the aforementioned fluorinated alkyl group represented by R⁷²².

Subsequently, the compound represented by general formula (b1-0-3) and a compound represented by general formula (b1-15-01) are added to and reacted in an organic acid H⁺B⁻. Then, pure water and an organic solvent (e.g., t-butylmethylether (TBME), dichloromethane or tetrahydrofuran) are added thereto, and the organic phase is collected. From the organic phase, a compound represented by general formula (b1-15-05), i.e., the compound (b0-2) is obtained.

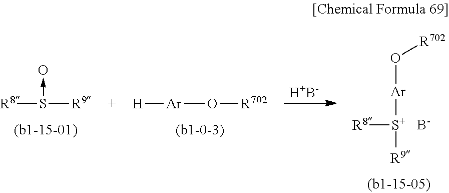

In the formulas, R⁸″ and R⁹″ are the same as defined above; Ar represents an arylene group in which one hydrogen atom has been removed from the aryl group represented by R⁷″ in general formula (b1); and R⁷⁰² represents an organic group, and is the same as defined above.

Reaction Between Compound (b0-1) and Compound (b0-2)

The reaction between the compound (b0-1) and the compound (b0-2) can be effected by dissolving the compounds in a solvent such as water, dichloromethane, acetonitrile, methanol, chloroform or methylene chloride, followed by stirring.

The reaction temperature is preferably 0 to 150° C., and more preferably 0 to 100° C. The reaction time varies depending on the reactivity of the compound (b0-1) and the compound (b0-2), the reaction temperature, and the like. However, in general, the reaction temperature is preferably 0.5 to 10 hours, and more preferably 1 to 5 hours.

In general, the amount of the compound (b0-2) used in the reaction is preferably 0.5 to 2 moles, per 1 mole of the compound (b0-1).

[Production Method of Compound (B1-2)]

The compound (B1-2) can be produced by a method including reacting a compound (b0-01) represented by general formula (b0-01) shown below with a compound (b0-02) represented by general formula (b0-02) shown below.

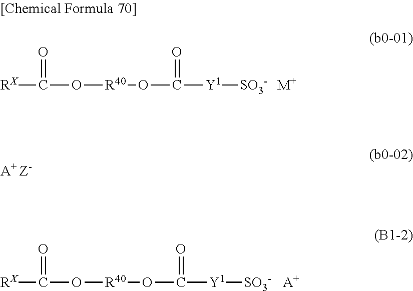

In the formulas, R^{X} represents an aliphatic group which may have a substituent (excluding a nitrogen atom); R⁴⁰ represents an alkylene group; Y¹ represents an alkylene group of 1 to 4 carbon atoms or a fluorinated alkylene group of 1 to 4 carbon atoms; M⁺ represents an alkali metal ion; A⁺ represents the cation moiety in general formula (b1) [⁺S(R⁷″)(R⁸″)(R⁹″)]; and Z⁻ represents a non-nucleophilic ion.

In the formulas, R^{X}, R⁴⁰, Y¹, M⁺, A⁺ and Z⁻ are the same as defined above.

Production Method of Compound (b0-01)

The aforementioned compound (b0-01) can be synthesized, for example, by reacting a compound (1-3) represented by general formula (1-3) shown below with a compound (2-1) represented by general formula (2-1) shown below.

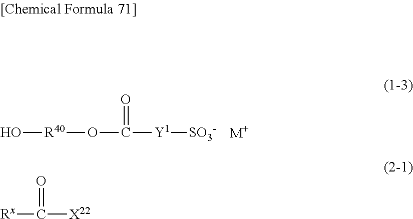

In the formulas, R^{X}, R⁴⁰, Y¹ and M⁺ are the same as defined above; and X²² represents a halogen atom.

Examples of the halogen atom represented by X²² include a bromine atom, a chlorine atom, an iodine atom and a fluorine atom. In terms of reactivity, a bromine atom or a chlorine atom is preferable, and a chlorine atom is particularly desirable.

As the compounds (1-3) and (2-1), commercially available compounds may be used, or the compounds may be synthesized.

A preferable method of synthesizing the compound (1-3) includes reacting a compound (1-1) represented by general formula (1-1) shown below with a compound (1-2) represented by general formula (1-2) shown below, thereby obtaining a compound (1-3).

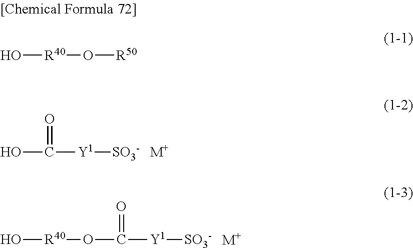

In the formulas, R⁴⁰, Y¹ and M⁺ are the same as defined above; R⁵⁰ represents an aliphatic group which may have an aromatic group as a substituent; and M⁺ represents an alkali metal ion.

As M⁺, the same alkali metal ions as those described above for M⁺ can be used.

In formula (1-1), R⁵⁰ represents an aliphatic group which may have an aromatic group as a substituent.

The aliphatic group may be either a saturated aliphatic group, or an unsaturated aliphatic group. Further, the aliphatic group may be linear, branched or cyclic, or a combination thereof.

The aliphatic group may be any one of an aliphatic hydrocarbon group consisting of carbon atoms and hydrogen atoms, a group in which part of the carbon atoms constituting the aforementioned aliphatic hydrocarbon group have been substituted with a hetero atom-containing substituent, or a group in which part or all of the hydrogen atoms constituting the aforementioned aliphatic hydrocarbon group have been substituted with a hetero atom-containing substituent.

As the hetero atom, there is no particular limitation as long as it is an atom other than carbon atom and hydrogen, and examples thereof include a halogen atom, an oxygen atom, a sulfur atom and a nitrogen atom. Examples of the halogen atom include a fluorine atom, a chlorine atom, an iodine atom and a bromine atom.

The hetero atom-containing substituent may consist of a hetero atom, or may be a group containing a group or atom other than a hetero atom.

Specific examples of the substituent group for substituting part of the carbon atoms include —O—, —C(═O)—O—, —C(═O)—, —O—C(═O)—O—, —C(═O)—NH—, —NH— (the H may be replaced with a substituent such as an alkyl group or an acyl group), —S—, —S(═O)₂— and —S(═O)₂—O—. When the aliphatic hydrocarbon group contains a cyclic group, the aliphatic hydrocarbon group may contain these substituent groups in the ring structure of the cyclic group.

Examples of the substituent group for substituting part or all of the hydrogen atoms include an alkoxy group, a halogen atom, a halogenated alkyl group, a hydroxyl group, an oxygen atom (═O), —COOR⁹⁶, —OC(═O)R⁹⁷ and a cyano group.

The aforementioned alkoxy group is preferably an alkoxy group having 1 to 5 carbon atoms, more preferably a methoxy group, ethoxy group, n-propoxy group, iso-propoxy group, n-butoxy group or tert-butoxy group, and most preferably a methoxy group or an ethoxy group.

Examples of the aforementioned halogen atom include a fluorine atom, a chlorine atom, a bromine atom and an iodine atom, and a fluorine atom is preferable.

Example of the aforementioned halogenated alkyl group includes a group in which part or all of the hydrogen atoms within an alkyl group of 1 to 5 carbon atoms (e.g., a methyl group, an ethyl group, a propyl group, an n-butyl group or a tert-butyl group) have been substituted with the aforementioned halogen atoms.

Each of R⁹⁶ and R⁹⁷ independently represents a hydrogen atom or a linear, branched or cyclic alkyl group of 1 to 15 carbon atoms.

When the alkyl group for R⁹⁶ and R⁹⁷ is a linear or branched alkyl group, it preferably has 1 to 10 carbon atoms, more preferably 1 to 5, and still more preferably 1 or 2. Specific examples of alkyl groups include the same groups as those for the linear or branched monovalent saturated hydrocarbon group described below.

When the alkyl group for R⁹⁶ and R⁹⁷ is a cyclic group, it may be either a monocyclic group or a polycyclic group. The cyclic group preferably has 3 to 15 carbon atoms, more preferably 4 to 12, and still more preferably 5 to 10. Specific examples of cyclic groups include the same groups as those for the cyclic monovalent saturated hydrocarbon group described below.

As the aliphatic hydrocarbon group, a linear or branched saturated hydrocarbon group of 1 to 30 carbon atoms, a linear or branched, monovalent unsaturated hydrocarbon group of 2 to 10 carbon atoms, or a cyclic aliphatic hydrocarbon group (aliphatic cyclic group) of 3 to 30 carbon atoms is preferable.

The linear saturated hydrocarbon group preferably has 1 to 20 carbon atoms, more preferably 1 to 15, and most preferably 1 to 10. Specific examples include a methyl group, an ethyl group, a propyl group, a butyl group, a pentyl group, a hexyl group, a heptyl group, an octyl group, a nonyl group, a decyl group, an undecyl group, a dodecyl group, a tridecyl group, an isotridecyl group, a tetradecyl group, a pentadecyl group, a hexadecyl group, an isohexadecyl group, a heptadecyl group, an octadecyl group, a nonadecyl group, an icosyl group, a henicosyl group and a docosyl group.

The branched saturated hydrocarbon group preferably has 3 to 20 carbon atoms, more preferably 3 to 15, and most preferably 3 to 10. Specific examples include a 1-methylethyl group, a 1-methylpropyl group, a 2-methylpropyl group, a 1-methylbutyl group, a 2-methylbutyl group, a 3-methylbutyl group, a 1-ethylbutyl group, a 2-ethylbutyl group, a 1-methylpentyl group, a 2-methylpentyl group, a 3-methylpentyl group and a 4-methylpentyl group.

The unsaturated hydrocarbon group preferably has 2 to 5 carbon atoms, more preferably 2 to 4, and most preferably 3. Examples of linear monovalent unsaturated hydrocarbon groups include a vinyl group, a propenyl group (an allyl group) and a butynyl group. Examples of branched monovalent unsaturated hydrocarbon groups include a 1-methylpropenyl group and a 2-methylpropenyl group.

Among the above-mentioned examples, as the unsaturated hydrocarbon group, a propenyl group is particularly desirable.

The aliphatic cyclic group may be either a monocyclic group or a polycyclic group. The aliphatic cyclic group preferably has 3 to 30 carbon atoms, more preferably 5 to 30, still more preferably 5 to 20, still more preferably 6 to 15, and most preferably 6 to 12. As the aliphatic cyclic group, a group in which one or more hydrogen atoms have been removed from a monocycloalkane or a polycycloalkane such as a bicycloalkane, tricycloalkane or tetracycloalkane can be used. Specific examples include groups in which one or more hydrogen atoms have been removed from a monocycloalkane such as cyclopentane or cyclohexane; and groups in which one or more hydrogen atoms have been removed from a polycycloalkane such as adamantane, norbornane, isobornane, tricyclodecane or tetracyclododecane.

The aliphatic group for R⁵⁰ in formula (1-1) may have an aromatic group as a substituent.

Examples of aromatic groups include an aryl group which is an aromatic hydrocarbon ring having one hydrogen atom removed therefrom, such as a phenyl group, a biphenyl group, a fluorenyl group, a naphthyl group, an anthryl group or a phenanthryl group; and a heteroaryl group in which a part of the carbon atoms constituting the aforementioned aryl group has been substituted with a hetero atom such as an oxygen atom, a sulfur atom or a nitrogen atom.

The aromatic group may have a substituent such as an alkyl group of 1 to 10 carbon atoms, a halogenated alkyl group, an alkoxy group, a hydroxyl group or a halogen atom. The alkyl group or halogenated alkyl group as a substituent preferably has 1 to 8 carbon atoms, and more preferably 1 to 4 carbon atoms. Further, the halogenated alkyl group is preferably a fluorinated alkyl group. Examples halogen atoms include a fluorine atom, a chlorine atom, an iodine atom and a bromine atom, and a fluorine atom is preferable.

If the R⁵⁰ group in the compound (1-1) represents an aromatic group, i.e., when the oxygen atom adjacent to the R⁵⁰ group is directly bonded to an aromatic ring without interposing an aliphatic group, the reaction between the compound (1-1) and the compound (1-2) does not proceed, such that the compound (1-3) cannot be obtained.

As the compounds (1-1) and (1-2), commercially available compounds may be used, or the compounds may be synthesized by a conventional method.

For example, a compound (1-2) can be obtained by a method including heating a compound (0-1) represented by general formula (0-1) shown below in the presence of an alkali, and neutralizing the resultant, thereby obtaining a compound (0-2) represented by general formula (0-2) shown below (hereafter, this step is referred to as “salt-formation step”, and

heating the compound (0-2) in the presence of an acid having an acid strength stronger than that of the compound (1-2), thereby obtaining the compound (1-2) (hereafter, this step is referred to as “carboxylic acid-generation step”).

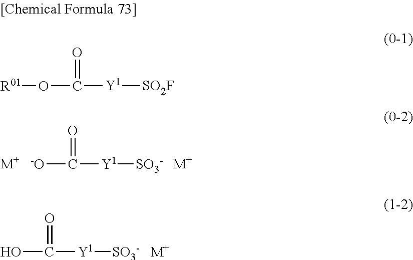

In the formulas, R⁰¹ represents an alkyl group; and Y¹ and M⁺ are the same as defined above.

As the alkyl group for R⁰¹, a linear or branched alkyl group is preferable, and specific examples include a methyl group, an ethyl group, a propyl group, an isopropyl group, an n-butyl group, an isobutyl group, a tert-butyl group, a pentyl group, an isopentyl group and a neopentyl group. Among these, an alkyl group of 1 to 4 carbon atoms is preferable, and a methyl group is particularly desirable.

As the compound (0-1), a commercially available compound can be used.

The salt-formation step can be performed, for example, by dissolving the compound (0-1) in a solvent, and adding an alkali to the resulting solution, followed by heating.

As the solvent, any solvent which is capable of dissolving the compound (0-1) can be used. Examples of such a solvent include water and tetrahydrofuran.

As the alkali, an alkali corresponding to M in formula (0-2) is used. Examples of such an alkali include alkali metal hydroxides such as sodium hydroxide, potassium hydroxide and lithium hydroxide.

The amount of the alkali used is preferably 1 to 5 moles, more preferably 2 to 4 moles, per 1 mole of the compound (0-1).

The heating temperature is preferably 20 to 120° C., and more preferably about 50 to 100° C. The heating time depends on the heating temperature, but in general, the heating time is preferably 0.5 to 12 hours, and more preferably 1 to 5 hours.

The neutralization following the heating can be conducted by adding an acid such as hydrochloric acid, sulfuric acid or p-toluenesulfonic acid to the reaction mixture following the heating.

It is preferable to conduct the neutralization so that the pH of the reaction mixture (25° C.) after addition of an acid falls within the range of 6 to 8. Further, the temperature of the reaction mixture during the neutralization is preferably 20 to 30° C., and more preferably 23 to 27° C.

After the reaction, the compound (0-2) within the reaction mixture may be separated and purified. The separation and purification can be conducted by a conventional method. For example, any one of concentration, solvent extraction, distillation, crystallization, recrystallization and chromatography can be used alone, or two or more of these methods may be used in combination.

In the carboxylic acid-generation step, the compound (0-2) obtained in the salt-formation step is heated in the presence of an acid having an acid strength stronger than that of the compound (1-2), thereby obtaining the compound (1-2).

“An acid having an acid strength stronger than that of the compound (1-2)” (hereafter, frequently referred to simply as “strong acid”) refers to an acid having a pKa value (25° C.) smaller than that of —COOH within the compound (1-2). By using such a strong acid, —COO⁻M⁺ within the compound (0-2) can be converted into —COOH, thereby obtaining the compound (1-2).

The strong acid can be appropriately selected from any conventional acids which exhibit a pKa value smaller than that of —COOH within the compound (1-2). The pKa value of —COOH within the compound (1-2) can be determined by a conventional titration method.

Specific examples of strong acids include a sulfonic acid, such as an arylsulfonic acid or an alkylsulfonic acid; sulfuric acid; and hydrochloric acid. An example of an arylsulfonic acid includes p-toluenesulfonic acid. Examples of alkylsulfonic acids include methanesulfonic acid and trifluoromethane sulfonic acid. In consideration of solubility in an organic solvent and ease in purification, p-toluenesulfonic acid is particularly desirable as the strong acid.

The carboxylic acid-generation step can be performed, for example, by dissolving the compound (0-2) in a solvent, and adding an acid to the resulting solution, followed by heating.

As the solvent, any solvent which is capable of dissolving the compound (0-2) can be used. Examples of such solvents include acetonitrile and methyl ethyl ketone.

The amount of the strong acid used is preferably 0.5 to 3 moles, and more preferably 1 to 2 moles, per 1 mole of the compound (0-2).

The heating temperature is preferably 20 to 150° C., and more preferably about 50 to 120° C. The heating time depends on the heating temperature, but in general, the heating time is preferably 0.5 to 12 hours, and more preferably 1 to 5 hours.

After the reaction, the compound (1-2) within the reaction mixture may be separated and purified. The separation and purification can be conducted by a conventional method. For example, any one of concentration, solvent extraction, distillation, crystallization, recrystallization and chromatography can be used alone, or two or more of these methods may be used in combination.

The method of reacting the compound (1-3) with the compound (2-1) is not particularly limited, and can be performed, for example, by allowing the compound (1-3) to come in contact with the compound (2-1) in a reaction solvent. Such a method can be performed, for example, by adding the compound (2-1) to a solution obtained by dissolving the compound (1-3) in a reaction solvent, in the presence of a base.

As the reaction solvent, any solvent which is capable of dissolving the compound (1-3) and the compound (2-1) as the raw materials can be used. Specific examples of such solvents include tetrahydrofuran (THF), acetone, dimethylformamide (DMF), dimethylacetamide, dimethylsulfoxide (DMSO) and acetonitrile.

Examples of the base include organic bases such as triethylamine, 4-dimethylaminopyridine (DMAP) and pyridine; and inorganic bases such as sodium hydride, K₂CO₃ and Cs₂CO₃.

The amount of the compound (2-1) is preferably 1 to 3 equivalents, and more preferably 1 to 2 equivalents, based on the amount of the compound (1-3).

The reaction temperature is preferably −20 to 40° C., more preferably 0 to 30° C. The reaction time depends on the reactivity of the compounds (1-3) and (2-1), the reaction temperature or the like. However, in general, the reaction time is preferably 1 to 120 hours, and more preferably 1 to 48 hours.

The compound (b0-02) can be produced in the same manner as the aforementioned compound (b0-2).

Reaction Between Compound (b0-01) and Compound (b0-02)

The reaction between the compound (b0-01) and the compound (b0-02) can be conducted by a conventional salt substitution method. For example, the reaction may be conducted by dissolving the compound (b0-01) and the compound (b0-02) in a solvent such as water, dichloromethane, acetonitrile, methanol or chloroform, followed by stirring or the like.

The reaction temperature is preferably 0 to 150° C., and more preferably 0 to 100° C. The reaction time varies depending on the reactivity of the compound (b0-01) and the compound (b0-02), the reaction temperature, and the like. However, in general, the reaction temperature is preferably 0.5 to 10 hours, and more preferably 1 to 5 hours.

After each of the aforementioned reactions, the compound (B1-1) or (B1-2) within the reaction mixture may be separated and purified. The separation and purification can be conducted by a conventional method. For example, any one of concentration, solvent extraction, distillation, crystallization, recrystallization and chromatography can be used alone, or two or more of these methods may be used in combination.

The structure of the thus obtained compound (B1-1) or (B1-2) can be confirmed by a general organic analysis method such as ¹H-nuclear magnetic resonance (NMR) spectrometry, ¹³C-NMR spectrometry, ¹⁹F-NMR spectrometry, infrared absorption (IR) spectrometry, mass spectrometry (MS), elementary analysis and X-ray diffraction analysis.

In the resist composition of the present invention, as the component (B1), one type of compound may be used, or two or more types of compounds may be used in combination.

In the component (B), the amount of the component (B1) based on the total weight of the component (B) is preferably 1% by weight or more, more preferably 10% by weight or more, still more preferably 20% by weight or more, and may be even 100% by weight. When the amount of the component (B1) is at least as large as the lower limit of the above-mentioned range, the effects of the present invention can be improved.

[Component (B2)]

In the resist composition of the present invention, if desired, the component (B) may further include an acid generator other than the component (B1) (hereafter, referred to as “component (B2)”).

As the component (B2), there is no particular limitation, and any of the known acid generators used in conventional chemically amplified resist compositions can be used.

Examples of these acid generators are numerous, and include onium salt acid generators such as iodonium salts and sulfonium salts; oxime sulfonate acid generators; diazomethane acid generators such as bisalkyl or bisaryl sulfonyl diazomethanes and poly(bis-sulfonyl)diazomethanes; nitrobenzylsulfonate acid generators; iminosulfonate acid generators; and disulfone acid generators.

As an onium salt acid generator, a compound represented by general formula (b-1) or (b-2) shown below can be used.

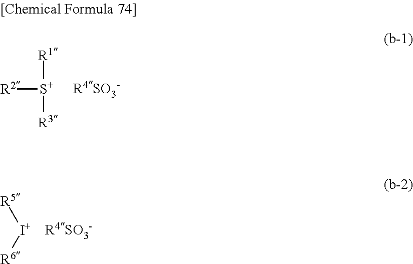

In the formulas above, R¹″ to R³″, R⁵″ and R⁶″ each independently represent an aryl group which may have a substituent or an alkyl group which may have a substituent, wherein two of R¹″ to R³″ may be bonded to each other to form a ring with the sulfur atom; and R⁴″ represents a linear, branched or cyclic alkyl group or a fluorinated alkyl group, with the provision that at least one of R¹″ to R³″ represents an aryl group, and at least one of R⁵″ and R⁶″ represents an aryl group.

In general formula (b-1), R¹″ to R³″ each independently represents an aryl group which may have a substituent or an alkyl group which may have a substituent. In formula (b-1), two of R¹″ to R³″ may be bonded to each other to form a ring with the sulfur atom.

Further, among R¹″ to R³″, at least one group represents an aryl group. Among R¹″ to R³″, two or more groups are preferably aryl groups, and it is particularly desirable that all of R¹″ to R³″ are aryl groups.

The aryl group for R¹″ to R³″ is not particularly limited. For example, an aryl group having 6 to 20 carbon atoms may be used in which part or all of the hydrogen atoms of the aryl group may or may not be substituted with alkyl groups, alkoxy groups, halogen atoms or hydroxyl groups. The aryl group is preferably an aryl group having 6 to 10 carbon atoms because it can be synthesized at a low cost. Specific examples thereof include a phenyl group and a naphthyl group.

The alkyl group, with which hydrogen atoms of the aryl group may be substituted, is preferably an alkyl group having 1 to 5 carbon atoms, and most preferably a methyl group, an ethyl group, a propyl group, an n-butyl group, or a tert-butyl group.

The alkoxy group, with which hydrogen atoms of the aryl group may be substituted, is preferably an alkoxy group having 1 to 5 carbon atoms, more preferably a methoxy group, an ethoxy group, an n-propoxy group, an iso-propoxy group, an n-butoxy group or a tert-butoxy group, and most preferably a methoxy group or an ethoxy group.

The halogen atom, with which hydrogen atoms of the aryl group may be substituted, is preferably a fluorine atom.

The alkyl group for R¹″ to R³″ is not particularly limited and includes, for example, a linear, branched or cyclic alkyl group having 1 to 10 carbon atoms. In terms of achieving excellent resolution, the alkyl group preferably has 1 to 5 carbon atoms. Specific examples thereof include a methyl group, an ethyl group, an n-propyl group, an isopropyl group, an n-butyl group, an isobutyl group, an n-pentyl group, a cyclopentyl group, a hexyl group, a cyclohexyl group, a nonyl group, and a decyl group, and a methyl group is most preferable because it is excellent in resolution and can be synthesized at a low cost.

It is particularly desirable that each of R¹″ to R³″ independently represent a phenyl group or a naphthyl group.

When two of R¹″ to R³″ in formula (b-1) are bonded to each other to form a ring with the sulfur atom, it is preferable that the two of R¹″ to R³″ form a 3 to 10-membered ring including the sulfur atom, and it is particularly desirable that the two of R¹″ to R³″ form a 5 to 7-membered ring including the sulfur atom.

When two of R¹″ to R³″ in formula (b-1) are bonded to each other to form a ring with the sulfur atom, the remaining one of R¹″ to R³″ is preferably an aryl group. As examples of the aryl group, the same as the above-mentioned aryl groups for R¹″ to R³″ can be given.

R⁴″ represents a linear, branched or cyclic alkyl group or a fluorinated alkyl group.

The linear or branched alkyl group preferably has 1 to 10 carbon atoms, more preferably 1 to 8 carbon atoms, and most preferably 1 to 4 carbon atoms.

The cyclic alkyl group is preferably a cyclic group, as described for R¹″, having 4 to 15 carbon atoms, more preferably 4 to 10 carbon atoms, and most preferably 6 to 10 carbon atoms.

The fluorinated alkyl group preferably has 1 to 10 carbon atoms, more preferably 1 to 8 carbon atoms, and most preferably 1 to 4 carbon atoms.

Further, the fluorination ratio of the fluorinated alkyl group (percentage of fluorine atoms within the alkyl group) is preferably from 10 to 100%, more preferably from 50 to 100%, and it is particularly desirable that all hydrogen atoms are substituted with fluorine atoms (namely, the fluorinated alkyl group is a perfluoroalkyl group) because the acid strength increases.

R⁴″ is most preferably a linear or cyclic alkyl group or a fluorinated alkyl group.

In general formula (b-2), R⁵″ and R⁶″ each independently represents an aryl group which may have a substituent or an alkyl group which may have a substituent. At least one of R⁵″ and R⁶″ represents an aryl group. It is preferable that both of R⁵″ and R⁶″ represent an aryl group.

As the aryl group for R⁵″ and R⁶″, the same as the aryl groups for R¹″ to R³″ can be used.

As the alkyl group for R⁵″ and R⁶″, the same as the alkyl groups for R¹″ to R³″ can be used.

It is particularly desirable that both of R⁵″ and R⁶″ represents a phenyl group.

As R⁴″ in formula (b-2), the same groups as those mentioned above for R⁴″ in formula (b-1) can be used.

Specific examples of suitable onium salt acid generators represented by formula (b-1) or (b-2) include diphenyliodonium trifluoromethanesulfonate or nonafluorobutanesulfonate; bis(4-tert-butylphenyl)iodonium trifluoromethanesulfonate or nonafluorobutanesulfonate; triphenylsulfonium trifluoromethanesulfonate, heptafluoropropanesulfonate or nonafluorobutanesulfonate; tri(4-methylphenyl)sulfonium trifluoromethanesulfonate, heptafluoropropanesulfonate or nonafluorobutanesulfonate; dimethyl(4-hydroxynaphthyl)sulfonium trifluoromethanesulfonate, heptafluoropropanesulfonate or nonafluorobutanesulfonate; monophenyldimethylsulfonium trifluoromethanesulfonate, heptafluoropropanesulfonate or nonafluorobutanesulfonate; diphenylmonomethylsulfonium trifluoromethanesulfonate, heptafluoropropanesulfonate or nonafluorobutanesulfonate; (4-methylphenyl)diphenylsulfonium trifluoromethanesulfonate, heptafluoropropanesulfonate or nonafluorobutanesulfonate; (4-methoxyphenyl)diphenylsulfonium trifluoromethanesulfonate, heptafluoropropanesulfonate or nonafluorobutanesulfonate; tri(4-tert-butyl)phenylsulfonium trifluoromethanesulfonate, heptafluoropropanesulfonate or nonafluorobutanesulfonate; diphenyl(1-(4-methoxy)naphthyl)sulfonium trifluoromethanesulfonate, heptafluoropropanesulfonate or nonafluorobutanesulfonate; di(1-naphthyl)phenylsulfonium trifluoromethanesulfonate, heptafluoropropanesulfonate or nonafluorobutanesulfonate; 1-phenyltetrahydrothiophenium trifluoromethanesulfonate, heptafluoropropanesulfonate or nonafluorobutanesulfonate; 1-(4-methylphenyl)tetrahydrothiophenium trifluoromethanesulfonate, heptafluoropropanesulfonate or nonafluorobutanesulfonate; 1-(3,5-dimethyl-4-hydroxyphenyl)tetrahydrothiophenium trifluoromethanesulfonate, heptafluoropropanesulfonate or nonafluorobutanesulfonate; 1-(4-methoxynaphthalene-1-yl)tetrahydrothiophenium trifluoromethanesulfonate, heptafluoropropanesulfonate or nonafluorobutanesulfonate; 1-(4-ethoxynaphthalene-1-yl)tetrahydrothiophenium trifluoromethanesulfonate, heptafluoropropanesulfonate or nonafluorobutanesulfonate; 1-(4-n-butoxynaphthalene-1-yl)tetrahydrothiophenium trifluoromethanesulfonate, heptafluoropropanesulfonate or nonafluorobutanesulfonate; 1-phenyltetrahydrothiopyranium trifluoromethanesulfonate, heptafluoropropanesulfonate or nonafluorobutanesulfonate; 1-(4-hydroxyphenyl)tetrahydrothiopyranium trifluoromethanesulfonate, heptafluoropropanesulfonate or nonafluorobutanesulfonate; 1-(3,5-dimethyl-4-hydroxyphenyl)tetrahydrothiopyranium trifluoromethanesulfonate, heptafluoropropanesulfonate or nonafluorobutanesulfonate; and 1-(4-methylphenyl)tetrahydrothiopyranium trifluoromethanesulfonate, heptafluoropropanesulfonate or nonafluorobutanesulfonate.

It is also possible to use onium salts in which the anion moiety of these onium salts are replaced by methanesulfonate, n-propanesulfonate, n-butanesulfonate, n-octanesulfonate or the like.

It is also possible to use onium salts in which the anion moiety of these onium salts is replaced by 1-adamantanesulfonate, or 2-norbornanesulfonate, d-camphor-10-sulfonate, benzenesulfonate, perfluorobenzenesulfonate, or p-toluenesulfonate.

Further, onium salt-based acid generators in which the anion moiety in general formula (b-1) or (b-2) is replaced by an anion moiety represented by general formula (b-3) or (b-4) shown below (the cation moiety is the same as (b-1) or (b-2)) may also be used.

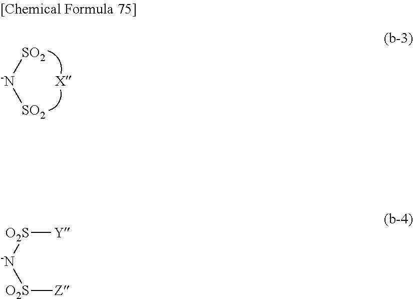

In the formulas, X″ represents an alkylene group of 2 to 6 carbon atoms in which at least one hydrogen atom has been substituted with a fluorine atom; and each of Y″ and Z″ independently represents an alkyl group of 1 to 10 carbon atoms in which at least one hydrogen atom has been substituted with a fluorine atom.

X″ represents a linear or branched alkylene group in which at least one hydrogen atom has been substituted with a fluorine atom, and the alkylene group has 2 to 6 carbon atoms, preferably 3 to 5 carbon atoms, and most preferably 3 carbon atoms.

Each of Y″ and Z″ independently represents a linear or branched alkyl group in which at least one hydrogen atom has been substituted with a fluorine atom, and the alkyl group has 1 to 10 carbon atoms, preferably 1 to 7 carbon atoms, and most preferably 1 to 3 carbon atoms.

The smaller the number of carbon atoms of the alkylene group for X″ or those of the alkyl group for Y″ and Z″ within the above-mentioned range of the number of carbon atoms, the more the solubility in a resist solvent is improved.

Further, in the alkylene group for X″ or the alkyl group for Y″ and Z″, it is preferable that the number of hydrogen atoms substituted with fluorine atoms is as large as possible because the acid strength increases and the transparency to high energy radiation of 200 nm or less or electron beam is improved. The fluorination ratio of the alkylene group or alkyl group is preferably from 70 to 100%, more preferably from 90 to 100%, and it is particularly desirable that the alkylene group or alkyl group be a perfluoroalkylene group or perfluoroalkyl group in which all hydrogen atoms are substituted with fluorine atoms.

Further, an onium salt-based acid generator in which the anion moiety (R⁴″SO₃⁻) in general formula (b-1) or (b-2) has been replaced with R¹²″—COO⁻ (in the formula, R¹²″ represents an alkyl group or a fluorinated alkyl group) can also be used (the cation moiety is the same as that in general formula (b-1) or (b-2)).

As R¹²″, the same groups as those described above for R⁴″ can be used.

Specific examples of the group represented by the formula “R¹²″—COO” include a trifluoroacetate ion, an acetate ion, and a 1-adamantanecarboxylic acid ion.

Furthermore, it is also possible to use an onium salt represented by general formula (b-1) or (b-2) in which the cation moiety has been replaced by a cation represented by formula (b′-1-9) or (b′-1-10) shown below or any one of the aforementioned cation moieties described above in relation to the cation moiety of the component (B1).

In formulas (b′-1-9) and (b′-1-10) shown below, each of R⁴ and R¹⁰ independently represents a phenyl group or naphthyl group which may have a substituent, an alkyl group of 1 to 5 carbon atoms, an alkoxy group or a hydroxyl group.

u is an integer of 1 to 3, and most preferably 1 or 2.

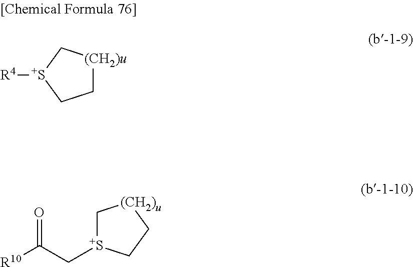

Furthermore, as an onium salt-based acid generator, a sulfonium salt having a cation represented by general formula (b-5) or (b-6) shown below as the cation moiety may be used.

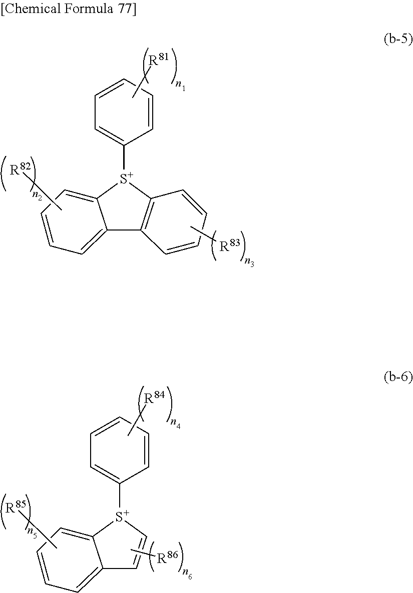

In formulas (b-5) and (b-6) above, each of R⁸¹ to R⁸⁶ independently represents an alkyl group, an acetyl group, an alkoxy group, a carboxy group, a hydroxyl group or a hydroxyalkyl group; each of n₁ to n₅ independently represents an integer of 0 to 3; and n₆ represents an integer of 0 to 2.

With respect to R⁸¹ to R⁸⁶, the alkyl group is preferably an alkyl group of 1 to 5 carbon atoms, more preferably a linear or branched alkyl group, and most preferably a methyl group, ethyl group, propyl group, isopropyl group, n-butyl group or tert butyl group.

The alkoxy group is preferably an alkoxy group of 1 to 5 carbon atoms, more preferably a linear or branched alkoxy group, and most preferably a methoxy group or ethoxy group.

The hydroxyalkyl group is preferably the aforementioned alkyl group in which one or more hydrogen atoms have been substituted with hydroxy groups, and examples thereof include a hydroxymethyl group, a hydroxyethyl group and a hydroxypropyl group.

If there are two or more of an individual R⁸¹ to R⁸⁶ group, as indicated by the corresponding value of n₁ to n₆, then the two or more of the individual R⁸¹ to R⁸⁶ group may be the same or different from each other.

n₁ is preferably 0 to 2, more preferably 0 or 1, and still more preferably 0.

It is preferable that n₂ and n₃ each independently represent 0 or 1, and more preferably 0.

n₄ is preferably 0 to 2, and more preferably 0 or 1.

n₅ is preferably 0 or 1, and more preferably 0.

n₆ is preferably 0 or 1, and more preferably 1.

The anion moiety of the sulfonium salt having a cation moiety represented by general formula (b-5) or (b-6) is not particularly limited, and the same anion moieties for onium salt-based acid generators which have been proposed may be used. Examples of such anion moieties include fluorinated alkylsulfonic acid ions such as anion moieties (R⁴″SO₃⁻) for onium salt-based acid generators represented by general formula (b-1) or (b-2) shown above; and anion moieties represented by general formula (b-3) or (b-4) shown above. Among these, a fluorinated alkylsulfonate ion is preferable, a fluorinated alkylsulfonate ion of 1 to 4 carbon atoms is more preferable, and a linear perfluoroalkylsulfonate ion of 1 to 4 carbon atoms is particularly desirable. Specific examples thereof include a trifluoromethylsulfonate ion, a heptafluoro-n-propanesulfonate ion and a nonafluoro-n-butanesulfonate ion.

In the present description, an oximesulfonate-based acid generator is a compound having at least one group represented by general formula (B-1) shown below, and has a feature of generating acid by irradiation. Such oximesulfonate acid generators are widely used for a chemically amplified resist composition, and can be appropriately selected.

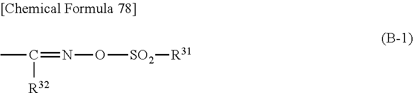

In the formula, each of R³¹ and R³² independently represents an organic group.

The organic group for R³¹ and R³² refers to a group containing a carbon atom, and may include atoms other than carbon atoms (e.g., a hydrogen atom, an oxygen atom, a nitrogen atom, a sulfur atom, a halogen atom (such as a fluorine atom and a chlorine atom) and the like).

As the organic group for R³¹, a linear, branched, or cyclic alkyl group or aryl group is preferable. The alkyl group or the aryl group may have a substituent. The substituent is not particularly limited, and examples thereof include a fluorine atom and a linear, branched, or cyclic alkyl group having 1 to 6 carbon atoms. The alkyl group or the aryl group “has a substituent” means that part or all of the hydrogen atoms of the alkyl group or the aryl group is substituted with a substituent.

The alkyl group preferably has 1 to 20 carbon atoms, more preferably 1 to 10 carbon atoms, still more preferably 1 to 8 carbon atoms, still more preferably 1 to 6 carbon atoms, and most preferably 1 to 4 carbon atoms. As the alkyl group, a partially or completely halogenated alkyl group (hereinafter, sometimes referred to as a “halogenated alkyl group”) is particularly desirable. The “partially halogenated alkyl group” refers to an alkyl group in which part of the hydrogen atoms are substituted with halogen atoms and the “completely halogenated alkyl group” refers to an alkyl group in which all of the hydrogen atoms are substituted with halogen atoms. Examples of halogen atoms include fluorine atoms, chlorine atoms, bromine atoms and iodine atoms, and fluorine atoms are particularly desirable. In other words, the halogenated alkyl group is preferably a fluorinated alkyl group.

The aryl group preferably has 4 to 20 carbon atoms, more preferably 4 to 10 carbon atoms, and most preferably 6 to 10 carbon atoms. As the aryl group, partially or completely halogenated aryl group is particularly desirable. The “partially halogenated aryl group” refers to an aryl group in which some of the hydrogen atoms are substituted with halogen atoms and the “completely halogenated aryl group” refers to an aryl group in which all of hydrogen atoms are substituted with halogen atoms.

As R³¹, an alkyl group of 1 to 4 carbon atoms which has no substituent or a fluorinated alkyl group of 1 to 4 carbon atoms is particularly desirable.

As the organic group for R³², a linear, branched, or cyclic alkyl group, aryl group, or cyano group is preferable. Examples of the alkyl group and the aryl group for R³² include the same alkyl groups and aryl groups as those described above for R³¹.

As R³², a cyano group, an alkyl group of 1 to 8 carbon atoms having no substituent or a fluorinated alkyl group of 1 to 8 carbon atoms is particularly desirable.

Preferred examples of the oxime sulfonate acid generator include compounds represented by general formula (B-2) or (B-3) shown below.

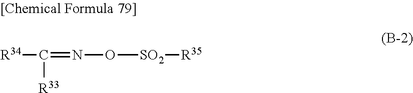

In the formula, R³³ represents a cyano group, an alkyl group having no substituent or a halogenated alkyl group; R³⁴ represents an aryl group; and R³⁵ represents an alkyl group having no substituent or a halogenated alkyl group.

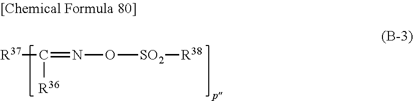

In the formula, R³⁶ represents a cyano group, an alkyl group having no substituent or a halogenated alkyl group; R³⁷ represents a divalent or trivalent aromatic hydrocarbon group; R³⁸ represents an alkyl group having no substituent or a halogenated alkyl group; and p″ represents 2 or 3.

In general formula (B-2), the alkyl group having no substituent or the halogenated alkyl group for R³³ preferably has 1 to 10 carbon atoms, more preferably 1 to 8 carbon atoms, and most preferably 1 to 6 carbon atoms.

As R³³, a halogenated alkyl group is preferable, and a fluorinated alkyl group is more preferable.

The fluorinated alkyl group for R³³ preferably has 50% or more of the hydrogen atoms thereof fluorinated, more preferably 70% or more, and most preferably 90% or more.

Examples of the aryl group for R³⁴ include groups in which one hydrogen atom has been removed from an aromatic hydrocarbon ring, such as a phenyl group, a biphenyl group, a fluorenyl group, a naphthyl group, an anthryl group, and a phenanthryl group, and heteroaryl groups in which some of the carbon atoms constituting the ring(s) of these groups are substituted with hetero atoms such as an oxygen atom, a sulfur atom, and a nitrogen atom. Of these, a fluorenyl group is preferable.

The aryl group for R³⁴ may have a substituent such as an alkyl group of 1 to 10 carbon atoms, a halogenated alkyl group, or an alkoxy group. The alkyl group and halogenated alkyl group as the substituent preferably has 1 to 8 carbon atoms, and more preferably 1 to 4 carbon atoms. Further, the halogenated alkyl group is preferably a fluorinated alkyl group.

The alkyl group having no substituent or the halogenated alkyl group for R³⁵ preferably has 1 to 10 carbon atoms, more preferably 1 to 8 carbon atoms, and most preferably 1 to 6 carbon atoms.

As R³⁵, a halogenated alkyl group is preferable, and a fluorinated alkyl group is more preferable.

In terms of enhancing the strength of the acid generated, the fluorinated alkyl group for R³⁵ preferably has 50% or more of the hydrogen atoms fluorinated, more preferably 70% or more, still more preferably 90% or more. A completely fluorinated alkyl group in which 100% of the hydrogen atoms are substituted with fluorine atoms is particularly desirable.

In general formula (B-3), as the alkyl group having no substituent and the halogenated alkyl group for R³⁶, the same alkyl group having no substituent and the halogenated alkyl group described above for R³³ can be used.

Examples of the divalent or trivalent aromatic hydrocarbon group for R³⁷ include groups in which one or two hydrogen atoms have been removed from the aryl group for R³⁴.

As the alkyl group having no substituent or the halogenated alkyl group for R³⁸, the same one as the alkyl group having no substituent or the halogenated alkyl group for R³⁵ can be used.

p″ is preferably 2.

Specific examples of suitable oxime sulfonate acid generators include
α-(p-toluenesulfonyloxyimino)-benzyl cyanide,
α-(p-chlorobenzenesulfonyloxyimino)-benzyl cyanide,
α-(4-nitrobenzenesulfonyloxyimino)-benzyl cyanide,
α-(4-nitro-2-trifluoromethylbenzenesulfonyloxyimino)-benzyl cyanide,
α-(benzenesulfonyloxyimino)-4-chlorobenzyl cyanide,
α-(benzenesulfonyloxyimino)-2,4-dichlorobenzyl cyanide,
α-(benzenesulfonyloxyimino)-2,6-dichlorobenzyl cyanide,
α-(benzenesulfonyloxyimino)-4-methoxybenzyl cyanide,
α-(2-chlorobenzenesulfonyloxyimino)-4-methoxybenzyl cyanide,
α-(benzenesulfonyloxyimino)-thien-2-yl acetonitrile,
α-(4-dodecylbenzenesulfonyloxyimino)benzyl cyanide,
α-[(p-toluenesulfonyloxyimino)-4-methoxyphenyl]acetonitrile,
α-[(dodecylbenzenesulfonyloxyimino)-4-methoxyphenyl]acetonitrile,
α-(tosyloxyimino)-4-thienyl cyanide, α-(methylsulfonyloxyimino)-1-cyclopentenyl acetonitrile, α-(methylsulfonyloxyimino)-1-cyclohexenyl acetonitrile,
α-(methylsulfonyloxyimino)-1-cycloheptenyl acetonitrile,
α-(methylsulfonyloxyimino)-1-cyclooctenyl acetonitrile,
α-(trifluoromethylsulfonyloxyimino)-1-cyclopentenyl acetonitrile,
α-(trifluoromethylsulfonyloxyimino)-cyclohexyl acetonitrile,
α-(ethylsulfonyloxyimino)-ethyl acetonitrile, α-(propylsulfonyloxyimino)-propyl acetonitrile, α-(cyclohexylsulfonyloxyimino)-cyclopentyl acetonitrile,
α-(cyclohexylsulfonyloxyimino)-cyclohexyl acetonitrile,
α-(cyclohexylsulfonyloxyimino)-1-cyclopentenyl acetonitrile,
α-(ethylsulfonyloxyimino)-1-cyclopentenyl acetonitrile,
α-(isopropylsulfonyloxyimino)-1-cyclopentenyl acetonitrile,
α-(n-butylsulfonyloxyimino)-1-cyclopentenyl acetonitrile,
α-(ethylsulfonyloxyimino)-1-cyclohexenyl acetonitrile,
α-(isopropylsulfonyloxyimino)-1-cyclohexenyl acetonitrile,
α-(n-butylsulfonyloxyimino)-1-cyclohexenyl acetonitrile,
α-(methylsulfonyloxyimino)-phenyl acetonitrile,
α-(methylsulfonyloxyimino)-p-methoxyphenyl acetonitrile,
α-(trifluoromethylsulfonyloxyimino)-phenyl acetonitrile,
α-(trifluoromethylsulfonyloxyimino)-p-methoxyphenyl acetonitrile,
α-(ethylsulfonyloxyimino)-p-methoxyphenyl acetonitrile,
α-(propylsulfonyloxyimino)-p-methylphenyl acetonitrile, and
α-(methylsulfonyloxyimino)-p-bromophenyl acetonitrile.

Further, oxime sulfonate acid generators disclosed in Japanese Unexamined Patent Application, First Publication No. Hei 9-208554 (Chemical Formulas 18 and 19 shown in paragraphs [0012] to [0014]) and oxime sulfonate acid generators disclosed in WO 2004/074242A2 (Examples 1 to 40 described at pages 65 to 85) may be preferably used.

Furthermore, as preferable examples, the following can be used.

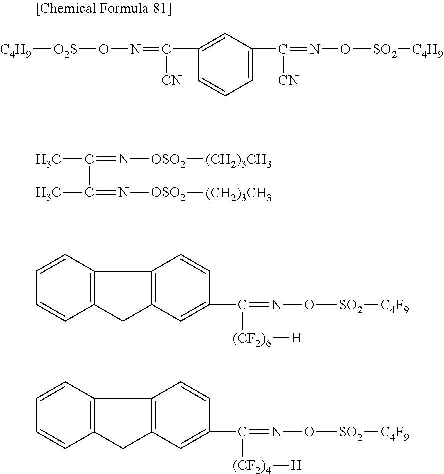

Of the aforementioned diazomethane acid generators, specific examples of suitable bisalkyl or bisaryl sulfonyl diazomethanes include bis(isopropylsulfonyl)diazomethane, bis(p-toluenesulfonyl)diazomethane, bis(1,1-dimethylethylsulfonyl)diazomethane, bis(cyclohexylsulfonyl)diazomethane, and bis(2,4-dimethylphenylsulfonyl)diazomethane.

Further, diazomethane acid generators disclosed in Japanese Unexamined Patent Application, First Publication No. Hei 11-035551, Japanese Unexamined Patent Application, First Publication No. Hei 11-035552 and Japanese Unexamined Patent Application, First Publication No. Hei 11-035573 may be preferably used.

Furthermore, as examples of poly(bis-sulfonyl)diazomethanes, those disclosed in Japanese Unexamined Patent Application, First Publication No. Hei 11-322707, including 1,3-bis(phenylsulfonyldiazomethylsulfonyl)propane, 1,4-bis(phenylsulfonyldiazomethylsulfonyl)butane, 1,6-bis(phenylsulfonyldiazomethylsulfonyl)hexane, 1,10-bis(phenylsulfonyldiazomethylsulfonyl)decane, 1,2-bis(cyclohexylsulfonyldiazomethylsulfonyl)ethane, 1,3-bis(cyclohexylsulfonyldiazomethylsulfonyl)propane, 1,6-bis(cyclohexylsulfonyldiazomethylsulfonyl)hexane, and 1,10-bis(cyclohexylsulfonyldiazomethylsulfonyl)decane, may be given.

As the component (B2), one type of acid generator may be used, or two or more types may be used in combination.

Among the aforementioned examples, as the component (B2), an acid generator having an anion in which R⁴″ represents a fluorinated alkyl group which may have a substituent, i.e., an onium salt acid generator having a fluorinated alkylsulfonate ion which may have a substituent is preferable.

When a combination of the component (B1) and the component (B2) is used as the component (B), in terms of improvement in lithography properties (e.g., reduction of pattern roughness), the ratio (molar ratio) of the amount of the component (B1) to the component (B2) (component (B1):component (B2)) is preferably 99:1 to 1:99, more preferably 99:1 to 10:90, and still more preferably 95:5 to 30:70.

In the resist composition of the present invention, the amount of the component (B), relative to 100 parts by weight of the component (A) is preferably 0.5 to 50 parts by weight, and more preferably 1 to 40 parts by weight. When the amount of the component (B) is within the above-mentioned range, formation of a resist pattern can be satisfactorily performed. Further, by virtue of the above-mentioned range, a uniform solution can be obtained and the storage stability becomes satisfactory.

<Component (S)>

In the resist composition of the present invention, the organic component (S) (hereafter, referred to as “component (S)”) includes an alcohol-based organic solvent having a boiling point of at least 150° C. (hereafter, such an alcohol-based organic solvent is referred to as “component (S1)”).

In the present descriptions and the claims, the term “alcohol-based organic solvent” refers to a compound in which at least one hydrogen atom within an aliphatic hydrocarbon has been substituted with an hydroxyl group, and is a liquid at normal temperature and normal pressure. The structure of the main chain constituting the aforementioned aliphatic hydrocarbon may be a chain-like structure or a cyclic structure, or may include a cyclic structure within the chain-like structure, or may include an ether bond within the chain-like structure.

Here, the term “boiling point” refers to the normal boiling point measured under normal pressure.

[Component (S1)]

The component (S1) is an alcohol-based organic solvent having a boiling point of at least 150° C.

The boiling point of the component (S1) is at least 150° C., and is preferably at least 155° C., and most preferably within a range from 155 to 250° C.

When the boiling point is at least 150° C., the component (A) exhibits excellent solubility in the organic solvent (S) containing the component (S1). Further, by making the lower limit and upper limit of the boiling point at least 150° C. and no more than 250° C., respectively, properties of the resist composition in terms of coatability (wettability) to a substrate become excellent.

Furthermore, because the component (A) exhibits excellent solubility in the component (S1), the number of options (that is, the polymeric compounds which can be used as the component (A)) increases, which contributes to improvements in the lithographic properties. These advantages can also be achieved in the application of a double patterning process.

As the component (S1), for example, a monohydric alcohol and a dihydric alcohol can be mentioned, and a monohydric alcohol is preferable, and a primary or secondary monohydric alcohol is more preferable. Further, the component (S1) preferably has a ring structure composed of at least 5 carbon atoms (more preferably at least 7 carbon atoms) or a chain-like structure composed of at least 5 carbon atoms (more preferably at least 7 carbon atoms). The ring structure or chain-like structure described above may contain an ether bond within the structure.

With respect to the chain-like structure composed of at least 5 carbon atoms (more preferably at least 7 carbon atoms), it is even more preferable that the longest main chain containing an —OH group have at least 5 carbon atoms. The main chain may contain an ether bond within the structure.

It is particularly desirable that the component (S1) be a monohydric alcohol having a chain-like structure composed of at least 5 carbon atoms (more preferably at least 7 carbon atoms).

Here, the term “monohydric alcohol” refers to compounds in which the number of hydroxyl groups incorporated within the alcohol molecule is 1, and does not include dihydric alcohols, trihydric alcohols, or derivatives thereof.

Specific examples of the component (S1) having a chain-like structure include propylene glycol (PG; boiling point: 188° C.); and monohydric alcohols such as 1-butoxy-2-propanol (BP; boiling point: 170° C.), n-hexanol (boiling point: 156° C.), 2-heptanol (boiling point: 160.4° C.), 3-heptanol (boiling point: 156.2° C.), 1-heptanol (boiling point: 176° C.), 5-methyl-1-hexanol (boiling point: 167° C.), 6-methyl-2-heptanol (boiling point: 171° C.), 1-octanol (boiling point: 196° C.), 2-octanol (boiling point: 179° C.), 3-octanol (boiling point: 175° C.), 4-octanol (boiling point: 175° C.), 2-ethyl-1-hexanol (boiling point: 185° C.), and 2-(2-butoxyethoxy)ethanol (boiling point: 231° C.).

Further, specific examples of the component (S1) having a ring structure include monohydric alcohols such as cyclopentane methanol (boiling point: 162° C.), 1-cyclopentylethanol (boiling point: 167° C.), cyclohexanol (boiling point: 161° C.), cyclohexane methanol (CM; boiling point: 183° C.), cyclohexane ethanol (boiling point: 205° C.), 1,2,3,6-tetrahydrobenzyl alcohol (boiling point: 191° C.), exo-norborneol (boiling point: 176° C.), 2-methylcyclohexanol (boiling point: 165° C.), cycloheptanol (boiling point: 185° C.), 3,5-dimethylcyclohexanol (boiling point: 185° C.), and benzyl alcohol (boiling point: 204° C.).

Of these, monohydric alcohols having a chain-like structure are preferable, and 1-butoxy-2-propanol is particularly desirable.

As the component (S1), one type may be used alone, or two or more types may be used in combination.

The amount of the component (S1) within the component (S) is preferably at least 50% by weight, more preferably at least 80% by weight, and most preferably 100% weight. When the amount of the component (S1) is at least as large as the lower limit of the above-mentioned range, the solubility of the component (A) in the component (S) becomes even more satisfactory.

In addition to the component (S1), the component (S) may include an organic solvent other than the component (S1), as long as the effects of the present invention are not impaired.

[Component (S2)]

As an organic solvent other than the component (S1), for example, an ether-based organic solvent having no hydroxyl group (hereafter, referred to as “component (S2)”) may be used.

Here, an “ether-based organic solvent having no hydroxyl group” refers to a compound that contains an ether bond (C—O—C) within the molecule but has no hydroxyl group, and is a liquid at normal temperature (room temperature) and normal pressure (atmospheric pressure).

Of the various possibilities, it is more preferable that the component (S2) be a compound having neither a hydroxyl group nor a carbonyl group.

Preferable examples of the component (S2) include compounds represented by general formula (s1′-1) shown below.

R⁷³—O—R⁷⁴ (s1′-1)

In the formula, each of R⁷³ and R⁷⁴ independently represents a hydrocarbon group. Alternatively, R⁷³ and R⁷⁴ may be bonded to each other to form a ring. —O— represents an ether bond.

In general formula (s1′-1), as the hydrocarbon group for R⁷³ and R⁷⁴, for example, an alkyl group, an aryl group or the like can be mentioned, and an alkyl group is preferable. It is more preferable that both of R⁷³ and R⁷⁴ represent an alkyl group, and it is particularly desirable that R⁷³ and R⁷⁴ represent the same alkyl group.

The alkyl group for R⁷³ and R⁷⁴ is not particularly limited and includes, for example, a linear, branched or cyclic alkyl group having 1 to 20 carbon atoms. Part or all of the hydrogen atoms of the alkyl group may or may not be substituted with halogen atoms or the like.

The alkyl group preferably has 1 to 15 carbon atoms, and more preferably 1 to 10 carbon atoms, because the coatability of the resist composition becomes satisfactory. Specific examples include an ethyl group, a propyl group, an isopropyl group, an n-butyl group, an isobutyl group, an n-pentyl group, an isopentyl group, a cyclopentyl group and a hexyl group, and an n-butyl group and an isopentyl group are particularly desirable.

The halogen atom, with which hydrogen atoms of the alkyl group may be substituted, is preferably a fluorine atom.

The aryl group for R⁷³ and R⁷⁴ is not particularly limited. For example, an aryl group having 6 to 12 carbon atoms may be used in which part or all of the hydrogen atoms of the aryl group may or may not be substituted with alkyl groups, alkoxy groups, halogen atoms, or the like.

The aryl group is preferably an aryl group having 6 to 10 carbon atoms because it can be synthesized at a low cost. Specific examples thereof include a phenyl group, a benzyl group and a naphthyl group.

The alkyl group, with which hydrogen atoms of the aryl group may be substituted, is preferably an alkyl group having 1 to 5 carbon atoms, and more preferably a methyl group, an ethyl group, a propyl group, an n-butyl group, or a tert-butyl group.

The alkoxy group, with which hydrogen atoms of the aryl group may be substituted, is preferably an alkoxy group having 1 to 5 carbon atoms, and more preferably a methoxy group or an ethoxy group.

The halogen atom, with which hydrogen atoms of the aryl group may be substituted, is preferably a fluorine atom.

Alternatively, in general formula (s1′-1), R⁷³ and R⁷⁴ may be bonded to each other to form a ring.

In this case, R⁷³ and R⁷⁴ each independently represents a linear or branched alkylene group (preferably an alkylene group of 1 to 10 carbon atoms) and the terminal of R⁷³ and the terminal of R⁷⁴ are bonded to each other to form a ring. Further, a carbon atom of the alkylene group may be substituted with an oxygen atom.

Specific examples of such ether-based organic solvents include 1,8-cineole, tetrahydrofuran and dioxane.

The boiling point (at normal pressure (atmospheric pressure)) of the component (S2) is preferably within a range from 30 to 300° C., more preferably from 100 to 200° C., and still more preferably from 140 to 180° C. When the boiling point of the component (S2) is at least as large as the lower limit of the above-mentioned temperature range, the component (S) hardly evaporates during the spin coating process when applying the resist composition of the present invention, thereby suppressing coating irregularities and improving the resulting coating properties. On the other hand, when the boiling point of the component (S2) is no more than the upper limit of the above-mentioned temperature range, the component (S) is satisfactorily removed from the resist film by a prebake (PAB) treatment, thereby improving formability of the resist film. Further, when the boiling point of the component (S2) is within the above-mentioned temperature range, the effect of reducing the thickness loss of the resist patterns and the stability of the composition upon storage are further improved. The above-mentioned temperature range for the boiling point of the component (S2) is also preferable from the viewpoints of the heating temperature required in the PAB step and/or PEB step.

Specific examples of the component (S2) include 1,8-cineole (boiling point: 176° C.), dibutyl ether (boiling point: 142° C.), diisopentyl ether (boiling point: 171° C.), dioxane (boiling point: 101° C.), anisole (boiling point: 155° C.), ethylbenzyl ether (boiling point: 189° C.), diphenyl ether (boiling point: 259° C.), dibenzyl ether (boiling point: 297° C.), phenetole (boiling point: 170° C.), butylphenyl ether, tetrahydrofuran (boiling point: 66° C.), ethylpropyl ether (boiling point: 63° C.), diisopropyl ether (boiling point: 69° C.), dihexyl ether (boiling point: 226° C.), dipropyl ether (boiling point: 91° C.), and cresylmethyl ether.

These components (S2) can be used either alone, or in combinations of two or more different solvents.

In the present invention, the component (S2) is preferably a cyclic or chain-like, ether-based organic solvent because the effect of reducing the thickness loss of the resist patterns becomes satisfactory, and it is particularly desirable that the component (S2) be at least one member selected from the group consisting of 1,8-cineole, dibutyl ether and diisopentyl ether.

[Component (S3)]

In addition to the component (S1), or in addition to the components (S1) and (S2), the component (S) may also include an organic solvent other than the components (S1) and (S2) (hereafter, referred to as “component (S3)”), as long as the effects of the present invention are not impaired.

The component (S3) may be any organic solvent which can dissolve the resist materials to give a uniform solution, and any one or more kinds of organic solvents can be appropriately selected from those which have been conventionally known as solvents for a chemically amplified resist.

By further including the component (S3), the solubility of the components (A), (B) and the like, and other properties can be adjusted.

Examples of the component (S3) include lactones such as γ-butyrolactone; ketones such as acetone, methyl ethyl ketone, cyclohexanone, methyl-n-pentyl ketone, methyl isopentyl ketone, and 2-heptanone; polyhydric alcohols, such as ethylene glycol, diethylene glycol, propylene glycol and dipropylene glycol; compounds having an ester bond, such as ethylene glycol monoacetate, diethylene glycol monoacetate, propylene glycol monoacetate, and dipropylene glycol monoacetate; polyhydric alcohol derivatives including compounds having an ether bond, such as a monoalkylether (e.g., monomethylether, monoethylether, monopropylether or monobutylether) or monophenylether of any of these polyhydric alcohols or compounds having an ester bond (among these, propylene glycol monomethyl ether acetate (PGMEA; boiling point: 146° C.) and propylene glycol monomethyl ether (PGME; boiling point: 120° C.) are preferable); esters such as methyl lactate, ethyl lactate (EL), methyl acetate, ethyl acetate, butyl acetate, methyl pyruvate, ethyl pyruvate, methyl methoxypropionate, and ethyl ethoxypropionate; aromatic organic solvents such as ethylbenzene, diethylbenzene, pentylbenzene, isopropylbenzene, toluene, xylene, cymene and mesitylene; dimethyl sulfoxide (DMSO); and alcohol-based organic solvents having a boiling point of less than 150° C. (hereafter, referred to as “component (S3a)”), such as n-pentyl alcohol (boiling point: 138.0° C.), s-pentyl alcohol (boiling point: 119.3° C.), t-pentyl alcohol (boiling point: 101.8° C.), isopentyl alcohol (boiling point: 130.8° C.), isobutanol (also called isobutyl alcohol or 2-methyl-1-propanol) (boiling point: 108° C.), isopropyl alcohol (boiling point: 82.3° C.), 2-ethylbutanol (boiling point: 147° C.), neopentyl alcohol (boiling point: 114° C.), n-butanol (boiling point: 117.6° C.), s-butanol (boiling point: 99.5° C.), t-butanol (boiling point: 82.5° C.), 1-propanol (boiling point: 97.2° C.), 2-methyl-1-butanol (boiling point: 128.0° C.), 3-methyl-1-butanol (130° C.), 2-methyl-2-butanol (boiling point: 112.0° C.), 3,3-dimethyl-1-butanol (143° C.), 4-methyl-2-pentanol (boiling point: 132° C.) and 2-hexanol (139° C.).

These components (S3) can be used either alone, or in combinations of two or more different solvents.

The total amount of the component (S) used is not particularly limited, and is appropriately adjusted to a concentration which enables coating of the resist composition of the present invention to a substrate, depending on the thickness of the coating film. In general, the component (S) is preferably used in an amount such that the solid content of the resist composition becomes within the range from 1 to 20% by weight, and more preferably from 2 to 15% by weight.

In the resist composition of the present invention, as the component (S), a mixed solvent of the components (S1) and (S3a) may also be used favorably. When such a mixed solvent is used, the solubility of resist materials, especially that of the component (A) (and preferably the component (A1)) is significantly enhanced, as compared to the case where the component (S3a) is used alone.

The mixing ratio (weight ratio) of the component (S1) to the component (S3a) (i.e., (S1)/(S3a)) is preferably within a range from 1/99 to 99/1, more preferably from 5/95 to 95/5, and is most preferably from 10/90 to 90/10. When the ratio of the component (S1) to the component (S3a) is within the above-mentioned range, the solubility of the resist materials and other properties can be improved even further.

<Optional Components>

[Component (D)]

It is preferable that the resist composition of the present invention further includes a nitrogen-containing organic compound (D) (hereafter referred to as the component (D)) as an optional component.

As the component (D), there is no particular limitation as long as it functions as an acid diffusion control agent, i.e., a quencher which traps the acid generated from the component (B) upon exposure. A multitude of these components (D) have already been proposed, and any of these known compounds may be used, although an aliphatic amine, and particularly a secondary aliphatic amine or tertiary aliphatic amine is preferable.

An aliphatic amine is an amine having one or more aliphatic groups, and the aliphatic groups preferably have 1 to 12 carbon atoms.

Examples of these aliphatic amines include amines in which at least one hydrogen atom of ammonia (NH₃) has been substituted with an alkyl group or hydroxyalkyl group of no more than 12 carbon atoms (i.e., alkylamines or alkylalcoholamines), and cyclic amines.

Specific examples of alkylamines and alkylalcoholamines include monoalkylamines such as n-hexylamine, n-heptylamine, n-octylamine, n-nonylamine, and n-decylamine; dialkylamines such as diethylamine, di-n-propylamine, di-n-heptylamine, di-n-octylamine, and dicyclohexylamine; trialkylamines such as trimethylamine, triethylamine, tri-n-propylamine, tri-n-butylamine, tri-n-hexylamine, tri-n-pentylamine, tri-n-heptylamine, tri-n-octylamine, tri-n-nonylamine, tri-n-decylamine, and tri-n-dodecylamine; and alkyl alcohol amines such as diethanolamine, triethanolamine, diisopropanolamine, triisopropanolamine, di-n-octanolamine, and tri-n-octanolamine. Among these, trialkylamines of 5 to 10 carbon atoms are preferable, and tri-n-pentylamine is particularly desirable.

Examples of the cyclic amine include heterocyclic compounds containing a nitrogen atom as a hetero atom. The heterocyclic compound may be a monocyclic compound (aliphatic monocyclic amine), or a polycyclic compound (aliphatic polycyclic amine).

Specific examples of the aliphatic monocyclic amine include piperidine, and piperazine.

The aliphatic polycyclic amine preferably has 6 to 10 carbon atoms, and specific examples thereof include 1,5-diazabicyclo[4.3.0]-5-nonene, 1,8-diazabicyclo[5.4.0]-7-undecene, hexamethylenetetramine, and 1,4-diazabicyclo[2.2.2]octane.

These compounds can be used either alone, or in combinations of two or more different compounds.

In the present invention, as the component (D), it is preferable to use a trialkylamine of 5 to 10 carbon atoms.

The component (D) is typically used in an amount within a range from 0.01 to 5.0 parts by weight, relative to 100 parts by weight of the component (A). When the amount of the component (D) is within the above-mentioned range, the shape of the resist pattern and the post exposure stability of the latent image formed by the pattern-wise exposure of the resist layer are improved.

[Component (E)]

Furthermore, in the resist composition of the present invention, for preventing any deterioration in sensitivity, and improving the resist pattern shape and the post exposure stability of the latent image formed by the pattern-wise exposure of the resist layer, at least one compound (E) (hereafter referred to as “component (E)”) selected from the group consisting of an organic carboxylic acid, or a phosphorus oxo acid or derivative thereof can be added.

Examples of suitable organic carboxylic acids include acetic acid, malonic acid, citric acid, malic acid, succinic acid, benzoic acid, and salicylic acid.

Examples of phosphorus oxo acids include phosphoric acid, phosphonic acid and phosphinic acid. Among these, phosphonic acid is particularly desirable.

Examples of oxo acid derivatives include esters in which a hydrogen atom within the above-mentioned oxo acids is substituted with a hydrocarbon group. Examples of the hydrocarbon group include an alkyl group of 1 to 5 carbon atoms and an aryl group of 6 to 15 carbon atoms.

Examples of phosphoric acid derivatives include phosphoric acid esters such as di-n-butyl phosphate and diphenyl phosphate.

Examples of phosphonic acid derivatives include phosphonic acid esters such as dimethyl phosphonate, di-n-butyl phosphonate, phenylphosphonic acid, diphenyl phosphonate and dibenzyl phosphonate.

Examples of phosphinic acid derivatives include phosphinic acid esters such as phenylphosphinic acid.

As the component (E), one type may be used alone, or two or more types may be used in combination.

As the component (E), an organic carboxylic acid is preferred, and salicylic acid is particularly desirable.

The component (E) is typically used in an amount within a range from 0.01 to 5.0 parts by weight, relative to 100 parts by weight of the component (A).

[Component (F)]

The resist composition of the present invention may further include a fluorine-containing compound component (F) (hereafter, referred to as “component (F)”). By including the component (F), the hydrophobicity of the surface of the resist film improves, thereby yielding a resist composition that is suitable also for immersion exposure.

The component (F) is not particularly limited and may be either a polymeric compound (polymer or copolymer) including a recurring unit, or a low molecular weight compound (non-polymer).

Examples of the polymeric compounds (polymers or copolymers) used as the component (F) include a polymeric compound having a recurring unit that contains a fluorine atom. More specifically, a polymeric compound including one or more recurring units that contain a fluorine atom; and a polymeric compound including recurring units consisting of a structural unit containing a fluorine atom and a structural unit with no fluorine atom, can be mentioned.

Further, examples of the low molecular weight compounds (non-polymers) used as the component (F) include a monomer for deriving structural units containing a fluorine atom which constitute the aforementioned polymeric compounds (polymers or copolymers).

Among these, the component (F) is preferably a polymeric compound (polymer or copolymer).

Structural Unit Containing a Fluorine Atom (Structural Unit (f1))

The structural unit containing a fluorine atom (hereafter, referred to as “structural unit (f1)”) is not particularly limited as long as it is a structural unit containing a fluorine atom. For example, in the structural unit, a fluorine atom may be included within the side chain or may be directly bonded to the main chain, or a fluorine atom may be included in a substituent which is directly bonded to the main chain.

Of these various possibilities, as the structural unit (f1), a structural unit containing a fluorine atom within the side chain thereof is preferable. Specific examples include a structural unit having a group represented by general formula (f1-1-0) shown below; a structural unit having a fluorine atom and a group that contains an acid dissociable, dissolution inhibiting group; and a structural unit having a non-acid-dissociable fluorinated alkyl group of 1 to 20 carbon atoms, and a structural unit having a group represented by general formula (f1-1-0) is more preferable.

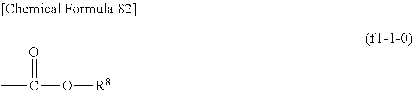

In formula (f1-1-0), R⁸ represents an organic group having a fluorine atom, provided that the carbon atom within the —C(═O)— moiety is not directly bonded to the main chain.

(Structural Unit Having a Group Represented by General Formula (f1-1-0))

In the formula (f1-1-0) above, R⁸ represents an organic group having a fluorine atom.

An “organic group” is a group containing at least one carbon atom.

In the organic group having a fluorine atom for R⁸, the structure of R⁸ may be linear, branched or cyclic, and is preferably linear or branched.

In R⁸, the organic group preferably has 1 to 20 carbon atoms, more preferably 1 to 15 carbon atoms, still more preferably 1 to 10 carbon atoms, and most preferably 1 to 5 carbon atoms.

In R⁸, the fluorination ratio of the organic group is preferably 25% or more, more preferably 50% or more, and most preferably 60% or more, as the hydrophobicity of the resist film is enhanced.

The term “fluorination ratio” refers to the percentage (%) of the number of fluorine atoms relative to the total number of hydrogen atoms and fluorine atoms contained within the organic group.

More specifically, preferable examples of R⁸ include a fluorinated hydrocarbon group which may have a substituent.

In the fluorinated hydrocarbon group, the hydrocarbon group (a hydrocarbon group which is not fluorinated) may be either an aliphatic hydrocarbon group or an aromatic hydrocarbon group, and an aliphatic hydrocarbon group is preferable.

An aliphatic hydrocarbon group refers to a hydrocarbon group having no aromaticity. The aliphatic hydrocarbon group may be either saturated or unsaturated, but in general, the aliphatic hydrocarbon group is preferably saturated.

As R⁸, a fluorinated, saturated hydrocarbon group or a fluorinated, unsaturated hydrocarbon group is preferable, more preferably a fluorinated, saturated hydrocarbon group, and most preferably a fluorinated alkyl group.

Examples of fluorinated alkyl groups include groups in which part or all of the hydrogen atoms within the below described unsubstituted alkyl groups (below-described groups which do not have a substituent) have been substituted with a fluorine atom.

The fluorinated alkyl group may be either a group in which part of the hydrogen atoms within an unsubstituted alkyl group described below has been substituted with a fluorine atom, or a group in which all of the hydrogen atoms within an unsubstituted alkyl group described below has been substituted with a fluorine atom (i.e., a perfluoroalkyl group).

The unsubstituted alkyl group may be any of linear, branched or cyclic. Alternatively, the unsubstituted alkyl group may be a combination of a linear or branched alkyl group with a cyclic alkyl group.

The unsubstituted linear alkyl group preferably has 1 to 10 carbon atoms, and more preferably 1 to 8. Specific examples include a methyl group, an ethyl group, an n-propyl group, an n-butyl group, an n-pentyl group, an n-hexyl group, an n-heptyl group, an n-octyl group, an n-nonyl group and an n-decyl group.

The unsubstituted branched alkyl group preferably has 3 to 10 carbon atoms, and more preferably 3 to 8. As the branched alkyl group, a tertiary alkyl group is preferable.

As an example of an unsubstituted cyclic alkyl group, a group in which one hydrogen atom has been removed from a monocycloalkane or a polycycloalkane such as a bicycloalkane, tricycloalkane or tetracycloalkane can be given. Specific examples include monocycloalkyl groups such as a cyclopentyl group and a cyclohexyl group; and polycycloalkyl groups such as an adamantyl group, a norbornyl group, an isobornyl group, a tricyclodecyl group and a tetracyclododecyl group.

Examples of the combination of a linear or branched alkyl group with a cyclic alkyl group include groups in which a cyclic alkyl group as a substituent is bonded to a linear or branched alkyl group, and groups in which a linear or branched alkyl group as a substituent is bonded to a cyclic alkyl group.

Examples of the substituent for the fluorinated hydrocarbon group include alkyl groups of 1 to 5 carbon atoms.

As the fluorinated alkyl group for R⁸, a linear or branched fluorinated alkyl group is preferable. In particular, a group represented by general formula (VII-1) or (VII-2) shown below is desirable, and a group represented by general formula (VII-1) is most preferable.

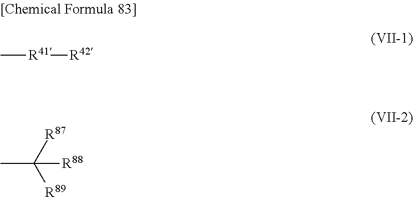

In general formula (VII-1), R⁴¹′ represents an unsubstituted alkylene group of 1 to 9 carbon atoms, and R⁴²′ represents a fluorinated alkyl group of 1 to 9 carbon atoms, provided that the total number of carbon atoms of R⁴¹′ and R⁴²′ is no more than 10. In general formula (VII-2), each of R⁸⁷ to R⁸⁹ independently represents a linear alkyl group of 1 to 5 carbon atoms, provided that at least one of R⁸⁷ to R⁸⁹ represents an alkyl group having a fluorine atom.

In general formula (VII-1), the alkylene group for R⁴¹′ may be linear, branched or cyclic, and is preferably linear or branched. Further, the number of carbon atoms within the alkylene group is preferably within a range of from 1 to 5.

As R⁴¹′, a methylene group, an ethylene group or a propylene group is particularly desirable.

As R⁴²′, a linear or branched fluorinated alkyl group of 1 to 5 carbon atoms is preferable, and a perfluoroalkyl group is particularly desirable. Among perfluoroalkyl groups, a trifluoromethyl group and a pentafluoroethyl group are preferable.

In general formula (VII-2), as the alkyl group for R⁸⁷ to R⁸⁹, an ethyl group or a methyl group is preferable, and a methyl group is particularly desirable. At least one of the alkyl groups for R⁸⁷ to R⁸⁹ is a fluorinated alkyl group, and all of the alkyl groups for R⁸⁷ to R⁸⁹ may be fluorinated alkyl groups.

In general formula (f1-1-0), the carbon atom within the —C(═O)— moiety is not directly bonded to the main chain. As a result, the “—O—R⁸” group may be dissociated satisfactorily by the action of an alkali developing solution which is weakly basic.

In other words, the “—O—R⁸” group is dissociated from a group represented by general formula (f1-1-0) due to hydrolysis caused by the action of an alkali developing solution. Therefore, in the group represented by general formula (f1-1-0), a hydrophilic group [—C(═O)—OH] is formed when the “—O—R⁸” group dissociates. Accordingly, the hydrophilicity of the component (F) is enhanced, and hence, the compatibility of the component (F) with the alkali developing solution is improved. As a result, the hydrophilicity of the resist film surface is enhanced during developing.

In the resist composition of the present invention, as the structural unit (f1), a structural unit (f1-1) represented by general formula (f1-1-1) shown below can be mentioned as a preferable example, because favorable solubility of the composition in organic solvents can be achieved, and the hydrophobicity of the surface of the resist film can be enhanced.

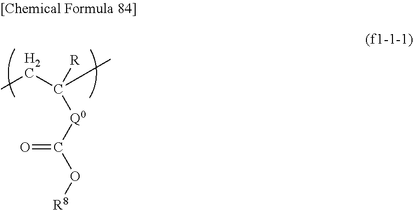

In formula (f1-1-1), R represents a hydrogen atom, an alkyl group of 1 to 5 carbon atoms or a halogenated alkyl group of 1 to 5 carbon atoms; Q⁰ represents a single bond or a divalent linking group; and R⁸ represents an organic group having a fluorine atom.

Structural Unit (f1-1)

The structural unit (f1-1) is a structural unit represented by the aforementioned general formula (f1-1-1).

In general formula (f1-1-1), R represents a hydrogen atom, an alkyl group of 1 to 5 carbon atoms or a halogenated alkyl group of 1 to 5 carbon atoms.

Examples of the alkyl group or halogenated alkyl group for R include the same groups as those described above for the alkyl group or halogenated alkyl group that may be bonded to the α-position of the above-mentioned acrylate ester.

In general formula (f1-1-1), Q⁰ represents a single bond or a divalent linking group.

Preferable examples of the divalent linking group for Q⁰ include a hydrocarbon group which may have a substituent, and a group containing a hetero atom.

(Hydrocarbon Group which May have a Substituent)

With respect to the divalent linking group for Q⁰, the hydrocarbon group may “have a substituent” means that part or all of the hydrogen atoms of the hydrocarbon group may be substituted with groups or atoms other than hydrogen atoms.

The hydrocarbon group for Q⁰ may be either an aliphatic hydrocarbon group, or an aromatic hydrocarbon group.

Here, an aliphatic hydrocarbon group refers to a hydrocarbon group that has no aromaticity. The aliphatic hydrocarbon group may be either saturated or unsaturated, but in general, the aliphatic hydrocarbon group is preferably saturated.

Specific examples of the aliphatic hydrocarbon group include a linear or branched aliphatic hydrocarbon group and an aliphatic hydrocarbon group containing a ring in the structure thereof.

The linear or branched aliphatic hydrocarbon group for Q⁰ preferably has 1 to 10 carbon atoms, more preferably 1 to 8 carbon atoms, still more preferably 1 to 5 carbon atoms, and most preferably 1 to 3 carbon atoms.

As a linear aliphatic hydrocarbon group, a linear alkylene group is preferable, and specific examples include a methylene group, an ethylene group [—(CH₂)₂—], a trimethylene group [—(CH₂)₃—], a tetramethylene group [—(CH₂)₄—] and a pentamethylene group [—(CH₂)₅—].

As the branched aliphatic hydrocarbon group, a branched alkylene group is preferable, and specific examples include alkylalkylene groups, e.g., alkylmethylene groups such as —CH(CH₃)—, —CH(CH₂CH₃)—, —C(CH₃)₂—, —C(CH₃)(CH₂CH₃)—, —C(CH₃)(CH₂CH₂CH₃)— and —C(CH₂CH₃)₂—; alkylethylene groups such as —CH(CH₃)CH₂—, —CH(CH₃)CH(CH₃)—, —C(CH₃)₂CH₂— and —CH(CH₂CH₃)CH₂—; alkyltrimethylene groups such as —CH(CH₃)CH₂CH₂— and —CH₂CH(CH₃)CH₂—; and alkyltetramethylene groups such as —CH(CH₃)CH₂CH₂CH₂— and —CH₂CH(CH₃)CH₂CH₂—. As the alkyl group within the alkylalkylene group, a linear alkyl group of 1 to 5 carbon atoms is preferable.

The linear or branched aliphatic hydrocarbon group (chain-like aliphatic hydrocarbon group) may or may not have a substituent. Examples of the substituent include a fluorine atom, a fluorinated alkyl group of 1 to 5 carbon atoms, and an oxygen atom (═O).

Examples of the aliphatic hydrocarbon group containing a ring represented by Q⁰ include a cyclic aliphatic hydrocarbon group (an aliphatic hydrocarbon ring having 2 hydrogen atoms removed therefrom), a group in which the cyclic aliphatic hydrocarbon group is bonded to the terminal of the aforementioned chain-like aliphatic hydrocarbon group or interposed within the chain-like aliphatic hydrocarbon group.

The cyclic aliphatic hydrocarbon group preferably has 3 to 20 carbon atoms, and more preferably 3 to 12 carbon atoms.

The cyclic aliphatic hydrocarbon group may be either a polycyclic group or a monocyclic group.

As the monocyclic group, a group in which two or more hydrogen atoms have been removed from a monocycloalkane of 3 to 6 carbon atoms is preferable. Examples of the monocycloalkane include cyclopentane and cyclohexane.

As the polycyclic group, a group in which two or more hydrogen atoms have been removed from a polycycloalkane of 7 to 12 carbon atoms is preferable. Examples of the polycycloalkane include adamantane, norbornane, isobornane, tricyclodecane and tetracyclododecane.

The cyclic aliphatic hydrocarbon group may or may not have a substituent. Examples of the substituent include an alkyl group of 1 to 5 carbon atoms, a fluorine atom, a fluorinated alkyl group of 1 to 5 carbon atoms, and an oxygen atom (═O).

Examples of the hydrocarbon group for Q⁰ include a divalent aromatic hydrocarbon group in which one hydrogen atom has been removed from a benzene ring of a monovalent aromatic hydrocarbon group such as a phenyl group, a biphenyl group, a fluorenyl group, a naphthyl group, an anthryl group or a phenanthryl group; an aromatic hydrocarbon group in which part of the carbon atoms constituting the ring of the aforementioned divalent aromatic hydrocarbon group has been substituted with a hetero atom such as an oxygen atom, a sulfur atom or a nitrogen atom; and an aromatic hydrocarbon group in which one hydrogen atom has been removed from a benzene ring of an arylalkyl group such as a benzyl group, a phenethyl group, a 1-naphthylmethyl group, a 2-naphthylmethyl group, a 1-naphthylethyl group or a 2-naphthylethyl group.

Among these examples, the aforementioned divalent aromatic hydrocarbon group is preferable, and an aromatic hydrocarbon group in which one hydrogen atom has been removed from a phenyl group, or an aromatic hydrocarbon group in which one hydrogen atom has been removed from a naphthyl group is particularly desirable.

The alkyl chain within the arylalkyl group preferably has 1 to 4 carbon atom, more preferably 1 or 2, and most preferably 1.

The aromatic hydrocarbon group may or may not have a substituent. Examples of the substituent include an alkyl group of 1 to 5 carbon atoms, a fluorine atom, a fluorinated alkyl group of 1 to 5 carbon atoms, and an oxygen atom (═O).

Among the above-mentioned examples, as the hydrocarbon group which may have a substituent, a linear, branched or cyclic aliphatic hydrocarbon group or a divalent aromatic hydrocarbon group is preferable, and a methylene group, and ethylene group, —CH(CH₃)—, a group in which one hydrogen atom has been removed from a tetracyclododecyl group, or an aromatic hydrocarbon group in which one hydrogen atom has been removed from a phenyl group is particularly desirable.

(Group Containing a Hetero Atom)

A hetero atom is an atom other than carbon and hydrogen, and examples thereof include an oxygen atom, a nitrogen atom, a sulfur atom and a halogen atom.

Examples of the group containing a hetero atom include —O—, —C(═O)—, —C(═O)—O—, a carbonate bond (—O—C(═O)—O—), —NH—, —NR⁰⁵— (wherein R⁰⁵ represents an alkyl group), —NH—C(═O)—, ═N—, and a combination of any of these “groups” with a divalent hydrocarbon group.

As examples of the divalent hydrocarbon group, the same groups as those described above for the hydrocarbon group which may have a substituent can be given, and a linear or branched aliphatic hydrocarbon group is preferable.

Among the above-mentioned examples, as the group containing a hetero atom, a combination of any of the aforementioned “groups” with a divalent hydrocarbon group is preferable. More specifically, it is particularly desirable to use a combination of any of the aforementioned “groups” with the aforementioned aliphatic hydrocarbon group, or a combination of the aforementioned aliphatic hydrocarbon group, any of the aforementioned “groups” and the aforementioned aliphatic hydrocarbon group.

In general formula (f1-1-1), R⁸ represents an organic group having a fluorine atom, and is the same defined for R⁸ in general formula (f1-1-0).

Preferable examples of the structural unit (f1-1) include structural units represented by general formula (f1-1-10) or (f1-1-20) shown below.

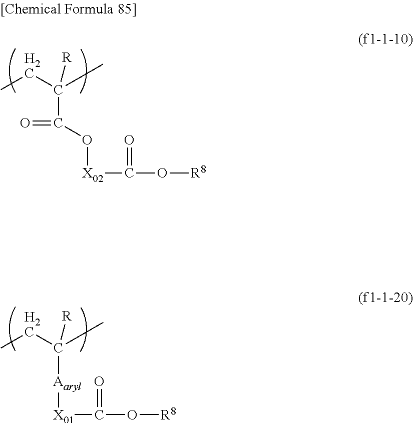

In the formulas, each R independently represents a hydrogen atom, an alkyl group of 1 to 5 carbon atoms or a halogenated alkyl group of 1 to 5 carbon atoms; X₀₂ represents a divalent organic group; A_{aryl} represents a divalent aromatic cyclic group which may have a substituent; X₀₁ represents a single bond or a divalent linking group; and each R⁸ independently represents an organic group having a fluorine atom.

In formulas (f1-1-10) and (f1-1-20), R⁸ is the same as defined above.

In formulas (f1-1-10) and (f1-1-20), as R⁸, a fluorinated hydrocarbon group is preferable, a fluorinated alkyl group is more preferable, a fluorinated alkyl group of 1 to 5 carbon atoms is still more preferable, and —CH₂—CF₃, —CH₂—CF₂—CF₃, —CH(CF₃)₂, —CH₂—CF₂—CF₂—CF₃, —CH₂—CH₂—CF₂—CF₂—CF₃, —CH₂—CH₂—CF₂—CF₂—CF₂—CF₃ are most preferable.

As the alkyl group of 1 to 5 carbon atoms represented by R, a linear or branched lower alkyl group is preferable, and specific examples thereof include a methyl group, an ethyl group, a propyl group, an isopropyl group, an n-butyl group, an isobutyl group, a tert-butyl group, a pentyl group, an isopentyl group and a neopentyl group.

Specific examples of the halogenated alkyl group of 1 to 5 carbon atoms include groups in which part or all of the hydrogen atoms of the aforementioned “alkyl group of 1 to 5 carbon atoms” have been substituted with a halogen atom. Examples of the halogen atom include a fluorine atom, a chlorine atom, a bromine atom and an iodine atom, and a fluorine atom is particularly desirable.

As R, a hydrogen atom, an alkyl group of 1 to 5 carbon atoms or a fluorinated alkyl group of 1 to 5 carbon atoms is preferable, and a hydrogen atom or a methyl group is more preferable in terms of industrial availability.

In general formula (f1-1-10), X₀₂ represents a divalent organic group.

Preferable examples of X₀₂ include a hydrocarbon group which may have a substituent, and a group containing a hetero atom, and the same hydrocarbon groups (which may have a substituent) and groups containing a hetero atom described above in the explanation of the divalent linking group for Q⁰ can be used.

In general formula (f1-1-20), A_{aryl} represents a divalent aromatic cyclic group which may have a substituent. A specific example of A_{aryl} includes an aromatic hydrocarbon ring (which may have a substituent) having two or more hydrogen atoms removed therefrom.

The ring skeleton of the aromatic cyclic group for A_{aryl} preferably has 6 to 15 carbon atoms. Examples of the ring skeleton include a benzene ring, a naphthalene ring, a phenanthrene ring and an anthracene ring. Among these, a benzene ring or a naphthalene ring is particularly desirable.

Examples of substituents which an aromatic cyclic group for A_{aryl} may have include a halogen atom, an alkyl group, an alkoxy group, a halogenated alkyl group of 1 to 5 carbon atoms, and an oxygen atom (═O). Examples of the halogen atom include a fluorine atom, a chlorine atom, an iodine atom and a bromine atom. As the substituent for the aromatic cyclic group represented by A_{aryl}, a fluorine atom is preferable.

A_{aryl} may be either an aromatic cyclic group having no substituent, or an aromatic cyclic group having a substituent, although an aromatic cyclic group having no substituent is preferable.

When A_{aryl} represents an aromatic cyclic group having a substituent, the number of the substituent may be either 1 or at least 2, preferably 1 or 2, and more preferably 1.

In general formula (f1-1-20), X₀₁ represents a single bond or a divalent linking group.

Examples of the divalent linking group include an alkylene group of 1 to 10 carbon atoms, —O—, —C(═O)—, —C(═O)—O—, a carbonate bond (—O—C(═O)—O—), —NH—C(═O)—, and a combination of these groups, and a combination of —O— with an alkylene group of 1 to 10 carbon atoms or a combination of —C(═O)—O— with an alkylene group of 1 to 10 carbon atoms is more preferable.

Examples of alkylene groups of 1 to 10 carbon atoms include linear, branched or cyclic alkylene groups, and a linear or branched alkylene group of 1 to 5 carbon atoms and a cyclic alkylene group of 4 to 10 carbon atoms are preferable.

Among structural units represented by the aforementioned general formula (f1-1-10), structural units represented by general formulas (f1-1-11) to (f1-1-16) shown below are preferable.

Further, among structural units represented by the aforementioned general formula (f1-1-20), structural units represented by general formulas (f1-1-21) to (f1-1-26) shown below are preferable.

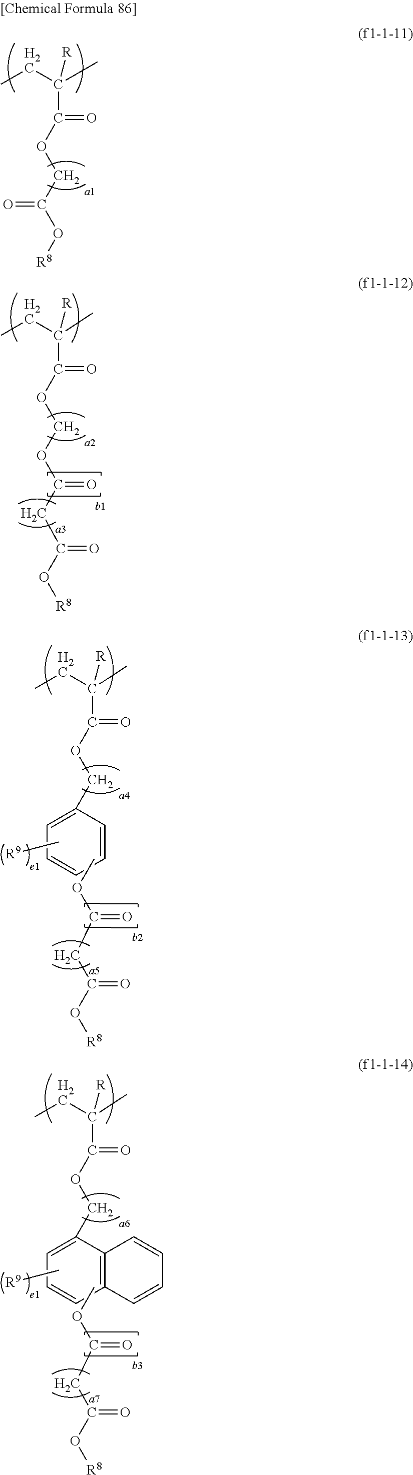

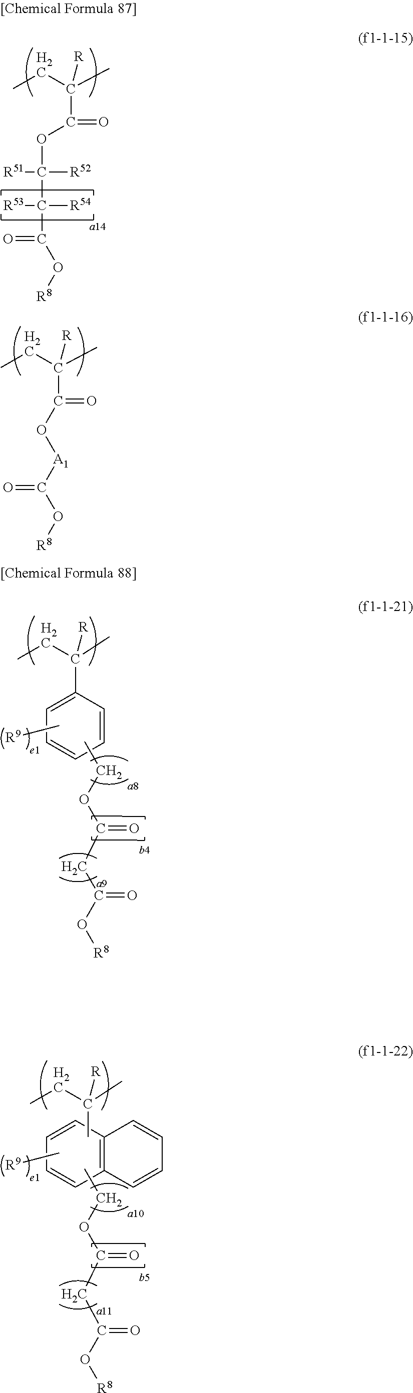

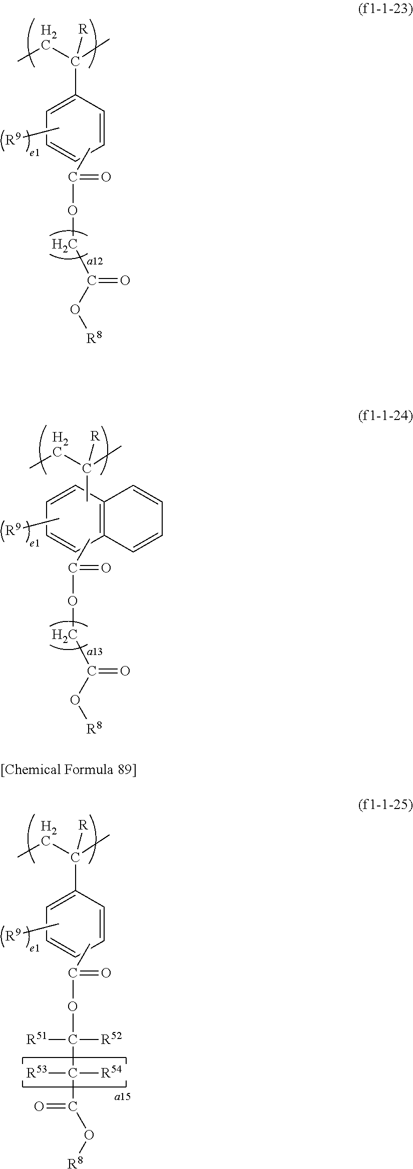

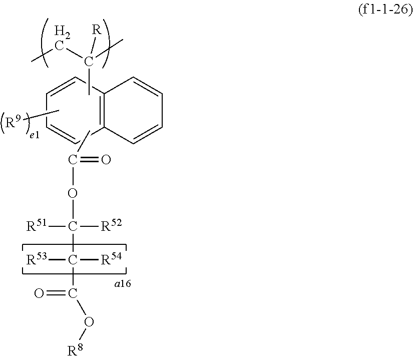

In general formulas (f1-1-11) to (f1-1-16) and (f1-1-21) to (f1-1-26), R and R⁸ are the same as defined above; each of R⁵¹ and R⁵² independently represents an alkyl group of 1 to 10 carbon atoms; each of R⁵³ and R⁵⁴ independently represents a hydrogen atom or an alkyl group of 1 to 10 carbon atoms; each of a1, a2, a3, a5, a7a9 and a11 to a13 independently represents an integer of 1 to 5; each of a4, a6, a8 and a10 independently represents an integer of 0 to 5; each of a14 to a16 independently represents an integer of 1 to 5; each of b1 to b5 independently represents 0 or 1; each R⁹ represents a substituent; e1 represents an integer of 0 to 2; and A₁ represents a cyclic alkylene group of 4 to 20 carbon atoms.

In formulas (f1-1-11) to (f1-1-16) and (f1-1-21) to (f1-1-26), as R, a hydrogen atom or a methyl group is preferable.

In formula (f1-1-11), a1 is preferably an integer of 1 to 3, and more preferably 1 or 2.

In formula (f1-1-12), it is preferable that each of a2 and a3 independently represent an integer of 1 to 3, and more preferably 1 or 2.

b1 is preferably 0.

In formula (f1-1-13), a4 is preferably an integer of 0 to 3, more preferably an integer of 0 to 2, and most preferably 0 or 1.

a5 is preferably an integer of 1 to 3, and more preferably 1 or 2.

Examples of the substituent for R⁹ include a halogen atom, a lower alkyl group, an alkoxy group of 1 to 5 carbon atoms, a halogenated alkyl group of 1 to 5 carbon atoms, and an oxygen atom (═O). Examples of the lower alkyl group include the same alkyl groups of 1 to 5 carbon atoms as those described above for R. Examples of the halogen atom include a fluorine atom, a chlorine atom, an iodine atom and a bromine atom. Examples of the halogenated alkyl group include the same halogenated alkyl group of 1 to 5 carbon atoms as those described above for R.

e1 is preferably 0 or 1, and most preferably 0 from an industrial viewpoint.

b2 is preferably 0.

In general formula (f1-1-14), a6 is preferably an integer of 0 to 3, more preferably an integer of 0 to 2, and most preferably 0 or 1.

a7 is preferably an integer of 1 to 3, and more preferably 1 or 2.

b3 is preferably 0.

R⁹ and e1 are the same as defined above.

In formula (f1-1-15), a14 is preferably an integer of 0 to 3, more preferably an integer of 0 to 2, and most preferably 0 or 1.

It is preferable that each of R⁵¹ and R⁵² independently represents a linear, branched or cyclic alkyl group of 1 to 10 carbon atoms, and specific examples thereof include a methyl group, an ethyl group, an n-propyl group, an isopropyl group, an n-butyl group, an isobutyl group, a tert-butyl group, a tert-pentyl group, a cyclopentyl group, a cyclohexyl group, a cyclooctyl group, a norbornyl group, an isobornyl group, a tricyclodecyl group, an adamantyl group and a tetracyclododecyl group. Of these, an alkyl group of 1 to 6 carbon atoms is preferable, more preferably an alkyl group of 1 to 4 carbon atoms, and most preferably a methyl group or an ethyl group.

It is preferable that each of R⁵³ and R⁵⁴ independently represents a hydrogen atom, or a linear, branched or cyclic alkyl group of 1 to 10 carbon atoms. For R⁵³ and R⁵⁴, the linear, branched or cyclic alkyl group of 1 to 10 carbon atoms is the same as defined above for R⁵¹ and R⁵².

In formula (f1-1-16), A₁ represents a cyclic alkylene group of 4 to 20 carbon atoms, and is preferably a cyclic alkylene group of 5 to 15 carbon atoms, and more preferably a cyclic alkylene group of 6 to 12 carbon atoms. Specific examples of the cyclic alkylene group include those described above as the “cyclic aliphatic hydrocarbon group” for the aforementioned hydrocarbon group which may have a substituent, and the cyclic aliphatic hydrocarbon group preferably has 3 to 20 carbon atoms, and more preferably 3 to 12 carbon atoms.

The cyclic aliphatic hydrocarbon group may be either a polycyclic group or a monocyclic group. As the monocyclic group, a group in which two hydrogen atoms have been removed from a monocycloalkane of 3 to 6 carbon atoms is preferable. Examples of the monocycloalkane include cyclopentane and cyclohexane. As the polycyclic group, a group in which two hydrogen atoms have been removed from a polycycloalkane of 7 to 12 carbon atoms is preferable. Examples of the polycycloalkane include adamantane, norbornane, isobornane, tricyclodecane and tetracyclododecane.

The cyclic aliphatic hydrocarbon group may or may not have a substituent. Examples of the substituent include an alkyl group of 1 to 5 carbon atoms, a fluorine atom, a fluorinated alkyl group of 1 to 5 carbon atoms, and an oxygen atom (═O).

In formula (f1-1-21), a8 is preferably an integer of 0 to 3, more preferably an integer of 0 to 2, and most preferably 0 or 1.

a9 is preferably an integer of 1 to 3, and more preferably 1 or 2.

b4 is preferably 0.

R⁹ and e1 are the same as defined above.

In formula (f1-1-22), a10 is preferably an integer of 0 to 3, more preferably an integer of 0 to 2, and most preferably 0 or 1.

a11 is preferably an integer of 1 to 3, and more preferably 1 or 2.

b5 is preferably 0.

R⁹ and e1 are the same as defined above.

In formula (f1-1-23), a12 is preferably an integer of 1 to 3, and more preferably 1 or 2.

R⁹ and e1 are the same as defined above.

In formula (f1-1-24), a13 is preferably an integer of 1 to 3, and more preferably 1 or 2.

R⁹ and e1 are the same as defined above.

In formulas (f1-1-25) and (f1-1-26), each of a15 and a16 is preferably an integer of 0 to 3, more preferably an integer of 0 to 2, and most preferably 0 or 1.

Each of R⁵¹, R⁵², R⁵³ and R⁵⁴ are the same as defined above.

R⁹ and e1 are the same as defined above.

Specific examples of structural units represented by the above general formulas (f1-1-11) to (f1-1-16) and (f1-1-21) to (f1-1-26) are shown below.

In the formulas, R^{α}′ represents a hydrogen atom or a methyl group.

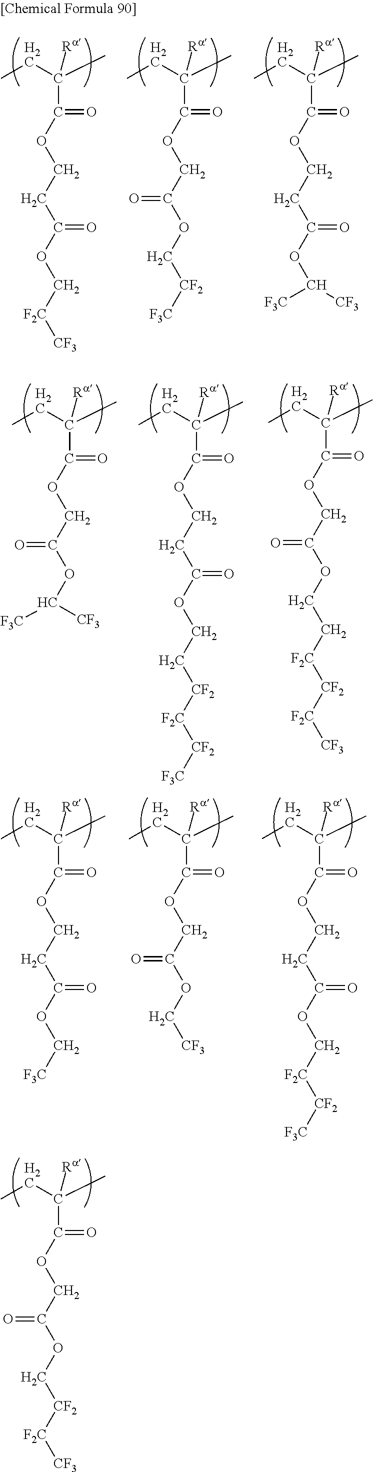

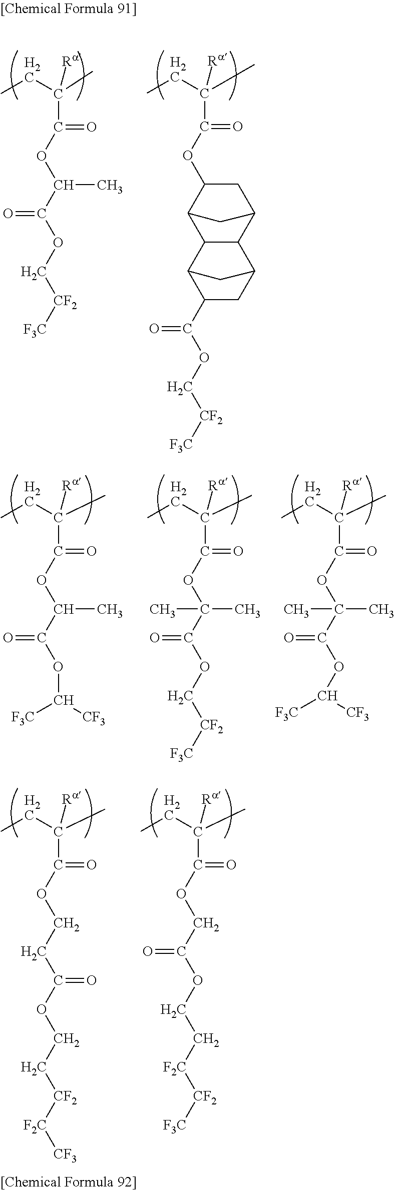

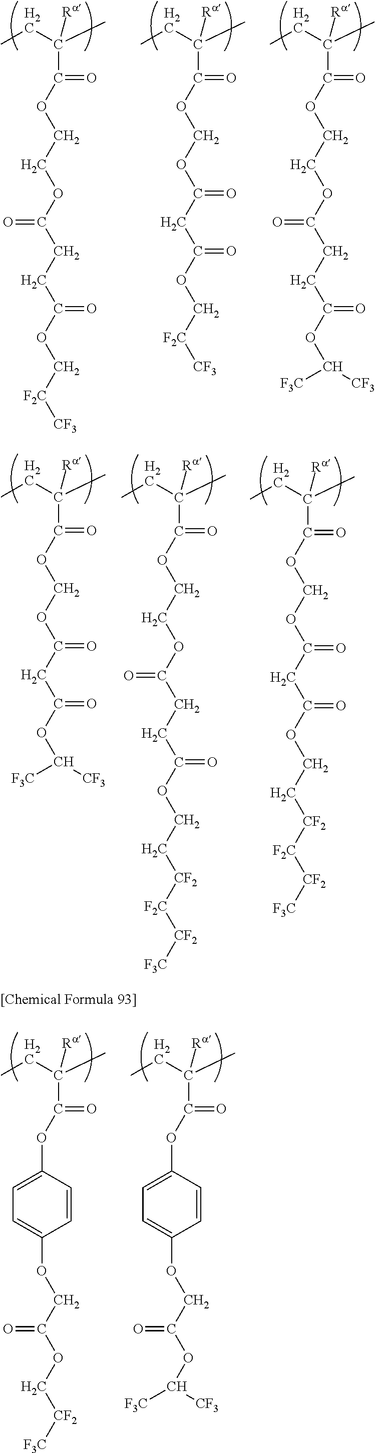

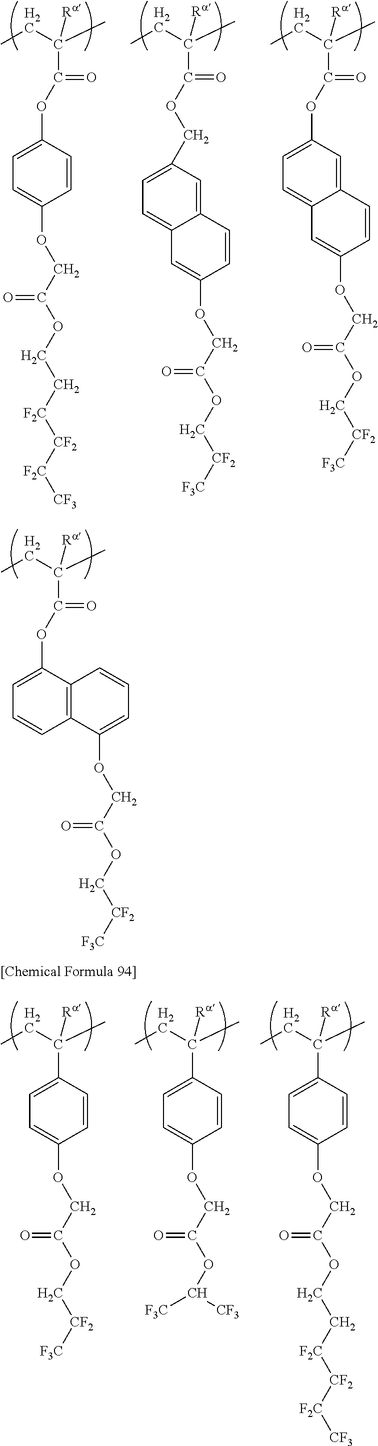

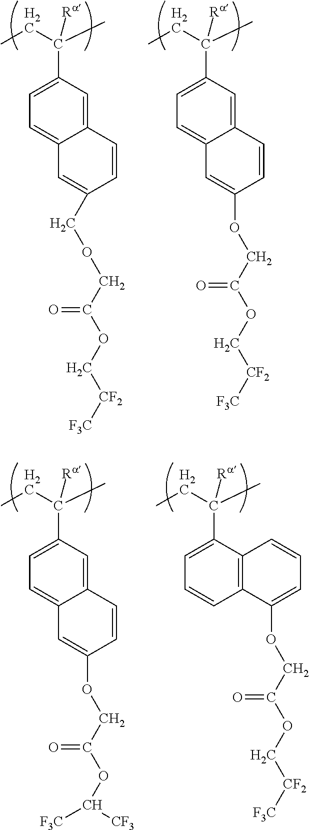

As the structural unit (f1-1), at least one structural unit selected from the group consisting of structural units represented by the aforementioned general formulas (f1-1-11) to (f1-1-16) and (f1-1-21) to (f1-1-26) is preferable, more preferably at least one structural unit selected from the group consisting of structural units represented by the aforementioned general formulas (f1-1-11) to (f1-1-13), (f1-1-21) and (f1-1-22), still more preferably at least one structural unit selected from the group consisting of structural units represented by the aforementioned general formulas (f1-1-11) and (f1-1-22), and most preferably structural units represented by the aforementioned general formula (f1-1-11).

In the component (F), as the structural unit (f1), one type of structural unit may be used alone, or two or more types may be used in combination.

In the component (F), the amount of the structural unit (f1) based on the combined total of all structural units constituting the component (F) is preferably 30 to 95 mol %, more preferably 40 to 90 mol %, and still more preferably 50 to 85 mol %.

When the amount of the structural unit (f1) is at least as large as the lower limit of the above-mentioned range, during resist pattern formation, the characteristic feature of enhancing hydrophobicity of the resist film is improved. On the other hand, when the amount is no more than the upper limit of the above-mentioned range, a good balance can be achieved with the other structural units.

When the structural unit (f1-1) is used as the structural unit (f1), in the component (F), the amount of the structural unit (f1-1) based on the combined total of all structural units constituting the component (F) is preferably 30 to 95 mol %, more preferably 40 to 90 mol %, and still more preferably 50 to 85 mol %. When the amount of the structural unit (f1-1) is at least as large as the lower limit of the above-mentioned range, the characteristic feature of enhancing hydrophobicity of the resist film is improved. On the other hand, when the amount of the structural unit (f1-1) is no more than the upper limit of the above-mentioned range, a good balance can be achieved with the other structural units.

Other Structural Unit (Structural Unit (f2))

The component (F) may include a structural unit other than the structural unit (f1) (hereafter, referred to as “structural unit (f2)”), as long as the effects of the present invention are not impaired.

There are no particular limitations on the structural unit (f2), provided the structural unit is derived from a compound that is copolymerizable with the compound that gives rise to the structural unit (f1).

Examples of the structural unit (f2) include structural units which have been proposed for the base resin of a conventional chemically amplified resist (such as the aforementioned structural units (a1) to (a4) in the component (A1)). When used in a positive resist composition, the structural unit (a1) can be mentioned as a preferable example of the structural unit (f2).

In the component (F), as the structural unit (f2), one type of structural unit may be used alone, or two or more types may be used in combination.

For example, when the structural unit (a1) is used as the structural unit (f2), of the various structural units classified as the structural unit (a1), structural units represented by general formulas (a1-1) and (a1-3) are preferable, structural units represented by general formula (a1-1) are more preferable, and structural units represented by general formulas (a1-1-16) to (a1-1-23), (a1-1-32) and (a1-1-33) are particularly desirable.

In the component (F), the amount of the structural unit (a1) based on the combined total of all structural units constituting the component (F) is preferably 1 to 40 mol %, and more preferably 5 to 30 mol %.

When the amount of the structural unit (a1) is within the above-mentioned range, the water repellency is improved, and a good balance can be achieved with the other structural units.

In the resist composition of the present invention, the component (F) is preferably a polymeric compound that includes the structural unit (f1) (hereafter, referred to as “fluorine-containing resin (F1-1)”).

Examples of such a fluorine-containing resin (F1-1) include a copolymer containing the structural unit (f1) and the structural unit (f2). More specifically, a copolymer containing the structural unit (f1) and the structural unit (a1) can be mentioned as a preferable example.

Among the above-mentioned examples, it is particularly desirable that the fluorine-containing resin (F1-1) be a copolymer consisting of the structural unit (f1-1) and the structural unit (a1).

In the component (F), as the fluorine-containing resin (F1-1), one type may be used alone, or two or more types may be used in combination.

In the resist composition of the present invention, as the fluorine-containing resin (F1-1), a resin that includes a combination of structural units such as that shown below is particularly desirable.

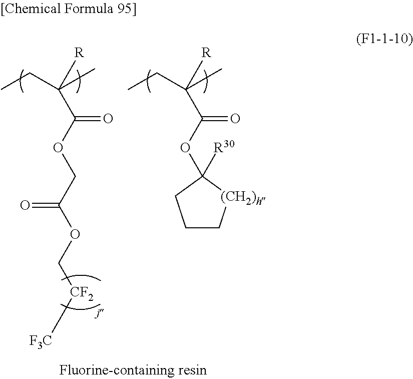

In the formula, R is the same as defined above, and the plurality of R may be either the same or different from each other; j″ represents an integer of 0 to 3, preferably 0 to 2, and most preferably 0 or 1. R³⁰ represents an alkyl group of 1 to 5 carbon atoms and is the same as the lower alkyl group for R above, and is preferably a methyl group or an ethyl group, and most preferably an ethyl group; h″ represents an integer of 1 to 6 and is preferably 3 or 4, and is most preferably 4.

The weight average molecular weight (Mw) (the polystyrene equivalent value determined by gel permeation chromatography) of the component (F) is not particularly limited, but is preferably 2,000 to 50,000, more preferably 3,000 to 30,000, and most preferably 4,000 to 25,000. When the weight average molecular weight is no more than the upper limit of the above-mentioned range, the resist composition exhibits a satisfactory solubility in a resist solvent. On the other hand, when the weight average molecular weight is at least as large as the lower limit of the above-mentioned range, dry etching resistance and the cross-sectional shape of the resist pattern becomes satisfactory.

Further, the dispersity (Mw/Mn) of the component (F) is preferably 1.0 to 5.0, more preferably 1.0 to 3.0, and most preferably 1.2 to 2.5. Here, Mn is the number average molecular weight.

The component (F) can be produced, for example, by a conventional radical polymerization or the like of the monomers corresponding with each of the structural units that constitute the component (F), using a radical polymerization initiator such as azobisisobutyronitrile (AIBN) or dimethyl 2,2′-azobis(isobutyrate) (V-601).

In the resist composition of the present invention, the amount of the component (F), relative to 100 parts by weight of the component (A) is preferably from 0.5 to 30 parts by weight, more preferably from 1 to 20 parts by weight, and most preferably from 1 to 10 parts by weight. When the amount of the component (F) is at least as large as the lower limit of the above-mentioned range, the hydrophobicity of a resist film formed using the resist composition is enhanced. Further, the hydrophobicity of a resist film formed using the resist composition is also suitable for immersion exposure. On the other hand, when the amount of the component (F) is no more than the upper limit of the above-mentioned range, solubility of the component (F) in a resist solvent (organic solvent) is improved. Further, the lithographic properties are also improved.

If desired, other miscible additives can also be added to the resist composition of the present invention. Examples of such miscible additives include additive resins for improving the performance of the resist film, surfactants for improving the applicability, dissolution inhibitors, plasticizers, stabilizers, colorants, halation prevention agents, and dyes.

Dissolving of the resist materials (e.g., the component (A), the component (B) and the like) in the component (S) can be conducted by simply mixing and stirring each of the above components together using conventional methods, and where required, the composition may also be mixed and dispersed using a dispersion device such as a dissolver, a homogenizer, or a triple roll mill. Furthermore, following mixing, the composition may also be filtered using a mesh, or a membrane filter or the like.

As described above, according to the present invention, resist materials exhibit excellent solubility, high resolution can be achieved, and a resist pattern having an excellent shape can be formed. The reasons why these effects can be achieved has not been elucidated yet, but are presumed as follows.

In the resist composition of the present invention, an acid generator (B1) containing a compound represented by general formula (b1) is used as the acid-generator component (B), and an alcohol-based organic solvent having a boiling point of at least 150° C. is used as the organic solvent (S).

The anion moiety of the acid generator (B1) has a substituent containing an oxygen atom (X-Q¹-Y¹-). By virtue of this feature, the anion moiety of such a component (B1) exhibits a high polarity and has a three-dimensionally bulky structure, as compared to an anion moiety of a conventional acid generator, such as nonafluorobutanesulfonate. As a result, the acid generated from the component (B1) upon exposure is chemically and physically suppressed from diffusing within a resist film. Further, since the diffusion length is shorter than a conventional acid generator, diffusion of the acid generated in an exposed region to an unexposed portion can be appropriately controlled.

Further, the component (B1) has a substituted aryl group which has been substituted with a group represented by general formula (b1c-0) in the cation moiety. By virtue of the component (B1) having a group represented by general formula (b1c-0), the affinity of the component (B) for the component (A) is enhanced. As a result, the component (B1) can be more uniformly distributed within the resist film than conventional acid generators. Further, by virtue of including a group represented by general formula (b1c-0), the affinity of the component (B1) for an alcohol-based organic solvent is enhanced. As a result, the component (B1) exhibits excellent solubility in the organic solvent (S). Furthermore, by virtue of the improvement in the solubility of the component (B1) in the organic solvent (S), stability of the resist composition with time is improved, and the component (B1) can be uniformly distributed within the resist composition. Thus, by these synergistic effects, a resist pattern having an excellent shape can be formed with high resolution.

An alcohol-based organic solvent having a boiling point of 150° C. (the aforementioned component (S1)) has a higher boiling point than those of the conventionally used organic solvents, and also exhibits relatively high lipophilicity. Therefore, it is presumed that the component (S1) exhibits high compatibility with the resist components.

For the reasons as described above, it is presumed that the effects of the present invention can be achieved.

Moreover, according to the resist composition of the present invention, a resist pattern can be formed that exhibits excellent lithography properties such as mask reproducibility in the formation of a resist pattern, improved mask error factor (MEF), reduced line width roughness (LWR) and line edge roughness (LER), and the like. In addition, a resist pattern having an excellent shape can be formed, regardless of the size of the pitch of the resist pattern.

The MEF is a parameter that indicates how faithfully mask patterns of differing dimensions can be reproduced (i.e., mask reproducibility) by using the same exposure dose with fixed pitch and changing the mask size (e.g., the line width of a line and space pattern or the hole diameter of a contact hole pattern).

“LWR” refers to the non-uniformity of the line widths of a line pattern, and improvement in this characteristic becomes more important as the pattern becomes finer.

“LER” refers to the unevenness (roughness) of the side walls of a line pattern.

The resist composition of the present invention is also advantageous in that, in a double patterning process, the first pattern is unlikely to be damaged by the second patterning, thereby enabling formation of a high resolution resist pattern.

In other words, the resist composition according to the present invention is preferably used as a second resist composition in a method of forming a resist pattern, the method including: applying a positive resist composition to a substrate to form a first resist film on the substrate; subjecting the first resist film to selective exposure and alkali developing to form a first resist pattern; applying a second resist composition on the substrate on which the first resist pattern is formed to form a second resist film; and subjecting the second resist film to selective exposure and alkali developing to form a resist pattern.

The steps conducted in the above-mentioned method of forming a resist pattern are the same as the steps conducted in the method of forming a resist pattern according to the present invention, which will be described later.

As described above, the resist composition of the present invention is useful in a double patterning process, and a minute patterning can be performed with precision by using the resist composition.

<<Method of Forming a Resist Pattern>>

The method of forming a resist pattern according to the second aspect of the present invention includes a step of applying a positive resist composition as a first resist composition to a substrate to form a first resist film on the substrate (hereafter, this step is referred to as “film forming step (1)”); a step of subjecting the first resist film to selective exposure and alkali developing to form a first resist pattern (hereafter, this step is referred to as “patterning step (1)”); a step of applying the resist composition of the present invention as a second resist composition to the substrate on which the first resist pattern is formed to form a second resist film (hereafter, this step is referred to as “film forming step (2)”); and a step of subjecting the second resist film to selective exposure and alkali developing to form a resist pattern (hereafter, this step is referred to as “patterning step (2)”).

Each of these steps will be described in more detail below.

[Film Forming Step (1)]

The substrate is not specifically limited and a conventionally known substrate can be used. For example, substrates for electronic components, and such substrates having wiring patterns formed thereon can be used. Specific examples of the material of the substrate include metals such as silicon wafer, copper, chromium, iron and aluminum; and glass. Suitable materials for the wiring pattern include copper, aluminum, nickel, and gold.

Further, as the substrate, any one of the above-mentioned substrates provided with an inorganic and/or organic film on the surface thereof may be used. As the inorganic film, an inorganic antireflection film (inorganic BARC) can be used. As the organic film, an organic antireflection film (organic BARC) and an organic film such as a lower-layer organic film used in a multilayer resist method can be used. It is particularly desirable that an organic film is provided because a pattern can be formed on the substrate with a high aspect ratio which is useful in the production of semiconductors.

Here, a “multilayer resist method” is method in which at least one layer of an organic film (lower-layer film) and at least one layer of a resist film are provided on a substrate, and a resist pattern formed on the upper resist film is used as a mask to conduct patterning of the lower-layer film. This method is considered as being capable of forming a pattern with a high aspect ratio. The multilayer resist method is broadly classified into a method in which a double-layer structure consisting of an upper-layer resist film and a lower-layer film is formed, and a method in which a multilayer structure having at least three layers consisting of an upper-layer resist film, a lower-layer film and at least one intermediate layer (thin metal film or the like) provided between the upper-layer resist film and the lower-layer film. In the multilayer resist method, a desired thickness can be ensured by the lower-layer film, and as a result, the thickness of the resist film can be reduced, and an extremely fine pattern with a high aspect ratio can be formed.

An inorganic film can be formed, for example, by coating an in organic anti-reflection film composition such as a silicon-based material on a substrate, followed by baking.

An organic film can be formed, for example, by dissolving a resin component and the like for forming the film in an organic solvent to obtain an organic film forming material, coating the organic film forming material on a substrate using a spinner or the like, and baking under heating conditions preferably in the range of 200 to 300° C. for 30 to 300 seconds, more preferably for 60 to 180 seconds.

The method of applying a first resist composition (positive resist composition described later) to form a first resist composition is not particularly limited, and a conventional method can be used.

More specifically, the first resist film can be formed, for example, by applying a chemically amplified positive resist composition as the first resist composition to a substrate by a conventional method using a spinner or the like, and vaporizing organic solvents by conducting a bake treatment (prebake) at a temperature of 80 to 150° C. for 40 to 120 seconds, preferably 60 to 90 seconds.

The thickness of the first resist film is preferably within the range from 50 to 500 nm, and more preferably from 50 to 450 nm. By ensuring that the thickness of the resist film satisfies the above-mentioned range, a resist pattern with a high level of resolution can be formed, and a satisfactory level of etching resistance can be achieved.

[Patterning Step (1)]

Next, the first resist film is subjected to selective exposure, followed by alkali development to form a first resist pattern.

Specifically, for example, the first resist film formed in the manner as described above is subjected to selective exposure through a photomask, preferably performing post exposure bake (PEB), followed by alkali development to form a first resist pattern.

The wavelength to be used for exposure is not particularly limited and the exposure can be conducted using radiation such as KrF excimer laser, ArF excimer laser, F₂ excimer laser, extreme ultraviolet rays (EUV), vacuum ultraviolet rays (VUV), electron beam (EB), X-rays, and soft X-rays.

As the photomask, for example, a binary mask in which the transmittance of the light shielding portion is 0% or a halftone-phase shift mask (HT-mask) in which the transmittance of the light shielding portion is 6% can be used.

As a binary mask, those in which a chromium film, a chromium oxide film, or the like is formed as a light shielding portion on a quartz glass substrate are generally used.

Examples of the half-tone type phase shift masks include those in which a MoSi (molybdenum silicide) film, a chromium film, a chromium oxide film, an oxynitriding silicon film, or the like is formed, as a light shielding portion on a substrate generally made of quartz glass.

The exposure may be conducted without using a mask, e.g., selective exposure by drawing with electron beam (EB) or the like.

The selective exposure of the first resist film can be either a general exposure (dry exposure) conducted in air or an inert gas such as nitrogen, or immersion exposure (immersion lithography).

In immersion lithography, exposure (immersion exposure) is conducted in a state where the region between the lens and the resist layer formed on a wafer (which was conventionally filled with air or an inert gas such as nitrogen) is filled with a solvent (a immersion medium) that has a larger refractive index than the refractive index of air.

More specifically, in immersion lithography, the region between the resist film formed in the above-described manner and lens at the lowermost portion of the exposure apparatus is filled with a solvent (a immersion medium) that has a larger refractive index than the refractive index of air, and in this state, the resist film is subjected to exposure (immersion exposure) through a desired photomask.

The immersion medium preferably exhibits a refractive index larger than the refractive index of air but smaller than the refractive index of the first resist film to be subjected to immersion exposure. The refractive index of the immersion medium is not particularly limited as long at it satisfies the above-mentioned requirements.

Examples of this immersion medium which exhibits a refractive index that is larger than the refractive index of air but smaller than the refractive index of the resist film include water, fluorine-based inert liquids, silicon-based solvents and hydrocarbon-based solvents.

Specific examples of the fluorine-based inert liquids include liquids containing a fluorine-based compound such as C₃HCl₂F₅, C₄F₉OCH₃, C₄F₉OC₂H₅ or C₅H₃F₇ as the main component, which have a boiling point within a range from 70 to 180° C. and preferably from 80 to 160° C. A fluorine-based inert liquid having a boiling point within the above-mentioned range is advantageous in that the removal of the immersion medium after the exposure can be conducted by a simple method.

As a fluorine-based inert liquid, a perfluoroalkyl compound in which all of the hydrogen atoms of the alkyl group are substituted with fluorine atoms is particularly desirable. Examples of these perfluoroalkyl compounds include perfluoroalkylether compounds and perfluoroalkylamine compounds.

Specifically, one example of a suitable perfluoroalkylether compound is perfluoro(2-butyl-tetrahydrofuran) (boiling point 102° C.), and an example of a suitable perfluoroalkylamine compound is perfluorotributylamine (boiling point 174° C.).

As the immersion medium, water is preferable in terms of cost, safety, environment and versatility.

The PEB treatment is conducted at a bake temperature which changes (increases or decreases) the solubility of the first resist film in an alkali developing solution.

Specifically, for example, when the first resist film is composed of a chemically amplified resist composition, by conducting PEB treatment after exposure, diffusion of acid generated from the acid-generator component within the resist film and change (increase or decrease) in solubility of the resist film in an alkali developing solution by the action of the acid proceed.

More specifically, the first resist film is selectively exposed through a photomask having a defined pattern, and then, post exposure bake (PEB) is conducted at a temperature of 80 to 150° C. for 40 to 120 seconds, preferably 60 to 90 seconds.

After the PEB treatment, alkali developing is conducted to form a first resist pattern.

The alkali developing can be conducted by a conventional method, for example, using a tetramethylammonium hydroxide (TMAH) solution having a concentration of 0.1 to 10% by weight. By the alkali development, the exposed portions of the first resist film are removed, thereby forming a first resist pattern.

After the alkali developing, a rinse treatment using water or the like can be conducted.

Further, after the alkali developing, post bake treatment may be conducted. Post bake (which is performed in order to remove water content after the alkali developing and rinsing) is generally conducted at about 100° C. preferably for 30 to 90 seconds.

[Film Forming Step (2)]

Next, the resist composition of the present invention is applied to the substrate having a first resist pattern formed thereon, to thereby form a second resist film. For example, when the first resist pattern is a line and space pattern (hereafter, referred to as “LS pattern”), the second resist film can be formed in the same manner as in the first resist film by a conventional method to fill the space portions formed between the plurality of LS patterns.

The film thickness of the second resist film is at least as thick as the first resist pattern and is preferably thicker. In other words, when the substrate is viewed from the second resist film side, it is preferable that the substrate surface be flat.

[Patterning Step (2)]

Next, the second resist film is subjected to selective exposure, followed by alkali development to form a resist pattern.

Specifically, for example, the second resist film is selectively exposed through a photomask at portions different from where the plurality of resist patterns have been formed, followed by PEB treatment and alkali developing, thereby forming a resist pattern.

Accordingly, the exposed portions of the second resist film when the resist composition of the present invention is a positive type and the unexposed portions of the second resist film when the resist composition of the present invention is a negative type are removed, and between a plurality of resist patterns formed previously, a plurality of resist patterns is newly formed in the LS pattern. As a result, a resist pattern is formed on the substrate which is composed of a plurality of resist patterns formed in the previous step, and a plurality of resist patterns newly formed on the second resist film.

In the present invention, when a first resist pattern is formed on a substrate, any region within the substrate which does not completely overlap with a region where the first resist pattern is formed is referred to as “region other than the region where the first resist pattern is formed”. In other words, the expression includes a region which does not overlap at all with the region where the first resist pattern is formed, and also includes a region which only partially overlaps with the region where the first resist pattern is formed.

In the present invention, when forming a resist pattern so as to ultimately form a line and space pattern, it is preferable that the region where the first resist pattern is formed and the region exposed selectively in the patterning step (2) do not overlap at all. As a result, a resist pattern can be formed with a pitch smaller than that of the first resist pattern formed in the patterning step (1).

The selective exposure of the second film can be conducted, for example, by slightly shifting the exposing position of the photomask used in the patterning step (1). Alternatively, at this time, a photomask different from that used in the patterning step (1) may be used.

The position of the resist pattern formed from the second resist film may be completely non-overlapping the position of first resist pattern, or partially overlapping the first resist pattern. However, it is preferable that the position of the resist pattern formed from the second resist film be completely non-overlapping the position of first resist pattern. As a result, a resist pattern can be formed with a pitch smaller than that of the first resist pattern formed in the patterning step (1).

For example, a line and space pattern may be formed in the patterning step (1) using a photomask for forming a line and space pattern, in which a plurality of lines are arranged with a constant pitch; and then a line pattern may be formed in intermediate regions between the adjacent line patterns formed in the patterning step (1) by changing the position of the photomask in the patterning step (2). Accordingly, a line and space pattern (dense pattern) can be newly formed which has a pitch smaller than that of the previously formed line and space resist pattern (isolated pattern).

The “isolated pattern” is preferably a line and space pattern in which the space width is large so that the ratio of the line width to the space width (i.e., line width:space width) is 1:at least 2.

After exposure, PEB treatment is conducted.

The PEB treatment can be conducted in the same manner as in the PEB treatment in patterning step (1).

After the PEB treatment, alkali development of the second resist film is conducted. The alkali developing can be conducted by a conventional method, for example, using a tetramethylammonium hydroxide (TMAH) solution having a concentration of 0.1 to 10% by weight. By the alkali development, the exposed portions of the second resist film when the resist composition of the present invention is a positive type and the unexposed portions of the second resist film when the resist composition of the present invention is a negative type are removed, thereby forming a resist pattern.

After the alkali developing, a rinse treatment using water or the like can be conducted.

Further, after the alkali developing, post bake treatment may be conducted. Post bake (which is performed in order to remove water content after the alkali developing and rinsing) is generally conducted at about 100° C. preferably for 30 to 90 seconds.

In the method of forming a resist pattern according to the present invention, since a dense line and space pattern with a narrow pitch can be formed reliably, it is preferable that the first resist pattern be a line and space pattern.

More specifically, for example, a line and space pattern with a line width of 100 nm and the line width:space width ratio of 1:3 (i.e., an isolated pattern) may be first formed; and then another line and space pattern with a line width of 100 nm and the line width:space width ratio of 1:3 may be formed by parallel displacement of the photomask by 200 nm in the direction perpendicular to the line direction. As a result, a line and space pattern with a line width of 100 nm and the line width:space width ratio of 1:1 (i.e., a dense pattern) can be formed.

Further, a fine resist pattern with or without various profiles can be formed, for example, through rotational movement of the photomask used in the patterning step (1), or by using a photomask different from the photomask used in the patterning step (1) (for instance, by using a photomask with a line and space pattern in the patterning step (1) and then using a photomask with a hole pattern in the patterning step (2)).

Furthermore, a resist pattern with a hole-like or lattice-like pattern can also be formed, for example, by conducting a crossline patterning process in which a first line and space resist pattern is formed in the patterning step (1), followed by exposure and developing processes conducted so as to form a pattern that intersects with the first resist pattern. When conducting a crossline patterning process, the line width:space width ratio or the intersection angle formed between the respective line and space patterns may be appropriately controlled, in accordance with the profiles of hole-like or lattice-like resist pattern to be ultimately formed. For example, depending on the types of targeted pattern, the intersection angle may be changed so that one pattern intersects with another pattern orthogonally or diagonally (i.e., at an angle less than 90°). It is thought that a hole-like (or lattice-like) resist pattern can be formed from the first and second L/S patterns because of the non-uniform diffusion of the acid generated upon exposure during formation of the second resist pattern (for example, acid generation may be controlled in the direction where the first L/S pattern resides (as compared to other directions where the first L/S pattern is absent)), apart from the factors associated with the pattern formation process.

In the method of forming a resist pattern according to the present invention, after the second patterning process, the same procedure as in the aforementioned film forming step (2) and patterning step (2) can be repeated a plurality of times. That is, the resist composition of the present invention is applied to the substrate having a resist pattern formed thereon in the patterning step (2), the resist film is subjected to selective exposure, followed by alkali development to form a resist pattern, and this procedure can be performed a plurality of times. As a result, a further dense with a narrow pitch or a pattern with a complicated shape can be formed.

In the method of forming a resist pattern according to the present invention, after the patterning step (2), the substrate can be subjected to etching using the mask for forming the resist pattern. By etching the substrate, a semiconductor device or the like can be produced.

The etching can be conducted by a conventional method. For example, etching of an organic film (resist pattern, organic antireflection film or the like) is preferably performed by dry etching. Among dry etching, oxygen-plasma etching or etching using a CF₄ gas or a CHF₃ gas is preferable, and oxygen-plasma etching is particularly desirable.

Etching of the substrate or inorganic antireflection film is preferably performed using a halogen gas, more preferably using a fluorinated carbon-based gas, and most preferably using a CF₄ gas or a CHF₃ gas.

(First Resist Composition)

In the film forming step (1) described above, the positive resist composition for forming the first resist film (hereafter, frequently referred to as “first positive resist composition”) is preferably a positive resist composition that exhibits a low compatibility with the aforementioned organic solvent (S), and a chemically amplified positive resist composition is particularly desirable.

There are no particular limitations on the chemically amplified positive resist composition, and any of the positive resist compositions which have been proposed for conventional ArF resists and the like can be appropriately selected for use depending on the exposure light source, lithographic properties, and the like.

The chemically amplified positive resist composition generally includes a base component (A′) (hereafter, referred to as “component (A′)”) which exhibits increased solubility in an alkali developing solution by the action of acid and an acid-generator component (B′) (hereafter, referred to as “component (B′)”) which generates acid upon exposure.

<Component (A′)>

In the first positive resist composition, the component (A′) may be a resin component (A1′) which exhibits increased solubility in an alkali developing solution under the action of acid (hereafter, frequently referred to as “component (A1′)”), a low molecular weight compound (A2′) which exhibits increased solubility in an alkali developing solution under the action of acid (hereafter, frequently referred to as “component (A2′)”), or a mixture of the component (A1′) and the component (A2′).

As the component (A2′), the same compounds as those described above for the component (A2) may be used.

[Component (A1′)]

It is preferable that the component (A1′) include a structural unit (a1) derived from an acrylate ester containing an acid dissociable, dissolution inhibiting group.

Further, it is preferable that the component (A1′) further include a structural unit (a2) derived from an acrylate ester containing a lactone-containing cyclic group, as well as the structural unit (a1).

Furthermore, it is preferable that the component (A1′) have a structural unit (a3) derived from an acrylate ester containing a polar group-containing aliphatic hydrocarbon group, as well as the structural unit (a1), or the structural unit (a1) and the structural unit (a2).

Also, the component (A1′) may further include a structural unit (a4′) different from the above-mentioned structural units (a1), (a2) and (a3′), as well as the structural unit (a1).

Structural Unit (a1)

The structural unit (a1) is a structural unit derived from an acrylate ester containing an acid dissociable, dissolution inhibiting group, and the same groups as those for the structural unit (a1) described in relation to the resist composition according to the first aspect of the present invention can be used.

In the component (A1′), as the structural unit (a1), one type of structural unit may be used alone, or two or more types of structural units may be used in combination.

Further, as the structural unit (a1), there is no particular limitation, and an arbitrary structural unit may be used. Among the various possibilities, structural units represented by the aforementioned general formula (a1-1) are preferable. More specifically, at least one structural unit selected from the group consisting of structural units represented by formulas (a1-1-1) to (a-1-1-4), (a1-1-20) to (a1-1-23) and (a1-3-25) to (a1-3-28) is more preferable.

In the component (A1′), the amount of the structural unit (a1) based on the combined total of all structural units constituting the component (A1′) is preferably 10 to 80 mol %, more preferably 20 to 70 mol %, and still more preferably 25 to 50 mol %. When the amount of the structural unit (a1) is at least as large as the lower limit of the above-mentioned range, a pattern can be easily formed using a resist composition prepared from the component (A1). On the other hand, when the amount of the structural unit (a1) is no more than the upper limit of the above-mentioned range, a good balance can be achieved with the other structural units.

Structural Unit (a2)

The structural unit (a2) is a structural unit derived from an acrylate ester containing a lactone-containing cyclic group, and the same groups as those for the structural unit (a2) described in relation to the resist composition according to the first aspect of the present invention can be used.

In the component (A1′), as the structural unit (a2), one type of structural unit may be used alone, or two or more types of structural units may be used in combination.

Further, as the structural unit (a2), there is no particular limitation, and an arbitrary structural unit may be used. In particular, at least one structural unit selected from the group consisting of formulas (a2-1) to (a2-5) is preferable, and at least one structural unit selected from the group consisting of formulas (a2-1) to (a2-3) is more preferable. Of these, it is preferable to use at least one structural unit selected from the group consisting of structural units represented by formulas (a2-1-1), (a2-1-2), (a2-2-1), (a2-2-7), (a2-3-1) and (a2-3-5).

In the component (A1′), the amount of the structural unit (a2) based on the combined total of all structural units constituting the component (A1′) is preferably 5 to 60 mol %, more preferably 10 to 50 mol %, and still more preferably 20 to 50 mol %. When the amount of the structural unit (a2) is at least as large as the lower limit of the above-mentioned range, the effect of using the structural unit (a2) can be satisfactorily achieved. On the other hand, when the amount of the structural unit (a2) is no more than the upper limit of the above-mentioned range, a good balance can be achieved with the other structural units.

Structural Unit (a3′)

The structural unit (a3′) is a structural unit derived from an acrylate ester containing a polar group-containing aliphatic hydrocarbon group.

When the component (A1′) includes the structural unit (a3′), the hydrophilicity of the component (A′) is enhanced, and hence, the compatibility of the component (A′) with the developing solution is improved. As a result, the alkali solubility of the exposed portions improves, which contributes to favorable improvements in the resolution.

Examples of the polar group include a hydroxyl group, cyano group, carboxyl group, or hydroxyalkyl group in which some of the hydrogen atoms of the alkyl group have been substituted with fluorine atoms, although a hydroxyl group is particularly desirable.

Examples of the aliphatic hydrocarbon group include linear or branched hydrocarbon groups (preferably alkylene groups) of 1 to 10 carbon atoms, and polycyclic aliphatic hydrocarbon groups (polycyclic groups). These polycyclic groups can be selected appropriately from the multitude of groups that have been proposed for the resins of resist compositions designed for use with ArF excimer lasers. The polycyclic group preferably has 7 to 30 carbon atoms.

Of the various possibilities, structural units derived from an acrylate ester that include an aliphatic polycyclic group that contains a hydroxyl group, cyano group, carboxyl group or a hydroxyalkyl group in which part of the hydrogen atoms of the alkyl group have been substituted with fluorine atoms are particularly desirable. Examples of the polycyclic group include groups in which two or more hydrogen atoms have been removed from a bicycloalkane, tricycloalkane, tetracycloalkane or the like. Specific examples include groups in which two or more hydrogen atoms have been removed from a polycycloalkane such as adamantane, norbornane, isobornane, tricyclodecane or tetracyclododecane. Of these polycyclic groups, groups in which two or more hydrogen atoms have been removed from adamantane, norbornane or tetracyclododecane are preferred industrially.

When the hydrocarbon group within the polar group-containing aliphatic hydrocarbon group is a linear or branched hydrocarbon group of 1 to 10 carbon atoms, the structural unit (a3′) is preferably a structural unit derived from a hydroxyethyl ester of acrylic acid. On the other hand, when the hydrocarbon group is a polycyclic group, structural units mentioned above in connection with the explanation of the structural unit (a6) in the resist composition according to the first aspect of the present invention and represented by general formula (a6-1); and structural units mentioned above in connection with the explanation of the structural unit (a3) and represented by general formula (a3-1) or (a3-2) are preferable.

In the component (A1′), as the structural unit (a3′), one type of structural unit may be used alone, or two or more types of structural units may be used in combination.

The amount of the structural unit (a3′) within the component (A1′) based on the combined total of all structural units constituting the component (A1′) is preferably 5 to 50 mol %, more preferably 5 to 40 mol %, and still more preferably 5 to 25 mol %. When the amount of the structural unit (a3′) is at least as large as the lower limit of the above-mentioned range, the effect of using the structural unit (a3′) can be satisfactorily achieved. On the other hand, when the amount of the structural unit (a3′) is no more than the upper limit of the above-mentioned range, a good balance can be achieved with the other structural units.

Structural Unit (a4′)

As the structural unit (a4′), any other structural unit which cannot be classified as one of the above structural units (a1), (a2) and (a3′) can be used without any particular limitations, and any of the multitude of conventional structural units used within resist resins for ArF excimer lasers or KrF excimer lasers (and particularly for ArF excimer lasers) can be used. For example, those structural units mentioned in relation to the resist composition according to the first aspect of the present invention can be used.

When the structural unit (a4′) is included in the component (A1′), the amount of the structural unit (a4′) based on the combined total of all the structural units that constitute the component (A1′) is preferably within the range from 1 to 30 mol %, and more preferably from 10 to 20 mol %.

In the first positive resist composition, the component (A1′) is preferably a copolymer having the structural unit (a1), and examples of such copolymers include a copolymer consisting of the structural units (a1) and (a2); a copolymer consisting of the structural units (a1) and (a3′); a copolymer consisting of the structural units (a1), (a2) and (a3′); and a copolymer consisting of the structural units (a1), (a2), (a3′) and (a4′).

In the component (A′), as the component (A1′), one type may be used alone, or two or more types may be used in combination.

In the first positive resist composition, it is particularly desirable that the component (A1′) include a combination of structural units such as that shown in the following general formula (A1′-11).

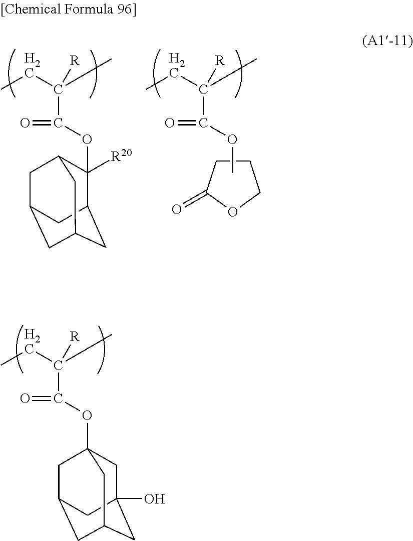

In formula (A1′-11), R is the same as defined above, and the plurality of R may be either the same or different from each other; and R²⁰ is the same as defined for R¹¹ in formula (a1-1-01).

The component (A1′) can be obtained, for example, by a conventional radical polymerization or the like of the monomers corresponding with each of the structural units, using a radical polymerization initiator such as azobisisobutyronitrile (AIBN).

Furthermore, in the component (A1′), by using a chain transfer agent such as HS—CH₂—CH₂—CH₂—C(CF₃)₂—OH, a —C(CF₃)₂—OH group can be introduced at the terminals of the component (A1′). Such a copolymer having introduced a hydroxyalkyl group in which part of the hydrogen atoms of the alkyl group are substituted with fluorine atoms is effective in reducing line width roughness (LWR). Such a copolymer is also effective in reducing developing defects and LER.

The weight average molecular weight (Mw) (the polystyrene equivalent value determined by gel permeation chromatography) of the component (A1′) is not particularly limited, but is preferably 1,000 to 50,000, more preferably 1,500 to 30,000, and most preferably 2,500 to 20,000.

When the weight average molecular weight is no more than the upper limit of the above-mentioned range, the resist composition exhibits a satisfactory solubility in a resist solvent. On the other hand, when the weight average molecular weight is at least as large as the lower limit of the above-mentioned range, dry etching resistance and the cross-sectional shape of the resist pattern becomes satisfactory.

Further, the dispersity (Mw/Mn) is not particularly limited, but is preferably 1.0 to 5.0, more preferably 1.0 to 3.0, and most preferably 1.2 to 2.5.

<Component (B′)>

As the component (B′), there is no particular limitation, and any of the known acid generators used in conventional chemically amplified resist compositions can be used. As the component (B′), the same acid generators as those for the component (B) described above in relation to the resist composition according to the first aspect of the present invention can be used.

As the component (B′), one type of these acid generators may be used alone, or two or more types may be used in combination.

In the present invention, as the component (B′), it is particularly desirable to use an onium salt having a fluorinated alkylsulfonic acid ion as the anion moiety.

The amount of the component (B′) within the first positive resist composition is preferably from 0.5 to 60 parts by weight and more preferably from 1 to 40 parts by weight, relative to 100 parts by weight of the component (A′). When the amount of the component (B) is within the above-mentioned range, formation of a resist pattern can be satisfactorily performed. Further, by virtue of the above-mentioned range, a uniform solution can be obtained and the storage stability becomes satisfactory.

<Component (D′)>

In order to improve factors such as the resist pattern shape and the post exposure stability of the latent image formed by the pattern-wise exposure of the resist layer, in the first positive resist composition, a nitrogen-containing organic compound (D′) (hereafter referred to as “component (D′)”) can be added as an optional component.

A multitude of these components (D′) have already been proposed, and any of these known compounds may be used. As the component (D′), the same compounds as those for the component (D) described above in relation to the resist composition according to the first aspect of the present invention can be used.

As the component (D′), one type of these nitrogen-containing organic compounds may be used alone, or two or more types may be used in combination.

The component (D′) is typically used in an amount within a range from 0.01 to 5.0 parts by weight, relative to 100 parts by weight of the component (A′).

<Component (E′)>

Furthermore, in the first positive resist composition, for preventing any deterioration in sensitivity, and improving the resist pattern shape and the post exposure stability of the latent image formed by the pattern-wise exposure of the resist layer, at least one compound (E′) (hereafter referred to as “component (E′)”) selected from the group consisting of an organic carboxylic acid, or a phosphorus oxo acid or derivative thereof can be added as an optional component.

A multitude of these components (E′) have already been proposed, and any of these known compounds may be used. As the component (E′), the same compounds as those for the component (E) described above in relation to the resist composition according to the first aspect of the present invention can be used.

As the component (E′), one type of these compounds may be used alone, or two or more types may be used in combination.

As the component (E′), an organic carboxylic acid is preferable, and salicylic acid is particularly desirable.

The component (E′) is typically used in an amount within a range from 0.01 to 5.0 parts by weight, relative to 100 parts by weight of the component (A′).

If desired, other miscible additives can also be added to the first positive resist composition. Examples of such miscible additives include additive resins for improving the performance of the resist film, surfactants for improving the applicability, dissolution inhibitors, plasticizers, stabilizers, colorants, halation prevention agents, and dyes.

<Component (S′)>

The first positive resist composition can be prepared by dissolving the materials for the resist composition in an organic solvent (hereafter, frequently referred to as “component (S′)”).

The component (S′) may be any organic solvent which can dissolve the respective components to give a uniform solution, and any one or more kinds of organic solvents can be appropriately selected from those which have been conventionally known as solvents for a chemically amplified resist.

As the component (S′), the same organic solvents as those for the component (S3) described above in relation to the resist composition according to the first aspect of the present invention can be used.

These components (S′) can be used either alone, or in combinations of two or more different solvents.

In the first positive resist composition, as the component (S′), propylene glycol monomethyl ether acetate (PGMEA), propylene glycol monomethyl ether (PGME) and ethyl lactate (EL) are preferable.

Further, among the mixed solvents, a mixed solvent obtained by mixing PGMEA with a polar solvent is preferable. The mixing ratio (weight ratio) of the mixed solvent can be appropriately determined, taking into consideration the compatibility of the PGMEA with the polar solvent, but is preferably in the range of 1:9 to 9:1, more preferably from 2:8 to 8:2.

Specifically, when EL is mixed as the polar solvent, the PGMEA:EL weight ratio is preferably from 1:9 to 9:1, and more preferably from 2:8 to 8:2. Alternatively, when PGME is mixed as the polar solvent, the PGMEA:PGME is preferably from 1:9 to 9:1, more preferably from 2:8 to 8:2, and still more preferably 3:7 to 7:3.

Further, as the component (S′), a mixed solvent of at least one of PGMEA and EL with γ-butyrolactone is also preferable. The mixing ratio (former:latter) of such a mixed solvent is preferably from 70:30 to 95:5.

There are no particular limitations on the overall amount used of the component (S′), and an amount that produces a liquid having a concentration that is suitable for application of the first positive resist composition onto a substrate is used.

If desired, other miscible additives can also be added to the chemically amplified positive resist composition. Examples of such miscible additives include additive resins for improving the performance of the resist film, surfactants for improving the applicability, dissolution inhibitors, plasticizers, stabilizers, colorants, halation prevention agents, and dyes.

By employing the method of forming a resist pattern according to the present invention, in a double patterning process, it is less likely to be adversely affected by the second patterning.

Further, by employing the method of forming a resist pattern according to the present invention, the difference in the size of the first resist pattern becomes small before and after the second patterning, and it becomes possible to form a resist pattern with high resolution and excellent shape. Furthermore, by employing the method of forming a resist pattern according to the present invention, there is no need to use a freezing agent or the like, which results in improved workability.

As the method of forming a resist pattern, a cross-line patterning method is preferable, which is a method including: applying a positive resist composition as a first resist composition on a substrate to form a first resist film on the substrate; subjecting the first resist film to selective exposure and alkali developing to form a first line and space resist pattern; applying the resist composition of the present invention as a second resist composition on the substrate on which the first line and space resist pattern is formed to form a second resist film; and subjecting the second resist film to selective exposure at a position that intersects with the first line and space resist pattern and alkali developing, so as to form a resist pattern.

By employing the cross-line patterning, particularly in the formation of a hole-like (or lattice) resist pattern, a hole-like (or lattice) resist pattern can be formed with high resolution and minute dimensions.

When conducting such a crossline patterning process, it is preferable to use an acid-generator component having a bulky substituent (preferably a polycyclic group) in the anion moiety of the resist composition according to the present invention used as the second resist composition, because a hole-like (or lattice-like) resist pattern with even higher levels of resolution and even finer dimensions can be formed. It is particularly desirable to use an acid-generator component having an anion represented by any one of the aforementioned formulas (b1-1-1) to (b1-1-5), (b1-2-1), (b1-2-2) and (b1-3-1) in the anion moiety thereof.

Furthermore, in addition to the use of an acid-generator component having a bulky substituent in the anion moiety of the second positive resist composition as described above, it is preferable to use an acid-generator component having a bulky substituent as the anion moiety in the first positive resist composition. In this case, it is more preferable to use an acid-generator component that includes a fluorinated alkylsulfonate ion (wherein the aforementioned R⁴″ group is a “group having a substituent group represented by formula X-Q¹-”) as an anion moiety, and it is most preferable to use an acid-generator component that includes a fluorinated alkylsulfonate ion (wherein the aforementioned R⁴″ group is a “group having a substituent group represented by formula X-Q¹-Y¹-”) as an anion moiety. More specifically, acid-generator components having anions represented by the above formulas (b1-1-1) to (b1-1-5), (b1-2-1), (b1-2-2) and (b1-3-1) as an anion moiety can be used favorably.

In the method of forming a resist pattern according to the present invention, the component (S1) included in the resist composition of the present invention for forming the second resist film is an organic solvent capable of satisfactorily dissolving resist components, such as the components (A) and (B), without dissolving the first resist film. According to the method of forming a resist pattern described above, a resist pattern can be stably formed by the double patterning process while hardly dissolving the first resist pattern formed by the first (positive) resist composition.

### EXAMPLES

As follows is a description of examples of the present invention, although the scope of the present invention is by no way limited by these examples.

<Synthesis of Resin Component (A1)>

In the present examples, the resin component (A1) used as the base component (A) was synthesized with reference to the synthesis examples described in Japanese Unexamined Patent Application, First Publication No. 2008-003540. The structure of the obtained resins are shown below.

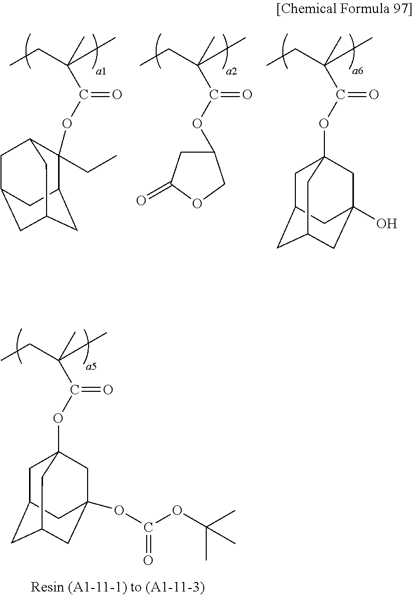

The weight average molecular weight (Mw) and dispersity (Mw/Mn) of the obtained resins were determined by the polystyrene equivalent value as measured by gel permeation chromatography (GPC).

Further, the compositional ratio indicating the percentage (mol %) of structural units derived from the respective monomers within the resins was determined by carbon NMR. In the formula shown above, the subscript numerals (a1, a2, a6, a5) on respective structural units indicate the amount (mol %) of the respective structural units.

The compositional ratio indicating the percentage (mol %) of structural units within the resins, and weight average molecular weight (Mw) and dispersity (Mw/Mn) of the copolymers are shown in Table 1.

TABLE 1

Amount of
structural unit
derived from
corresponding
monomer
(mol %)

| Resin | a1 | a2 | a6 | a5 | Mw | Mw/Mn |
|---|---|---|---|---|---|---|
| (A1-11-1) | 45 | 25 | 15 | 15 | 7000 | 1.50 |
| (A1-11-2) | 35 | 35 | 15 | 15 | 7000 | 1.50 |
| (A1-11-3) | 45 | 25 | 15 | 15 | 7000 | 1.70 |

<Synthesis of Acid-Generator Component (B)>

The compounds used as the acid-generator component (B) in the present examples were synthesized in accordance with the following acid-generator synthesis examples.

In the NMR analysis, the internal standard for ¹H-NMR is tetramethylsilane (TMS), and the internal standard for ¹⁹F-NMR is hexafluorobenzene (the peak of hexafluorobenzene was regarded as −160 ppm).

### Acid-Generator Synthesis Example 1

### Synthesis of Acid Generator (B21)

Acid generator (B21) was synthesized in accordance with the synthesis example described in Japanese Unexamined Patent Application, First Publication No. 2009-019028. The structure of the obtained compound is shown below.

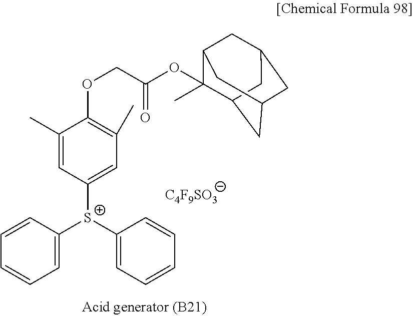

### Acid-Generator Synthesis Example 2

### Synthesis of Acid Generator (B11)

(i) Synthesis of Compound (V)

To 60.75 g of methanesulfonic acid controlled to 20° C. or lower was added 8.53 g of phosphorus oxide, 8.81 g of 2,6-dimethylphenol and 12.2 g of diphenylsulfoxide in small amounts. The resultant was matured for 30 minutes while maintaining the temperature at 15 to 20° C., followed by elevating the temperature to 40° C. and maturing for 2 hours. Then, the reaction mixture was dropwise added to 109.35 g of pure water cooled to 15° C. or lower. Thereafter, 54.68 g of dichloromethane was added and stirred, and the dichloromethane phase was collected. 386.86 g of hexane at a temperature of 20 to 25° C. was added to a separate vessel, and the dichloromethane phase was dropwise added thereto. Then, the resultant was matured at 20 to 25° C. for 30 minutes, followed by filtration, thereby obtaining a compound (V) (yield: 70.9%).

The obtained compound (V) was analyzed by NMR.

¹H-NMR (DMSO-d6, 600 MHz): δ(ppm)=7.61-7.72 (m, 10H, phenyl), 7.14 (s, 2H, H^{c}), 3.12 (s, 3H, H^{b}), 2.22 (s, 6H, H^{a})

From the results above, it was confirmed that the compound (V) had a structure shown below.

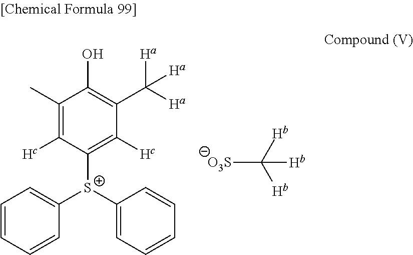

(ii) Synthesis of Compound (1)

28.98 g of the aforementioned compound (V), 289.80 g of dichloromethane and 9.47 g of triethylamine were mixed together and cooled to 10° C. while stirring. Then, 17.69 g of undecylic acid chloride was dropwise added thereto, and the temperature of the resultant was elevated to room temperature, followed by stirring for 1 hour. Thereafter, the reaction mixture was washed twice with 109.36 g of a saturated sodium bromide aqueous solution and four times with 109.36 g of pure water, followed by concentrating the organic phase, thereby obtaining 38 g of a compound (1).

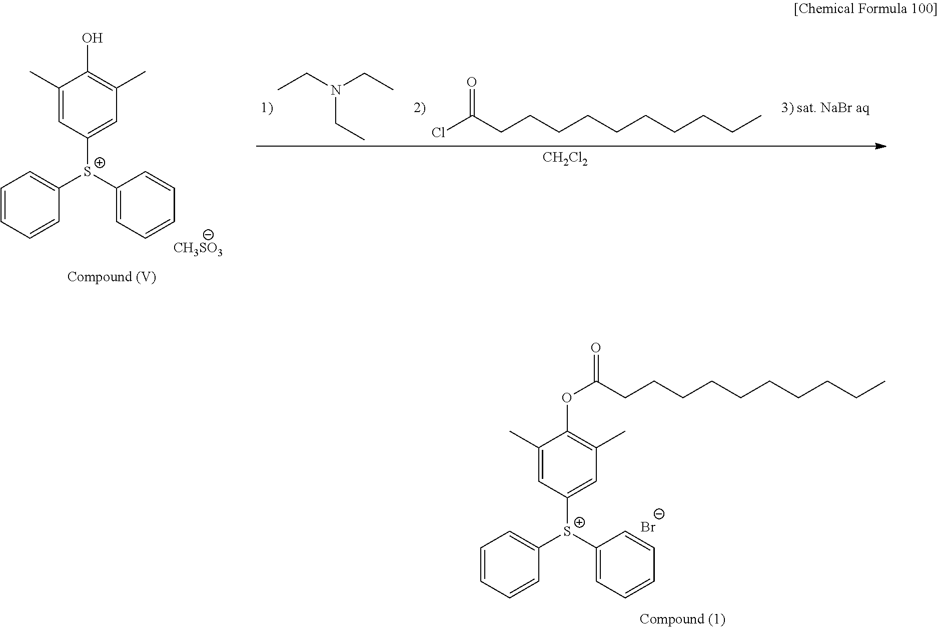

The obtained compound (1) was analyzed by NMR.

¹H-NMR (DMSO-d6, 400 MHz): δ (ppm)=7.79-7.93 (m, 12H, Ar), 2.73 (t, 2H, —CO—CH₂—), 2.19 (s, 6H, Ar—CH₃), 1.65-1.72 (m, 2H, —CH₂—), 1.25-1.38 (m, 14H, —CH₂—), 0.85 (t, 3H, —CH₃)

From the results, it was confirmed that the compound (1) had a structure shown above.

(iii) Synthesis of Acid Generator (B11)

2 g of the compound (1) was added to 20 g of dichloromethane and 20 g of water, followed by stirring. Then, 1.76 g of a compound (2) was added thereto, followed by stirring for 1 hour. The reaction mixture was subjected to liquid separation, and the resultant was washed four times with 20 g of water. The organic solvent phase was concentrated and solidified, thereby obtaining 2.40 g of an acid generator (B11).

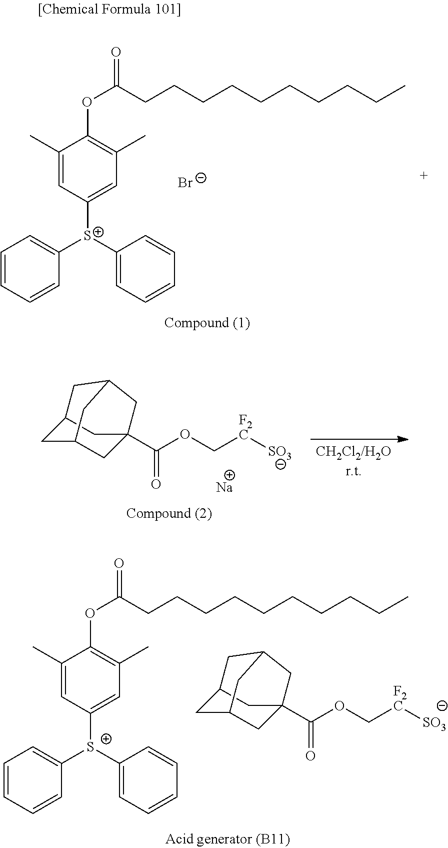

The obtained acid generator (B 11) was analyzed by NMR.

¹H-NMR (DMSO-d6, 400 MHz): δ (ppm)=7.79-7.93 (m, 12H, Ar), 4.55 (t, 2H, CF₂CH₂), 2.73 (t, 2H, —CO—CH₂—), 2.19 (s, 6H, Ar—CH₃), 1.94 (m, 3H, Ad), 1.82 (m, 6H, Ad), 1.64-1.72 (m, 8H, Ad, —CH₂—), 1.25-1.38 (m, 14H, —CH₂—), 0.85 (t, 3H, —CH₃)

¹⁹F-NMR (DMSO-d6, 376 MHz): δ (ppm)=−111.2

From the results, it was confirmed that the acid generator (B11) had a structure shown above.

### Acid-Generator Synthesis Example 3

### Synthesis of Acid Generator (B12)

Acid generator (B12) was synthesized in the same manner as in Acid-generator Synthesis Example 2, except that in step (iii), the compound (2) was changed to a compound (3) shown below (equimolar amount).

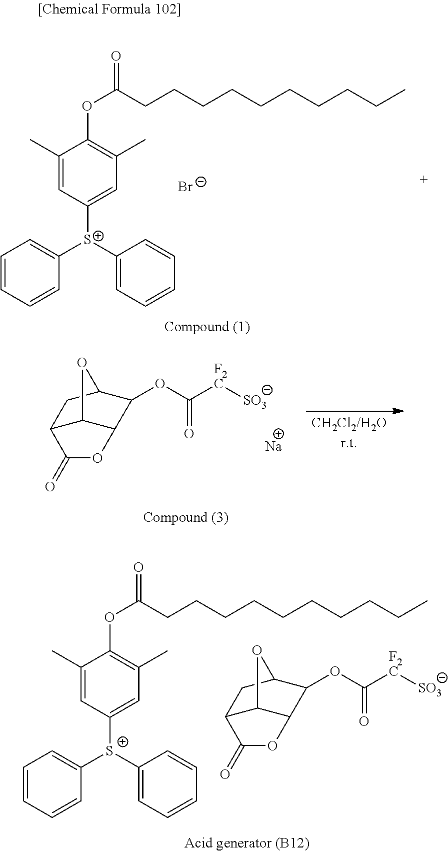

The obtained acid generator (B12) was analyzed by NMR.

¹H-NMR (DMSO-d6, 400 MHz): δ (ppm)=7.79-7.93 (m, 12H, Ar), 5.46 (t, 1H, oxo-norbornane), 4.97 (s, 1H, oxo-norbornane), 4.71 (d, 1H, oxo-norbornane), 4.57 (d, 1H, oxo-norbornane), 2.69-2.73 (m, 3H, oxo-norbornane, —CO—CH₂—), 2.19 (s, 6H, Ar—CH₃), 2.06-2.16 (m, 2H, oxo-norbornane), 1.65-1.72 (m, 2H, —CH₂—), 1.25-1.38 (m, 14H, —CH₂—), 0.85 (t, 3H, —CH₃)

¹⁹F-NMR (DMSO-d6, 376 MHz): δ (ppm)=−107.1

From the results, it was confirmed that the acid generator (B12) had a structure shown above.

### Acid-Generator Synthesis Example 4

### Synthesis of Acid Generator (B13)

(i) Synthesis of Compound (III)

150 g of methyl fluorosulfonyl(difluoro)acetate and 375 g of pure water were maintained at 10° C. or lower in an ice bath, and 343.6 g of a 30% by weight aqueous solution of sodium hydroxide was dropwise added thereto. Then, the resultant was refluxed at 100° C. for 3 hours, followed by cooling and neutralizing with a concentrated hydrochloric acid. The resulting solution was dropwise added to 8,888 g of acetone, and the precipitate was collected by filtration and dried, thereby obtaining 184.5 g of a compound (1) in the form of a white solid (purity: 88.9%, yield: 95.5%).

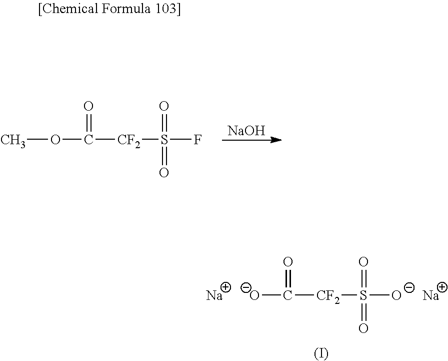

Subsequently, 56.2 g of the compound (1) and 562.2 g of acetonitrile were prepared, and 77.4 g of p-toluenesulfonic acid monohydrate was added thereto. The resultant was refluxed at 110° C. for 3 hours. Then, the reaction mixture was filtered, and the filtrate was concentrated and dried to obtain a solid. 900 g of t-butyl methyl ether was added to the obtained solid and stirred. Thereafter, the resultant was filtered, and the residue was dried, thereby obtaining 22.2 g of a compound (II) in the form of a white solid (purity: 91.0%, yield: 44.9%).

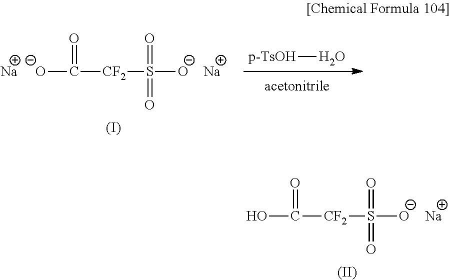

Subsequently, 4.34 g of the compound (II) (purity: 94.1%), 3.14 g of 2-benzyloxyethanol and 43.4 g of toluene were prepared, and 0.47 g of p-toluenesulfonic acid monohydrate was added thereto. The resultant was refluxed at 105° C. for 20 hours. Then, the reaction mixture was filtered, and 20 g of hexane was added to the residue and stirred. Thereafter, the resultant was filtered, and the residue was dried, thereby obtaining 1.41 g of a compound (III) (yield: 43.1%).

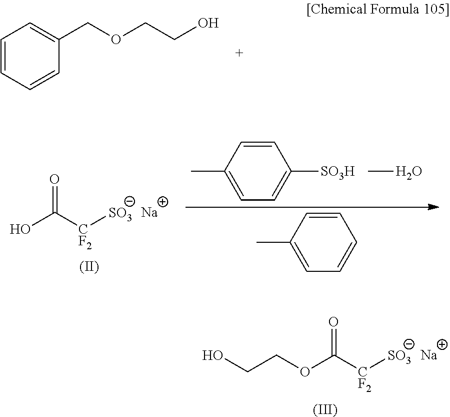

The obtained compound (III) was analyzed by NMR.

¹H-NMR (DMSO-d6, 400 MHz): δ (ppm)=4.74-4.83 (t, 1H₂OH), 4.18-4.22 (t, 2H, H^{a}), 3.59-3.64 (q, 2H, H^{b})

¹⁹F-NMR (DMSO-d6, 376 MHz): δ (ppm)=−106.6

From the results shown above, it was confirmed that the compound (III) had a structure shown below.

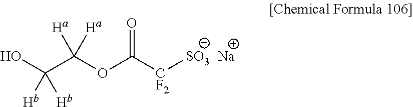

(ii) Synthesis of Compound (IV)

To 1.00 g of the compound (III) and 3.00 g of acetonitrile were dropwise added 0.82 g of 1-adamantanecarbonyl chloride and 0.397 g of triethylamine while cooling with ice. Then, the resultant was stirred at room temperature for 20 hours, followed by filtration. The filtrate was concentrated and dried, and dissolved in 30 g of dichloromethane, followed by washing with water three times. Thereafter, the organic phase was concentrated and dried, thereby obtaining 0.82 g of a compound (IV) (yield: 41%).

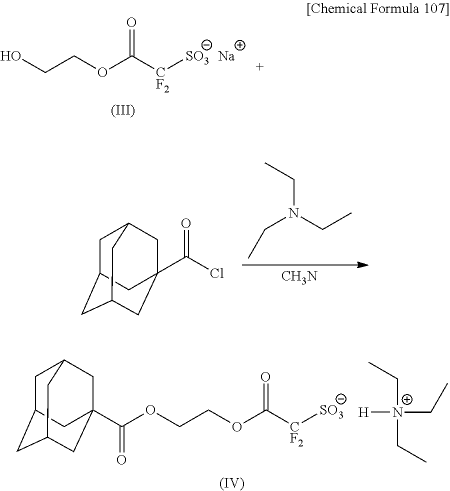

The obtained compound (IV) was analyzed by NMR.

¹H-NMR (DMSO-d6, 400 MHz): δ (ppm)=8.81 (s, 1H, H^{c}), 4.37-4.44 (t, 2H, H^{d}), 4.17-4.26 (t, 2H, H^{c}), 3.03-3.15 (q, 6H, H^{b}), 1.61-1.98 (m, 15H, Adamantane), 1.10-1.24 (t, 9H, H^{a})

¹⁹F-NMR (DMSO-d6, 376 MHz): δ (ppm)=−106.61

From the results above, it was confirmed that the compound (IV) had a structure shown below.

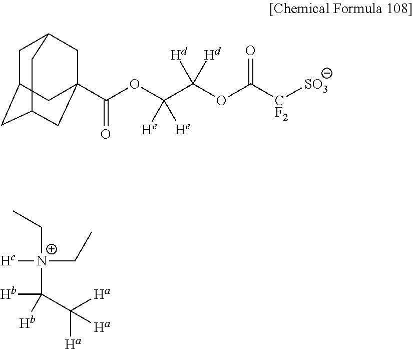

(iii) Synthesis of Compound (VI)

4 g of the compound (V) was dissolved in 79.8 g of dichloromethane. After confirming that the compound (VI) had dissolved in dichloromethane, 6.87 g of potassium carbonate was added thereto, and 3.42 g of methyl adamantyl bromoacetate was further added. A reaction was effected under reflux for 24 hours, followed by filtration, washing with water, and crystallization with hexane. The resulting powder was dried under reduced pressure, thereby obtaining 3.98 g of an objective compound (VI) (yield: 66%).

The obtained compound (VI) was analyzed by NMR.

¹H-NMR (CDCl₃, 400 MHz): δ (ppm)=7.83-7.86 (m, 4H, Phenyl), 7.69-7.78 (m, 6H, Phenyl), 7.51 (s, 2H, H^{d}), 4.46 (s, 2H, H^{c}), 2.39 (s, 6H, H^{a}), 2.33 (s, 2H, Adamantane), 2.17 (s, 2H, Adamantane), 1.71-1.98 (m, 11H, Adamantane), 1.68 (s, 3H, H^{b}), 1.57-1.61 (m, 2H, Adamantane)

From the results above, it was confirmed that the compound (VI) had a structure shown below.

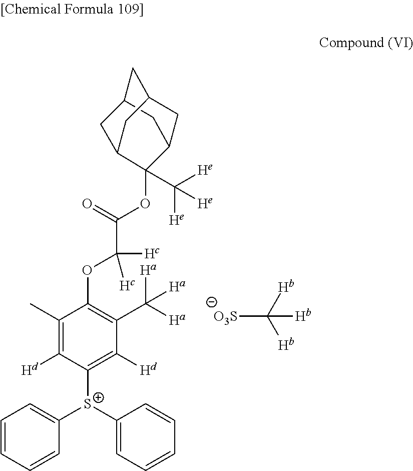

(iv) Synthesis of Acid Generator (B13)

4.77 g of the compound (VI) was dissolved in 23.83 g of dichloromethane and 23.83 g of pure water, and 3.22 g of the compound (IV) was then added to the resulting solution. The resultant was stirred for 1 hour, followed by liquid separation to collect the organic phase. The organic phase was washed with 3.84 g of water three times. Thereafter, the resulting organic layer was concentrated and solidified, thereby obtaining 4.98 g of a compound (B13) (yield: 87%).

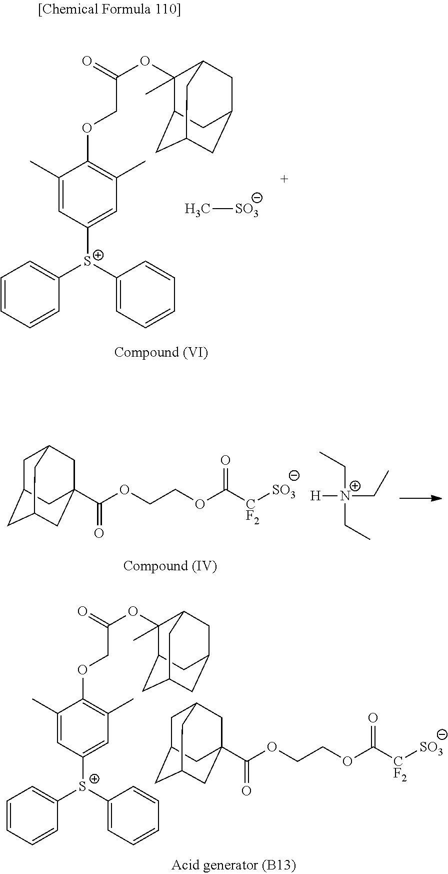

The obtained acid generator (B13) was analyzed by NMR.

¹H-NMR (DMSO-d6, 400 MHz): δ (ppm)=7.76-7.88 (m, 10H, Phenyl), 7.62 (s, 2H, Phenyl), 4.64 (s, 2H, H^{b}), 4.43-4.44 (t, 2H, H^{c}), 4.22-4.23 (t, 2H, H^{d}), 1.51-2.36 (m, 38H, Adamantane+H^{a}+H^{c})

¹⁹F-NMR (DMSO-d6, 376 MHz): δ (ppm)=−106.7

From the results shown above, it was confirmed that the acid generator (B13) had a structure shown below.

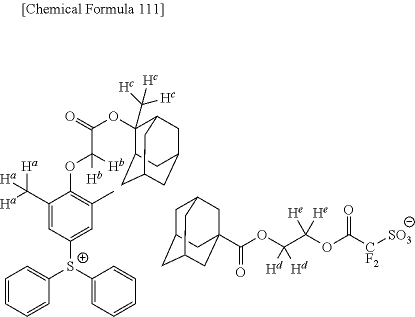

### Acid-Generator Synthesis Example 5

### Synthesis of Acid Generator (B14)

(i) Synthesis of Compound (5)

4.74 g of xylenol and 16.1 g of anhydrous potassium carbonate were mixed in 94.8 g of acetone. Then, 32.9 g of 1-iodohexane was gradually added thereto in dropwise manner, and a reaction was effected for 19 hours under reflux. After the reaction, the reaction mixture was cooled and subjected to filtration. Acetone was removed from the obtained filtrate, thereby obtaining 25.5 g of a viscous liquid. Then, 25.4 g of t-butylmethylether and 25.4 g of a 1% aqueous solution of sodium hydroxide were added to the obtained liquid, and the organic phase was collected, followed by washing the organic phase with 25.4 g of a 1% aqueous solution of sodium hydroxide. The organic phase was collected again, and washing was conducted four times with 25.4 g of a 1% aqueous solution of sodium hydroxide. Thereafter, t-butylmethylether was removed to obtain 23.5 g of a crude product.

The obtained crude product was purified by distillation under a pressure of 1.1 to 1.0 kPa, thereby obtaining 5.77 g of a compound (4) in the form of a transparent liquid (yield: 72.0%).

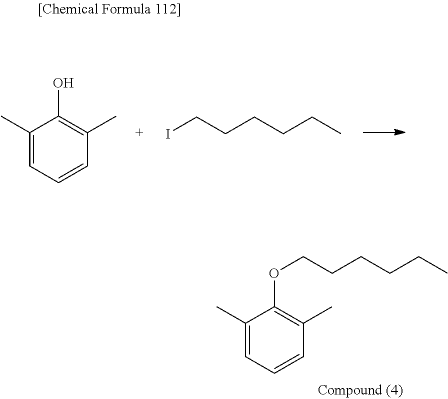

Subsequently, 2.24 g of diphosphorus pentoxide was dissolved in 25.1 g of methanesulfonic acid, and while cooling the resultant with ice, 3.91 g of the compound (4) was gradually added thereto in a dropwise manner. Further, a solution obtained by dissolving 3.20 g of diphenylsulfoxide in 3.20 g of methanesulfonic acid was gradually added thereto in a dropwise manner. After the dropwise addition, the resultant was cooled to room temperature, and stirred for 6 hours. Then, the reaction solution was added to a mixed solvent containing 75 g of water and 75 g of TBME, and the aqueous phase was collected. Further, washing was conducted with 75 g of TBME, and extraction was conducted 3 times with 75 g of methylene chloride. The collected methylene chloride solution was concentrated so that the total weight thereof became 50 g, and washing was conducted 3 times with 50 g of distilled water. Thereafter, the methylene chloride phase was concentrated, thereby obtaining 5.21 g of a compound (5) in the form of a transparent liquid (yield: 67.8%).

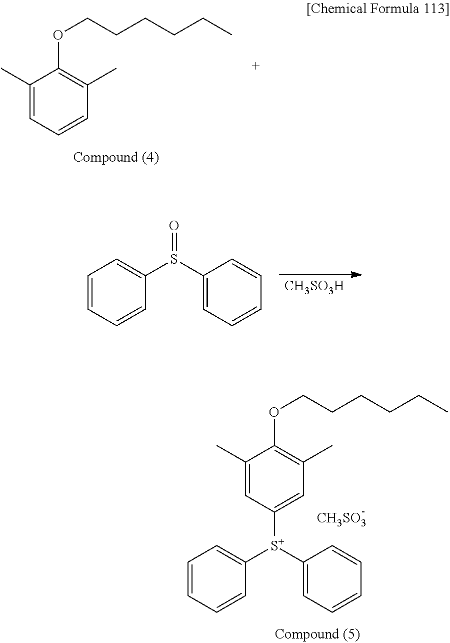

(ii) Synthesis of Acid Generator (B14)

3.78 g of the compound (5) and 3.23 g of the compound (2) were added to 18.9 g of distilled water, and 18.9 g of methylene chloride was further added thereto, followed by stirring at room temperature for 2 hours. Then, the methylene chloride phase was collected, and washed 3 times with 18.9 g of a 1% aqueous hydrochloric acid solution. Next, washing was conducted 4 times with 18.9 g of distilled water, and the resulting methylene chloride solution was gradually added to a mixed solvent containing 100 g of hexane and 100 g of TBME in a dropwise manner. Thereafter, the resultant was subjected to filtration, and the obtained solid was dried, thereby obtaining 3.65 g of an acid generator (B14) (yield: 67.8%, purity: 99.7 wt %).

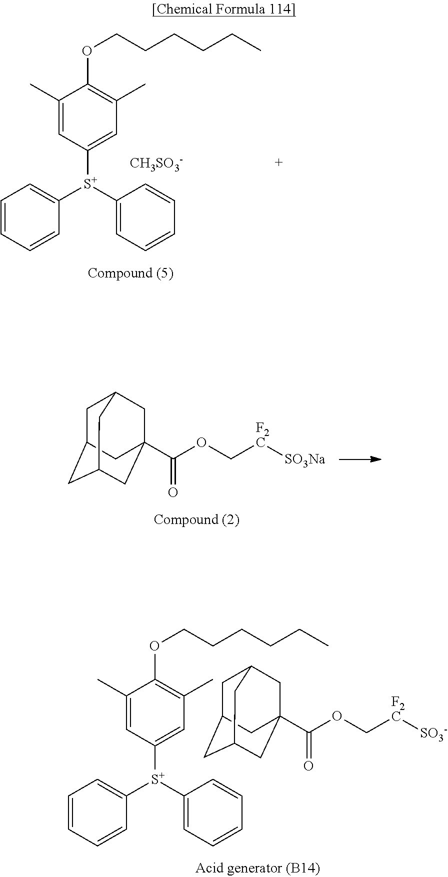

The obtained acid generator (B14) was analyzed by ¹H-NMR and ¹⁹F-NMR. ¹H-NMR (DMSO-d6, 400 MHz): δ (ppm)=0.87 (t, 3H, H^{a}), 1.29 (m, 4H, Hc, Hd), 1.45 (m, 2H, Hd), 1.65-1.95 (m, 17H, He, Hk), 2.33 (s, 6H, Hg), 3.83 (t, 2H, Hf), 4.54 (t, 2H, Hj), 7.59 (s, 2H, Hh), 7.73-7.85 (m, 10H, Hi)

¹⁹F-NMR (DMSO-d6, 400 MHz): δ (ppm)=−111.5 (t, 2F, Fa) (potassium nonafluoro-n-butanesulfonate was used as an internal standard, and the peak of hexafluorobenzene was regarded as −160 ppm.)

From the results shown above, it was confirmed that the acid generator (B14) had a structure shown below. Furthermore, from the results of ¹⁹F-NMR analysis, it was confirmed that the purity was 99.7 wt %.

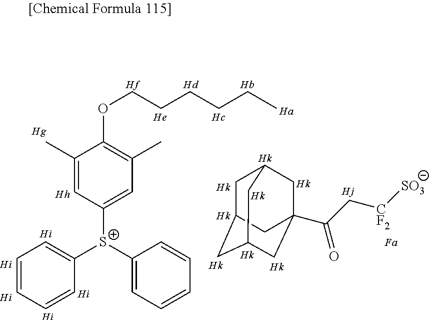

### Acid-Generator Synthesis Example 6

### Synthesis of Acid Generator (B15)

(i) Synthesis of Compound (8)

21.7 g of a compound (6) (Br:Cl=85.2:14.2) was dissolved in 108.5 g of acetonitrile, and 6.00 g of triethylamine was further added to obtain a uniform solution. Then, 57.6 g of a 25 wt % acetonitrile solution of a compound (7) was dropwise added thereto, and a reaction was effected at a reflux temperature for 2 hours. Subsequently, acetonitrile was removed, and the resultant was dissolved in 300 g of pure water, followed by washing twice with 150 g of a mixed solvent containing n-hexane and TBME (1:1 wt/wt).

Thereafter, 300 g of methylene chloride and 30 g of sodium chloride were added and stirred. The organic phase was collected, and washed once with 150 g of a 10% aqueous solution of sodium chloride and once with pure water. Then, the organic phase was concentrated and solidified, thereby obtaining 20.9 g of a compound (8) in the form of a white solid (Br:Cl=15.4:84.6).

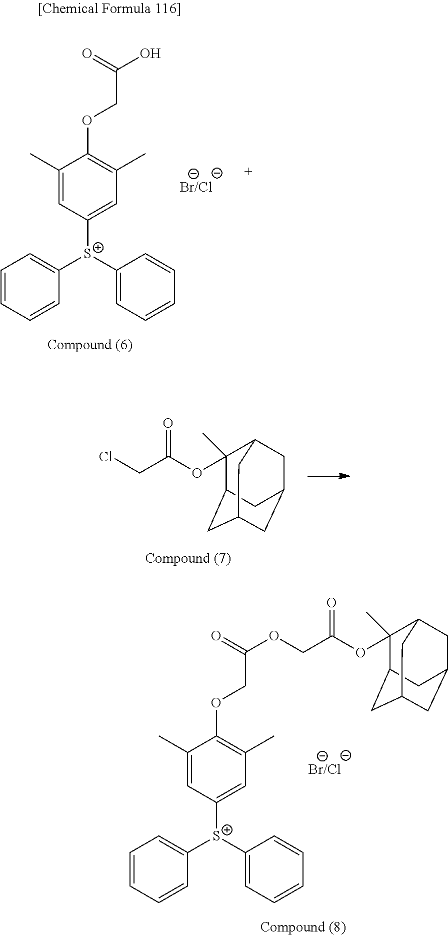

(ii) Synthesis of Acid Generator (B15)

5.00 g of the compound (8) (Br:Cl=15.4:84.6) was mixed with 3.25 g of a compound (2), and 50.0 g of pure water and 50.0 g of methylene chloride were added thereto, followed by stirring at room temperature for 4 hours. Thereafter, the organic phase was collected, and washing was conducted twice with 25.0 g of a 1% aqueous hydrochloric acid solution and 4 times with 25.0 g of pure water. Then, the organic phase was concentrated and solidified, thereby obtaining 5.00 g of an acid generator (B15) in the form of a white solid.

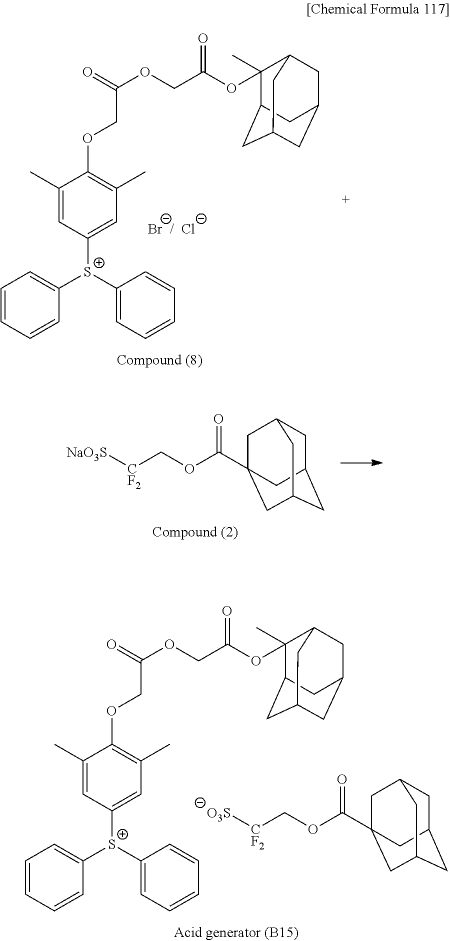

The obtained acid generator (B15) was analyzed by NMR.

¹H-NMR (DMSO-d6, 400 MHz): δ (ppm)=1.47-1.95 (m, 30H, Adamantane), 2.12 (m, 2H, Adamantane), 2.31 (d, 6H, CH3-Ph), 4.51 (t, 2H, ester), 4.75 (s, 4H, ester), 7.56 (s, 2H, Ph), 7.69-7.84 (m, 10H, Ph)

¹⁹F-NMR (DMSO-d6, 376 MHz): δ (ppm)=−111.5 (the peak of hexafluorobenzene was regarded as −160 ppm.)

From the results, it was confirmed that the acid generator (B15) had a structure as shown above.

### Acid-Generator Synthesis Example 7

### Synthesis of Acid Generator (B16)

Acid generator (B16) was synthesized in the same manner as in Acid-generator Synthesis Example 6, except that in step (ii), the compound (2) was changed to a compound (IV) shown below (equimolar amount).

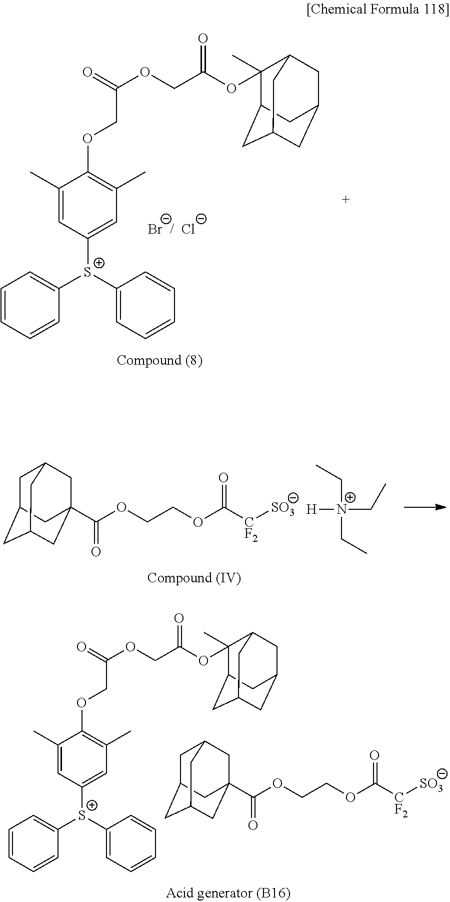

<Synthesis of Fluorine-Containing Compound Component (F)>

20.00 g (88.44 mmol) of a compound (9) and 6.60 g (29.48 mmol) of a compound (10) were added to a three-necked flask equipped with a thermometer and a reflux tube and were dissolved by adding 39.90 g of THF thereto. Then, 23.58 mmol of dimethyl 2,2′-azobis(isobutyrate) (product name: V-601) as a polymerization initiator was added and dissolved in the resulting solution. The solution was dropwise added to 22.17 g of tetrahydrofuran heated to 67° C. in a nitrogen atmosphere over 3 hours to effect a polymerization reaction. The resulting reaction solution was heated while stirring for 4 hours, and then cooled to room temperature. The resulting polymer solution was dropwise added to an excess amount of n-heptane to precipitate a polymer. Then, the precipitated polymer was separated by filtration, followed by washing and drying, thereby obtaining 13 g of a fluorine-containing resin (F1-1-11) as an objective compound.

With respect to the fluorine-containing resin (F1-1-11), the weight average molecular weight (Mw) and the dispersity (Mw/Mn) were determined by the polystyrene equivalent value as measured by gel permeation chromatography (GPC). As a result, it was found that the weight average molecular weight was 13,800, and the dispersity was 1.5. Further, analysis was conducted by carbon 13 nuclear magnetic resonance spectroscopy (600 MHz, ¹³C-NMR) to determine the composition of the copolymer (ratio l/m (molar ratio) of the respective structural units within the structural formula). As a result, it was found that the composition of the copolymer was l/m=77.6/22.4 (molar ratio).

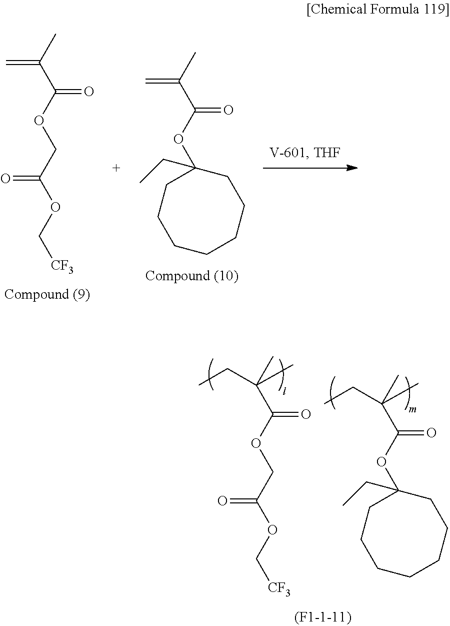

### Production of Resist Composition (1)

### Examples 1 to 3, Comparative Examples 1 to 4

The components shown in Table 2 were mixed together and dissolved to obtain positive resist compositions.

In Table 2, the reference characters indicate the following. Further, in Table 2, the values in brackets [ ] indicate the amount (in terms of parts by weight) of the component added.

TABLE 2

| | Component | | | Component | Component | Component |
|---|---|---|---|---|---|---|
| | (A) | Component (B) | | (D) | (E) | (S) |
| Comp. Ex. 1 | (A)-1 | (B)-1 | — | (D)-1 | (E)-1 | (S)-1 |
| | [100] | [15.0] | | [1.6] | [3.0] | [2800] |
| Comp. Ex. 2 | (A)-2 | (B)-1 | — | (D)-1 | (E)-1 | (S)-2 |
| | [100] | [11.0] | | [0.6] | [1.2] | [2800] |
| Comp. Ex. 3 | (A)-1 | (B)-2 | — | (D)-1 | (E)-1 | (S)-2 |
| | [100] | [7.0] | | [0.45] | [1.0] | [2800] |
| Ex. 1 | (A)-1 | (B)-3 | — | (D)-1 | (E)-1 | (S)-2 |
| | [100] | [14.0] | | [0.15] | [0.35] | [2800] |
| Comp. Ex. 4 | (A)-1 | (B)-2 | (B)-5 | (D)-1 | (E)-1 | (S)-2 |
| | [100] | [7.0] | [1.5] | [0.45] | [1.0] | [2800] |
| Ex. 2 | (A)-1 | (B)-3 | (B)-5 | (D)-1 | (E)-1 | (S)-2 |
| | [100] | [14.0] | [1.5] | [0.15] | [0.35] | [2800] |
| Ex. 3 | (A)-1 | (B)-4 | (B)-5 | (D)-1 | (E)-1 | (S)-2 |
| | [100] | [13.8] | [1.5] | [0.15] | [0.35] | [2800] |

(A)-1: the aforementioned resin (A1-11-1).
(A)-2: the aforementioned resin (A1-11-2).
(B)-1: the aforementioned acid generator (B21)
(B)-2: (4-methylphenyl)diphenylsulfonium nonafluoro-n-butanesulfonate
(B)-3: the aforementioned acid generator (B11)
(B)-4: the aforementioned acid generator (B12)
(B)-5: an acid generator (B22) represented by the chemical formula shown below
[Chemical Formula 120] 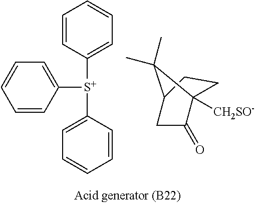
(D)-1: tri-n-pentylamine
(E)-1: salicylic acid
(S)-1: 1-butoxy-2-propanol (BP), boiling point: 170° C.
(S)-2: a mixed solvent of BP/PGMEA (boiling point: 146° C.) = 90/10 (weight ratio)

<Evaluation of Lithography Properties (1)>

[Resolution and Sensitivity]

An organic anti-reflection film composition (product name: ARC95, manufactured by Brewer Science Ltd.) was applied to an 12-inch silicon wafer using a spinner, and the composition was then baked at 205° C. for 90 seconds, thereby forming an organic anti-reflection film having a film thickness of 90 nm.

Then, each positive resist composition obtained in Examples 1 to 3 and Comparative Examples 1 to 4 was applied onto the anti-reflection film using a spinner, and was then prebaked (PAB) on a hotplate at a temperature indicated in Table 3 for 60 seconds and dried, thereby forming a resist film having a film thickness of 80 nm.

Subsequently, a coating solution for forming a protection film (product name: TILC-057; manufactured by Tokyo Ohka Kogyo Co., Ltd.) was applied to the resist film using a spinner, and then heated at 90° C. for 60 seconds, thereby forming a top coat with a film thickness of 35 nm.

Subsequently, the resist film was selectively irradiated with an ArF excimer laser (193 nm) through a mask, using an ArF immersion exposure apparatus NSR-S609B (manufactured by Nikon Corporation, NA (numerical aperture)=1.07, Dipole 0.78/0.97).

Next, a post exposure bake (PEB) treatment was conducted at a temperature indicated in Table 3 for 60 seconds, followed by alkali development for 10 seconds at 23° C. in a 2.38% by weight aqueous TMAH solution (product name: NMD-3; manufactured by Tokyo Ohka Kogyo Co., Ltd.). Then, the resist was washed for 25 seconds with pure water, followed by drying by shaking. Finally, a bake treatment (post bake) was conducted at 100° C. for 45 seconds.

As a result, in each of the examples, a line and space pattern (hereafter, referred to as “LS pattern”) having a line width of 50 nm and a pitch of 100 nm was formed.

The optimum exposure dose (Eop mJ/cm²) with which the pattern was formed, i.e., sensitivity, was determined. The results are shown in Table 3.

[Evaluation of Line Width Roughness (LWR)]

With respect to each of the LS patterns formed with the above Eop and having a line width of 50 nm and a pitch of 100 nm, the line width at 400 points in the lengthwise direction of the line were measured using a measuring scanning electron microscope (SEM) (product name: S-9220, manufactured by Hitachi, Ltd.; acceleration voltage: 800V). From the results, the value of 3 times the standard deviation s (i.e., 3s) was determined, and the average of the 3s values at 5 points was calculated as a yardstick of LWR. The results are shown in Table 3.

The smaller this 3s value is, the lower the level of roughness of the line width, indicating that a LS pattern with a uniform width was obtained.

[Evaluation of Line Edge Roughness (LER)]

The LER of the LS pattern having a line width of 50 nm and a pitch of 100 nm was determined.

Specifically, using a measuring scanning electron microscope (SEM) (product name: S-9360, manufactured by Hitachi, Ltd.; measurement voltage: 300V), deviation from the average line of the line edge in each resist pattern was measured at 400 points. From the results, the value of 3 times the standard deviation s (i.e., 3s) was determined, and the average of the 3s values at 5 points was calculated as a yardstick of LER. The results are shown in Table 3.

The smaller the determined value is, the lower the level of roughness of the line width, indicating that a LS pattern with a uniform width was obtained.

[Evaluation of Resist Pattern Shape]

With respect to each LS pattern having a line width of 50 nm and a pitch of 100 nm, the cross-sectional shape of the resist pattern was observed using a scanning electron microscope (product name: S-4700, manufactured by Hitachi, Ltd.) The results are shown in Table 3.

TABLE 3

| | PAB | PEB | Eop | LWR | LER | Resist pattern |
|---|---|---|---|---|---|---|
| | (° C.) | (° C.) | (mJ/cm²) | (nm) | (nm) | shape |
| Comp. Ex. 1 | 120 | 90 | 22.7 | 5.87 | 3.72 | Slight footing |
| Comp. Ex. 2 | 130 | 90 | 19.9 | 5.04 | 3.42 | Slight footing |
| Comp. Ex. 3 | 130 | 90 | 15.4 | 5.44 | 4.48 | Slight footing |
| Ex. 1 | 130 | 90 | 12.0 | 4.84 | 3.98 | Perpendicular |
| Comp. Ex. 4 | 130 | 90 | 19.8 | 5.04 | 4.08 | Slight footing |
| Ex. 2 | 130 | 90 | 15.5 | 4.74 | 3.05 | Perpendicular |
| Ex. 3 | 130 | 90 | 22.4 | 4.33 | 2.94 | Perpendicular |

From the results shown in Table 3, it was confirmed that the resist compositions of Examples 1 to 3 according to the present invention exhibited excellent properties with respect to LWR, LER and resist pattern shape, as compared to the resist compositions of Comparative Examples 1 to 4.

### Production of Resist Composition (2)

### Example 4, Comparative Example 5

The components shown in Table 4 were mixed together and dissolved to obtain positive resist compositions.

In Table 4, the reference characters indicate the following. Further, in Table 4, the values in brackets [ ] indicate the amount (in terms of parts by weight) of the component added.

TABLE 4

| | | Component | | | Component | Component | Component | Component |
|---|---|---|---|---|---|---|---|---|
| | | (A) | Component (B) | | (D) | (E) | (F) | (S) |
| First resist | | (A)-3 | (B)-6 | — | (D)-1 | (E)-1 | — | (S)-3 |
| composition (a) | | [100] | [8.0] | | [0.40] | [0.22] | | [3000] |
| First resist | | (A)-3 | (B)-7 | (B)-8 | (D)-1 | (E)-1 | — | (S)-3 |
| composition (b) | | [100] | [10.0] | [1.0] | [1.0] | [1.82] | | [3000] |
| Second | Comp. Ex. 5 | (A)-4 | (B)-1 | — | (D)-1 | (E)-1 | (F)-1 | (S)-1 |
| resist | | [100] | [15.0] | | [1.60] | [3.00] | [5.0] | [2400] |
| composition | Ex. 4 | (A)-4 | (B)-1 | (B)-9 | (D)-1 | (E)-1 | (F)-1 | (S)-1 |
| | | [100] | [5.0] | [10.5] | [1.60] | [3.00] | [5.0] | [2400] |

(A)-3: a copolymer represented by chemical formula (A1′-11-1) shown below with Mw =7,000 and Mw/Mn = 1.7. In the formula, the subscript numerals shown to the bottom right of the parentheses ( ) indicate the percentage (mol%) of the respective structural units within the copolymer.
[Chemical Formula 121] 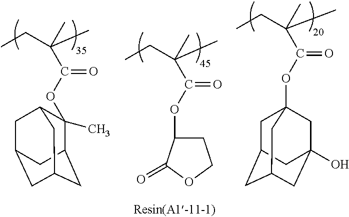
(A)-4: the aforementioned resin (A1-11-3).
(B)-1: the aforementioned acid generator (B21)
(B)-6: (4-methylphenyl)diphenylsulfonium nonafluoro-n-propane sulfonate.
(B)-7: an acid generator (B23) represented by the chemical formula shown below
(B)-8: an acid generator (B24) represented by the chemical formula shown below
(B)-9: the aforementioned acid generator (B13)
[Chemical Formula 122] 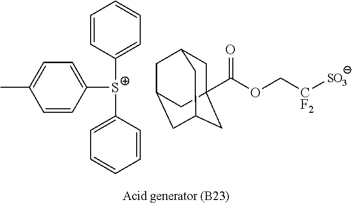 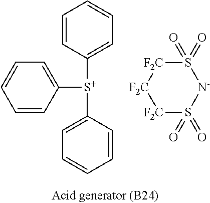
(D)-1: tri-n-pentylamine
(E)-1: salicylic acid
(F)-1: the aforementioned fluorine-containing resin (F1-1-11).
(S)-1: 1-butoxy-2-propanol (BP), boiling point: 170° C.
(S)-3: a mixed solvent of PGMEA (boiling point: 146° C.)/PGME (boiling point: 120° C.) = 6/4 (weight ratio).

<Crossline Patterning by Double Patterning Process>

A crossline patterning process was conducted as follows by combining the first resist composition and the second resist composition.

Combination of a first resist composition (a) and the second resist composition of Comparative Example 5

Combination of a first resist composition (a) and the second resist composition of Example 4

Combination of a first resist composition (b) and the second resist composition of Comparative Example 5

Combination of a first resist composition (b) and the second resist composition of Example 4

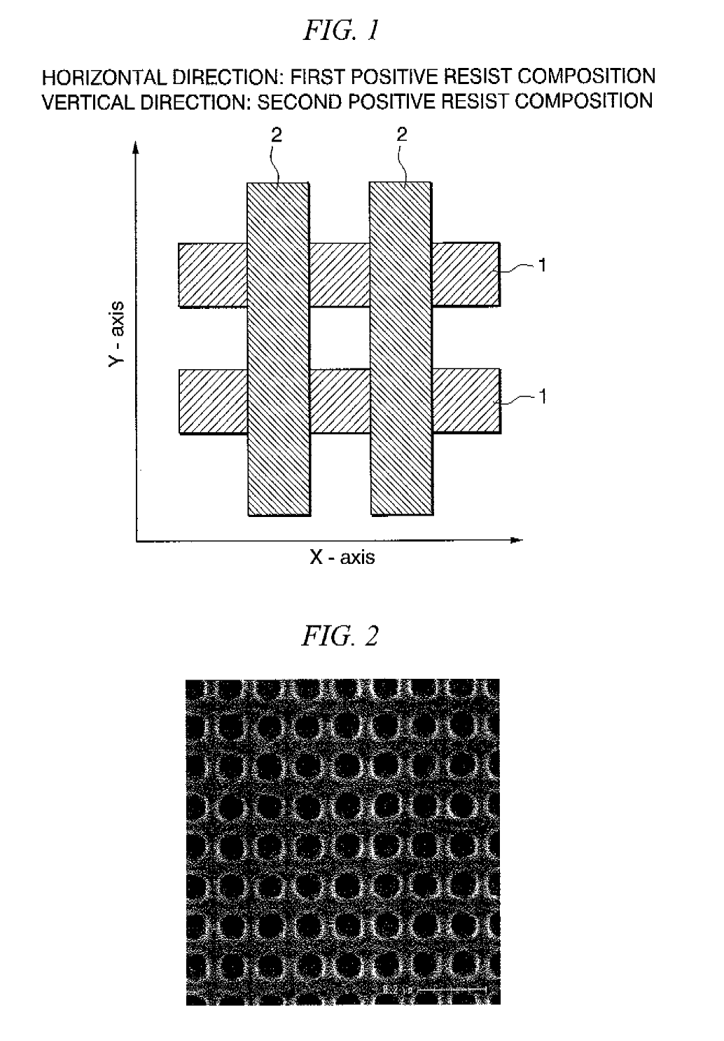

As shown in FIG. 1, after forming a first L/S pattern 1 substantially in parallel to the X-axis using the first positive resist composition (a) or (b), a second resist film was formed by applying the second resist composition obtained in Comparative Example 5 or Example 4 onto the substrate where the first L/S pattern 1 was formed, and the second resist film was then subjected to exposure and alkali developing so as to form an L/S pattern 2 substantially in parallel to the Y-axis which is orthogonal to the first L/S pattern 1, thereby ultimately forming a hole-like (or lattice-like) resist pattern. The image (photograph) of the actual resist pattern formed is shown in FIG. 2.

More specifically, the crossline patterning process by the double patterning method was conducted as follows.

[Formation of First L/Pattern]

First, an organic antireflection film composition (product name: ARC29SR, manufactured by Brewer Science Ltd.) was applied to a 12-inch silicon wafer using a spinner, and the composition was then baked and dried on a hotplate at 205° C. for 60 seconds, thereby forming an organic antireflection film having a thickness of 95 nm.

Then, the first positive resist composition (a) or (b) as a first resist composition was applied to the organic antireflection film using a spinner, and was then prebaked (PAB) and dried on a hotplate at 120° C. for 60 seconds, thereby forming resist films (the first resist films) having the respective film thicknesses shown in Table 5.

Subsequently, the first resist film was selectively irradiated with an ArF excimer laser (193 nm) through a mask pattern, using an immersion exposure apparatus XT1900Gi (manufactured by ASML, NA (numerical aperture)=1.35, Dipole40X, sigma 0.98/0.81).

Thereafter, a post exposure bake (PEB) treatment was conducted at 110° C. for 60 seconds, followed by development for 10 seconds at 23° C. in a 2.38% by weight aqueous solution of tetramethylammonium hydroxide (TMAH).

As a result, a line and space pattern (a first L/S pattern) having a line width of 40 nm and a pitch of 80 nm as a target size was formed on the resist film. The sensitivity values (Eop (1)) during this step are shown in Table 5.

[Crossline Patterning Process]

Then, the resist composition obtained in Comparative Example 5 or Example 4 as a second resist composition was applied to the first L/S pattern formed as described above, and was then prebaked (PAB) and dried on a hotplate at 130° C. for 60 seconds, thereby forming resist films having the respective film thicknesses shown in Table 5.

Subsequently, the resist film was selectively irradiated with an ArF excimer laser (193 nm) through a mask pattern, using an immersion exposure apparatus XT1900Gi (manufactured by ASML, NA (numerical aperture)=1.35, Dipole40X, sigma 0.98/0.81). Direction of the L/S pattern of the mask was orthogonal to that of the first L/S pattern, and a latent image of the L/S pattern formed on the second resist film was an L/S pattern having a line width of 40 nm and a pitch of 80 nm. The sensitivity values (Eop (2)) during this step are shown in Table 5.

Thereafter, a post exposure bake (PEB) treatment was conducted at 90° C. for 60 seconds, followed by development for 10 seconds at 23° C. in a 2.38% by weight aqueous solution of tetramethylammonium hydroxide (TMAH). As a result, a hole-like resist pattern was formed.

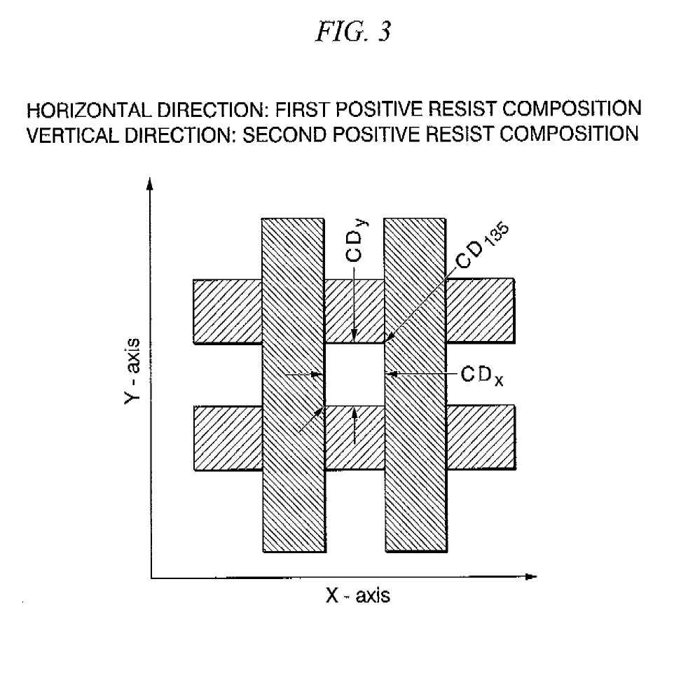

FIG. 3 is a schematic diagram showing the dimensions of a hole portion in the resist pattern, formed by a crossline patterning process, in the X-axis direction (CDₓ) and the Y-axis direction (CD_{y}), and the length of a diagonal line (CD₁₃₅).

With respect to the hole portion in the formed resist pattern, dimensions in the X-axis direction (CDₓ) and in the Y-axis direction (CD_{y}), and the length of a diagonal line (CD₁₃₅) shown in FIG. 3 were measured using a scanning electron microscope (product name: S 9380, manufactured by Hitachi, Ltd.). The results are shown in Table 5.

TABLE 5

| | | Film thickness | | | | | | Average | |
|---|---|---|---|---|---|---|---|---|---|
| | Second | (nm) | | Sensitivity | | | | of Cdy | |
| First resist | resist | First | Second | (mJ/cm²) | | CDy | CDx | and CDx | CD₁₃₅ |
| composition | composition | resist film | resist film | Eop (1) | Eop (2) | (nm) | (nm) | (nm) | (nm) |
| (a) | Comp. Ex. 5 | 85 | 80 | 20 | 24 | 42.2 | 38.9 | 40.55 | 40.6 |
| (a) | Ex. 4 | 85 | 80 | 19 | 28 | 39.6 | 38.2 | 38.9 | 40.1 |
| (b) | Comp. Ex. 5 | 80 | 80 | 14 | 23 | 41.1 | 38.3 | 39.7 | 40.0 |
| (b) | Ex. 4 | 80 | 80 | 14 | 29 | 39.0 | 38.3 | 38.65 | 40.2 |

From the results shown in Table 5, it was confirmed that by using any of the above combinations of resist compositions, a hole-like resist pattern can be formed satisfactorily with a high level of resolution and minute dimensions.

Further, when the resist composition of Example 4 containing an acid-generator component having an anion moiety that included a bulky substituent (namely, the aforementioned acid generator (B13)), was used as the second resist composition, it was confirmed that a “CD₁₃₅ value relative to the average of CDₓ and CD_{y}” was large, as compared to the case where the resist composition of Comparative Example 5 was used, which did not contain the aforementioned acid generator (B13). From the above results, when using the resist composition of Example 4, it is evident that more rectangular-shaped holes were formed, as compared to the case where the resist composition of Comparative Example 5 was used. Because it is thought that this is a result of resolution faithful to irradiated light, it can be concluded that the resist composition of Example 4 exhibits a high level of resolution as compared to the resist composition of Comparative Example 5. It is presumed that such effects can be achieved because an acid-generator component having an anion moiety that includes a bulky substituent has a short diffusion length.

Furthermore, when the resist composition of Example 4 was used as the second resist composition, it was confirmed that a “CD₁₃₅ value relative to the average of CDₓ and CD_{y}” was large when the first resist composition (b) containing an acid-generator component having an anion moiety that included a bulky substituent was used as the first resist composition, as compared to the case where the first resist composition (a) was used, which did not contain an acid-generator component having an anion moiety that included a bulky substituent. From these results, it was confirmed that an even higher level of resolution can be achieved when an acid-generator component having an anion moiety that included a bulky substituent was used in both of the first and second resist compositions.

### Production of Resist Composition (3)

### Examples 5 to 12, Comparative Examples 6 to 12

The components shown in Table 6 were mixed together and dissolved to obtain positive resist compositions.

In Table 6, the reference characters indicate the following. Further, in Table 6, the values in brackets [ ] indicate the amount (in terms of parts by weight) of the component added.

TABLE 6

| | | | | After one day | | After one week | |
|---|---|---|---|---|---|---|---|
| | Component | Component | Component | | Room | | Room |
| | (A) | (B) | (S) | Refrigeration | temperature | Refrigeration | temperature |
| Ex. 5 | (A)-1 | (B)-10 | (S)-1 | A | A | A | A |
| | [100] | [12.0] | [2400] | | | | |
| Ex. 6 | (A)-1 | (B)-11 | (S)-1 | A | A | A | A |
| | [100] | [15.0] | [2400] | | | | |
| Ex. 7 | (A)-1 | (B)-12 | (S)-1 | A | A | A | A |
| | [100] | [15.5] | [2400] | | | | |
| Ex. 8 | (A)-1 | (B)-3 | (S)-1 | A | A | A | A |
| | [100] | [13.0] | [2400] | | | | |
| Ex. 9 | (A)-1 | (B)-3 | (S)-4 | A | A | A | A |
| | [100] | [13.0] | [2400] | | | | |
| Ex. 10 | (A)-1 | (B)-3 | (S)-5 | A | A | A | A |
| | [100] | [13.0] | [2400] | | | | |
| Ex. 11 | (A)-1 | (B)-3 | (S)-6 | A | A | A | A |
| | [100] | [13.0] | [2400] | | | | |
| Ex. 12 | (A)-1 | (B)-3 | (S)-7 | A | A | A | A |
| | [100] | [13.0] | [2400] | | | | |
| Comp. Ex. 6 | (A)-1 | (B)-3 | (S)-8 | B | A | B | A |
| | [100] | [13.0] | [2400] | | | | |
| Comp. Ex. 7 | (A)-1 | (B)-3 | (S)-9 | B | A | B | A |
| | [100] | [13.0] | [2400] | | | | |
| Comp. Ex. 8 | (A)-1 | (B)-3 | (S)-10 | B | A | B | B |
| | [100] | [13.0] | [2400] | | | | |
| Comp. Ex. 9 | (A)-1 | (B)-3 | (S)-11 | B | A | B | A |
| | [100] | [13.0] | [2400] | | | | |
| Comp. Ex. | (A)-1 | (B)-3 | (S)-12 | B | A | B | A |
| 10 | [100] | [13.0] | [2400] | | | | |
| Comp. Ex. | (A)-1 | (B)-3 | (S)-13 | B | A | B | A |
| 11 | [100] | [13.0] | [2400] | | | | |
| Comp. Ex. | (A)-1 | (B)-7 | (S)-1 | B | B | B | B |
| 12 | [100] | [9.8] | [2400] | | | | |

(A)-1: the aforementioned resin (A1-11-1).
(B)-3: the aforementioned acid generator (B11)
(B)-7: the aforementioned acid generator (B23)
(B)-10: the aforementioned acid generator (B14)
(B)-11: the aforementioned acid generator (B15)
(B)-12: the aforementioned acid generator (B16)
(S)-1: 1-butoxy-2-propanol (BP), boiling point: 170° C.
(S)-4: a mixed solvent of BP/IBA = 50/50 (weight ratio)
(S)-5: a mixed solvent of BP/2-heptanol (boiling point: 160° C.) = 50/50 (weight ratio)
(S)-6: a mixed solvent of BP/n-hexanol (boiling point: 156° C.) = 50/50 (weight ratio)
(S)-7: a mixed solvent of BP/cyclohexanol (boiling point: 161° C.) = 50/50 (weight ratio)
(S)-8: isobutanol (IBA) (boiling point: 108° C.)
(S)-9: 3,3-dimethyl-1-butanol (boiling point: 143° C.)
(S)-10: 2-hexanol (boiling point: 139° C.).
(S)-11: 3-methyl-1-butanol (boiling point: 130° C.)
(S)-12: 4-methyl-2-pentanol (boiling point: 132° C.).
(S)-13: n-butanol (boiling point: 117.6° C.)

<Evaluation of Storage Stability of Resist Composition>

Each of the resist compositions shown in Table 6 were adjusted to a resin concentration of 4% by weight, and was stored under the temperature conditions of refrigeration (−20° C.) and room temperature (23° C.). The storage stability was evaluated by visually observing the appearance of the liquid after one day and after one week of storage. The obtained evaluation results are shown in Table 6.

In the table, “A” indicates that the solutions appeared transparent and uniform after one day of storage or after one week of storage, whereas “B” indicates that precipitate formation was observed when the appearance of solutions were inspected after one day of storage or after one week of storage.

From the results shown in Table 6, with respect to the positive resist compositions of Examples 5 to 12 containing the component (B1) and an alcohol-based organic solvent having a boiling point of 150° C. or higher, it was confirmed that the appearance of the liquid was uniformly transparent under both temperature conditions, and the storage stability was excellent.

On the other hand, with respect to the positive resist compositions of Comparative Examples 6 to 11 containing an alcohol-based organic solvent having a boiling point lower than 150° C., it was confirmed that generation of deposit was observed under the temperature condition of refrigeration. Further, with respect to the positive resist composition of Comparative Example 12 containing an acid generator other than the component (B1) as the component (B), it was confirmed that generation of deposit was observed under the temperature conditions of refrigeration and room temperature. Therefore, it was confirmed that the positive resist compositions of Comparative Examples 6 to 12 exhibited poor storage stability.

### Production of Resist Composition (4)

### Examples 13 to 16, Comparative Example 1

The components shown in Table 7 were mixed together and dissolved to obtain positive resist compositions.

In Table 7, the reference characters are the same as defined above. Further, in Table 7, the values in brackets [ ] indicate the amount (in terms of parts by weight) of the component added.

The resist composition of Comparative Example 1 in Table 7 is the same as the resist composition of Comparative Example 1 in Table 2. The resist compositions of Examples 13 to 16 respectively contain the same components (A), (B) and (S) as in the resist compositions of Examples 5 to 8 in Table 6, and the mixing ratios of the component (A) to the component (B) are respectively the same.

TABLE 7

| | Component | Component | Component | Component | Component | Eop | CD |
|---|---|---|---|---|---|---|---|
| | (A) | (B) | (D) | (E) | (S) | (mJ/cm²) | (%) |
| Comp. Ex. 1 | (A)-1 | (B)-1 | (D)-1 | (E)-1 | (S)-1 | 30.5 | 77.1 |
| | [100] | [15.0] | [1.6] | [3.0] | [2800] | | |
| Ex. 13 | (A)-1 | (B)-10 | (D)-1 | (E)-1 | (S)-1 | 47.0 | 74.0 |
| | [100] | [12.0] | [1.6] | [3.0] | [2800] | | |
| Ex. 14 | (A)-1 | (B)-11 | (D)-1 | (E)-1 | (S)-1 | 42.5 | 74.1 |
| | [100] | [15.0] | [1.6] | [3.0] | [2800] | | |
| Ex. 15 | (A)-1 | (B)-12 | (D)-1 | (E)-1 | (S)-1 | 39.0 | 73.5 |
| | [100] | [15.5] | [0.15] | [0.35] | [2800] | | |
| Ex. 16 | (A)-1 | (B)-3 | (D)-1 | (E)-1 | (S)-1 | 47.0 | 72.1 |
| | [100] | [13.0] | [0.15] | [0.35] | [2800] | | |

<Evaluation of Lithography Properties (2)>

[Resolution and Sensitivity]

First, an organic antireflection film composition (product name: ARC29, manufactured by Brewer Science Ltd.) was applied to an 8-inch silicon wafer using a spinner, and the composition was then baked and dried on a hotplate at 205° C. for 60 seconds, thereby forming an organic antireflection film having a thickness of 82 nm.

Then, a positive resist composition indicated in Table 7 was applied to the antireflection film by spin coating, and was then prebaked (PAB) and dried on a hotplate at 120° C. for 60 seconds, thereby forming a resist film (first resist film) having a film thickness of 100 nm.

Subsequently, the resist film was selectively irradiated with an ArF excimer laser (193 nm) through a mask pattern, using an ArF exposure apparatus NSR-S302A (manufactured by Nikon Corporation, NA (numerical aperture)=0.60).

Thereafter, a post exposure bake (PEB) treatment was conducted at 90° C. for 60 seconds, followed by development for 30 seconds at 23° C. in a 2.38% by weight aqueous solution of tetramethylammonium hydroxide (TMAH). Then, the resist film was washed for 30 seconds with pure water, followed by drying by shaking.

As a result, in each of the examples, a line and space pattern (LS pattern) having a line width of 130 nm and a pitch of 260 nm was formed.

The optimum exposure dose (Eop, mJ/cm²) with which the pattern was formed, i.e., sensitivity, was determined. The results are shown in Table 7.

[Evaluation of Pattern Collapse]

LS patterns were formed in the same manner as described above, except that the Eop was varied, and the line width was measured just before the pattern collapsed. The change in size was calculated as the percentage (%) of the “line width of the pattern just before collapsing”, based on the “target line width (i.e., 130 nm)”. The results are indicated “CD (%)” in Table 7.

The smaller this “CD (%)” value is, the more resistant is the resist pattern to a pattern collapse.

From the results shown in Table 7, the positive resist compositions of Examples 13 to 16 according to the present invention excellent resistance to pattern collapse, as compared to the positive resist composition of Comparative Example 1. Therefore, it can be concluded that according to the resist composition of the present invention, a resist pattern can be obtained without pattern collapse or disappearance of the pattern even in a pattern formation with a minute target size.

While preferred embodiments of the invention have been described and illustrated above, it should be understood that these are exemplary of the invention and are not to be considered as limiting. Additions, omissions, substitutions, and other modifications can be made without departing from the spirit or scope of the present invention. Accordingly, the invention is not to be considered as being limited by the foregoing description, and is only limited by the scope of the appended claims.

What is claimed is:

1. A resist composition comprising: a base component (A) which exhibits changed solubility in an alkali developing solution under the action of acid; and an acid-generator component (B) which generates acid upon exposure; dissolved in an organic solvent (S),
the acid-generator component (B) comprising an acid generator (B1) consisting of a compound represented by general formula (b1) shown below, and
the organic solvent (S) comprising an alcohol-based organic solvent having a boiling point of at least 150° C.: 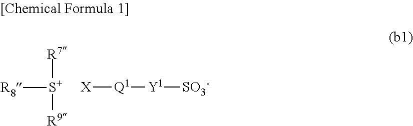
wherein R⁷″ to R⁹″ each independently represents an aryl group which may have a substituent or an alkyl group which may have a substituent, provided that at least one of R⁷″ to R⁹″ represents a substituted aryl group which has been substituted with a group represented by general formula (b1c-0) shown below, and two of R⁷″ to R⁹″ may be mutually bonded to form a ring with the sulfur atom; X represents a hydrocarbon group of 3 to 30 carbon atoms which may have a substituent; Q¹ represents a divalent linking group containing an oxygen atom; and Y¹ represents an alkylene group of 1 to 4 carbon atoms which may have a substituent or a fluorinated alkylene group of 1 to 4 carbon atoms which may have a substituent; and
[Chemical Formula 2]
—O—R⁷⁰ (b1c-0)
wherein R⁷⁰ represents an organic group.

2. The resist composition according to claim 1, wherein the group represented by general formula (b1c-0) is a group represented by general formula (b1c-0-1) shown below, a group represented by general formula (b1c-0-2) shown below or a group represented by general formula (b1c-0-3) shown below: 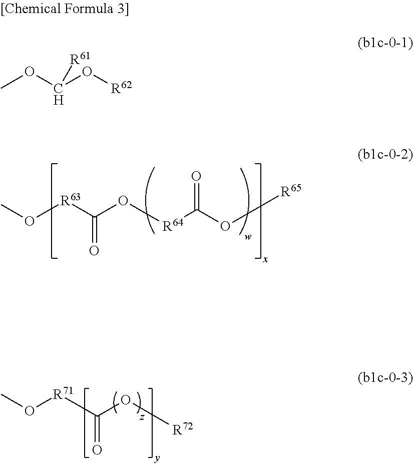
in general formula (b1c-0-1), R⁶¹ represents a hydrogen atom or a linear or branched alkyl group, and R⁶² represents an alkyl group, provided that R⁶¹ and R⁶² may be mutually bonded to form a ring structure; in general formula (b1c-0-2), each of R⁶³ and R⁶⁴ independently represents a linear or branched alkylene group, R⁶⁵ represents an acid dissociable group, w represents 0 or 1 and x represents 0 or 1; and in general formula (b1c-0-3), R⁷¹ represents a single bond or a divalent linking group, R⁷² represents a group that is not dissociable by the action of an acid, y represents 0 or 1 and z represents 0 or 1.

3. The resist composition according to claim 1, which is used as a second resist composition in a method of forming a resist pattern comprising: applying a positive resist composition as a first resist composition to a substrate to form a first resist film on the substrate; subjecting the first resist film to selective exposure and alkali developing to form a first resist pattern; applying the second resist composition to the substrate on which the first resist pattern is formed to form a second resist film; and subjecting the second resist film to selective exposure and alkali developing to form a resist pattern.

4. The resist composition according to claim 1, wherein the base component (A) comprises a base component (A1) which exhibits increased solubility in an alkali developing solution under action of acid.

5. The resist composition according to claim 4, wherein the resin component (A1) comprises a structural unit (a1) derived from an acrylate ester containing an acid dissociable, dissolution inhibiting group.

6. The resist composition according to claim 5, wherein the resin component (A1) further comprises a structural unit (a2) derived from an acrylate ester containing a lactone-containing cyclic group.

7. The resist composition according to claim 5, wherein the resin component (A1) further comprises a structural unit (a5) represented by general formula (a5-1) shown below: 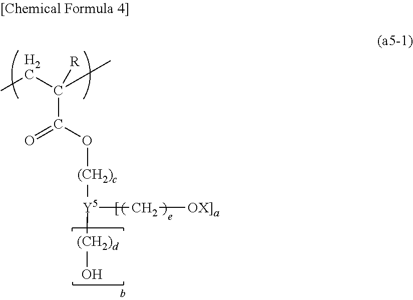
wherein R represents a hydrogen atom, an alkyl group of 1 to 5 carbon atoms or a halogenated alkyl group of 1 to 5 carbon atoms; Y⁵ represents an aliphatic hydrocarbon group which may have a substituent; Z represents a monovalent organic group; a represents an integer of 1 to 3, and b represents an integer of 0 to 2, provided that a+b=1 to 3; and each of c, d and e independently represents an integer of 0 to 3.

8. The resist composition according to claim 5, wherein the resin component (A1) further comprises a structural unit (a6) represented by general formula (a6-1) shown below: 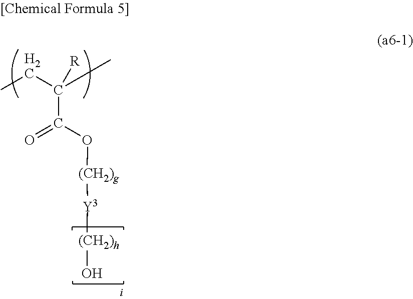
wherein R represents a hydrogen atom, an alkyl group of 1 to 5 carbon atoms or a halogenated alkyl group of 1 to 5 carbon atoms; Y³ represents an alkylene group or an aliphatic cyclic group; each of g and h independently represents an integer of 0 to 3; and i represents an integer of 1 to 3.

9. The resist composition according to claim 1, which further comprises a nitrogen-containing organic compound (D).

10. A method of forming a resist pattern comprising: applying a positive resist composition as a first resist composition to a substrate to form a first resist film on the substrate; subjecting the first resist film to selective exposure and alkali developing to form a first resist pattern; applying the resist composition of claim 1 as a second resist composition to the substrate on which the first resist pattern is formed to form a second resist film; and subjecting the second resist film to selective exposure and alkali developing to form a resist pattern.

11. A method of forming a resist pattern according to claim 10 comprising: applying a positive resist composition as a first resist composition on a substrate to form a first resist film on the substrate; subjecting the first resist film to selective exposure and alkali developing to form a first line and space resist pattern; applying the resist composition of claim 1 as a second resist composition on the substrate on which the first line and space resist pattern is formed to form a second resist film; and subjecting the second resist film to selective exposure at a position that intersects with the first line and space resist pattern and alkali developing, so as to form a resist pattern.
